(19) United States
(12) Patent Application Publication
(10) Pub. No.: US 2024/0292752 A1
(43) Pub. Date: Aug. 29, 2024

(54) Compound and Organic Light Emitting Device Comprising Same

(71) Applicant: LG Chem, Ltd., Seoul (KR)

(72) Inventors: Byeong Yun Lim, Daejeon (KR); Jaechol Lee, Daejeon (KR); Yongwook Kim, Daejeon (KR); Soyoung Yu, Daejeon (KR); Shin Sung Kim, Daejeon (KR); Young Kwang Kim, Daejeon (KR); Hyunju Choi, Daejeon (KR)

(73) Assignee: LG Chem, Ltd., Seoul (KR)

(21) Appl. No.: 18/565,302

(22) PCT Filed: Apr. 18, 2022
(86) PCT No.: PCT/KR2022/005520

§ 371 Date: Nov. 29, 2023

(30) Foreign Application Priority Data
Jun. 2, 2021 (KR) 10-2021-0071681

(51) Int. Cl. H10K 85/60; C07F 5/02; C09K 11/06; H10K 50/12

(52) U.S. Cl. CPC H10K 85/658; C07F 5/027; C09K 11/06; C09K 2211/1018; H10K 50/12

(57) ABSTRACT

A compound represented by the following Chemical Formula 1 and an organic light emitting device including the same are described:

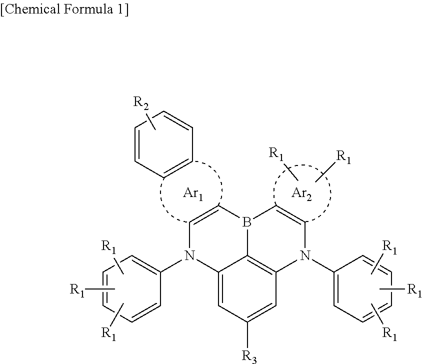

wherein all the variables are described herein.

### CROSS-REFERENCE TO RELATED APPLICATION(S)

This application is a national stage entry under 35 U.S.C. § 371 of International Application No. PCT/KR2022/005520 filed on Apr. 18, 2022, which claims priority from Korean Patent Application No. 10-2021-0071681 filed on Jun. 2, 2021, all the disclosures of which are incorporated by reference herein in their entirety.

### TECHNICAL FIELD

The present disclosure relates to a novel compound and an organic light emitting device including the same.

### BACKGROUND OF ART

In general, an organic light emitting phenomenon refers to a phenomenon where electric energy is converted into light energy by using an organic material. The organic light emitting device using the organic light emitting phenomenon has characteristics such as a wide viewing angle, an excellent contrast, a fast response time, and an excellent luminance, driving voltage and response speed, and thus many studies have proceeded.

The organic light emitting device generally has a structure which comprises an anode, a cathode, and an organic material layer interposed between the anode and the cathode. The organic material layer frequently has a multilayered structure that comprises different materials in order to enhance efficiency and stability of the organic light emitting device, and for example, the organic material layer may be formed of a hole injection layer, a hole transport layer, a light emitting layer, an electron transport layer, an electron injection layer, and the like. In the structure of the organic light emitting device, if a voltage is applied between two electrodes, the holes are injected from an anode into the organic material layer and the electrons are injected from the cathode into the organic material layer, and when the injected holes and electrons meet each other, an exciton is formed, and light is emitted when the exciton falls to a ground state again.

There is a continuing need for the development of new materials for the organic materials used in the organic light emitting devices as described above.

Meanwhile, in recent years, an organic light emitting device prepared using a solution process, particularly an inkjet process, instead of a conventional deposition process has been developed in order to reduce process costs. In the early days, it was attempted to develop an organic light emitting device in which all organic light emitting device layers were coated with a solution process, but there was a limitation in the development with the current technology.

Accordingly, in the present disclosure, there is provided a novel material for an organic light emitting device that can be used in an organic light emitting device and can be used in a solution process at the same time.

### PRIOR ART LITERATURE

### Patent Literature

(Patent Literature 0001) Korean Unexamined Patent Publication No. 10-2000-0051826

### DETAILED DESCRIPTION

### Technical Problem

The present disclosure relates to a novel compound and an organic light emitting device including the same.

### Technical Solution

In the present disclosure, there is provided a compound represented by the following Chemical Formula 1:

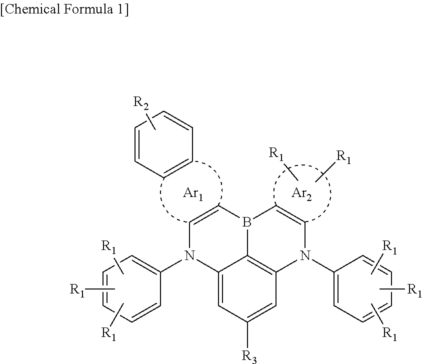

in Chemical Formula 1,
Ar₁ is furan, or thiophene, which is fused with two adjacent rings,
Ar₂ is benzene, benzofuran, or benzothiophene, which is fused with an adjacent ring,
each R₁ is independently not present, or deuterium, a substituted or unsubstituted C₁₋₆₀ alkyl, or a substituted or unsubstituted C₆₋₆₀ aryl, or two adjacent R₁s are combined to form —O—(CH₂)ₘ—O—, wherein m is an integer of 1 to 4;
R₂ is not present, deuterium, or a substituted or unsubstituted C₁₋₆₀ alkyl, and
R₃ is hydrogen, deuterium, or a substituted or unsubstituted C₁₋₆₀ alkyl,
provided that the Chemical Formula 1 comprises at least one —O—(CH₂)ₘ—O-formed by combining two adjacent R₁s.

In addition, there is provided an organic light emitting device including: a first electrode; a second electrode that is provided opposite to the first electrode; and one or more organic material layers that are provided between the first electrode and the second electrode, wherein at least one layer of the organic material layers includes the compound represented by the Chemical Formula 1.

### Advantageous Effects

The compound represented by the Chemical Formula 1 may be used as a material for an organic material layer of an organic light emitting device, may be used in a solution process, and may improve efficiency, low driving voltage, and/or lifespan of the organic light emitting device.

### BRIEF DESCRIPTION OF THE DRAWINGS

FIG. 1 shows an example of an organic light emitting device including a substrate 1, an anode 2, a light emitting layer 3, and a cathode 4.

FIG. 2 shows an example of an organic light emitting device including a substrate 1, an anode 2, a hole injection layer 5, a hole transport layer 6, a light emitting layer 7, an electron injection and transport layer 8, and a cathode 4.

### DETAILED DESCRIPTION OF THE EMBODIMENTS

Hereinafter, embodiments of the present disclosure will be described in more detail to facilitate understanding of the disclosure.

### DEFINITION OF TERMS

As used herein, the notation

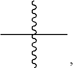

or [symbol] means a bond linked to another substituent group.

As used herein, the term “substituted or unsubstituted” means being substituted with one or more substituents selected from the group consisting of deuterium; a halogen group; a cyano group; a nitro group; a hydroxyl group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; and heteroaryl containing at least one of N, O or S atoms, or being substituted with a substituent in which two or more substituents of the above-exemplified substituents are connected, or being unsubstituted. For example, “a substituent in which two or more substituents are connected” may be a biphenyl group. Namely, a biphenyl group may be an aryl group, or it may also be interpreted as a substituent in which two phenyl groups are connected.

In the present disclosure, the carbon number of a carbonyl group is not particularly limited, but is preferably 1 to 40. Specifically, the carbonyl group may be a compound having the following structural formulae, but is not limited thereto.

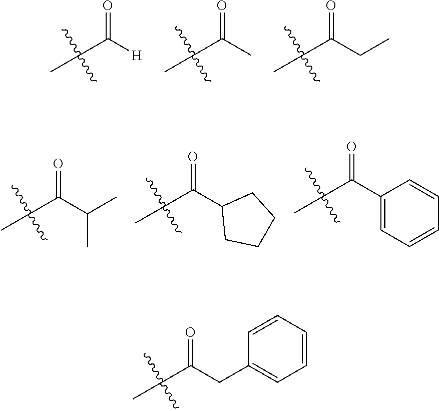

In the present disclosure, an ester group may have a structure in which oxygen of the ester group is substituted by a straight-chain, branched-chain, or cyclic alkyl group having 1 to 25 carbon atoms, or an aryl group having 6 to 25 carbon atoms. Specifically, the ester group may be a compound having the following structural formulae, but is not limited thereto.

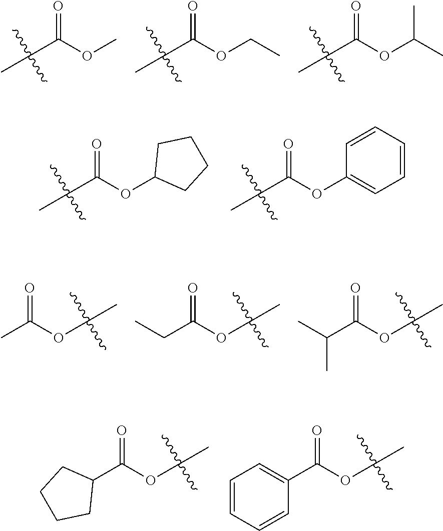

In the present disclosure, the carbon number of an imide group is not particularly limited, but is preferably 1 to 25. Specifically, the imide group may be a compound having the following structural formulae, but is not limited thereto.

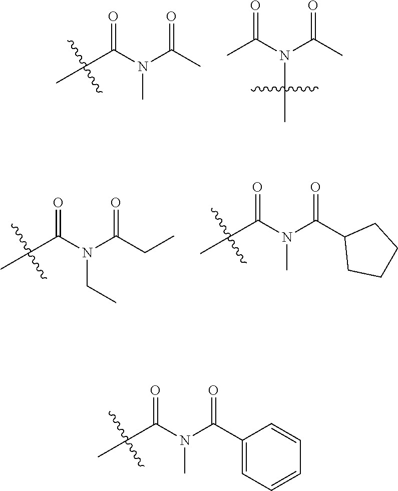

In the present disclosure, a silyl group specifically includes a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but is not limited thereto.

In the present disclosure, a boron group specifically includes a trimethylboron group, a triethylboron group, a t-butyldimethylboron group, a triphenylboron group, a phenylboron group, and the like, but is not limited thereto.

In the present disclosure, examples of a halogen group include fluorine, chlorine, bromine, or iodine.

In the present disclosure, the alkyl group may be straight-chain, or branched-chain, and the carbon number thereof is not particularly limited, but is preferably 1 to 40. According to one embodiment, the carbon number of the alkyl group is 1 to 20. According to another embodiment, the carbon number of the alkyl group is 1 to 10. According to another embodiment, the carbon number of the alkyl group is 1 to 6. Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, and the like, but are not limited thereto.

In the present disclosure, the alkenyl group may be straight-chain or branched-chain, and the carbon number thereof is not particularly limited, but is preferably 2 to 40. According to one embodiment, the carbon number of the alkenyl group is 2 to 20. According to another embodiment, the carbon number of the alkenyl group is 2 to 10. According to another embodiment, the carbon number of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present disclosure, a cycloalkyl group is not particularly limited, but the carbon number thereof is preferably 3 to 60. According to one embodiment, the carbon number of the cycloalkyl group is 3 to 30. According to another embodiment, the carbon number of the cycloalkyl group is 3 to 20. According to another embodiment, the carbon number of the cycloalkyl group is 3 to 6. Specific examples thereof include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

In the present disclosure, an aryl group is not particularly limited, but the carbon number thereof is preferably 6 to 60, and it may be a monocyclic aryl group or a polycyclic aryl group. According to one embodiment, the carbon number of the aryl group is 6 to 30. According to one embodiment, the carbon number of the aryl group is 6 to 20. The monocyclic aryl group includes a phenyl group, a biphenyl group, a terphenyl group and the like, but is not limited thereto. The polycyclic aryl group includes a naphthyl group, an anthracenyl group, a phenanthrenyl group, a pyrenyl group, a perylenyl group, a chrysenyl group, a fluorenyl group or the like, but is not limited thereto.

In the present disclosure, a fluorenyl group may be substituted, and two substituents may be bonded to each other to form a spiro structure. In the case where the fluorenyl group is substituted,

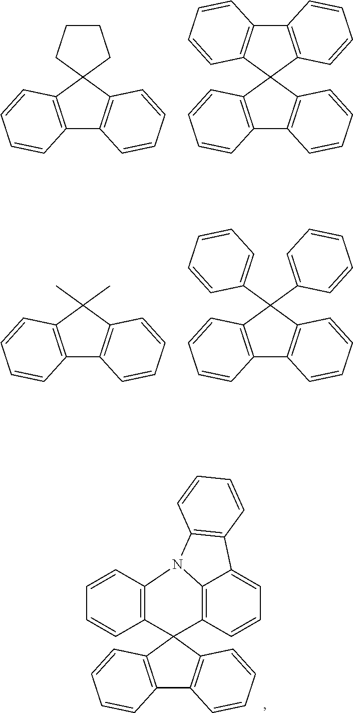

and the like can be formed. However, the structure is not limited thereto.

In the present disclosure, heteroaryl is a heteroaryl containing at least one heteroatom of O, N, Si or S as a heterogeneous element, and the carbon number thereof is not particularly limited, but is preferably 2 to 60. Examples of the heteroaryl include xanthene, thioxanthene, a thiophene group, a furan group, a pyrrole group, an imidazole group, a thiazole group, an oxazol group, an oxadiazol group, a triazol group, a pyridyl group, a bipyridyl group, a pyrimidyl group, a triazine group, an acridyl group, a pyridazine group, a pyrazinyl group, a quinolinyl group, a quinazoline group, a quinoxalinyl group, a phthalazinyl group, a pyridopyrimidinyl group, a pyridopyrazinyl group, a pyrazinopyrazinyl group, an isoquinoline group, an indole group, a carbazole group, a benzoxazole group, a benzoimidazole group, a benzothiazol group, a benzocarbazole group, a benzothiophene group, a dibenzothiophene group, a benzofuranyl group, a phenanthroline group, an isoxazolyl group, a thiadiazolyl group, a phenothiazinyl group, a dibenzofuranyl group, and the like, but are not limited thereto.

In the present disclosure, the aryl group in the aralkyl group, the aralkenyl group, the alkylaryl group, the arylamine group and the arylsilyl group is the same as the aforementioned examples of the aryl group. In the present disclosure, the alkyl group in the aralkyl group, the alkylaryl group and the alkylamine group is the same as the aforementioned examples of the alkyl group. In the present disclosure, the heteroaryl in the heteroarylamine can apply the aforementioned description of the heteroaryl. In the present disclosure, the alkenyl group in the aralkenyl group is the same as the aforementioned examples of the alkenyl group. In the present disclosure, the aforementioned description of the aryl group may be applied except that the arylene is a divalent group. In the present disclosure, the aforementioned description of the heteroaryl can be applied except that the heteroarylene is a divalent group. In the present disclosure, the aforementioned description of the aryl group or cycloalkyl group can be applied except that the hydrocarbon ring is not a monovalent group but formed by combining two substituent groups. In the present disclosure, the aforementioned description of the heteroaryl can be applied, except that the heterocycle is not a monovalent group but formed by combining two substituent groups.

### (Compound)

In the present disclosure, there is provided a compound represented by the Chemical Formula 1.

Preferably, the Chemical Formula 1 is represented by any one of the following Chemical Formulae 1-1 to 1-4 depending on the fused position of Ar₁:

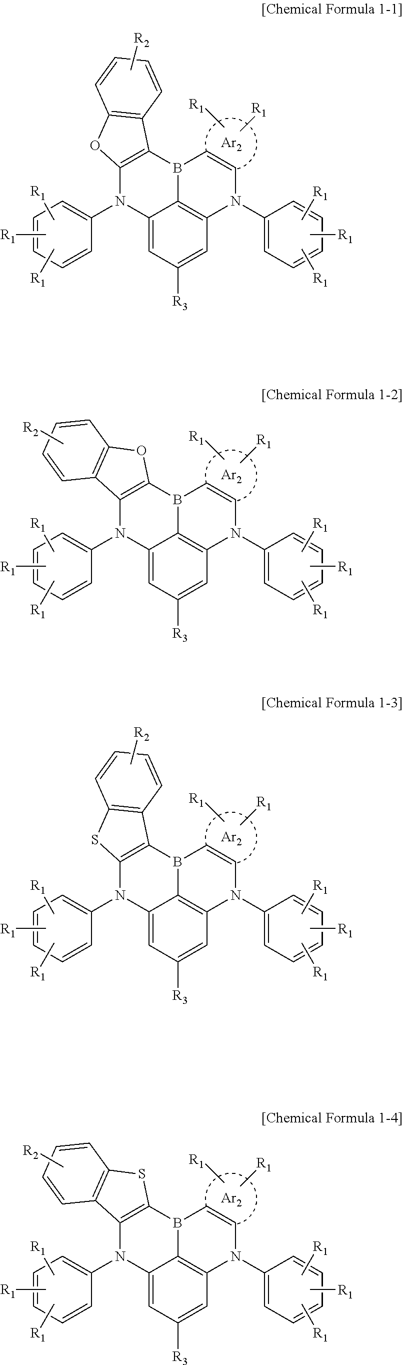

in the Chemical Formulae 1-1 to 1-4,
Ar₂ and R₁ to R₃ are as defined above.

Preferably, the Chemical Formula 1 is represented by any one of the following Chemical Formulae 1-5 to 1-9 depending on the fused position of Ar₂:

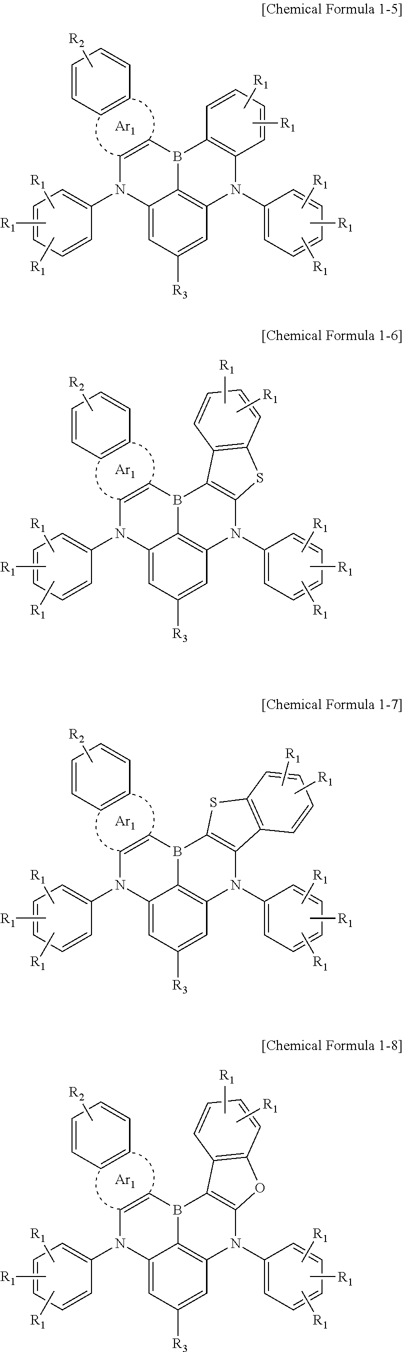

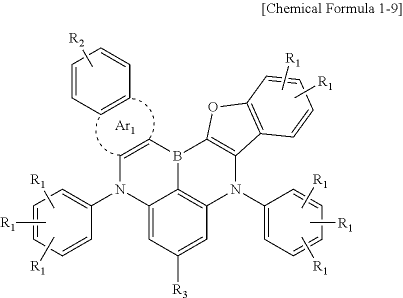

in the Chemical Formulae 1-5 to 1-9,
Ar₁ and R₁ to R₃ are as defined above.

Preferably, each R₁ is independently not present, or deuterium, C₁₋₁₀ alkyl, or C₆₋₂₀ aryl, or two adjacent R₁s are combined to form

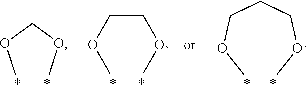

Preferably, each R₁ is independently not present, or deuterium, methyl, ethyl, propyl, isopropyl, butyl, isobutyl, tertbutyl, or phenyl, or two adjacent R₁s are combined to form

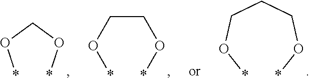

Preferably, R₂ is not present, or deuterium, or C₁₋₁₀ alkyl.

Preferably, R₂ is not present, or deuterium, methyl, ethyl, propyl, isopropyl, butyl, isobutyl, or tertbutyl.

Preferably, R₃ is hydrogen, deuterium, or C₁₋₁₀ alkyl.

Preferably, R₃ is hydrogen, deuterium, methyl, ethyl, propyl, isopropyl, butyl, isobutyl, or tertbutyl.

Representative examples of the compound represented by the Chemical Formula 1 are as follows:

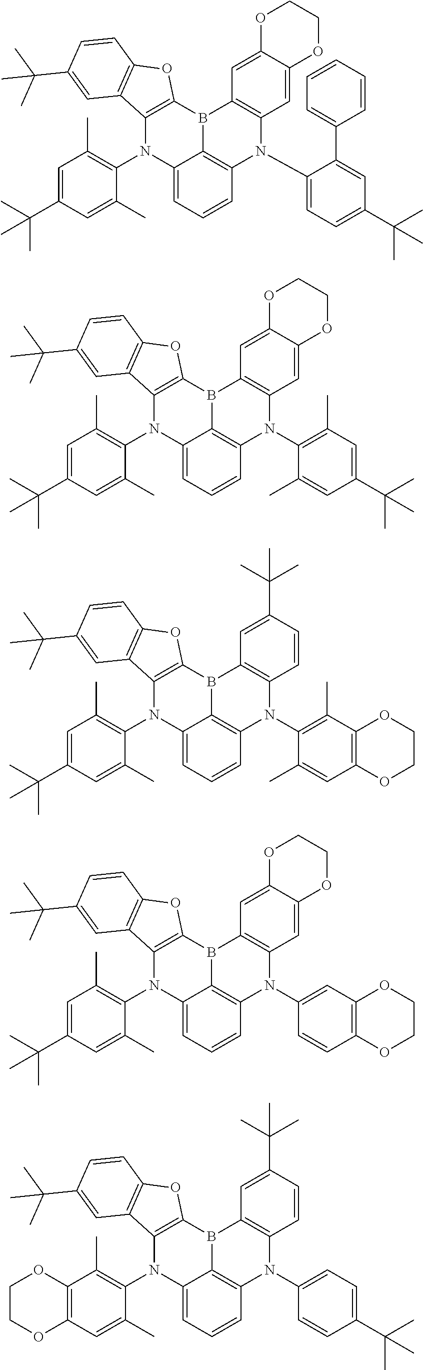

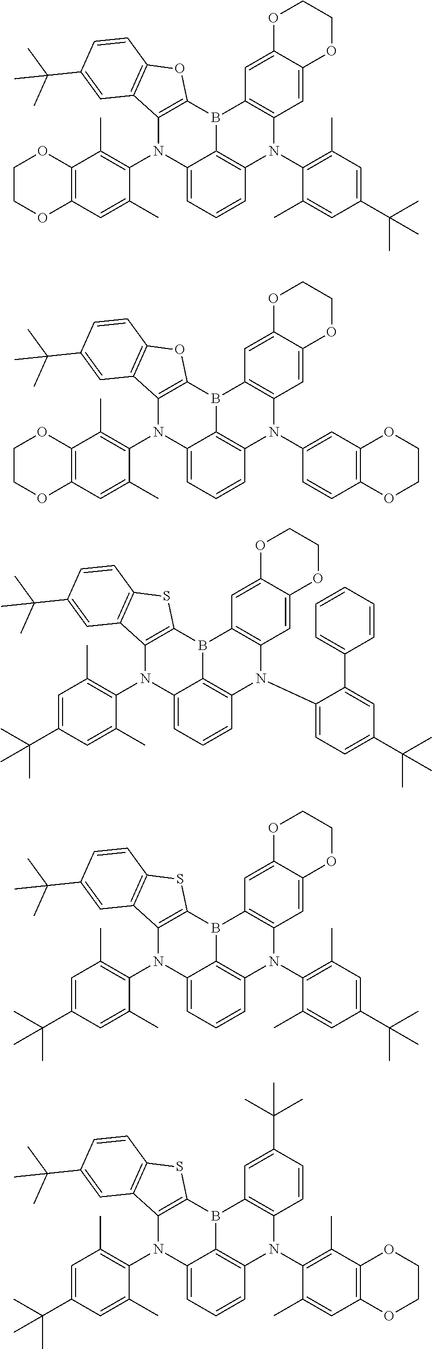

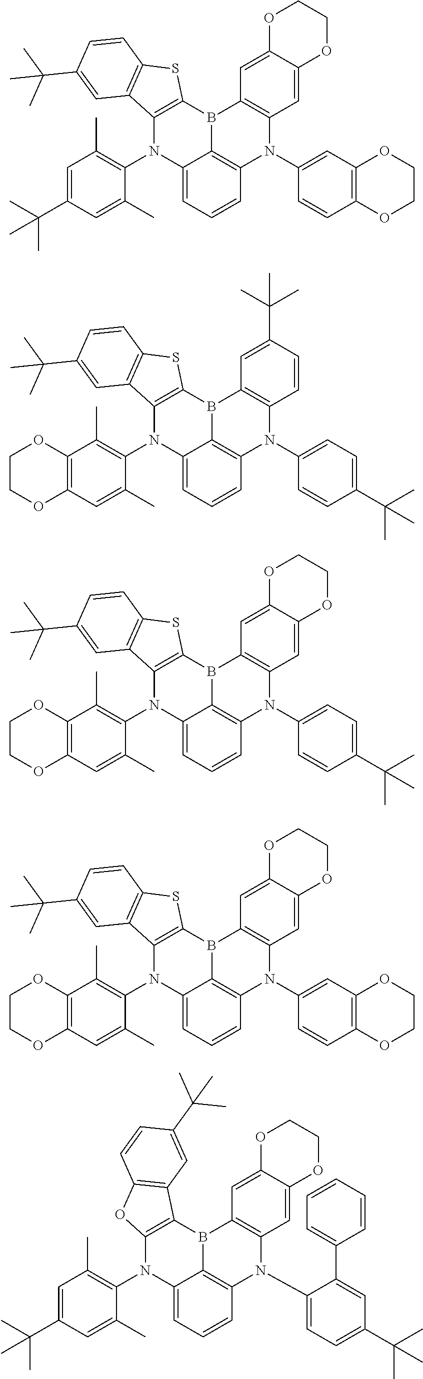

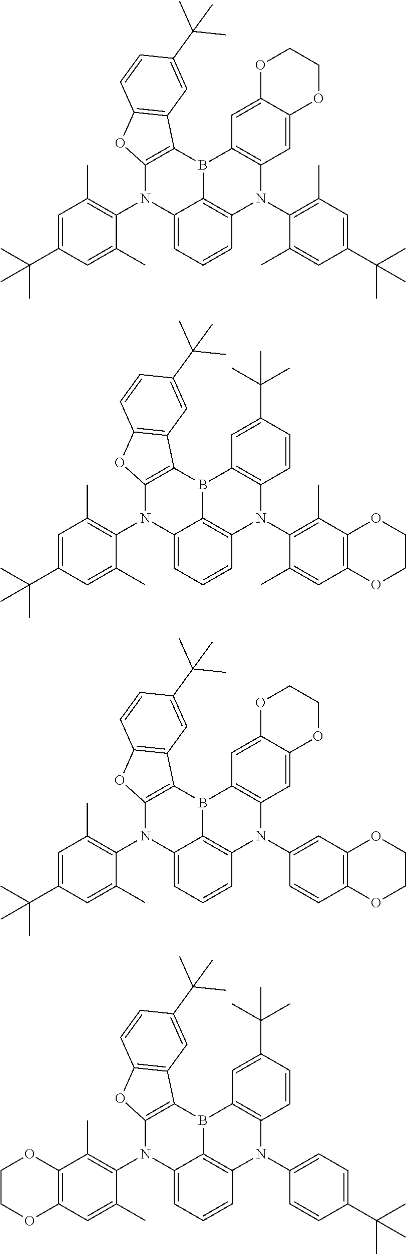

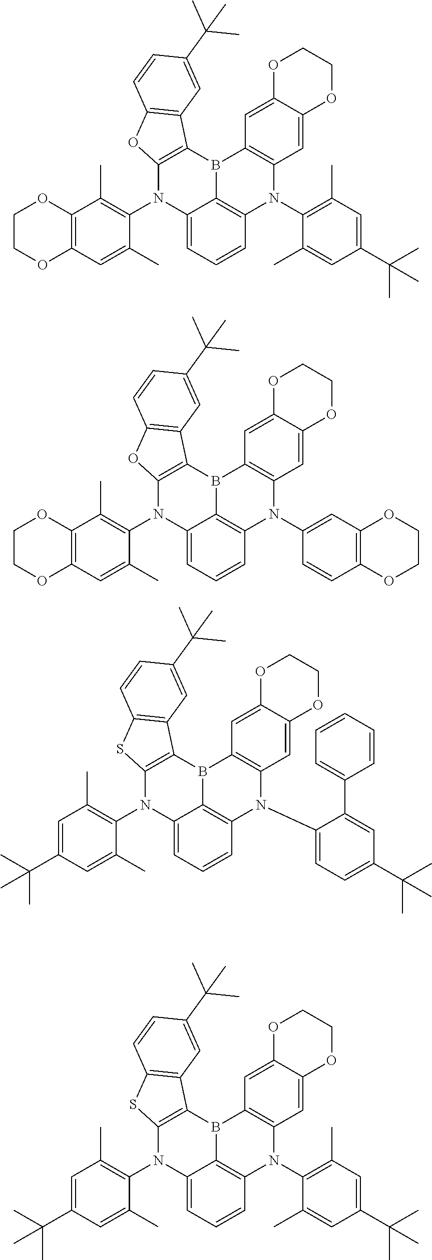

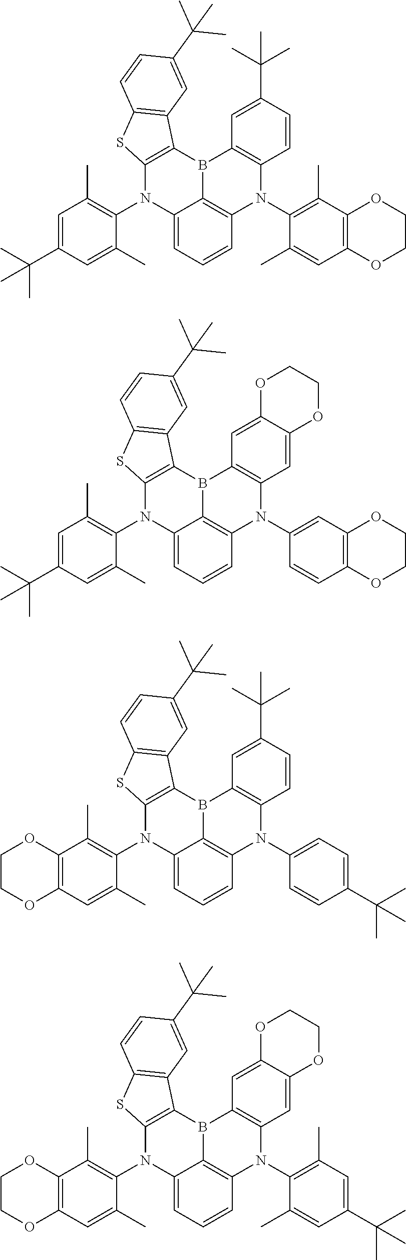 [SMILES: Cc1cc(C(C)(C)C)cc(C)c1N1c2cccc3c2B(c2cc(C(C)(C)C)ccc2N3c2c(C)cc3c(c2C)OCCO3)c2c1sc1ccc(C(C)(C)C)cc21 ; Cc1cc(C(C)(C)C)cc(C)c1N1c2cccc3c2B(c2cc4c(cc2N3c2ccc3c(c2)OCCO3)OCCO4)c2c1sc1ccc(C(C)(C)C)cc21 ; Cc1cc2c(c(C)c1N1c3cccc4c3B(c3cc(C(C)(C)C)ccc3N4c3ccc(C(C)(C)C)cc3)c3c1sc1ccc(C(C)(C)C)cc31)OCCO2 ; Cc1cc(C(C)(C)C)cc(C)c1N1c2cc3c(cc2B2c4c1cccc4N(c1c(C)cc4c(c1C)OCCO4)c1sc4ccc(C(C)(C)C)cc4c12)OCCO3]

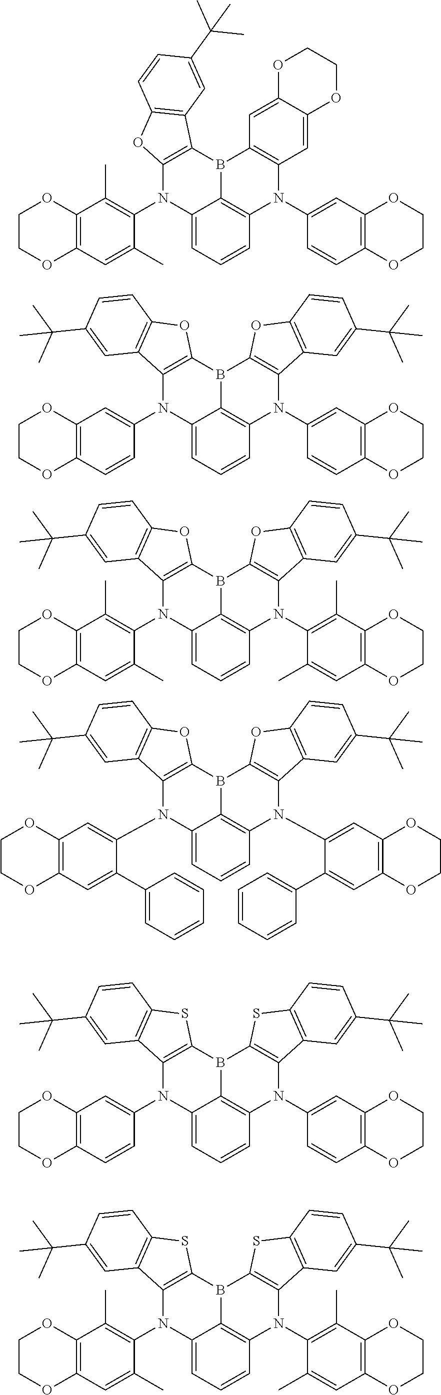

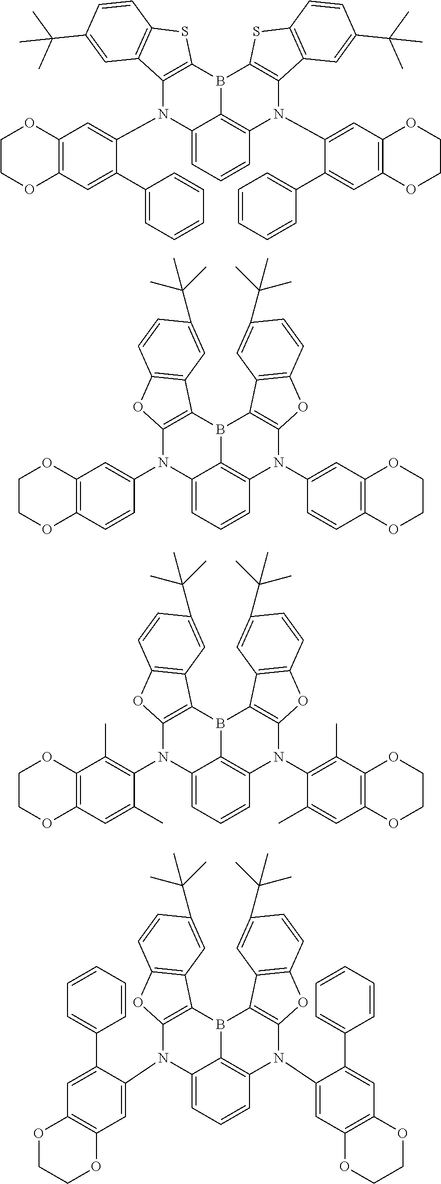

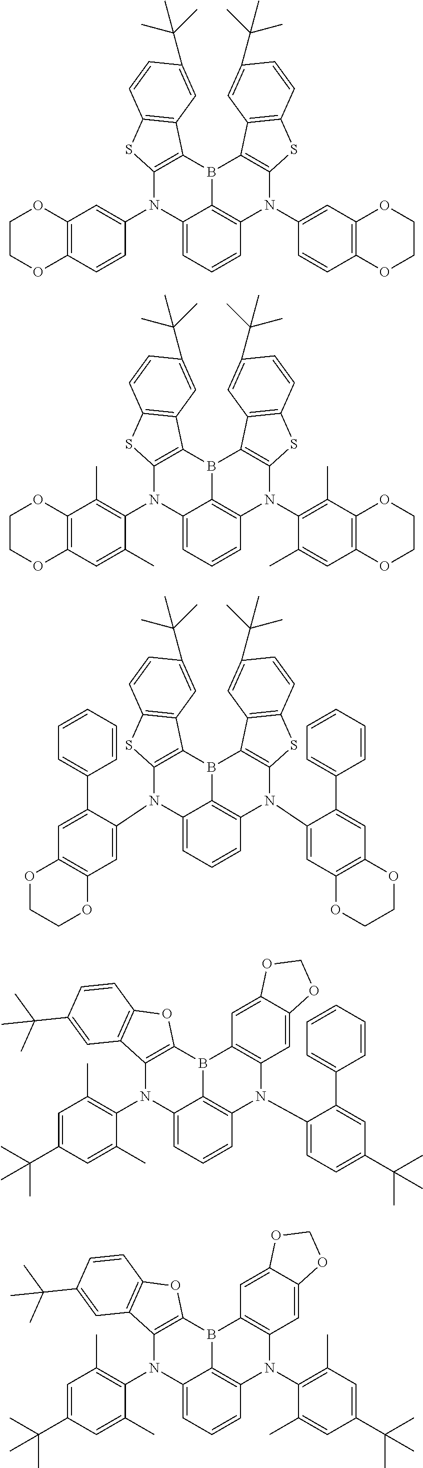

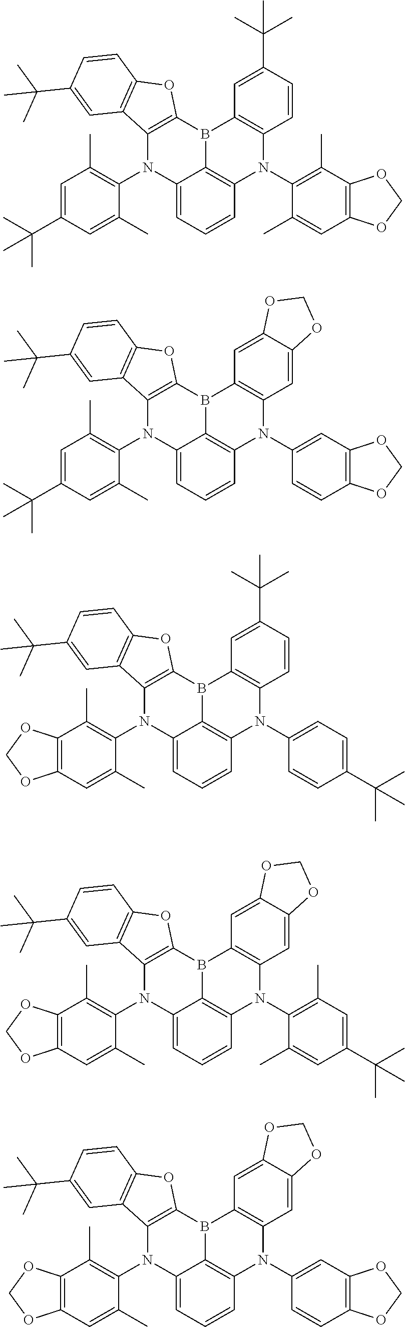

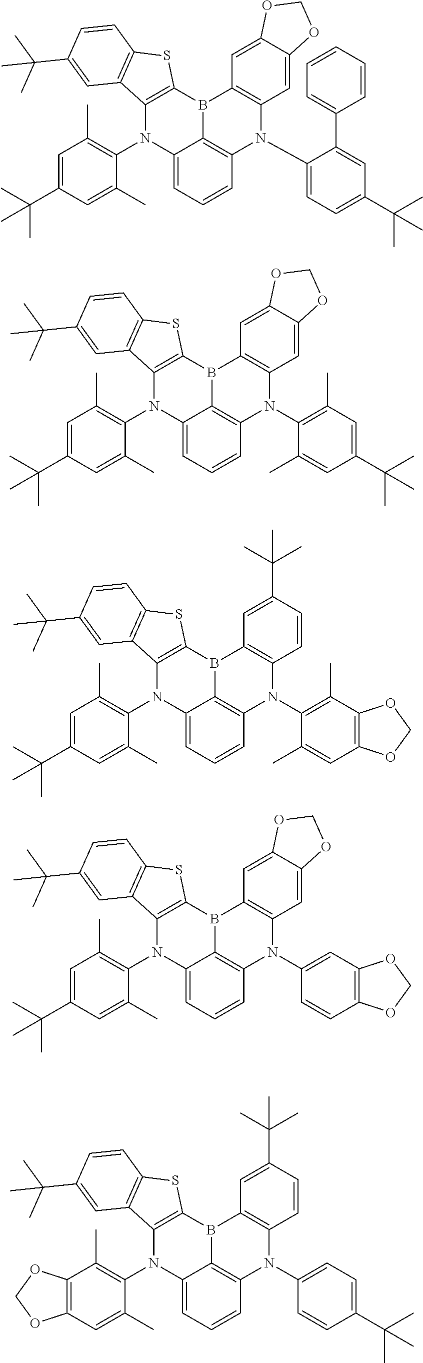

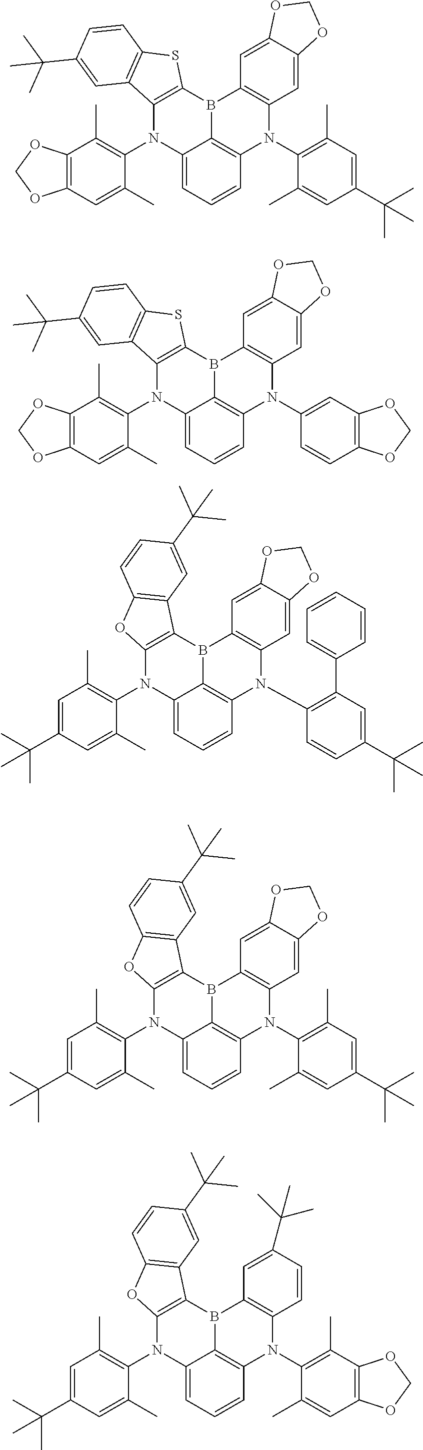

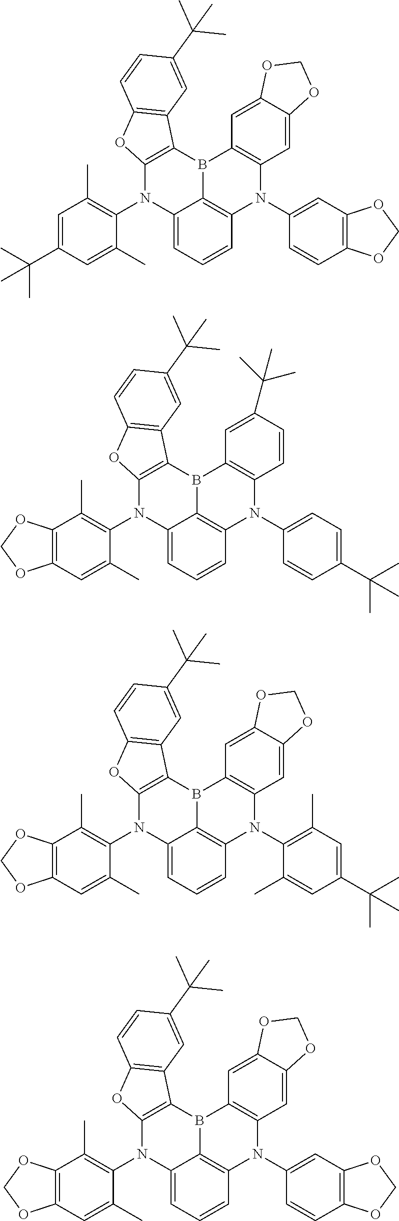 [SMILES: Cc1cc(C(C)(C)C)cc(C)c1N1c2cccc3c2B(c2cc4c(cc2N3c2ccc3c(c2)OCO3)OCO4)c2c1oc1ccc(C(C)(C)C)cc21 ; Cc1cc2c(c(C)c1N1c3cccc4c3B(c3cc(C(C)(C)C)ccc3N4c3ccc(C(C)(C)C)cc3)c3c1oc1ccc(C(C)(C)C)cc31)OCO2 ; Cc1cc(C(C)(C)C)cc(C)c1N1c2cc3c(cc2B2c4c1cccc4N(c1c(C)cc4c(c1C)OCO4)c1oc4ccc(C(C)(C)C)cc4c12)OCO3 ; Cc1cc2c(c(C)c1N1c3cccc4c3B(c3cc5c(cc3N4c3ccc4c(c3)OCO4)OCO5)c3c1oc1ccc(C(C)(C)C)cc31)OCO2]

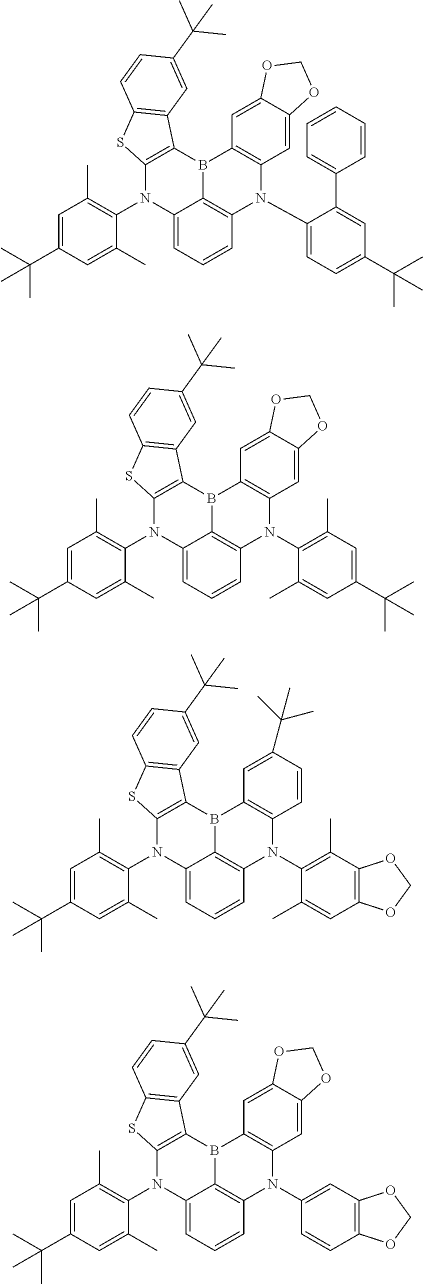

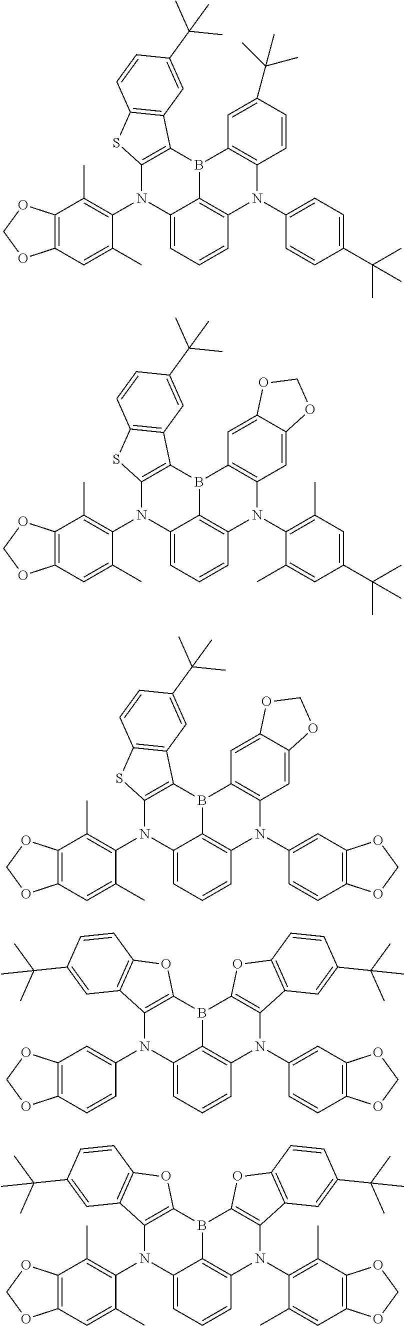

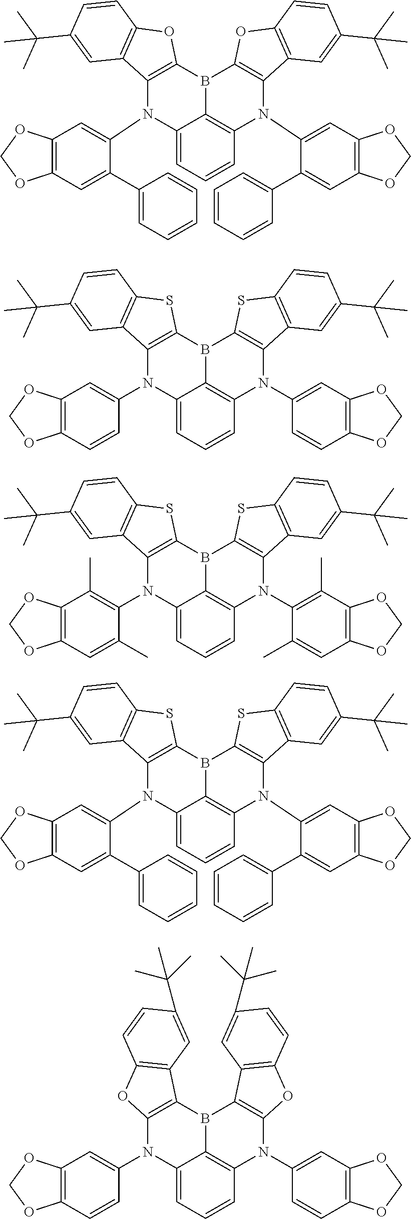

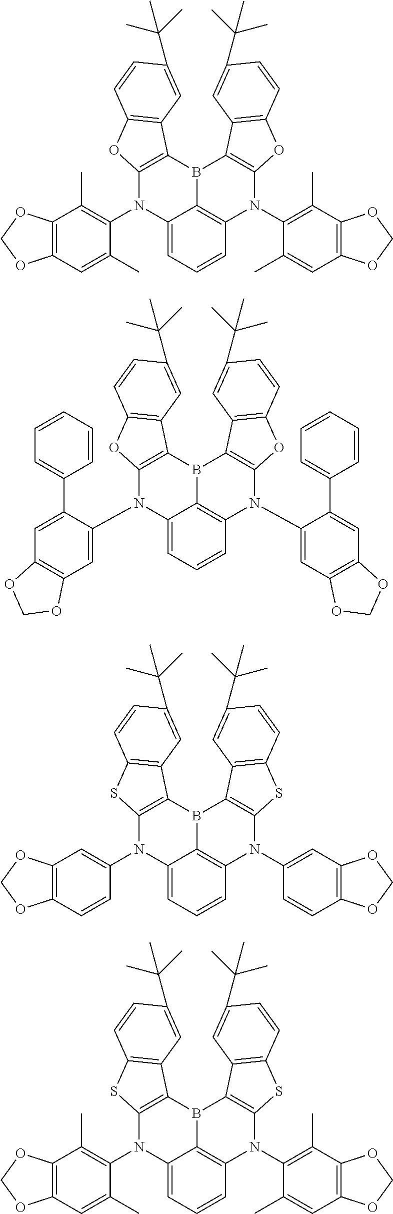

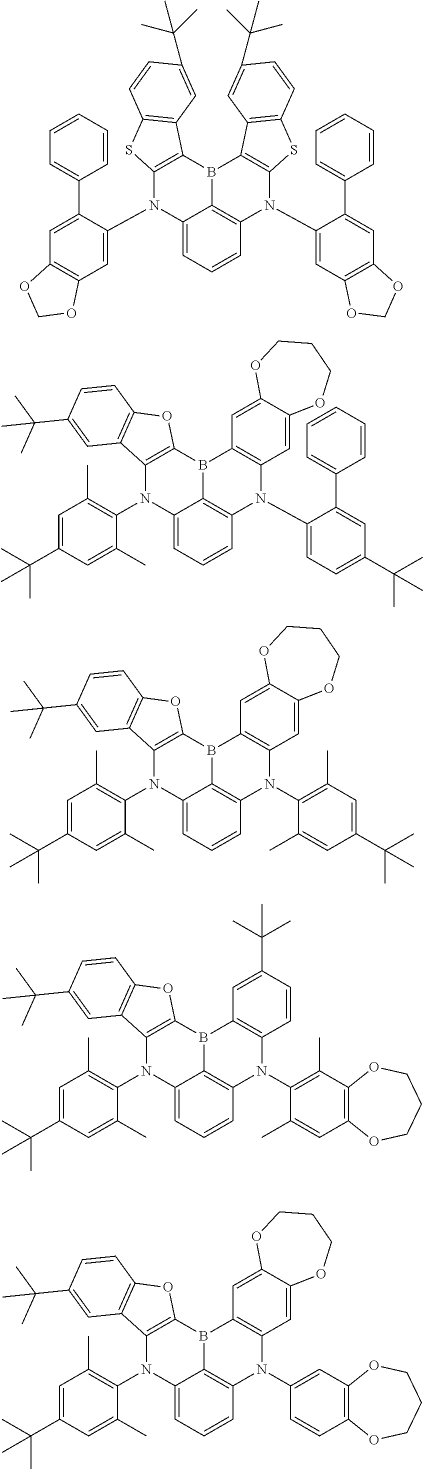

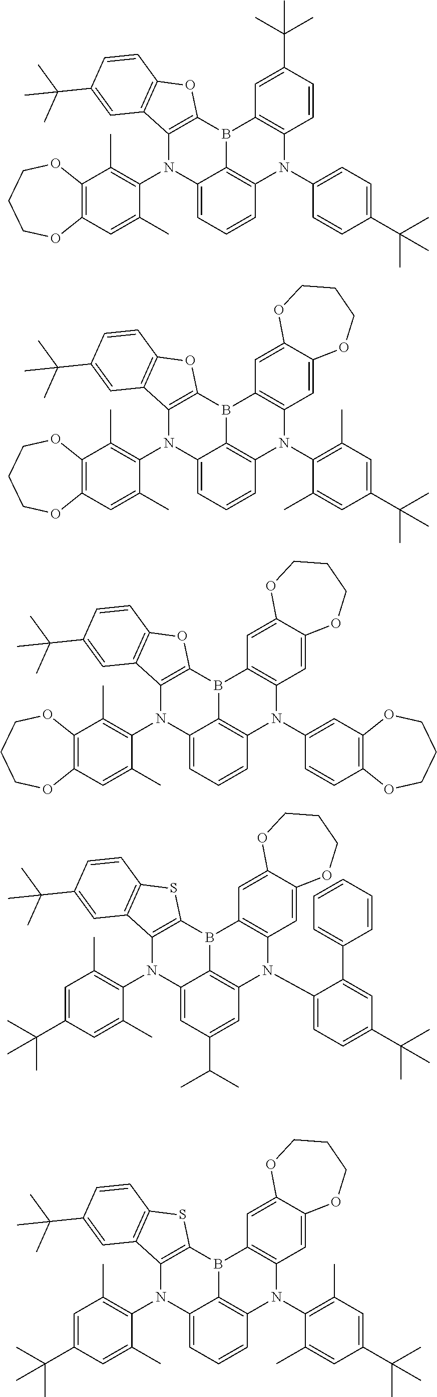

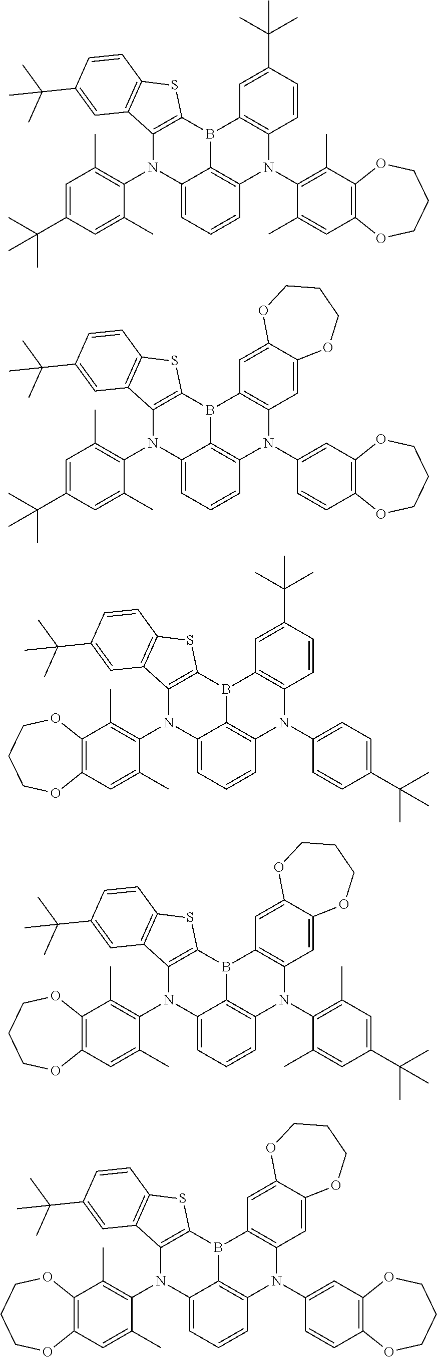

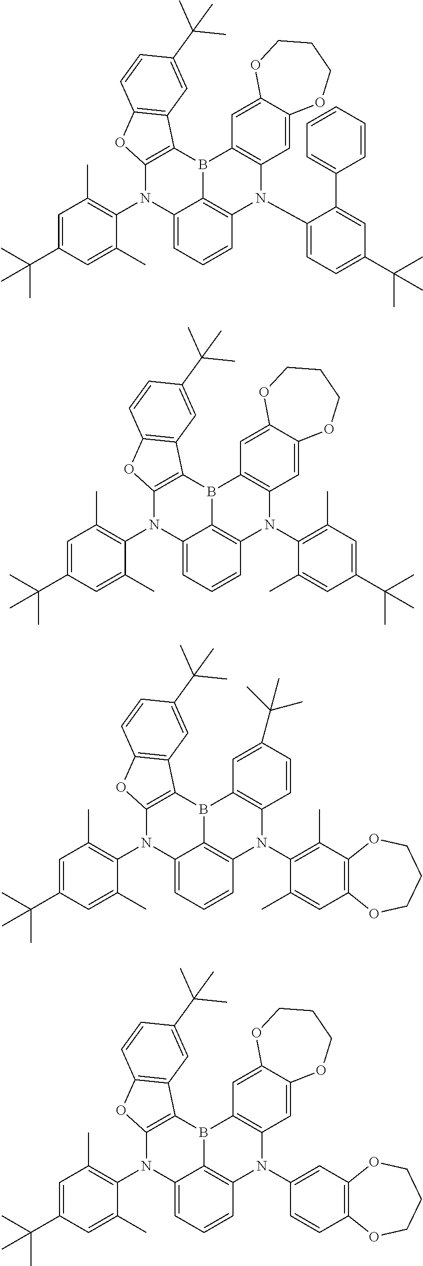

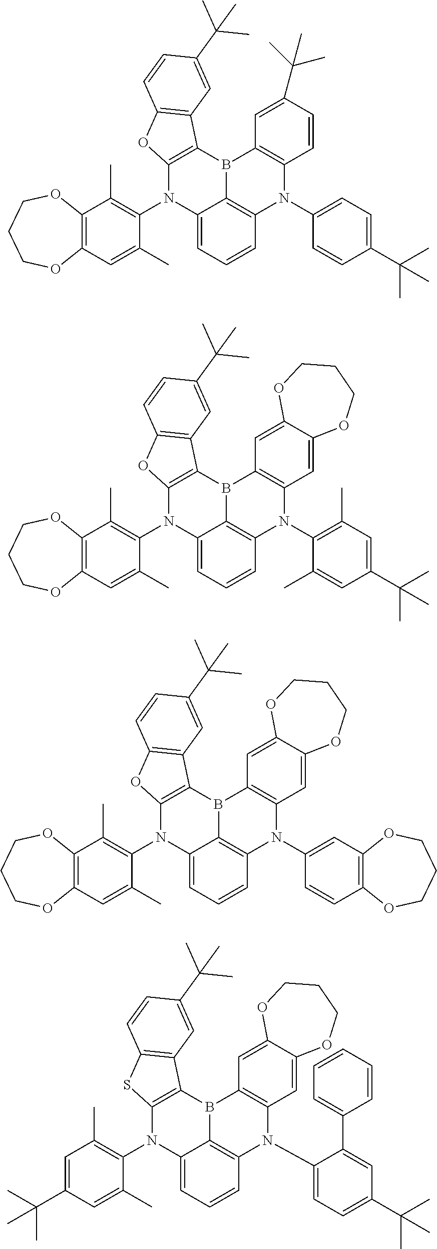

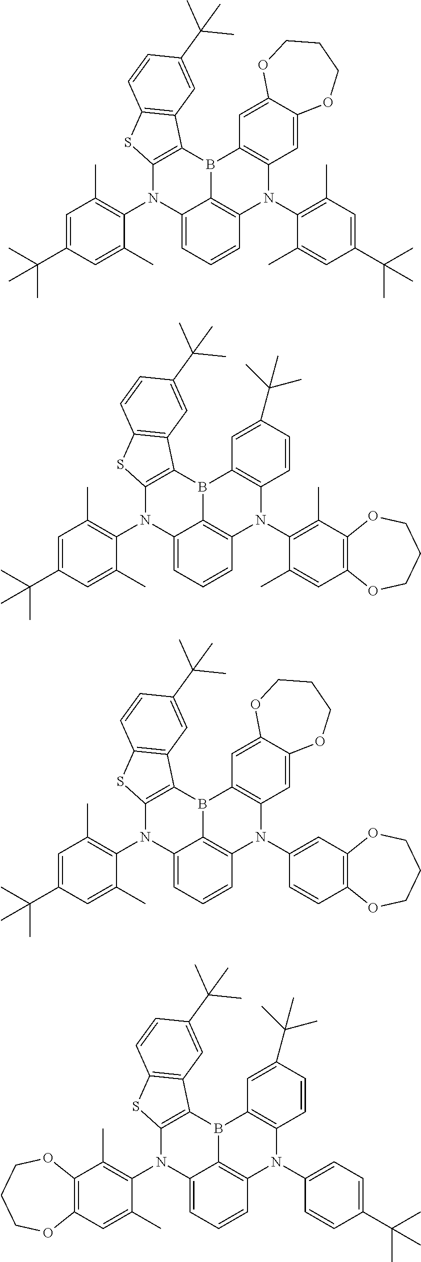

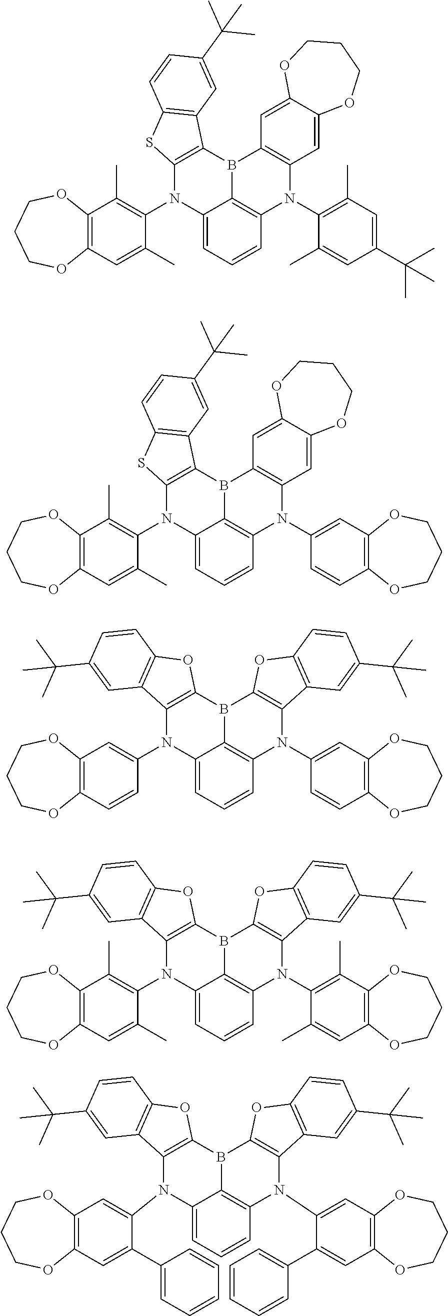

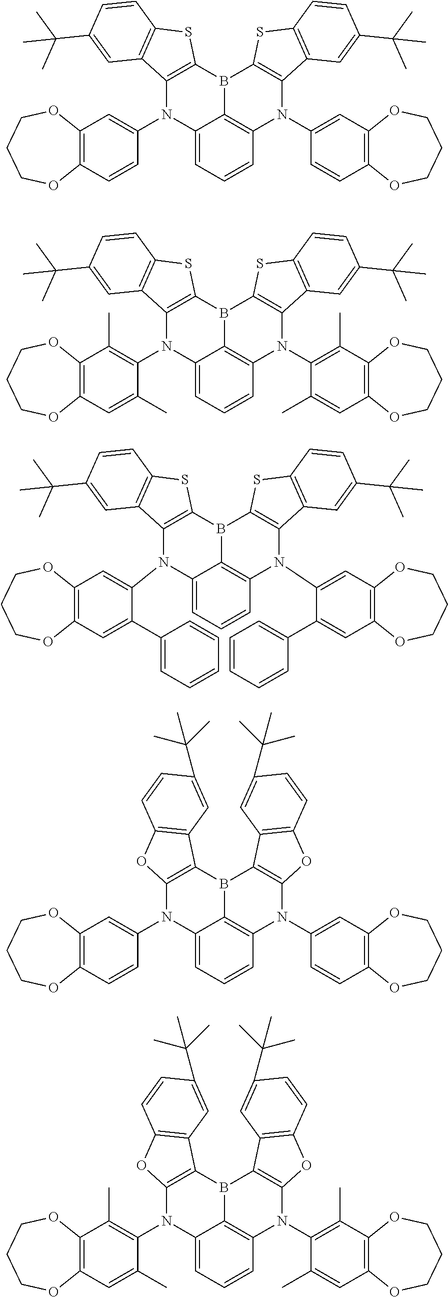

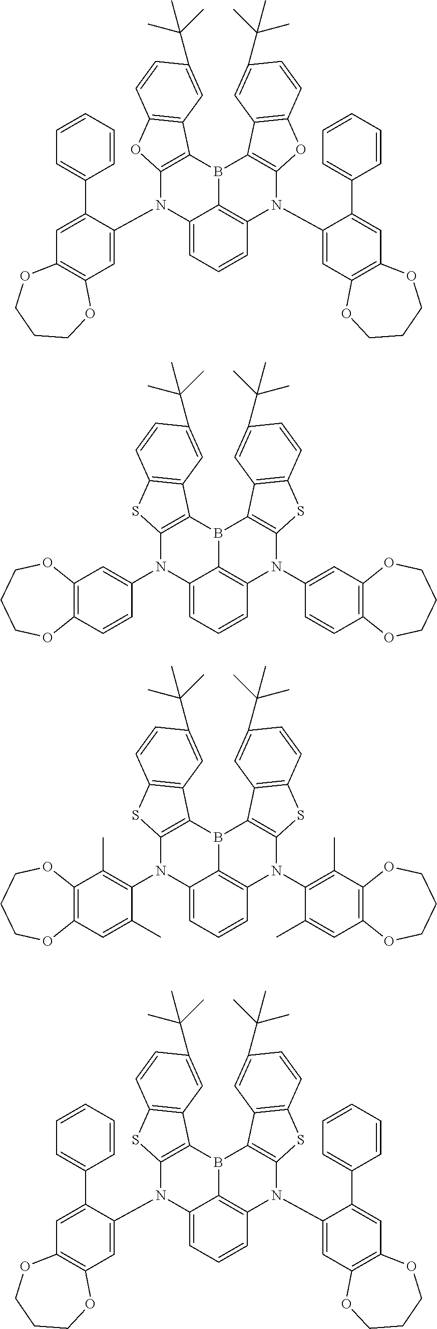

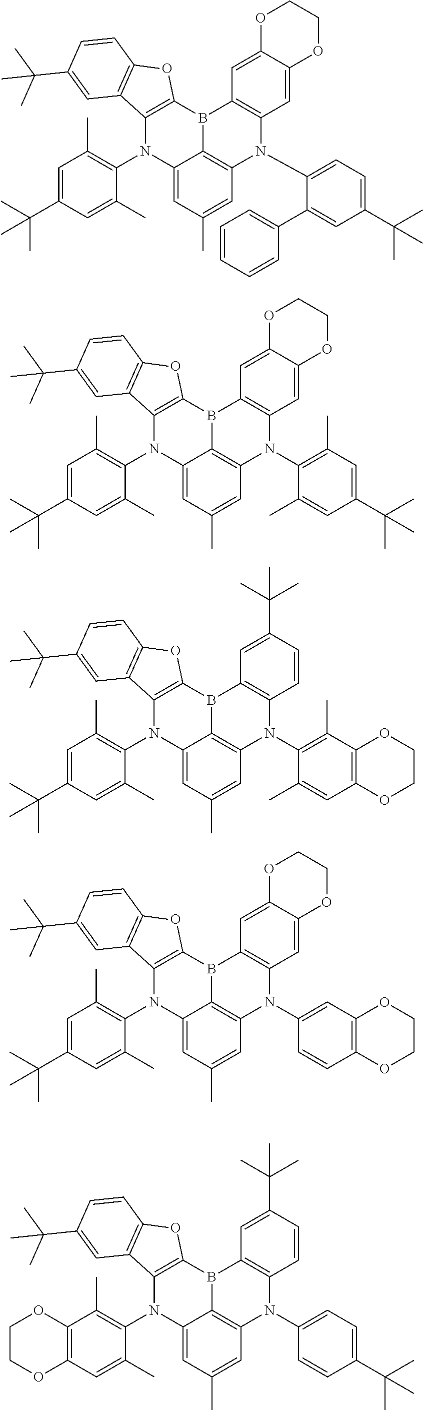

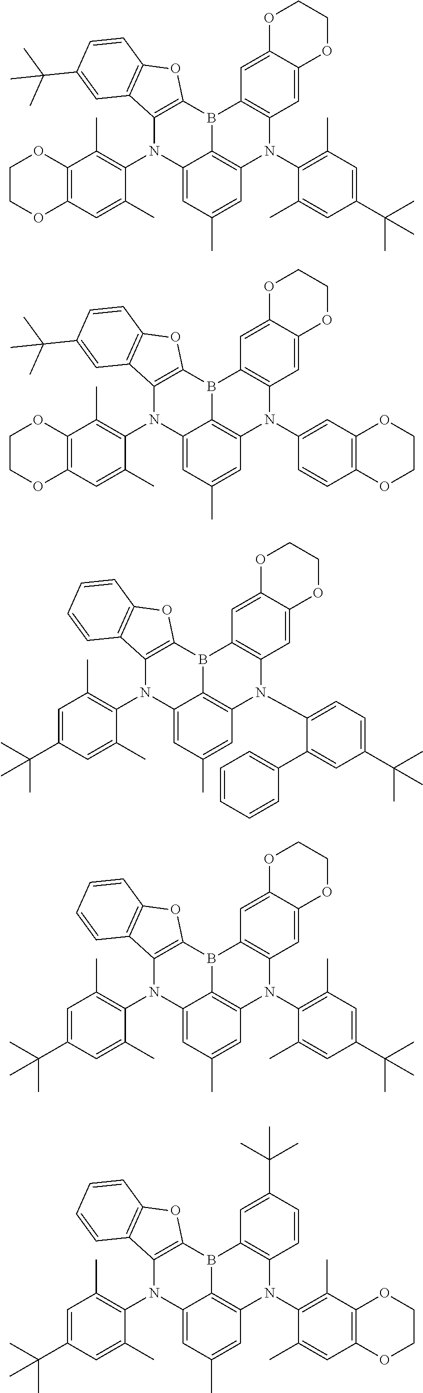

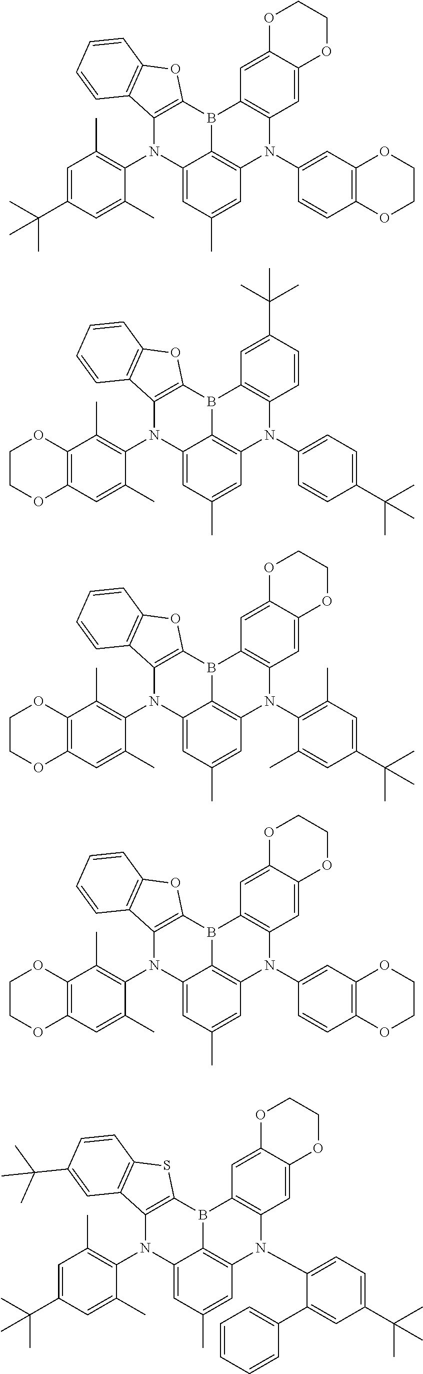

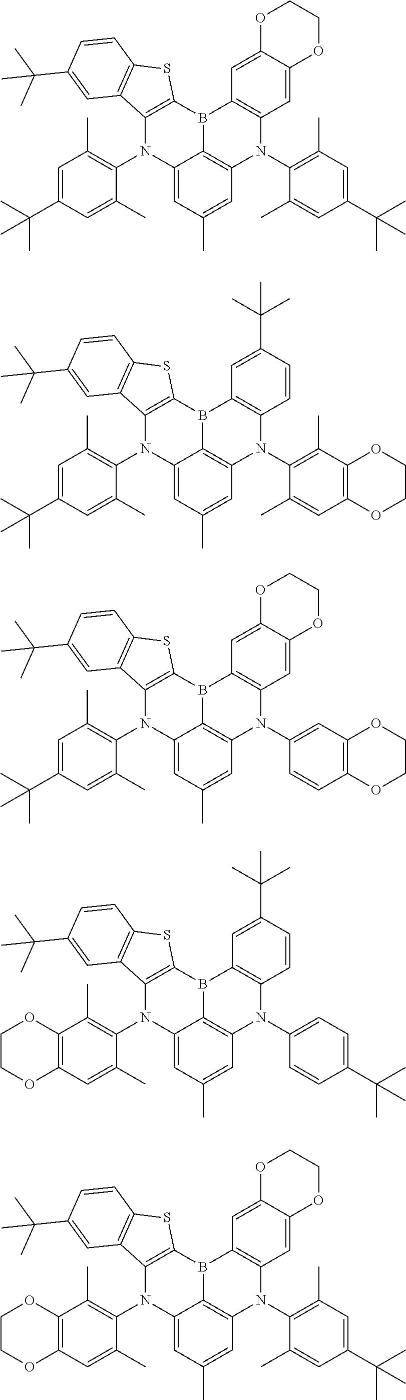

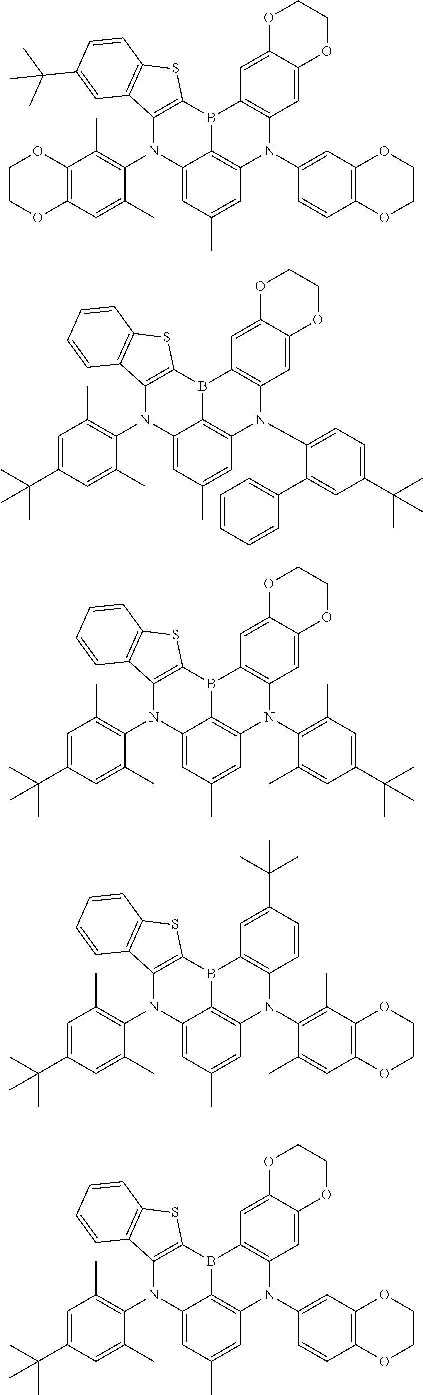

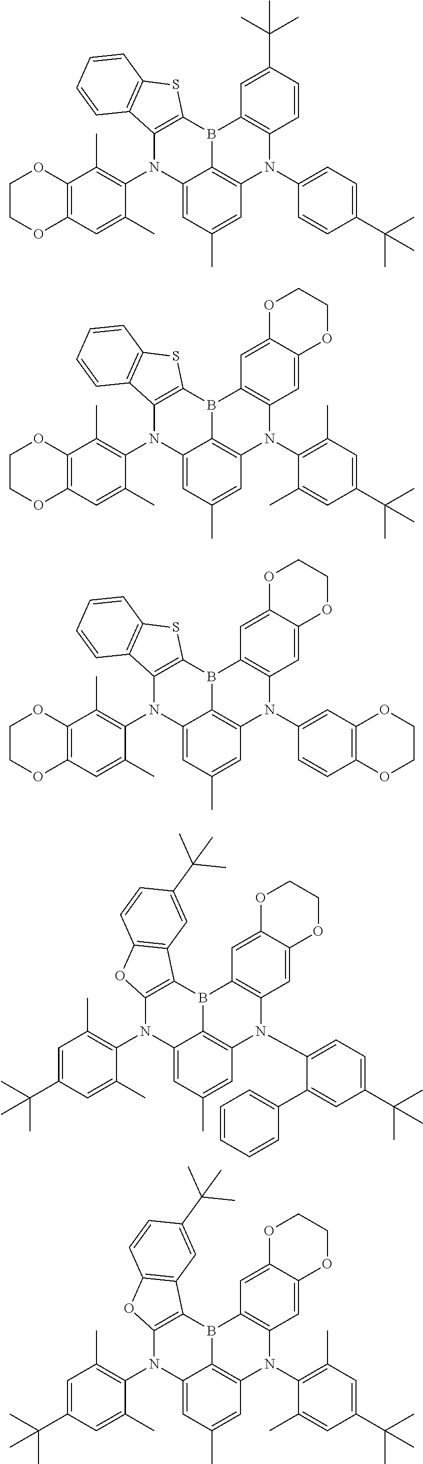

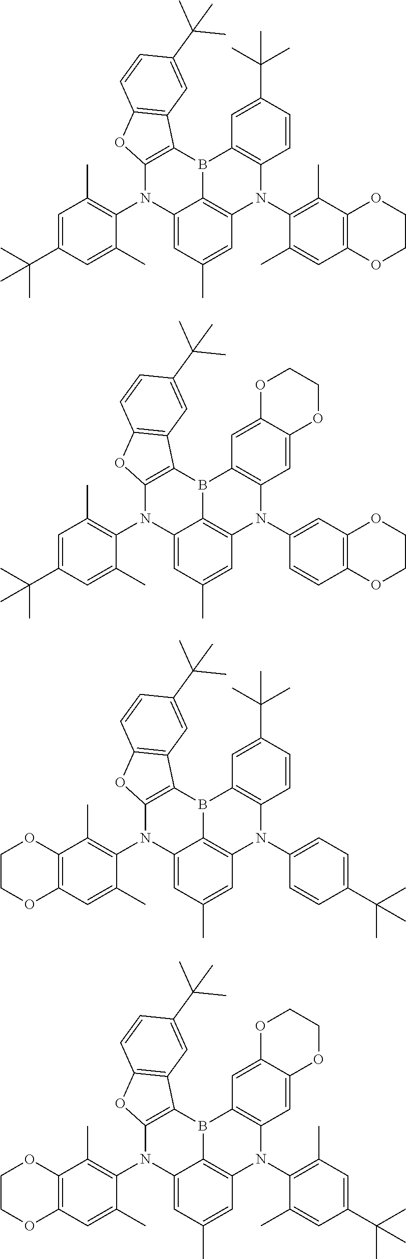

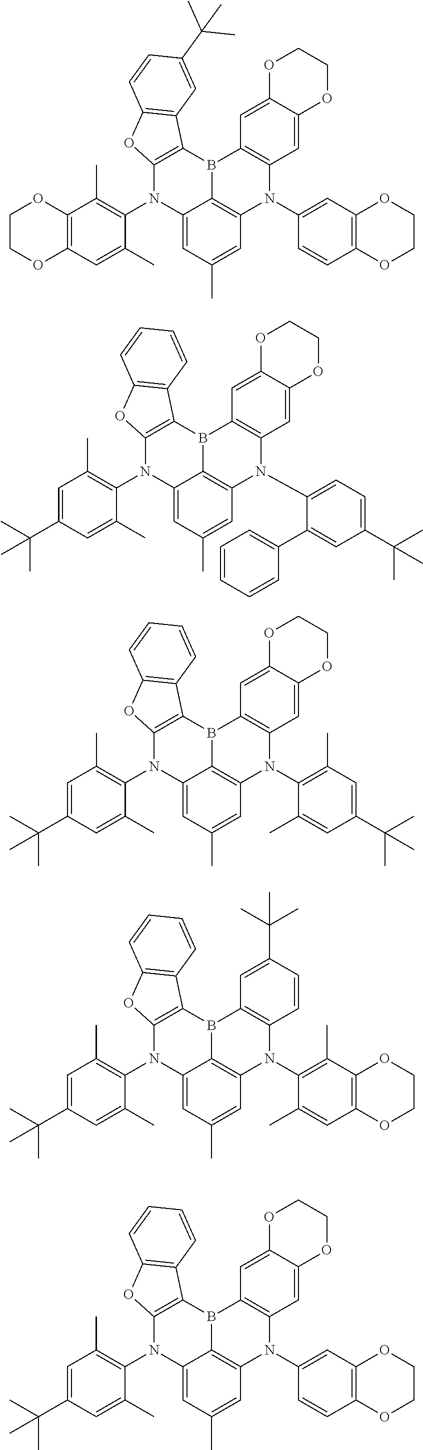

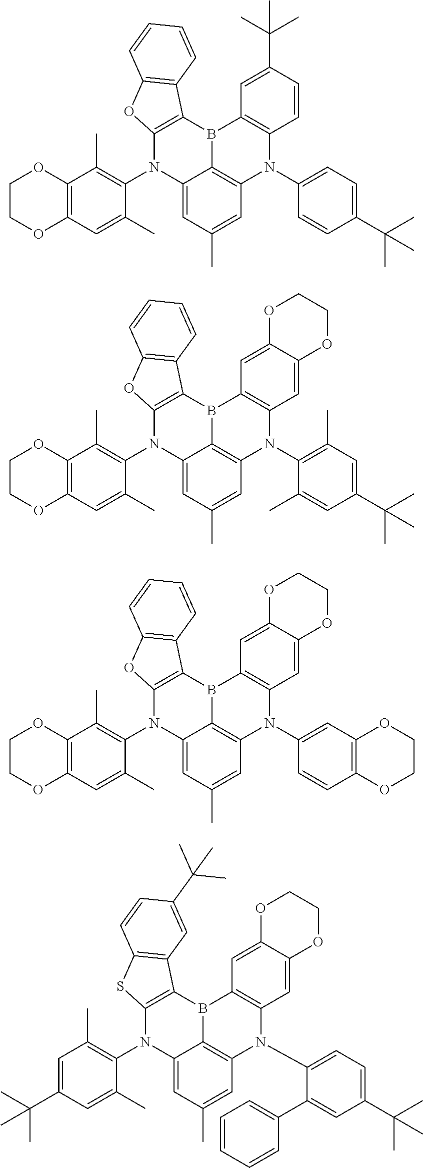

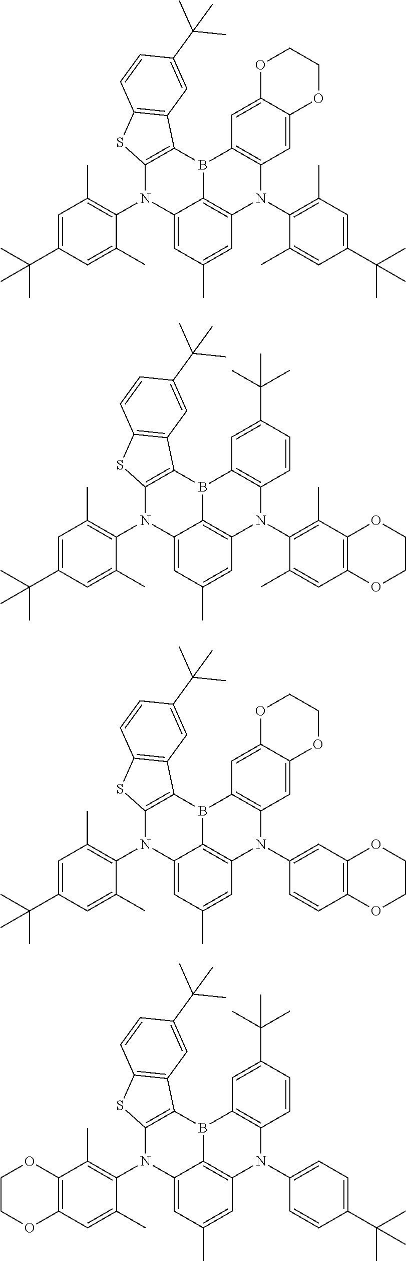

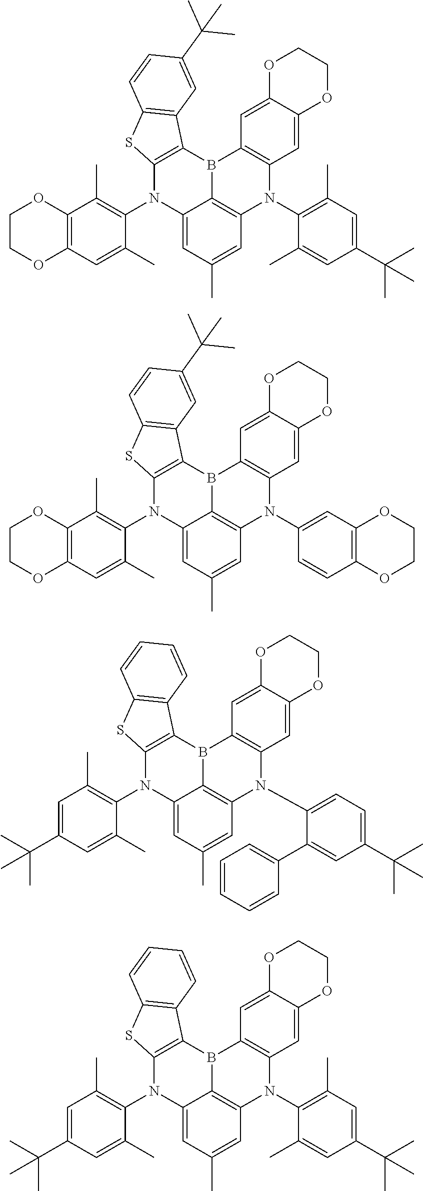

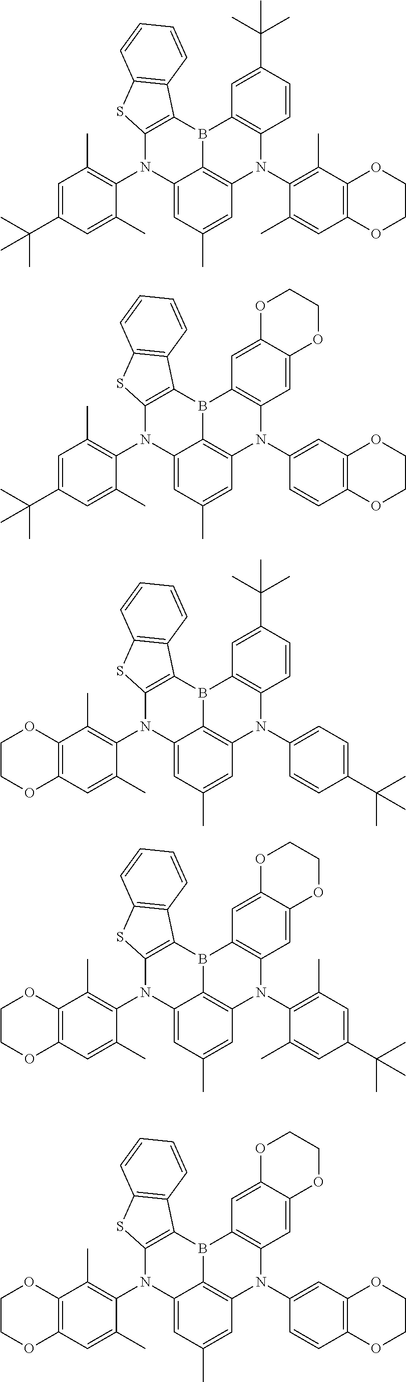

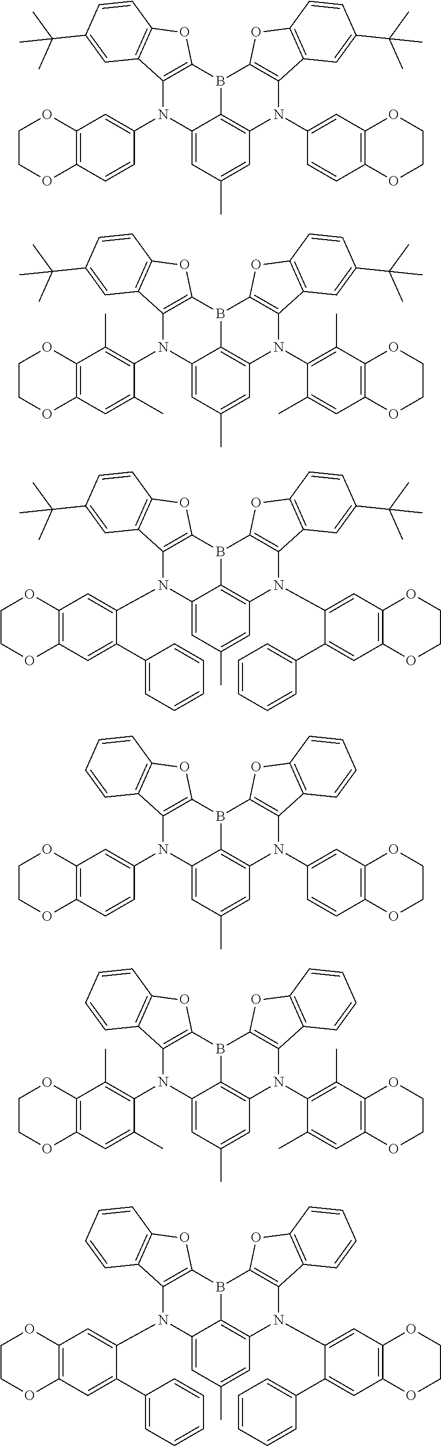

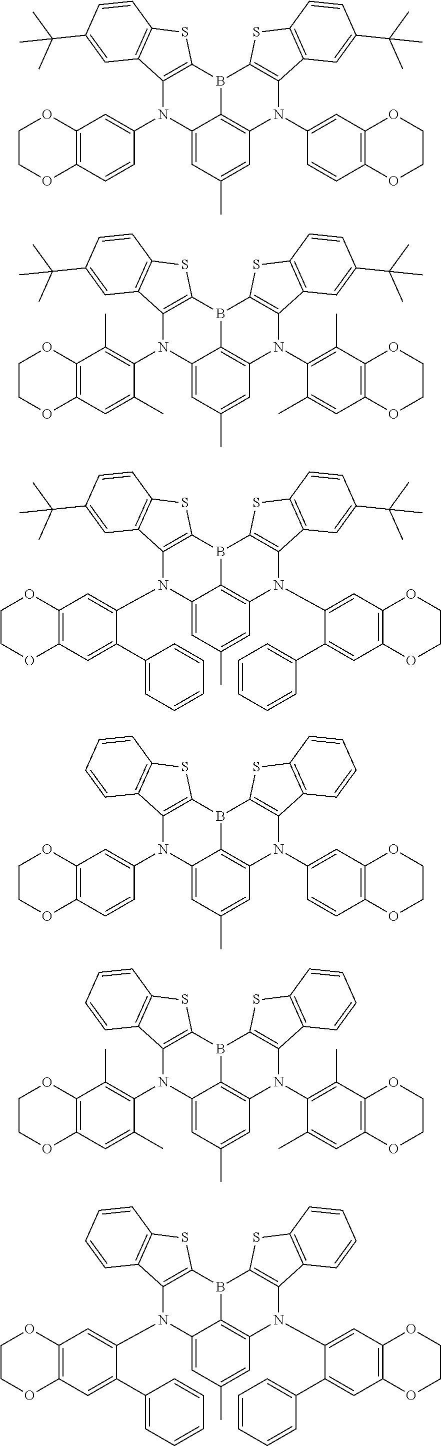

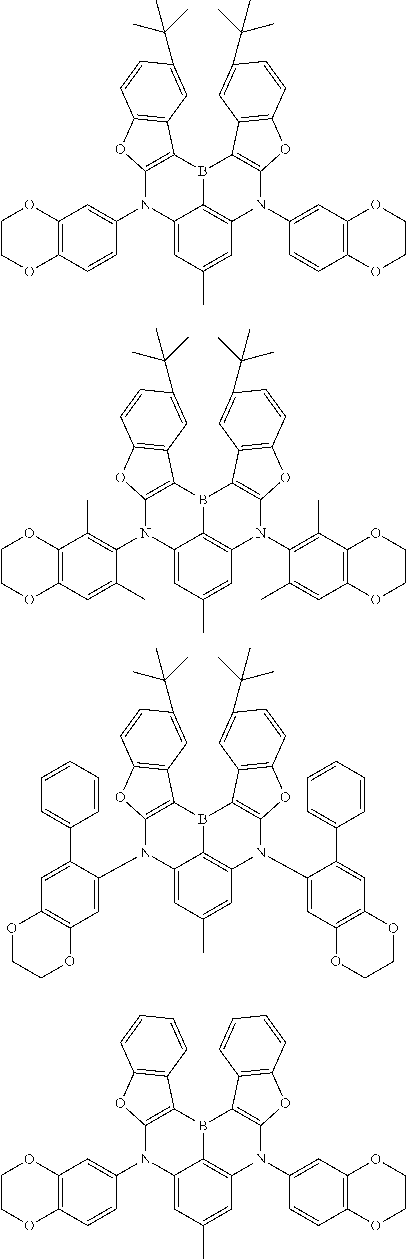

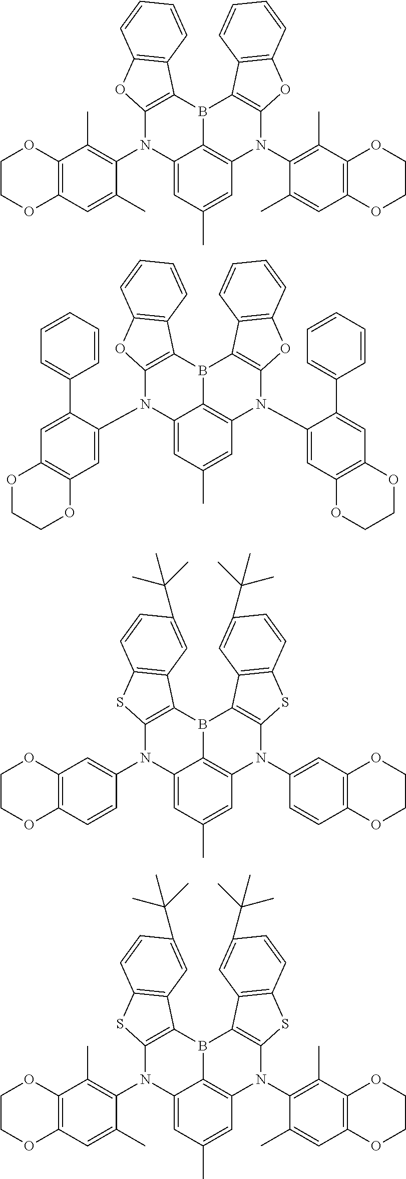

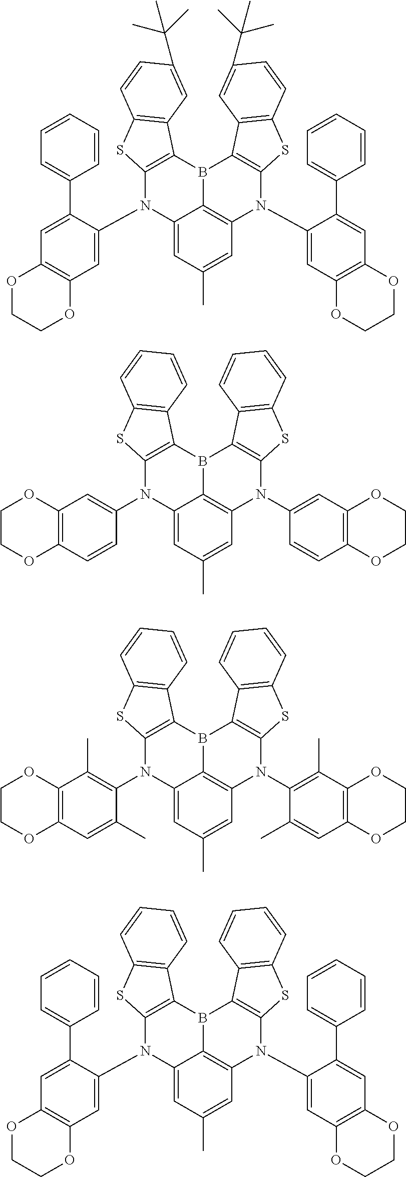 [SMILES: Cc1cc2c3c(c1)N(c1cc4c(cc1-c1ccccc1)OCCO4)c1sc4ccc(C(C)(C)C)cc4c1B3c1c(sc3ccc(C(C)(C)C)cc13)N2c1cc2c(cc1-c1ccccc1)OCCO2 ; Cc1cc2c3c(c1)N(c1ccc4c(c1)OCCO4)c1sc4ccccc4c1B3c1c(sc3ccccc13)N2c1ccc2c(c1)OCCO2 ; Cc1cc2c3c(c1)N(c1c(C)cc4c(c1C)OCCO4)c1sc4ccccc4c1B3c1c(sc3ccccc13)N2c1c(C)cc2c(c1C)OCCO2 ; Cc1cc2c3c(c1)N(c1cc4c(cc1-c1ccccc1)OCCO4)c1sc4ccccc4c1B3c1c(sc3ccccc13)N2c1cc2c(cc1-c1ccccc1)OCCO2]

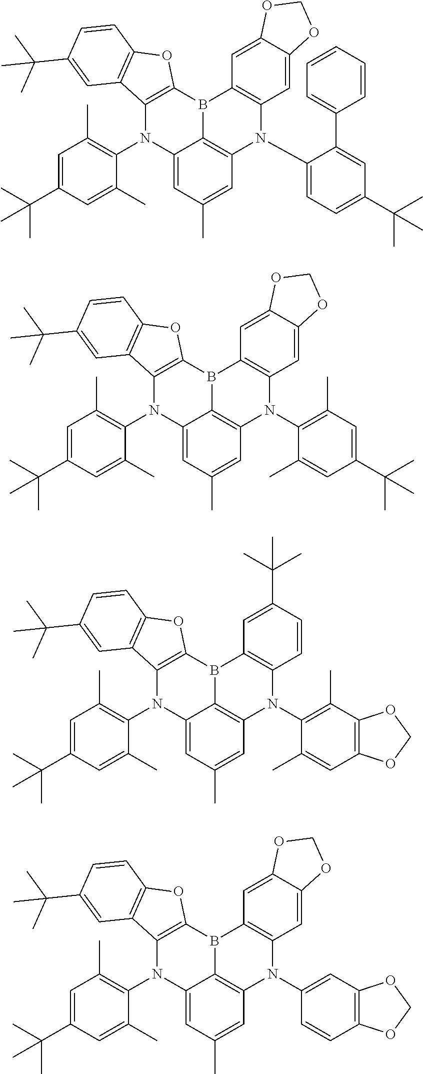

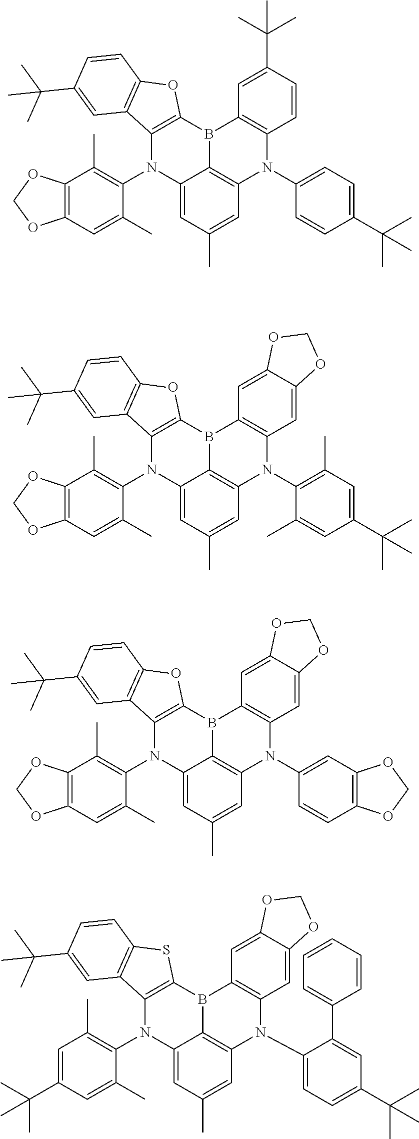

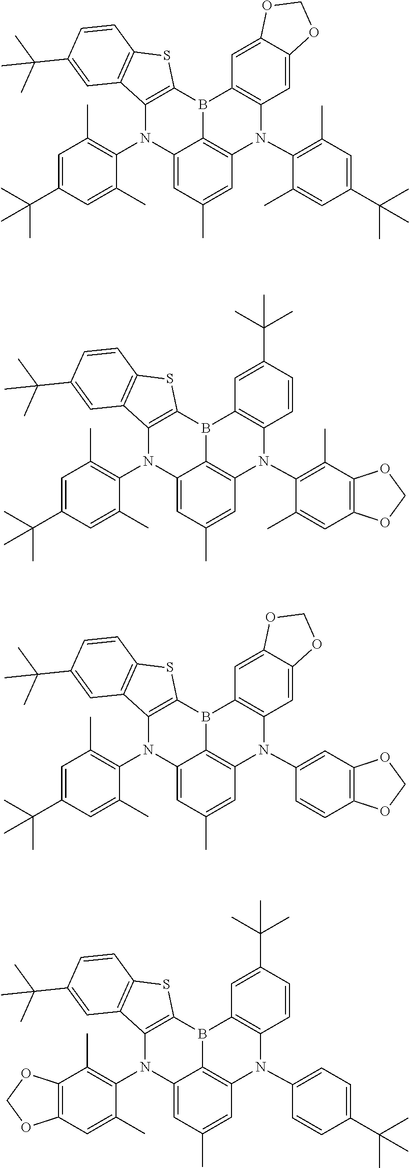

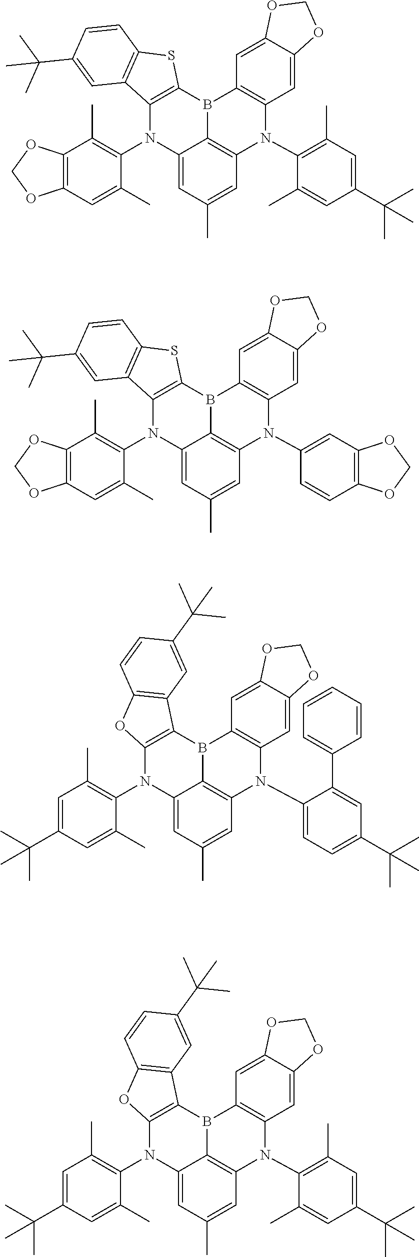

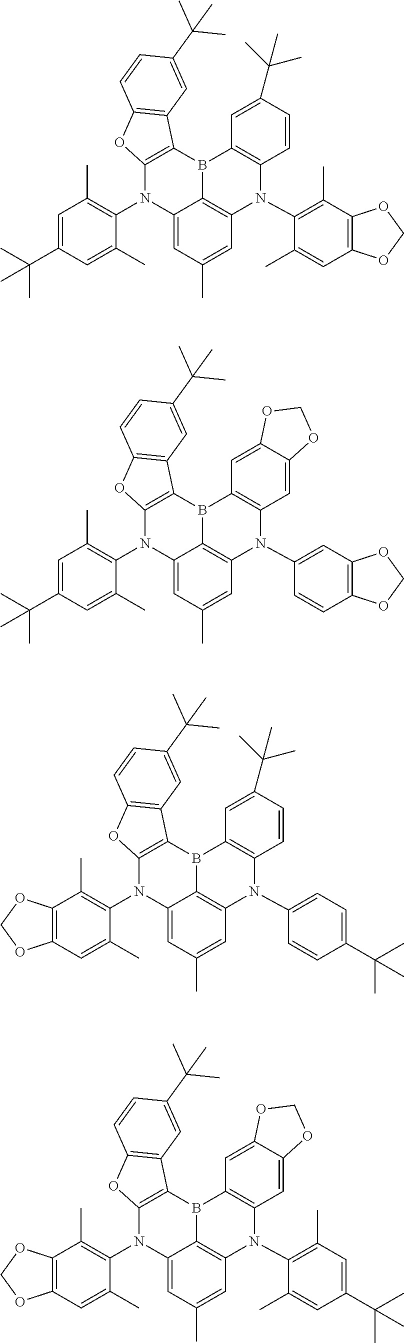 [SMILES: Cc1cc2c3c(c1)N(c1c(C)cc(C(C)(C)C)cc1C)c1oc4ccc(C(C)(C)C)cc4c1B3c1cc(C(C)(C)C)ccc1N2c1c(C)cc2c(c1C)OCO2 ; Cc1cc2c3c(c1)N(c1c(C)cc(C(C)(C)C)cc1C)c1oc4ccc(C(C)(C)C)cc4c1B3c1cc3c(cc1N2c1ccc2c(c1)OCO2)OCO3 ; Cc1cc2c3c(c1)N(c1c(C)cc4c(c1C)OCO4)c1oc4ccc(C(C)(C)C)cc4c1B3c1cc(C(C)(C)C)ccc1N2c1ccc(C(C)(C)C)cc1 ; Cc1cc2c3c(c1)N(c1c(C)cc4c(c1C)OCO4)c1oc4ccc(C(C)(C)C)cc4c1B3c1cc3c(cc1N2c1c(C)cc(C(C)(C)C)cc1C)OCO3]

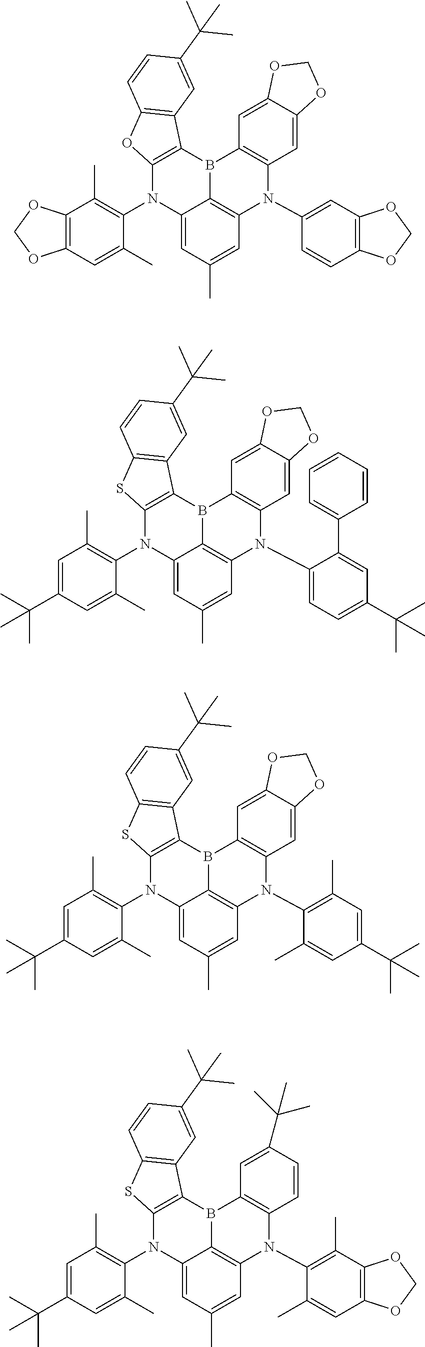

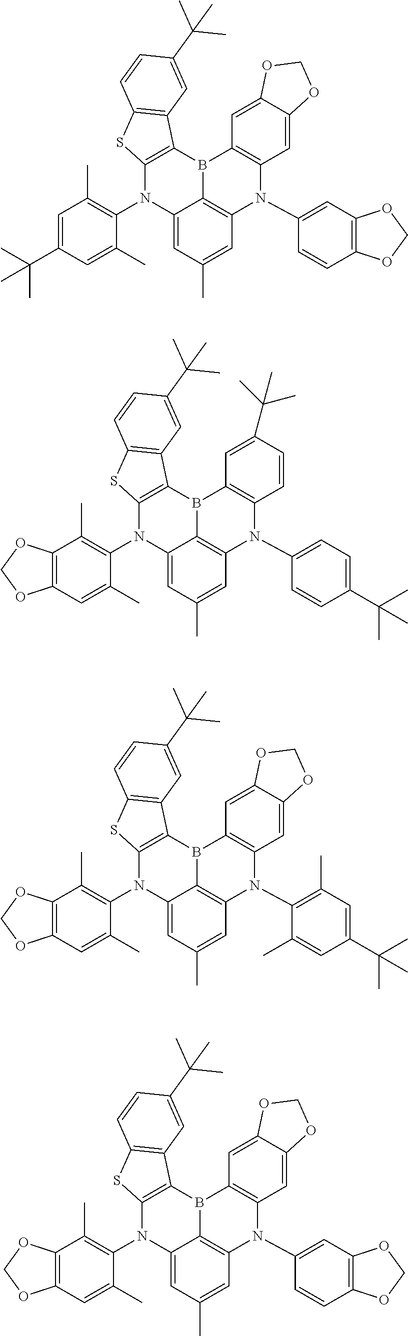

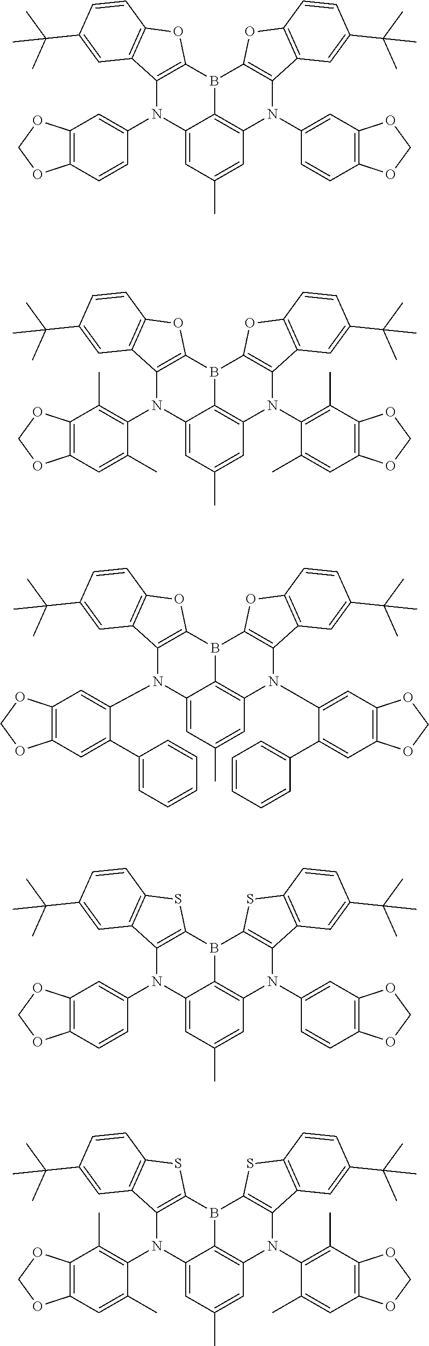

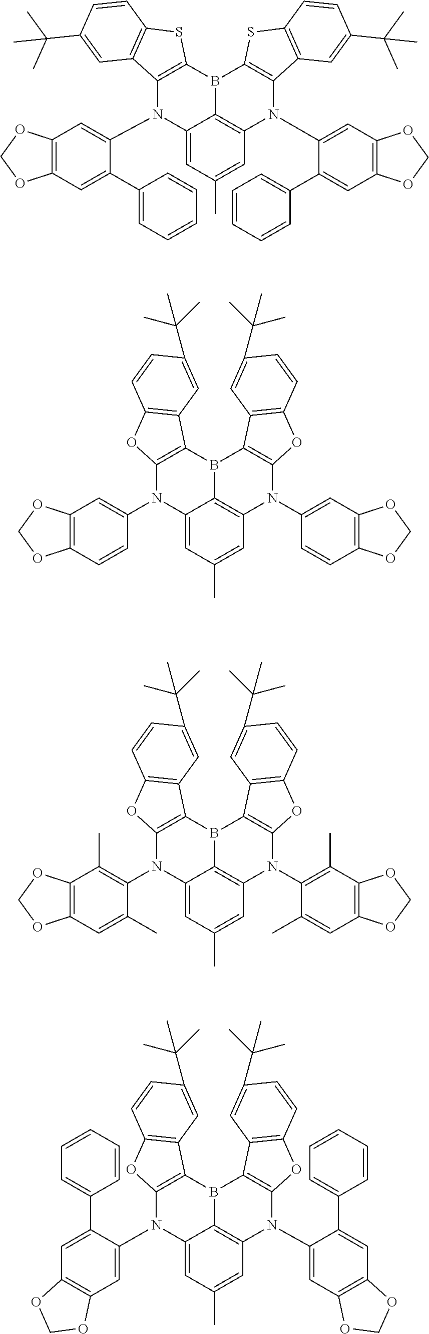 [SMILES: Cc1cc2c3c(c1)N(c1cc4c(cc1-c1ccccc1)OCO4)c1c(sc4ccc(C(C)(C)C)cc14)B3c1sc3ccc(C(C)(C)C)cc3c1N2c1cc2c(cc1-c1ccccc1)OCO2 ; Cc1cc2c3c(c1)N(c1ccc4c(c1)OCO4)c1oc4ccc(C(C)(C)C)cc4c1B3c1c(oc3ccc(C(C)(C)C)cc13)N2c1ccc2c(c1)OCO2 ; Cc1cc2c3c(c1)N(c1c(C)cc4c(c1C)OCO4)c1oc4ccc(C(C)(C)C)cc4c1B3c1c(oc3ccc(C(C)(C)C)cc13)N2c1c(C)cc2c(c1C)OCO2 ; Cc1cc2c3c(c1)N(c1cc4c(cc1-c1ccccc1)OCO4)c1oc4ccc(C(C)(C)C)cc4c1B3c1c(oc3ccc(C(C)(C)C)cc13)N2c1cc2c(cc1-c1ccccc1)OCO2]

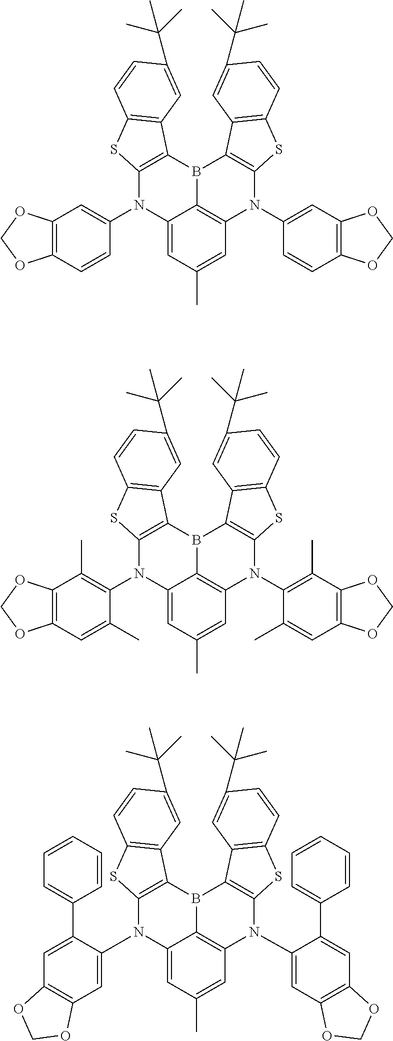 [SMILES: Cc1cc2c3c(c1)N(c1ccc4c(c1)OCO4)c1sc4ccc(C(C)(C)C)cc4c1B3c1c(sc3ccc(C(C)(C)C)cc13)N2c1ccc2c(c1)OCO2 ; Cc1cc2c3c(c1)N(c1c(C)cc4c(c1C)OCO4)c1sc4ccc(C(C)(C)C)cc4c1B3c1c(sc3ccc(C(C)(C)C)cc13)N2c1c(C)cc2c(c1C)OCO2 ; Cc1cc2c3c(c1)N(c1cc4c(cc1-c1ccccc1)OCO4)c1sc4ccc(C(C)(C)C)cc4c1B3c1c(sc3ccc(C(C)(C)C)cc13)N2c1cc2c(cc1-c1ccccc1)OCO2]

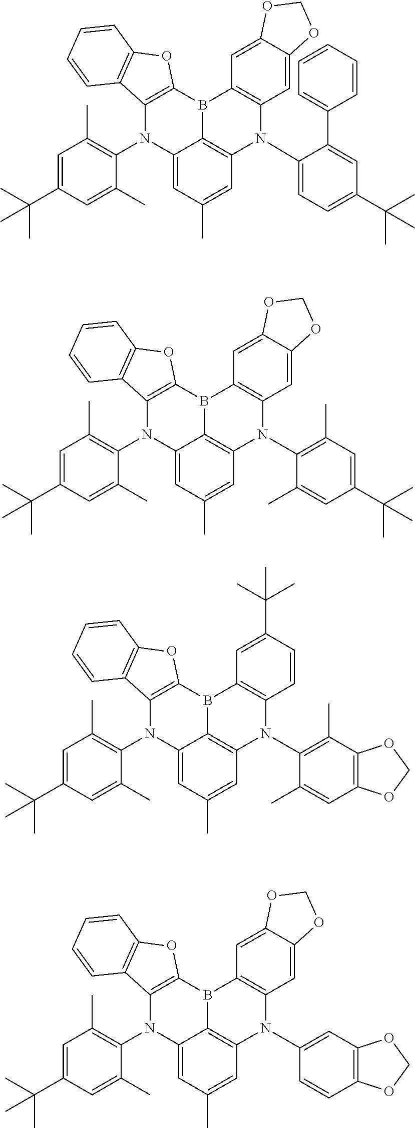

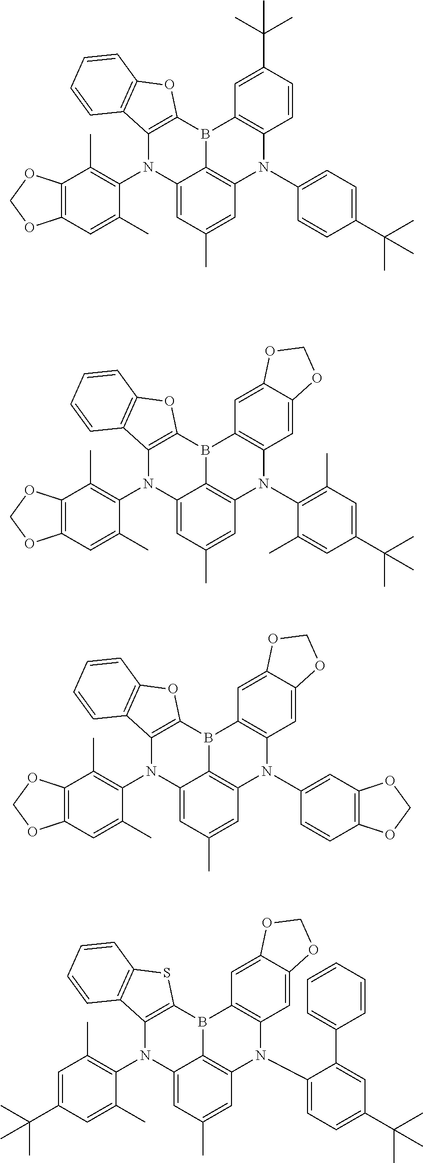

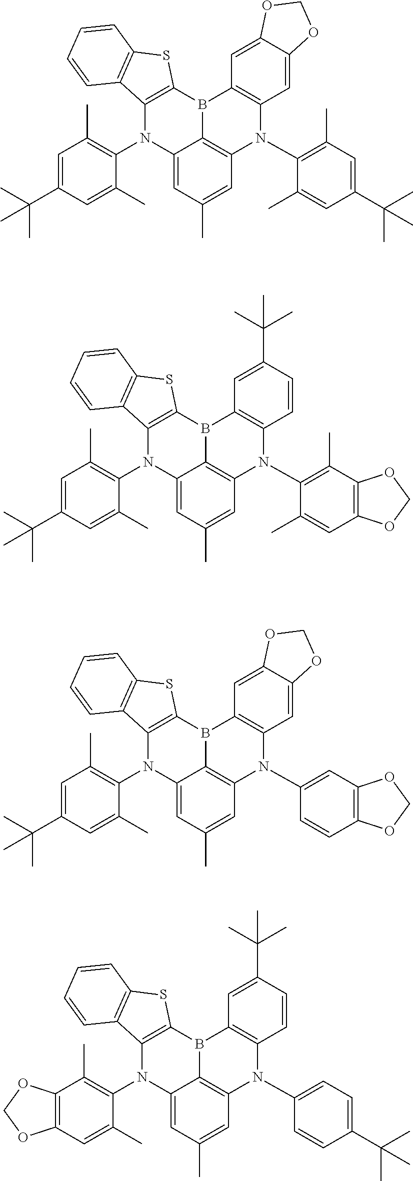

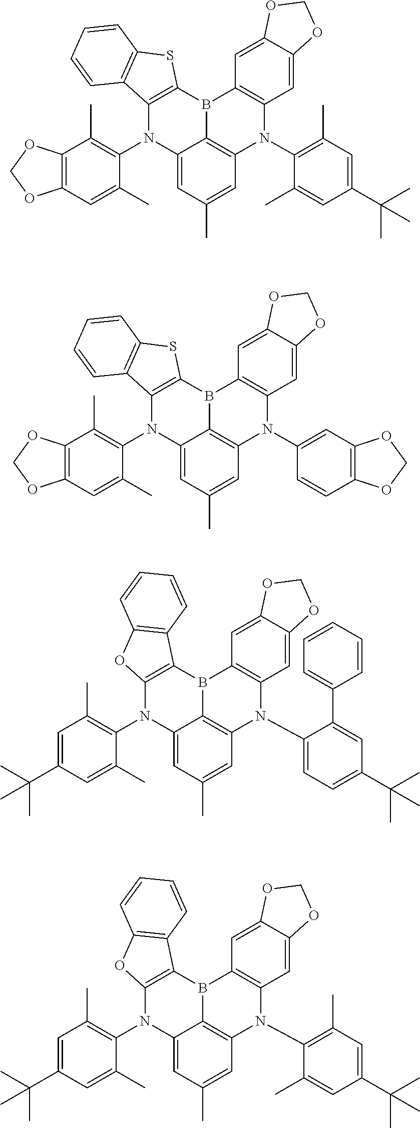

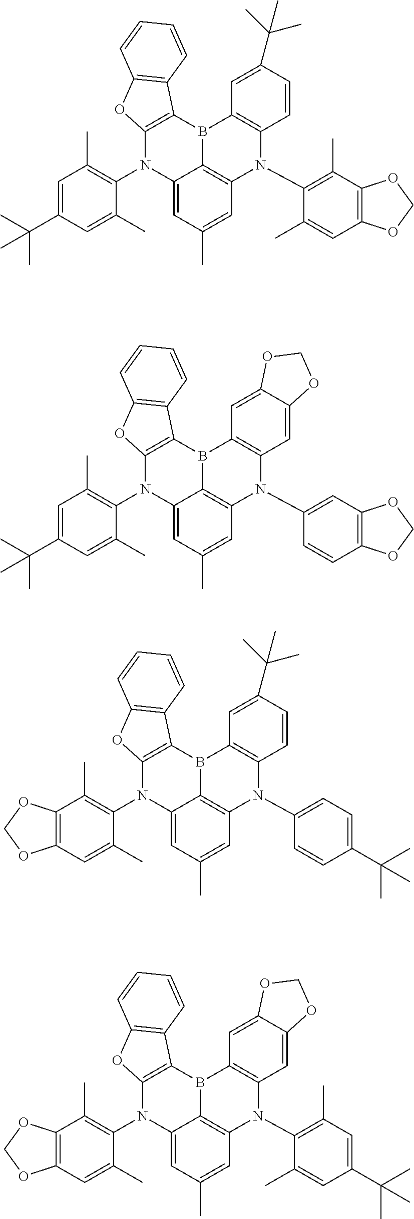 [SMILES: Cc1cc2c3c(c1)N(c1c(C)cc(C(C)(C)C)cc1C)c1oc4ccccc4c1B3c1cc(C(C)(C)C)ccc1N2c1c(C)cc2c(c1C)OCO2 ; Cc1cc2c3c(c1)N(c1c(C)cc(C(C)(C)C)cc1C)c1oc4ccccc4c1B3c1cc3c(cc1N2c1ccc2c(c1)OCO2)OCO3 ; Cc1cc2c3c(c1)N(c1c(C)cc4c(c1C)OCO4)c1oc4ccccc4c1B3c1cc(C(C)(C)C)ccc1N2c1ccc(C(C)(C)C)cc1 ; Cc1cc2c3c(c1)N(c1c(C)cc4c(c1C)OCO4)c1oc4ccccc4c1B3c1cc3c(cc1N2c1c(C)cc(C(C)(C)C)cc1C)OCO3]

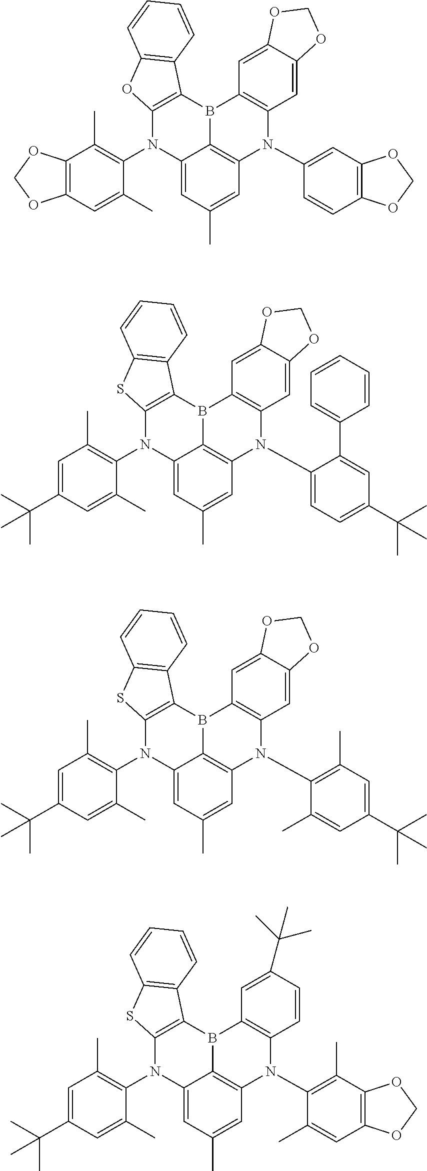

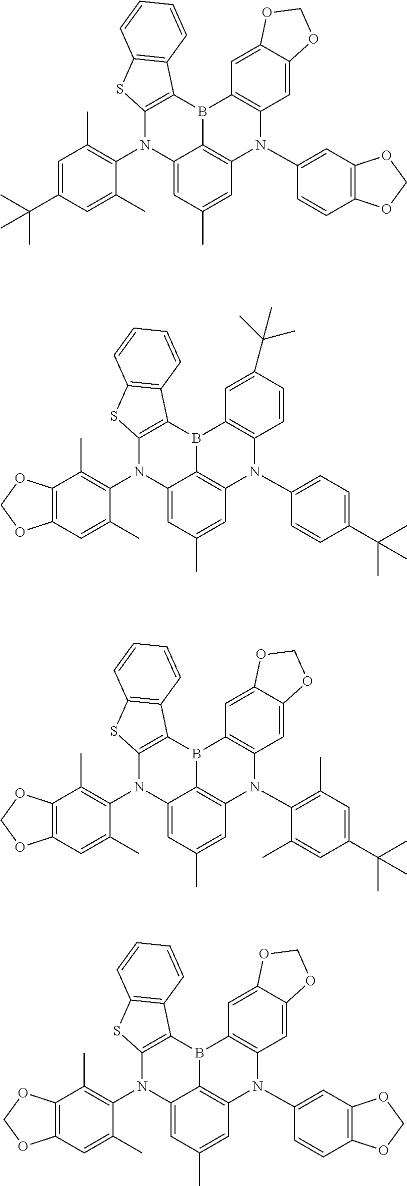 [SMILES: Cc1cc2c3c(c1)N(c1c(C)cc(C(C)(C)C)cc1C)c1sc4ccccc4c1B3c1cc3c(cc1N2c1ccc2c(c1)OCO2)OCO3 ; Cc1cc2c3c(c1)N(c1c(C)cc4c(c1C)OCO4)c1sc4ccccc4c1B3c1cc(C(C)(C)C)ccc1N2c1ccc(C(C)(C)C)cc1 ; Cc1cc2c3c(c1)N(c1c(C)cc4c(c1C)OCO4)c1sc4ccccc4c1B3c1cc3c(cc1N2c1c(C)cc(C(C)(C)C)cc1C)OCO3 ; Cc1cc2c3c(c1)N(c1c(C)cc4c(c1C)OCO4)c1sc4ccccc4c1B3c1cc3c(cc1N2c1ccc2c(c1)OCO2)OCO3]

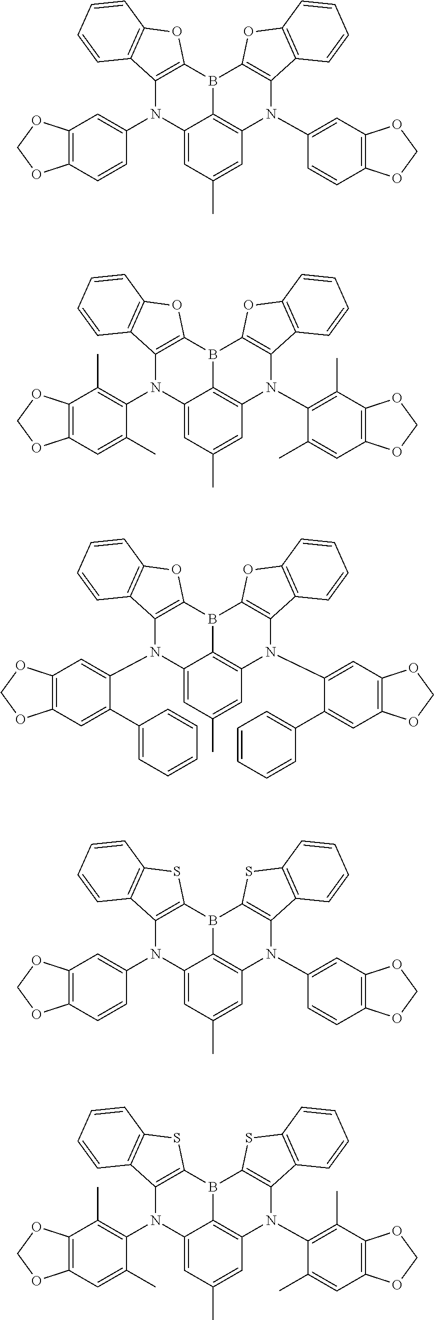 [SMILES: Cc1cc2c3c(c1)N(c1ccc4c(c1)OCO4)c1c(oc4ccccc14)B3c1oc3ccccc3c1N2c1ccc2c(c1)OCO2 ; Cc1cc2c3c(c1)N(c1c(C)cc4c(c1C)OCO4)c1c(oc4ccccc14)B3c1oc3ccccc3c1N2c1c(C)cc2c(c1C)OCO2 ; Cc1cc2c3c(c1)N(c1cc4c(cc1-c1ccccc1)OCO4)c1c(oc4ccccc14)B3c1oc3ccccc3c1N2c1cc2c(cc1-c1ccccc1)OCO2 ; Cc1cc2c3c(c1)N(c1ccc4c(c1)OCO4)c1c(sc4ccccc14)B3c1sc3ccccc3c1N2c1ccc2c(c1)OCO2 ; Cc1cc2c3c(c1)N(c1c(C)cc4c(c1C)OCO4)c1c(sc4ccccc14)B3c1sc3ccccc3c1N2c1c(C)cc2c(c1C)OCO2]

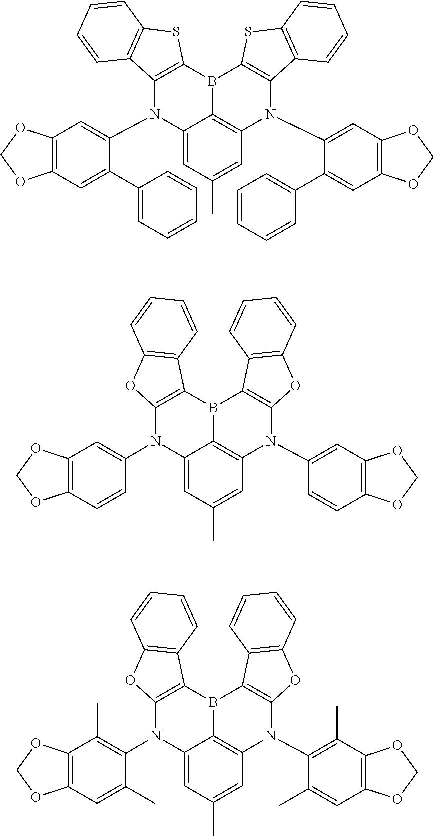 [SMILES: Cc1cc2c3c(c1)N(c1cc4c(cc1-c1ccccc1)OCO4)c1c(sc4ccccc14)B3c1sc3ccccc3c1N2c1cc2c(cc1-c1ccccc1)OCO2 ; Cc1cc2c3c(c1)N(c1ccc4c(c1)OCO4)c1oc4ccccc4c1B3c1c(oc3ccccc13)N2c1ccc2c(c1)OCO2 ; Cc1cc2c3c(c1)N(c1c(C)cc4c(c1C)OCO4)c1oc4ccccc4c1B3c1c(oc3ccccc13)N2c1c(C)cc2c(c1C)OCO2]

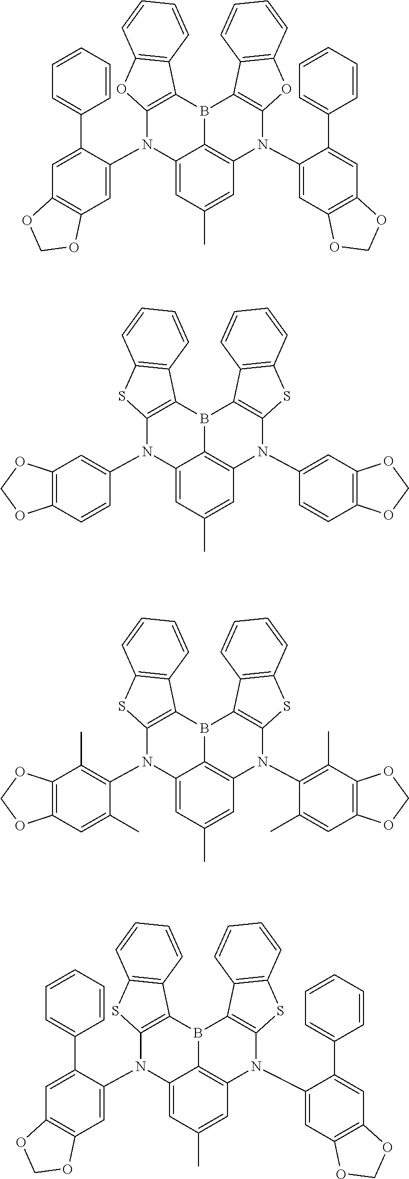 [SMILES: Cc1cc2c3c(c1)N(c1cc4c(cc1-c1ccccc1)OCO4)c1oc4ccccc4c1B3c1c(oc3ccccc13)N2c1cc2c(cc1-c1ccccc1)OCO2 ; Cc1cc2c3c(c1)N(c1ccc4c(c1)OCO4)c1sc4ccccc4c1B3c1c(sc3ccccc13)N2c1ccc2c(c1)OCO2 ; Cc1cc2c3c(c1)N(c1c(C)cc4c(c1C)OCO4)c1sc4ccccc4c1B3c1c(sc3ccccc13)N2c1c(C)cc2c(c1C)OCO2 ; Cc1cc2c3c(c1)N(c1cc4c(cc1-c1ccccc1)OCO4)c1sc4ccccc4c1B3c1c(sc3ccccc13)N2c1cc2c(cc1-c1ccccc1)OCO2]

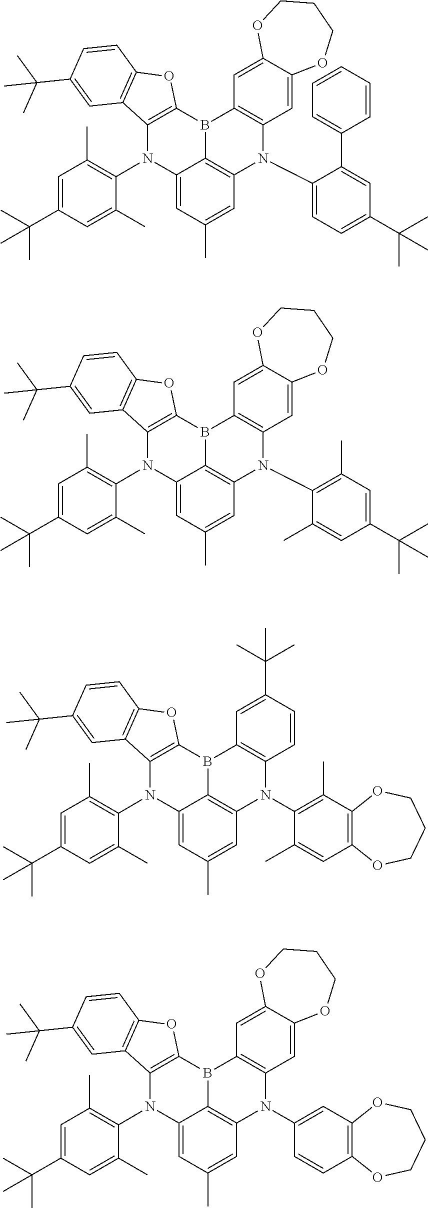

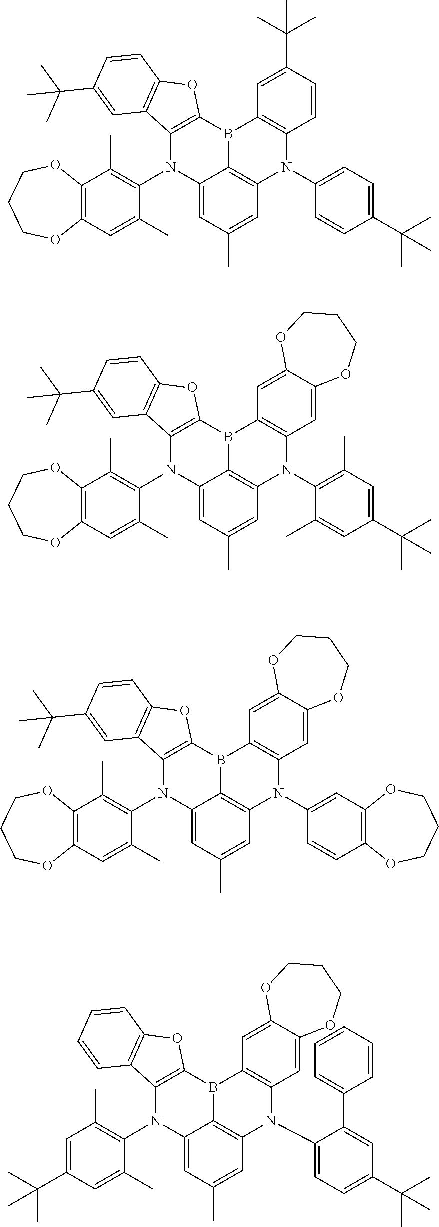

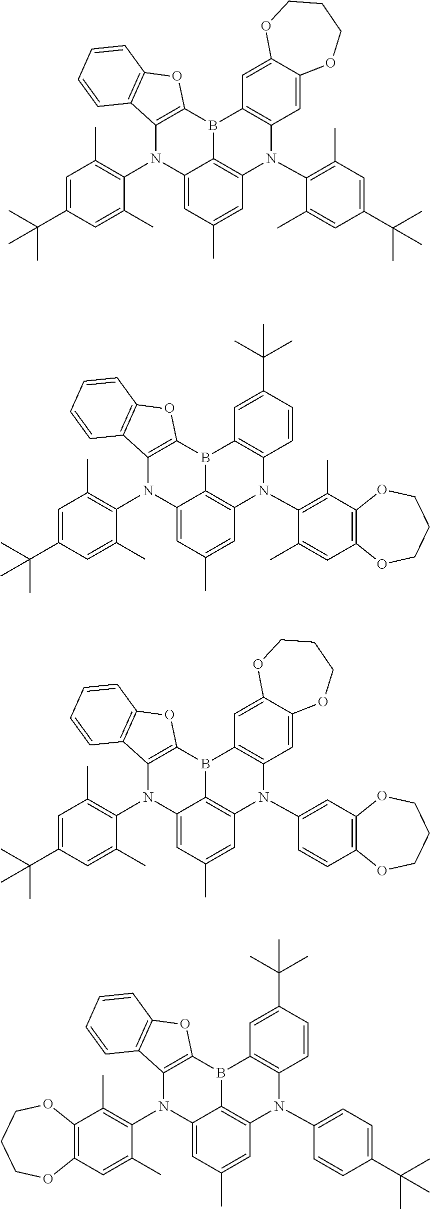

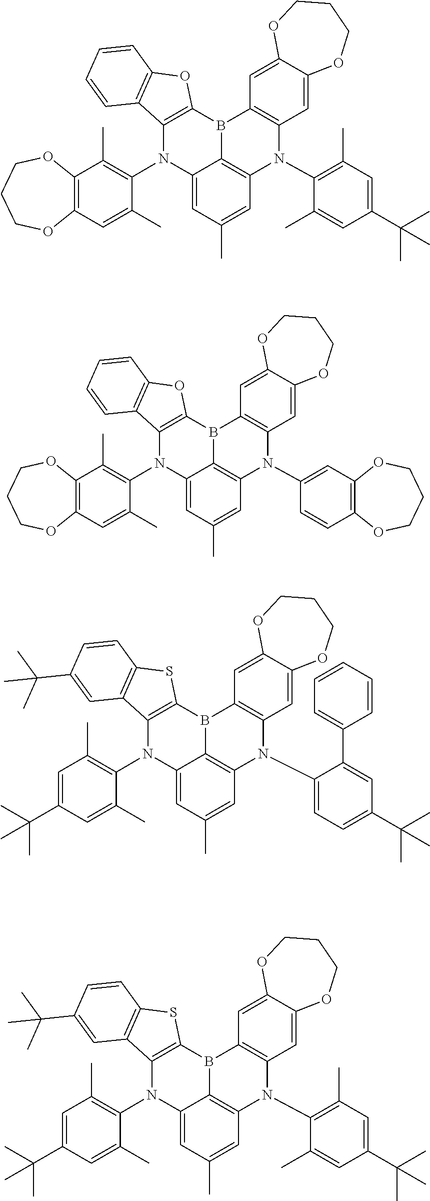

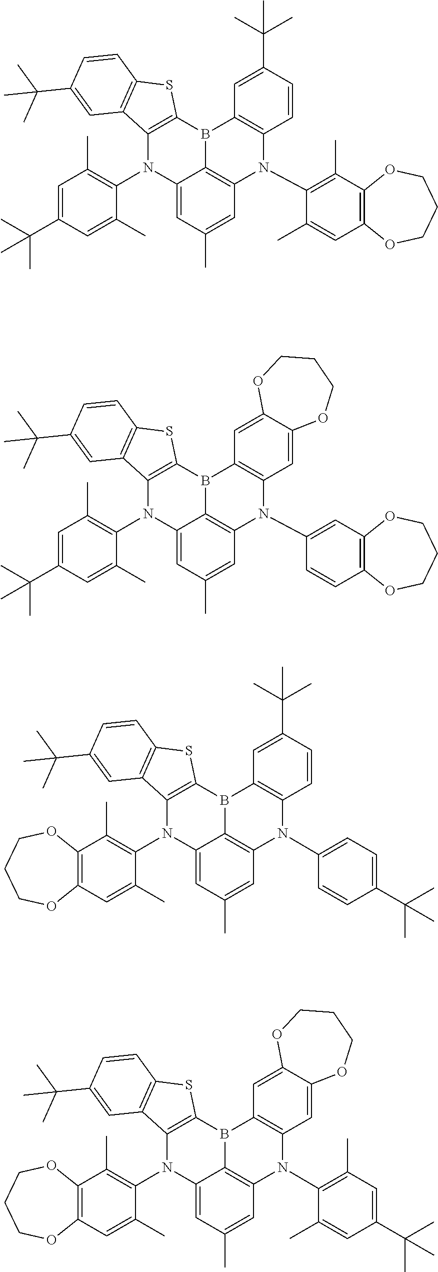 [SMILES: Cc1cc2c3c(c1)N(c1c(C)cc(C(C)(C)C)cc1C)c1c(sc4ccc(C(C)(C)C)cc14)B3c1cc(C(C)(C)C)ccc1N2c1c(C)cc2c(c1C)OCCCO2 ; Cc1cc2c3c(c1)N(c1c(C)cc(C(C)(C)C)cc1C)c1c(sc4ccc(C(C)(C)C)cc14)B3c1cc3c(cc1N2c1ccc2c(c1)OCCCO2)OCCCO3 ; Cc1cc2c3c(c1)N(c1c(C)cc4c(c1C)OCCCO4)c1c(sc4ccc(C(C)(C)C)cc14)B3c1cc(C(C)(C)C)ccc1N2c1ccc(C(C)(C)C)cc1 ; Cc1cc2c3c(c1)N(c1c(C)cc4c(c1C)OCCCO4)c1c(sc4ccc(C(C)(C)C)cc14)B3c1cc3c(cc1N2c1c(C)cc(C(C)(C)C)cc1C)OCCCO3]

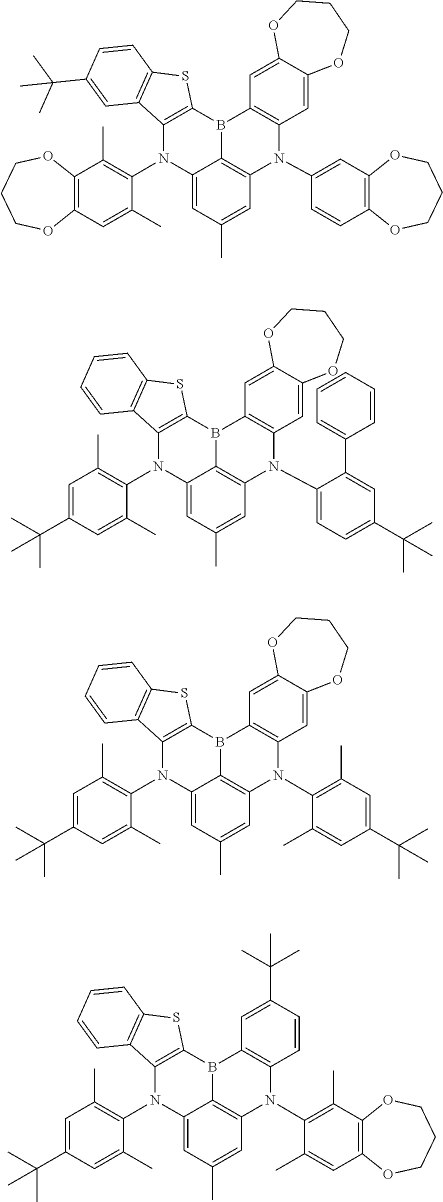

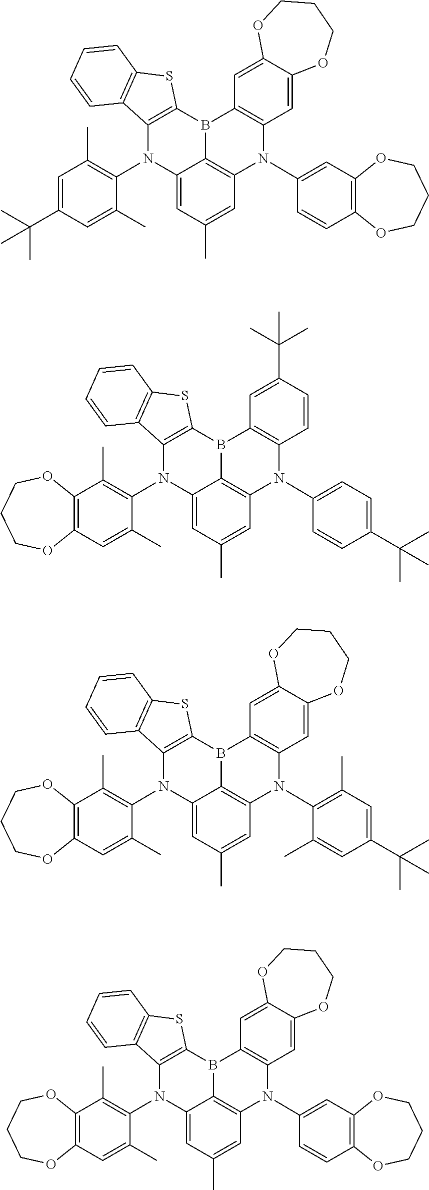 [SMILES: Cc1cc2c3c(c1)N(c1c(C)cc(C(C)(C)C)cc1C)c1c(sc4ccccc14)B3c1cc3c(cc1N2c1ccc2c(c1)OCCCO2)OCCCO3 ; Cc1cc2c3c(c1)N(c1c(C)cc4c(c1C)OCCCO4)c1c(sc4ccccc14)B3c1cc(C(C)(C)C)ccc1N2c1ccc(C(C)(C)C)cc1 ; Cc1cc2c3c(c1)N(c1c(C)cc4c(c1C)OCCCO4)c1c(sc4ccccc14)B3c1cc3c(cc1N2c1c(C)cc(C(C)(C)C)cc1C)OCCCO3 ; Cc1cc2c3c(c1)N(c1c(C)cc4c(c1C)OCCCO4)c1c(sc4ccccc14)B3c1cc3c(cc1N2c1ccc2c(c1)OCCCO2)OCCCO3]

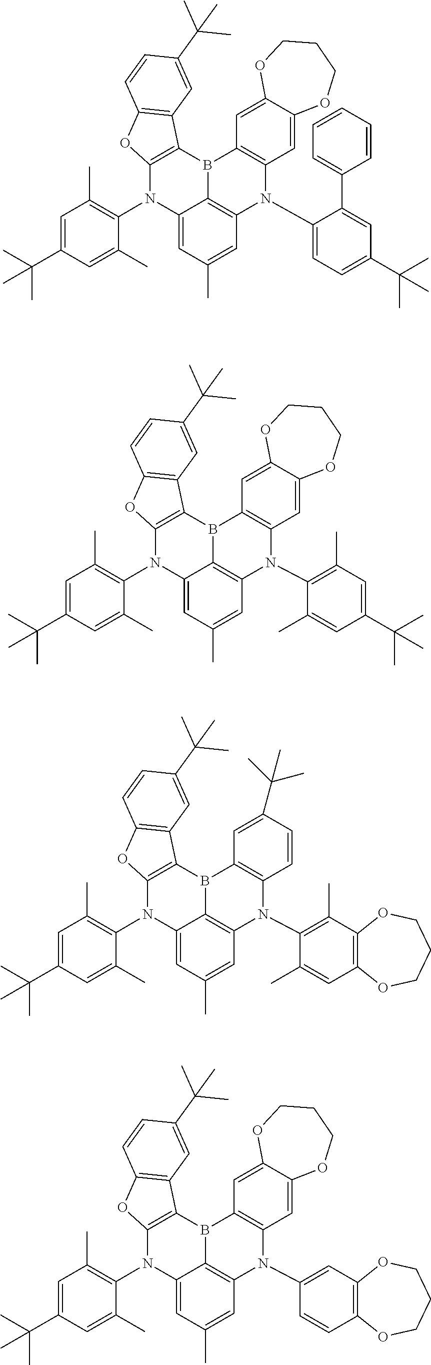

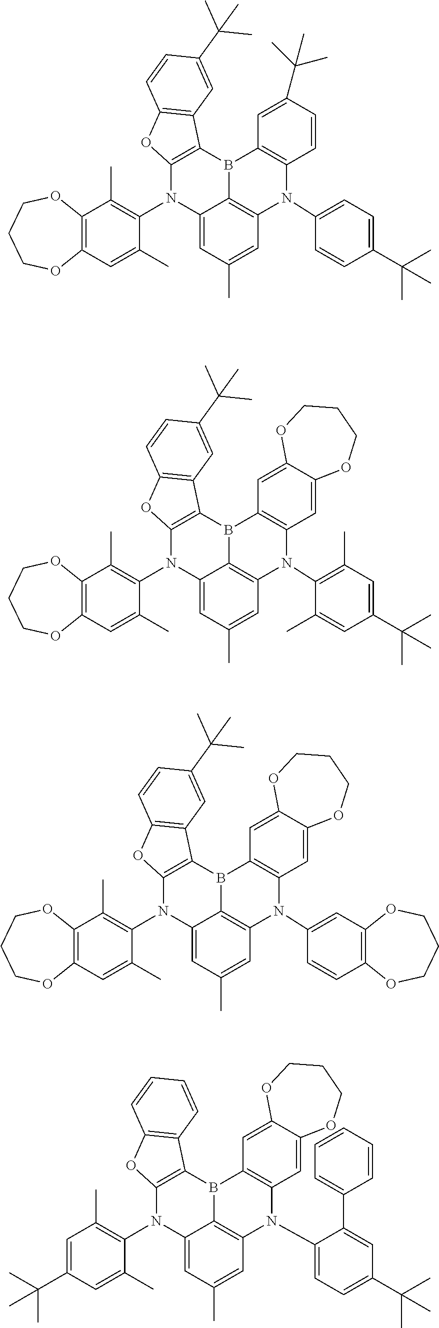

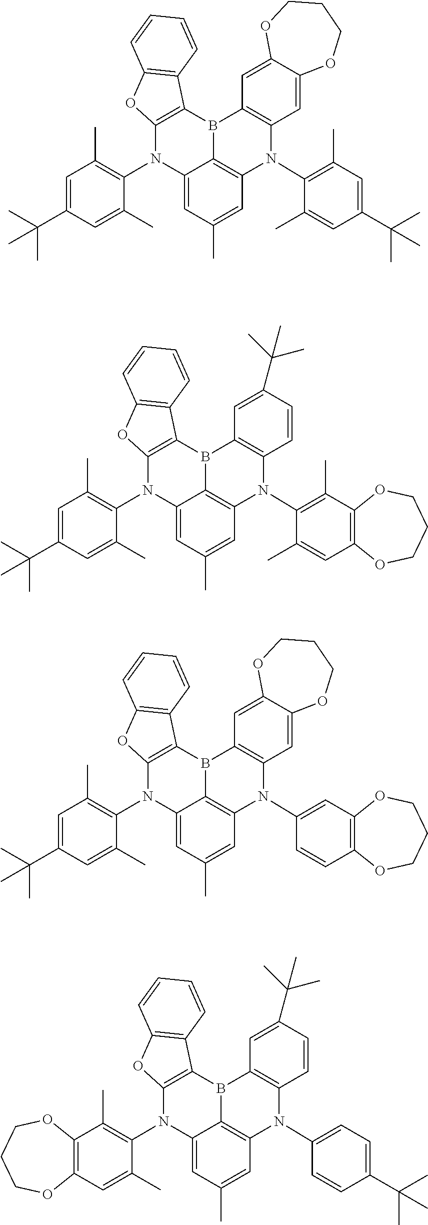

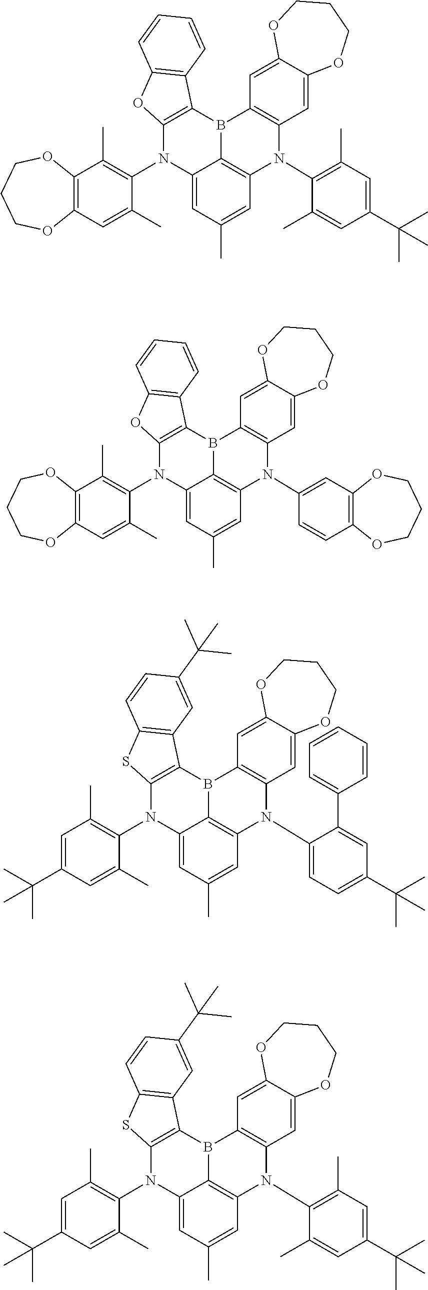

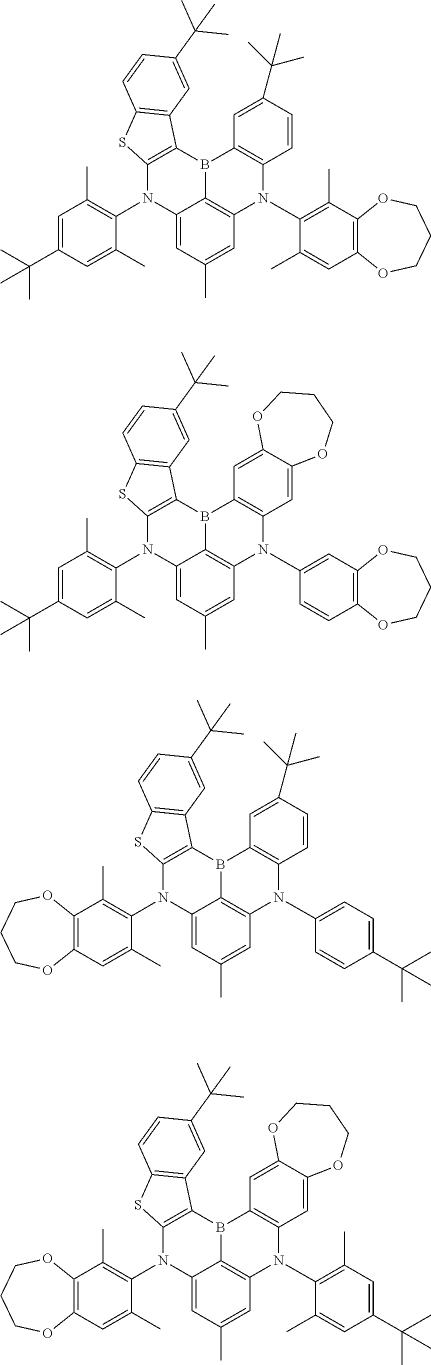 [SMILES: Cc1cc2c3c(c1)N(c1c(C)cc(C(C)(C)C)cc1C)c1sc4ccc(C(C)(C)C)cc4c1B3c1cc(C(C)(C)C)ccc1N2c1c(C)cc2c(c1C)OCCCO2 ; Cc1cc2c3c(c1)N(c1c(C)cc(C(C)(C)C)cc1C)c1sc4ccc(C(C)(C)C)cc4c1B3c1cc3c(cc1N2c1ccc2c(c1)OCCCO2)OCCCO3 ; Cc1cc2c3c(c1)N(c1c(C)cc4c(c1C)OCCCO4)c1sc4ccc(C(C)(C)C)cc4c1B3c1cc(C(C)(C)C)ccc1N2c1ccc(C(C)(C)C)cc1 ; Cc1cc2c3c(c1)N(c1c(C)cc4c(c1C)OCCCO4)c1sc4ccc(C(C)(C)C)cc4c1B3c1cc3c(cc1N2c1c(C)cc(C(C)(C)C)cc1C)OCCCO3]

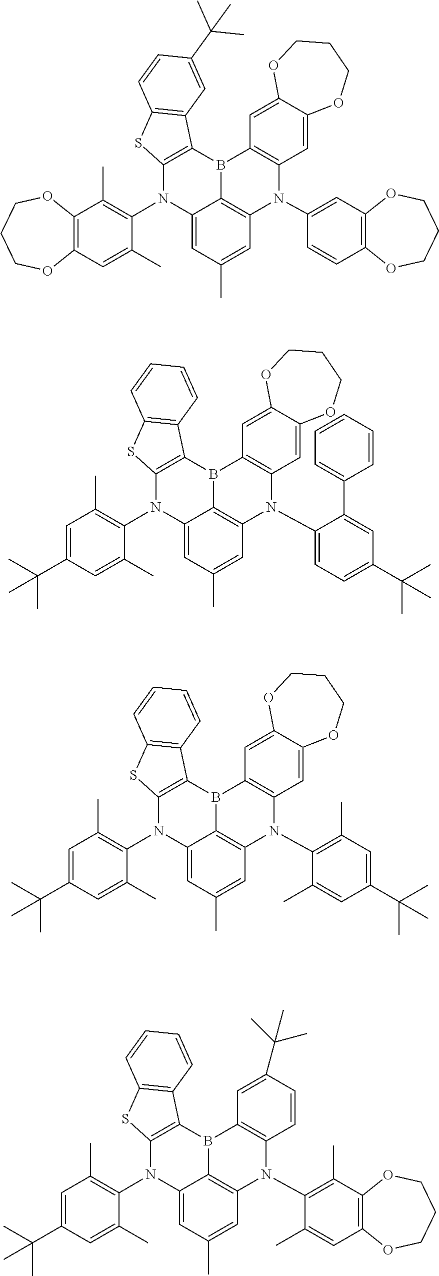

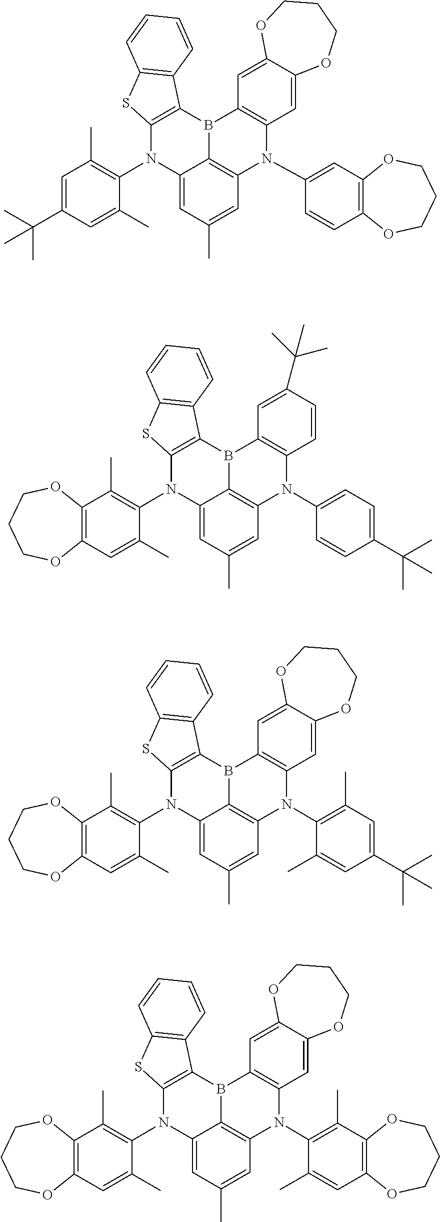 [SMILES: Cc1cc2c3c(c1)N(c1c(C)cc(C(C)(C)C)cc1C)c1sc4ccccc4c1B3c1cc3c(cc1N2c1ccc2c(c1)OCCCO2)OCCCO3 ; Cc1cc2c3c(c1)N(c1c(C)cc4c(c1C)OCCCO4)c1sc4ccccc4c1B3c1cc(C(C)(C)C)ccc1N2c1ccc(C(C)(C)C)cc1 ; Cc1cc2c3c(c1)N(c1c(C)cc4c(c1C)OCCCO4)c1sc4ccccc4c1B3c1cc3c(cc1N2c1c(C)cc(C(C)(C)C)cc1C)OCCCO3 ; Cc1cc2c3c(c1)N(c1c(C)cc4c(c1C)OCCCO4)c1sc4ccccc4c1B3c1cc3c(cc1N2c1c(C)cc2c(c1C)OCCCO2)OCCCO3]

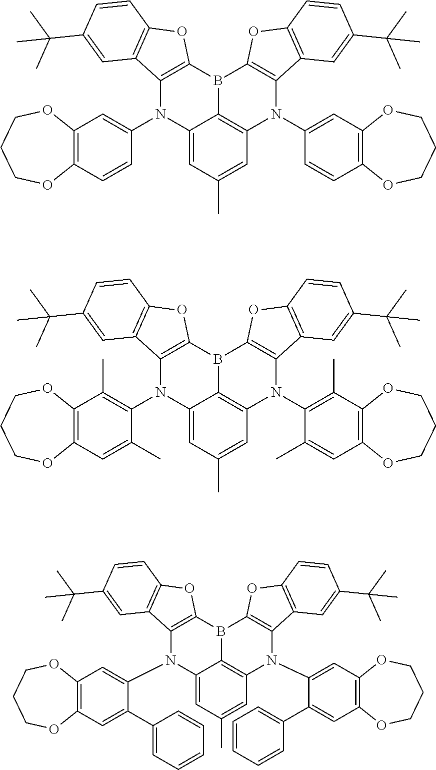 [SMILES: Cc1cc2c3c(c1)N(c1ccc4c(c1)OCCCO4)c1c(oc4ccc(C(C)(C)C)cc14)B3c1oc3ccc(C(C)(C)C)cc3c1N2c1ccc2c(c1)OCCCO2 ; Cc1cc2c3c(c1)N(c1c(C)cc4c(c1C)OCCCO4)c1c(oc4ccc(C(C)(C)C)cc14)B3c1oc3ccc(C(C)(C)C)cc3c1N2c1c(C)cc2c(c1C)OCCCO2 ; Cc1cc2c3c(c1)N(c1cc4c(cc1-c1ccccc1)OCCCO4)c1c(oc4ccc(C(C)(C)C)cc14)B3c1oc3ccc(C(C)(C)C)cc3c1N2c1cc2c(cc1-c1ccccc1)OCCCO2]

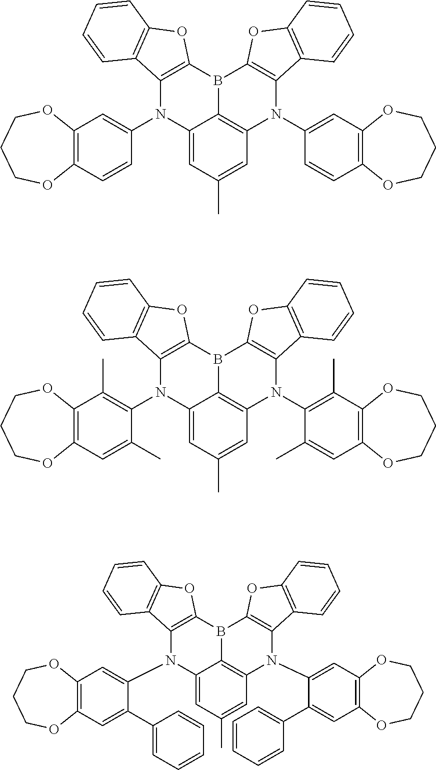 [SMILES: Cc1cc2c3c(c1)N(c1ccc4c(c1)OCCCO4)c1c(oc4ccccc14)B3c1oc3ccccc3c1N2c1ccc2c(c1)OCCCO2 ; Cc1cc2c3c(c1)N(c1c(C)cc4c(c1C)OCCCO4)c1c(oc4ccccc14)B3c1oc3ccccc3c1N2c1c(C)cc2c(c1C)OCCCO2 ; Cc1cc2c3c(c1)N(c1cc4c(cc1-c1ccccc1)OCCCO4)c1c(oc4ccccc14)B3c1oc3ccccc3c1N2c1cc2c(cc1-c1ccccc1)OCCCO2]

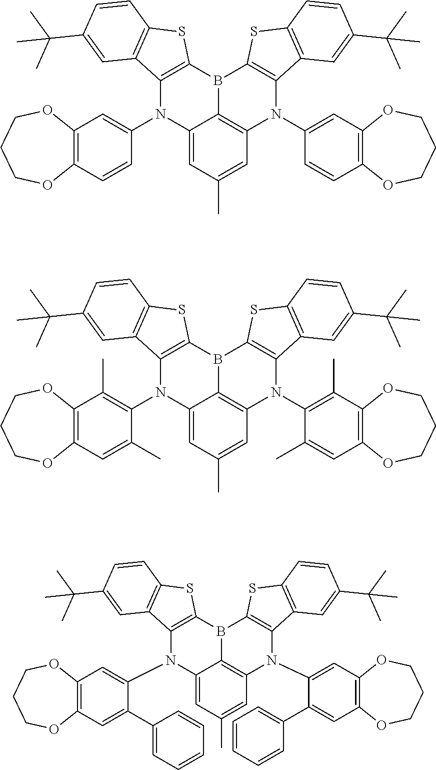 [SMILES: Cc1cc2c3c(c1)N(c1ccc4c(c1)OCCCO4)c1c(sc4ccc(C(C)(C)C)cc14)B3c1sc3ccc(C(C)(C)C)cc3c1N2c1ccc2c(c1)OCCCO2 ; Cc1cc2c3c(c1)N(c1c(C)cc4c(c1C)OCCCO4)c1c(sc4ccc(C(C)(C)C)cc14)B3c1sc3ccc(C(C)(C)C)cc3c1N2c1c(C)cc2c(c1C)OCCCO2 ; Cc1cc2c3c(c1)N(c1cc4c(cc1-c1ccccc1)OCCCO4)c1c(sc4ccc(C(C)(C)C)cc14)B3c1sc3ccc(C(C)(C)C)cc3c1N2c1cc2c(cc1-c1ccccc1)OCCCO2]

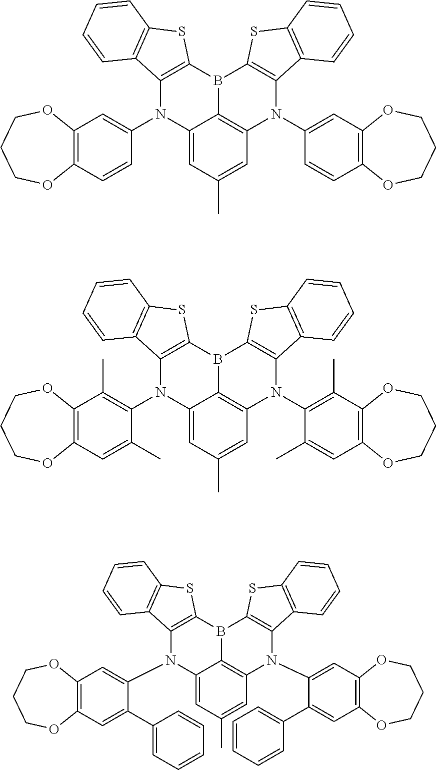 [SMILES: Cc1cc2c3c(c1)N(c1ccc4c(c1)OCCCO4)c1c(sc4ccccc14)B3c1sc3ccccc3c1N2c1ccc2c(c1)OCCCO2 ; Cc1cc2c3c(c1)N(c1c(C)cc4c(c1C)OCCCO4)c1c(sc4ccccc14)B3c1sc3ccccc3c1N2c1c(C)cc2c(c1C)OCCCO2 ; Cc1cc2c3c(c1)N(c1cc4c(cc1-c1ccccc1)OCCCO4)c1c(sc4ccccc14)B3c1sc3ccccc3c1N2c1cc2c(cc1-c1ccccc1)OCCCO2]

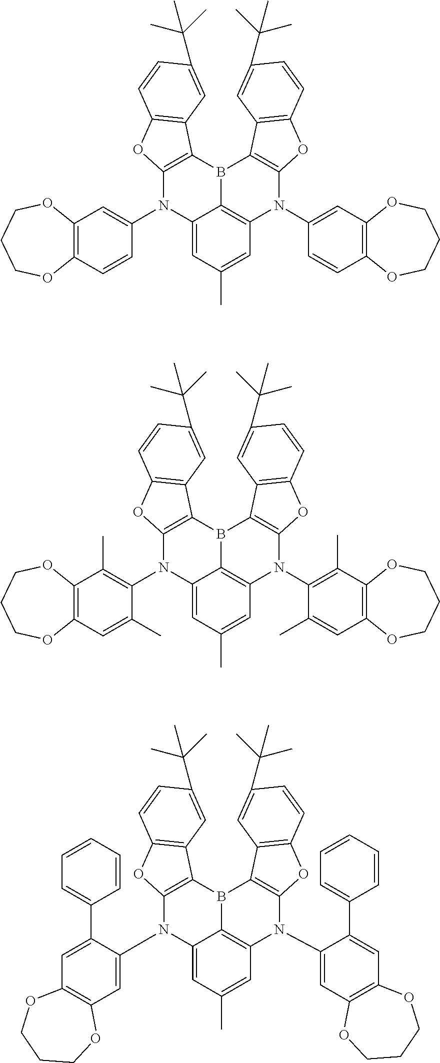 [SMILES: Cc1cc2c3c(c1)N(c1ccc4c(c1)OCCCO4)c1oc4ccc(C(C)(C)C)cc4c1B3c1c(oc3ccc(C(C)(C)C)cc13)N2c1ccc2c(c1)OCCCO2 ; Cc1cc2c3c(c1)N(c1c(C)cc4c(c1C)OCCCO4)c1oc4ccc(C(C)(C)C)cc4c1B3c1c(oc3ccc(C(C)(C)C)cc13)N2c1c(C)cc2c(c1C)OCCCO2 ; Cc1cc2c3c(c1)N(c1cc4c(cc1-c1ccccc1)OCCCO4)c1oc4ccc(C(C)(C)C)cc4c1B3c1c(oc3ccc(C(C)(C)C)cc13)N2c1cc2c(cc1-c1ccccc1)OCCCO2]

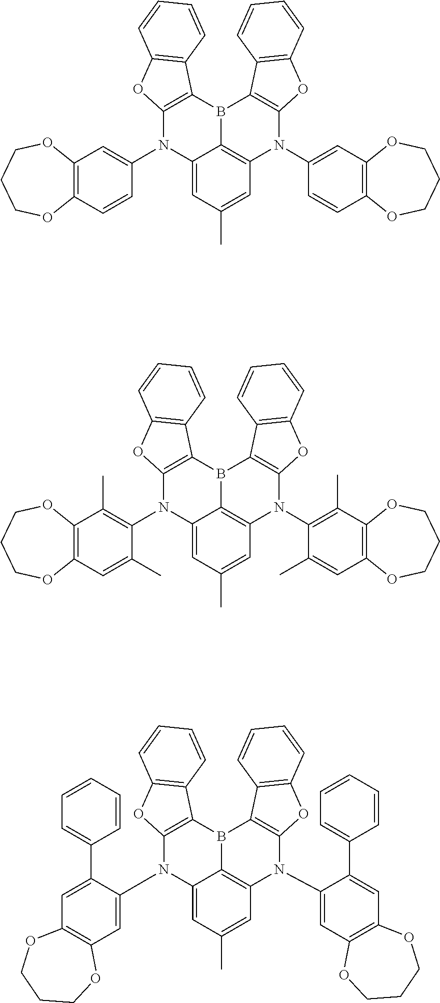 [SMILES: Cc1cc2c3c(c1)N(c1ccc4c(c1)OCCCO4)c1oc4ccccc4c1B3c1c(oc3ccccc13)N2c1ccc2c(c1)OCCCO2 ; Cc1cc2c3c(c1)N(c1c(C)cc4c(c1C)OCCCO4)c1oc4ccccc4c1B3c1c(oc3ccccc13)N2c1c(C)cc2c(c1C)OCCCO2 ; Cc1cc2c3c(c1)N(c1cc4c(cc1-c1ccccc1)OCCCO4)c1oc4ccccc4c1B3c1c(oc3ccccc13)N2c1cc2c(cc1-c1ccccc1)OCCCO2]

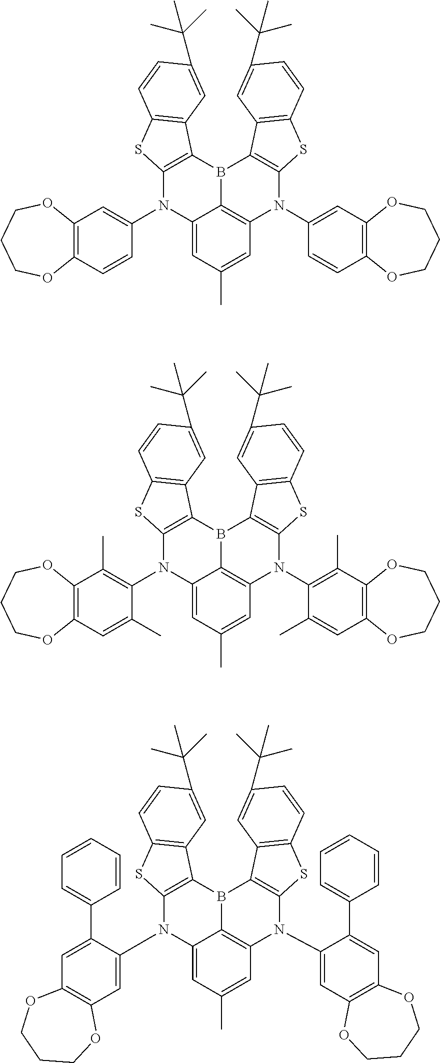 [SMILES: Cc1cc2c3c(c1)N(c1ccc4c(c1)OCCCO4)c1sc4ccc(C(C)(C)C)cc4c1B3c1c(sc3ccc(C(C)(C)C)cc13)N2c1ccc2c(c1)OCCCO2 ; Cc1cc2c3c(c1)N(c1c(C)cc4c(c1C)OCCCO4)c1sc4ccc(C(C)(C)C)cc4c1B3c1c(sc3ccc(C(C)(C)C)cc13)N2c1c(C)cc2c(c1C)OCCCO2 ; Cc1cc2c3c(c1)N(c1cc4c(cc1-c1ccccc1)OCCCO4)c1sc4ccc(C(C)(C)C)cc4c1B3c1c(sc3ccc(C(C)(C)C)cc13)N2c1cc2c(cc1-c1ccccc1)OCCCO2]

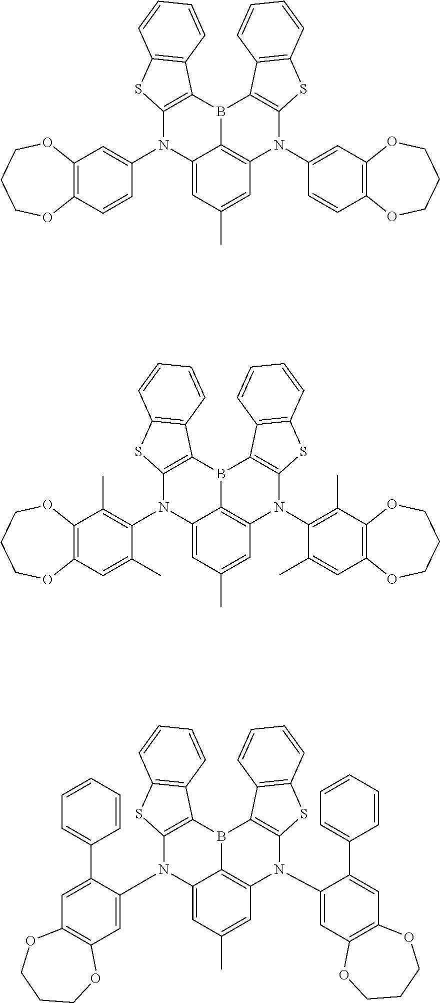 [SMILES: Cc1cc2c3c(c1)N(c1ccc4c(c1)OCCCO4)c1sc4ccccc4c1B3c1c(sc3ccccc13)N2c1ccc2c(c1)OCCCO2 ; Cc1cc2c3c(c1)N(c1c(C)cc4c(c1C)OCCCO4)c1sc4ccccc4c1B3c1c(sc3ccccc13)N2c1c(C)cc2c(c1C)OCCCO2 ; Cc1cc2c3c(c1)N(c1cc4c(cc1-c1ccccc1)OCCCO4)c1sc4ccccc4c1B3c1c(sc3ccccc13)N2c1cc2c(cc1-c1ccccc1)OCCCO2]

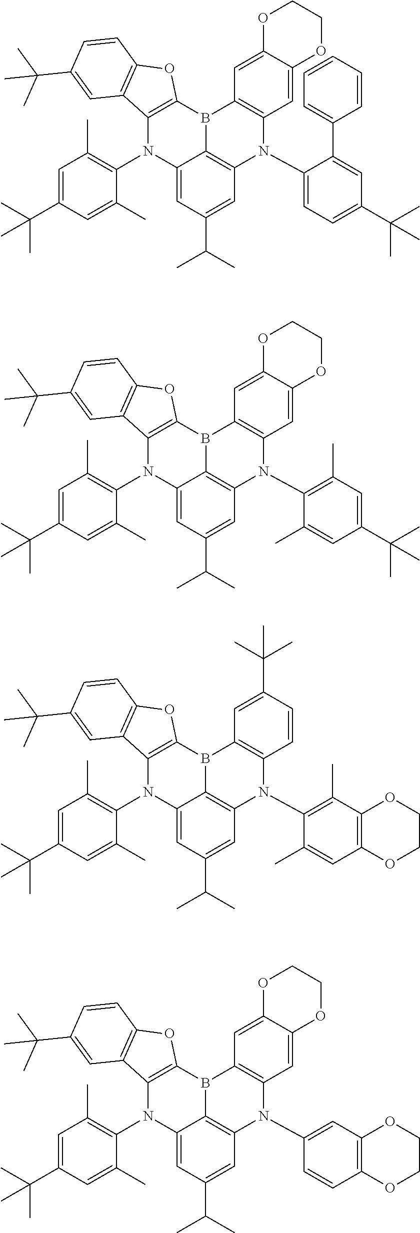

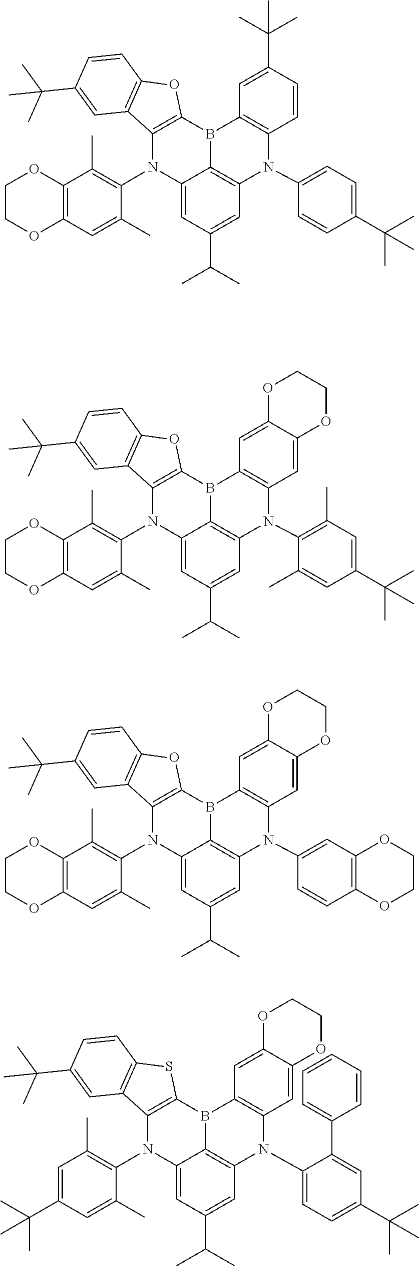

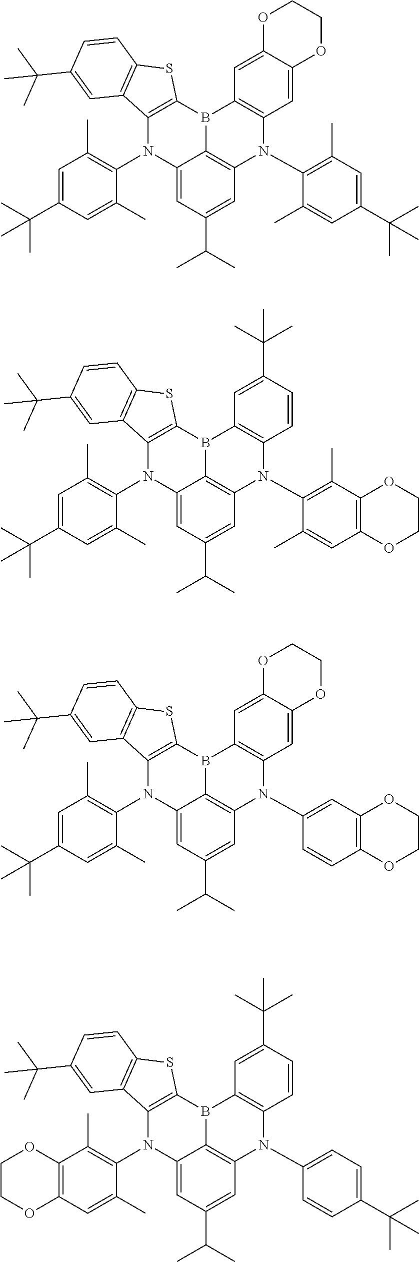

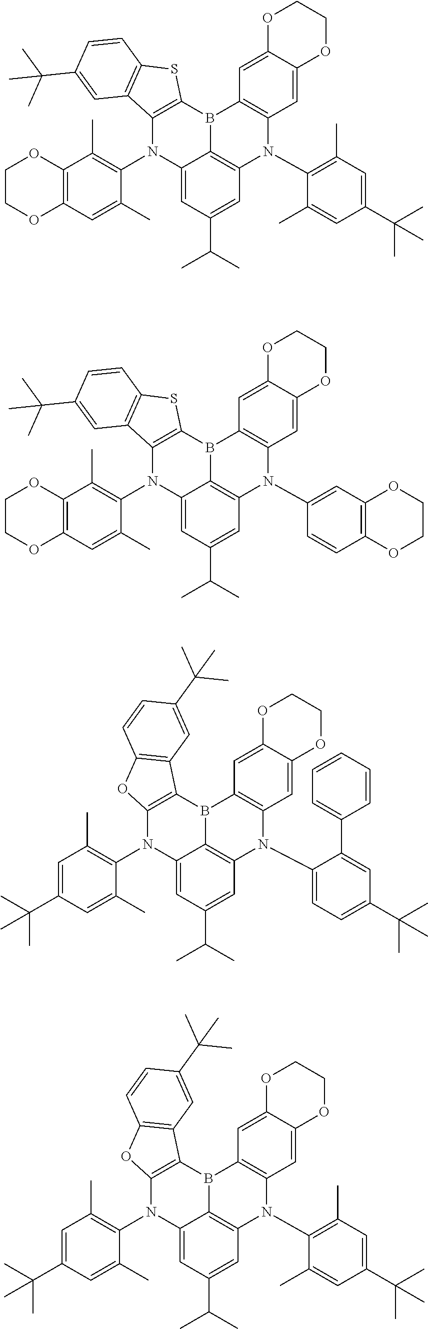

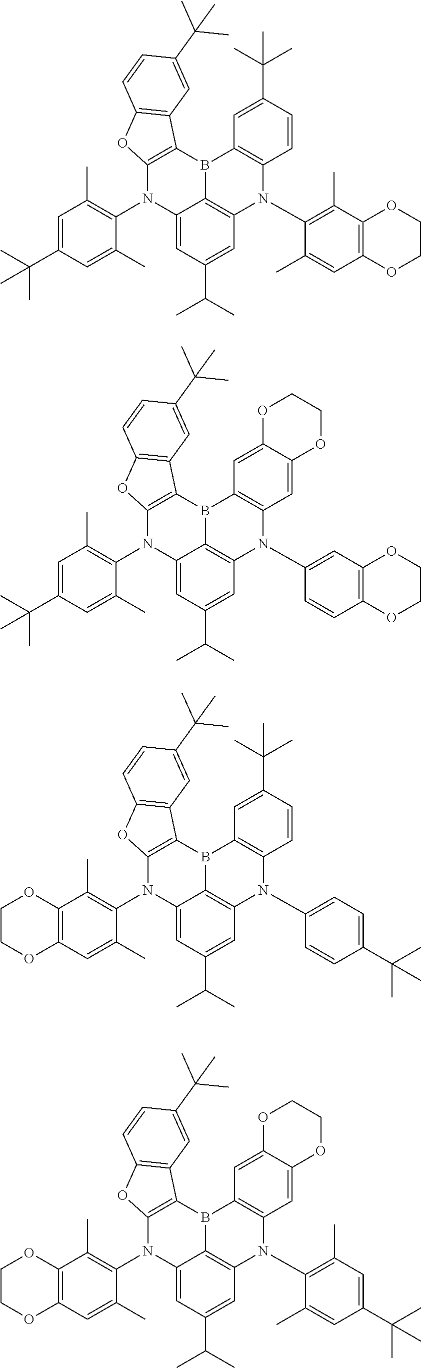

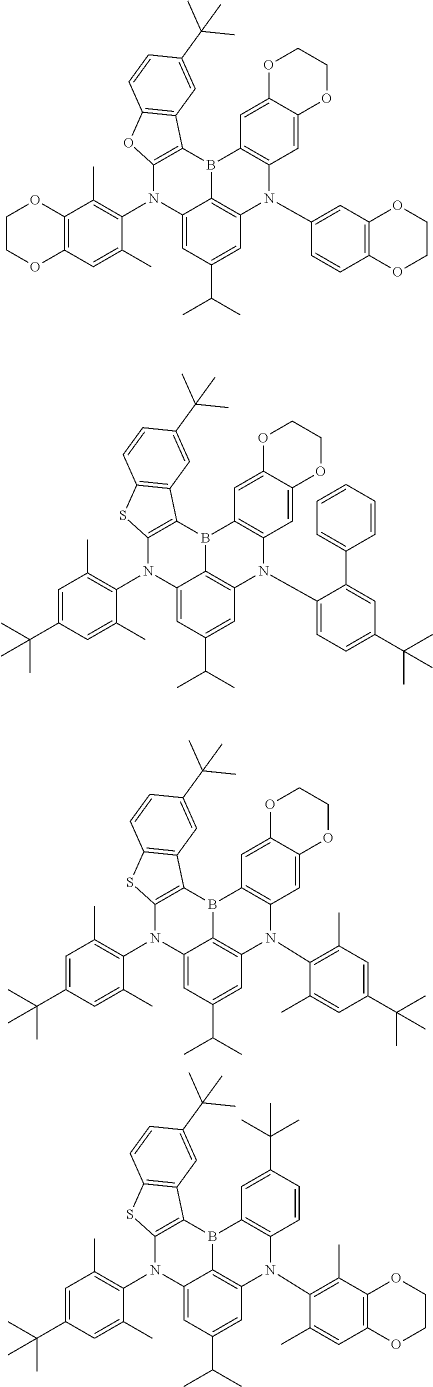

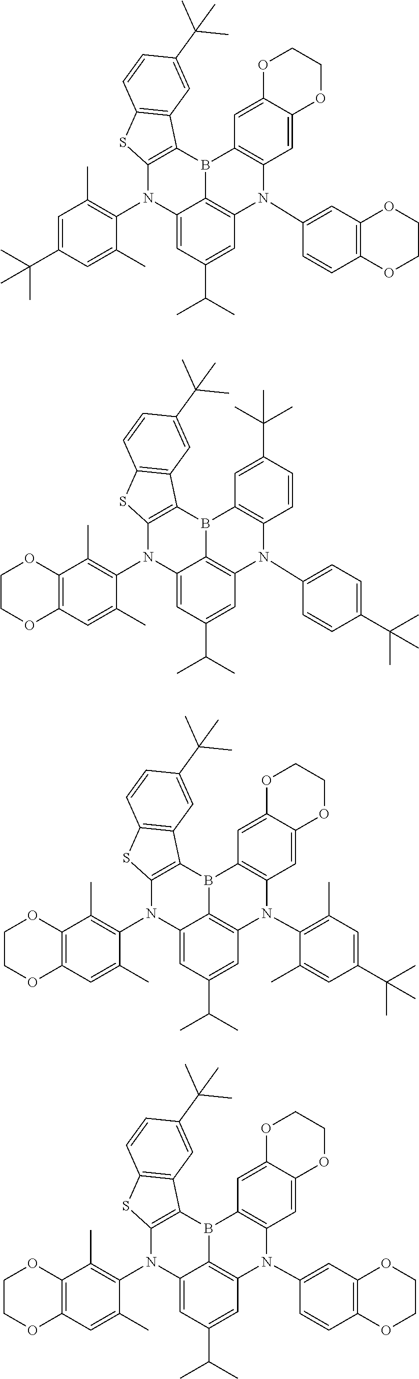

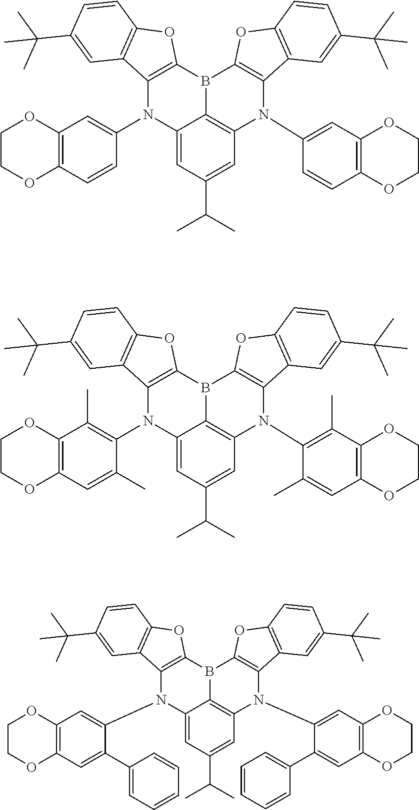 [SMILES: CC(C)c1cc2c3c(c1)N(c1ccc4c(c1)OCCO4)c1c(oc4ccc(C(C)(C)C)cc14)B3c1oc3ccc(C(C)(C)C)cc3c1N2c1ccc2c(c1)OCCO2 ; Cc1cc2c(c(C)c1N1c3cc(C(C)C)cc4c3B(c3oc5ccc(C(C)(C)C)cc5c31)c1oc3ccc(C(C)(C)C)cc3c1N4c1c(C)cc3c(c1C)OCCO3)OCCO2 ; CC(C)c1cc2c3c(c1)N(c1cc4c(cc1-c1ccccc1)OCCO4)c1c(oc4ccc(C(C)(C)C)cc14)B3c1oc3ccc(C(C)(C)C)cc3c1N2c1cc2c(cc1-c1ccccc1)OCCO2]

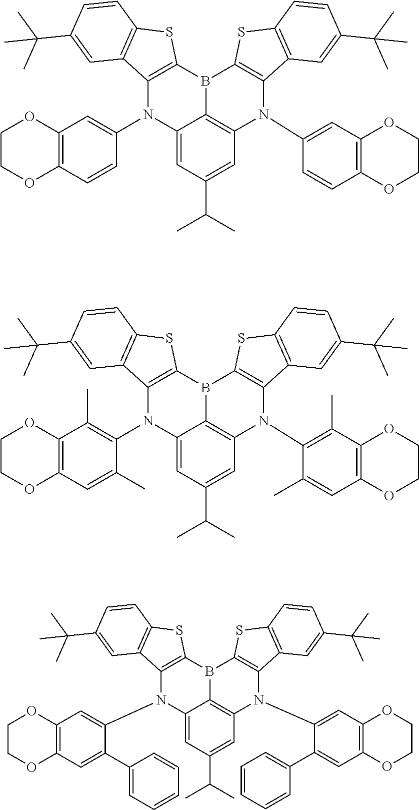 [SMILES: CC(C)c1cc2c3c(c1)N(c1ccc4c(c1)OCCO4)c1c(sc4ccc(C(C)(C)C)cc14)B3c1sc3ccc(C(C)(C)C)cc3c1N2c1ccc2c(c1)OCCO2 ; Cc1cc2c(c(C)c1N1c3cc(C(C)C)cc4c3B(c3sc5ccc(C(C)(C)C)cc5c31)c1sc3ccc(C(C)(C)C)cc3c1N4c1c(C)cc3c(c1C)OCCO3)OCCO2 ; CC(C)c1cc2c3c(c1)N(c1cc4c(cc1-c1ccccc1)OCCO4)c1c(sc4ccc(C(C)(C)C)cc14)B3c1sc3ccc(C(C)(C)C)cc3c1N2c1cc2c(cc1-c1ccccc1)OCCO2]

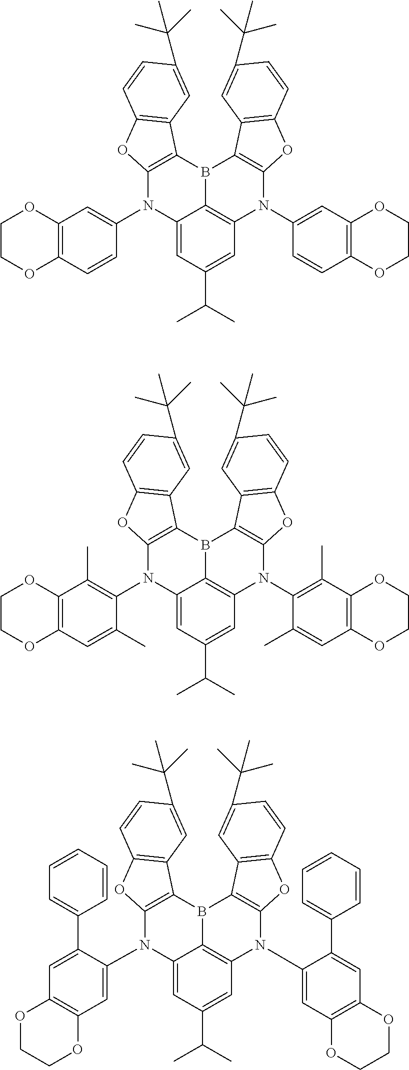 [SMILES: CC(C)c1cc2c3c(c1)N(c1ccc4c(c1)OCCO4)c1oc4ccc(C(C)(C)C)cc4c1B3c1c(oc3ccc(C(C)(C)C)cc13)N2c1ccc2c(c1)OCCO2 ; Cc1cc2c(c(C)c1N1c3cc(C(C)C)cc4c3B(c3c1oc1ccc(C(C)(C)C)cc31)c1c(oc3ccc(C(C)(C)C)cc13)N4c1c(C)cc3c(c1C)OCCO3)OCCO2 ; CC(C)c1cc2c3c(c1)N(c1cc4c(cc1-c1ccccc1)OCCO4)c1oc4ccc(C(C)(C)C)cc4c1B3c1c(oc3ccc(C(C)(C)C)cc13)N2c1cc2c(cc1-c1ccccc1)OCCO2]

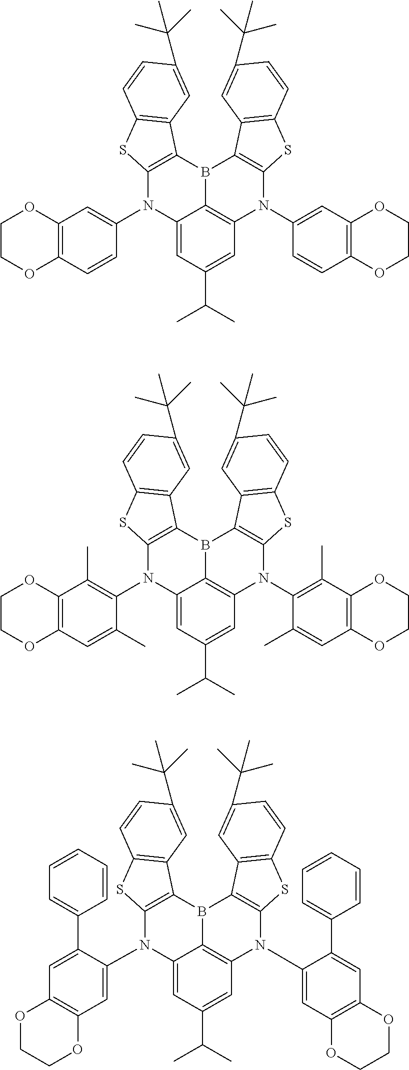 [SMILES: CC(C)c1cc2c3c(c1)N(c1ccc4c(c1)OCCO4)c1sc4ccc(C(C)(C)C)cc4c1B3c1c(sc3ccc(C(C)(C)C)cc13)N2c1ccc2c(c1)OCCO2 ; Cc1cc2c(c(C)c1N1c3cc(C(C)C)cc4c3B(c3c1sc1ccc(C(C)(C)C)cc31)c1c(sc3ccc(C(C)(C)C)cc13)N4c1c(C)cc3c(c1C)OCCO3)OCCO2 ; CC(C)c1cc2c3c(c1)N(c1cc4c(cc1-c1ccccc1)OCCO4)c1sc4ccc(C(C)(C)C)cc4c1B3c1c(sc3ccc(C(C)(C)C)cc13)N2c1cc2c(cc1-c1ccccc1)OCCO2]

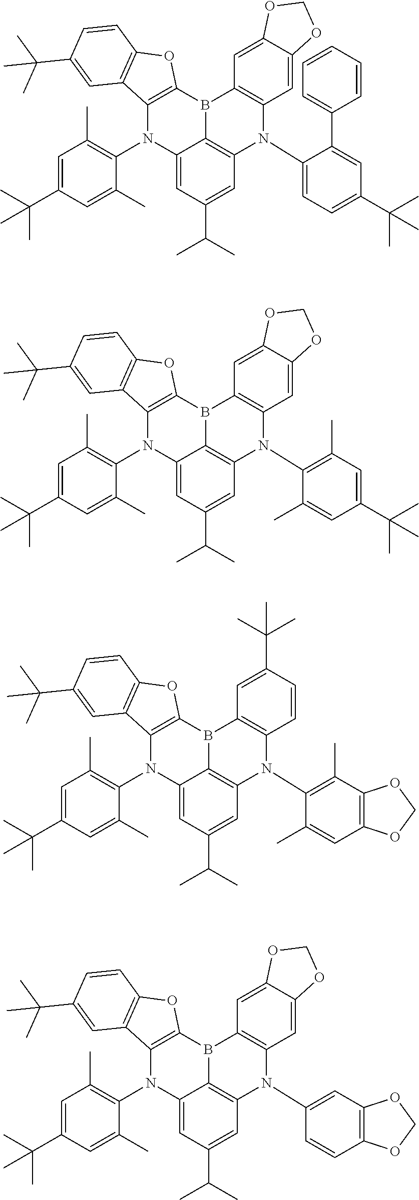

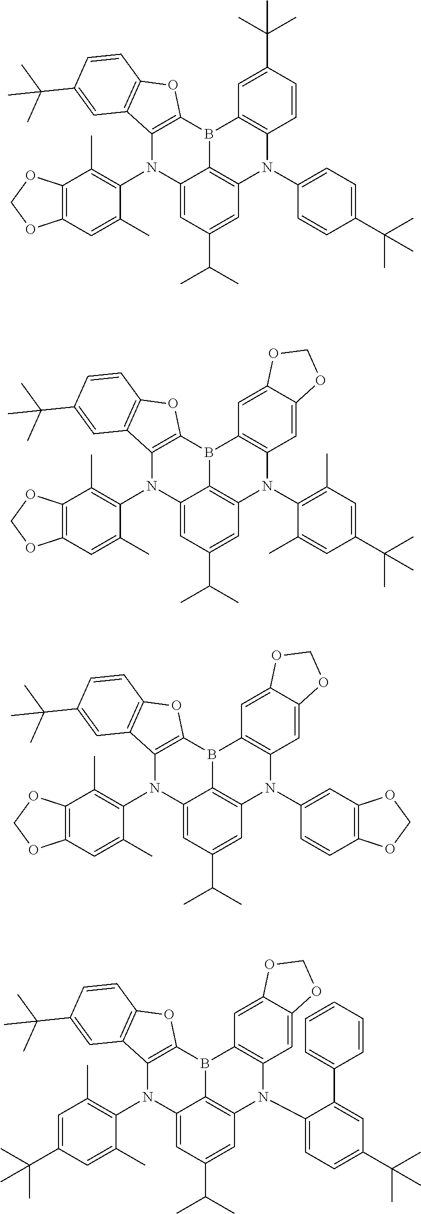

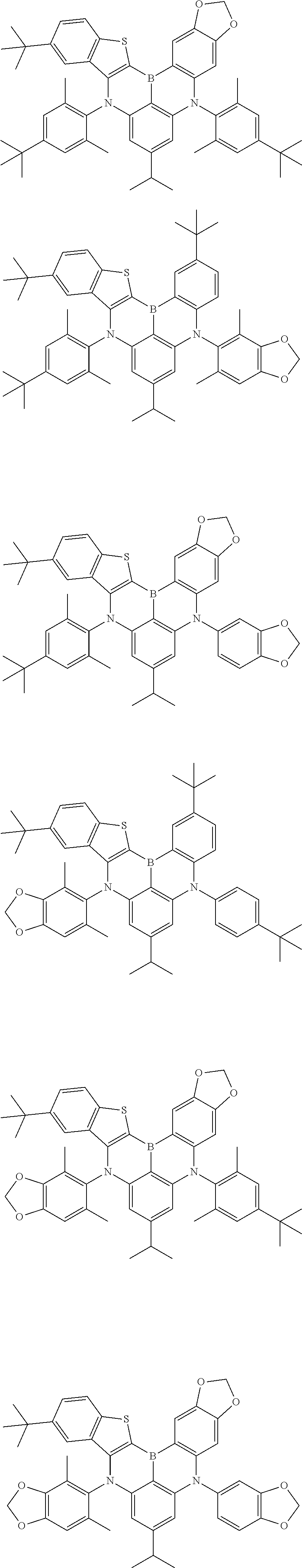

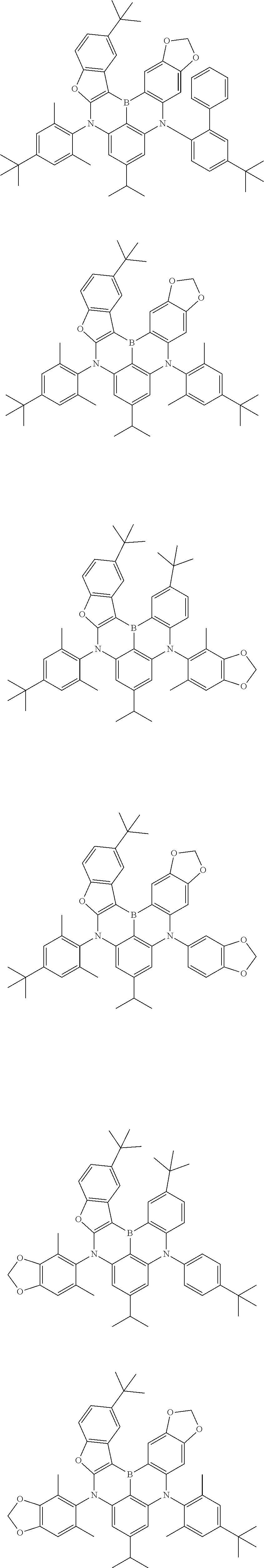

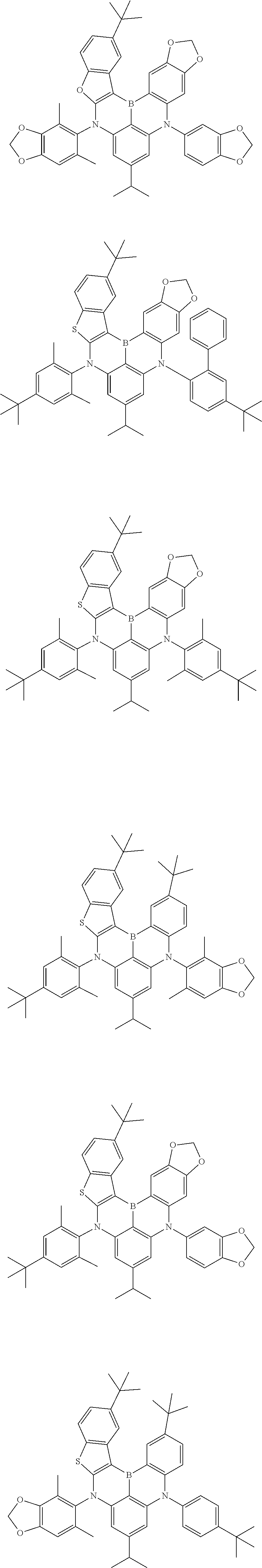

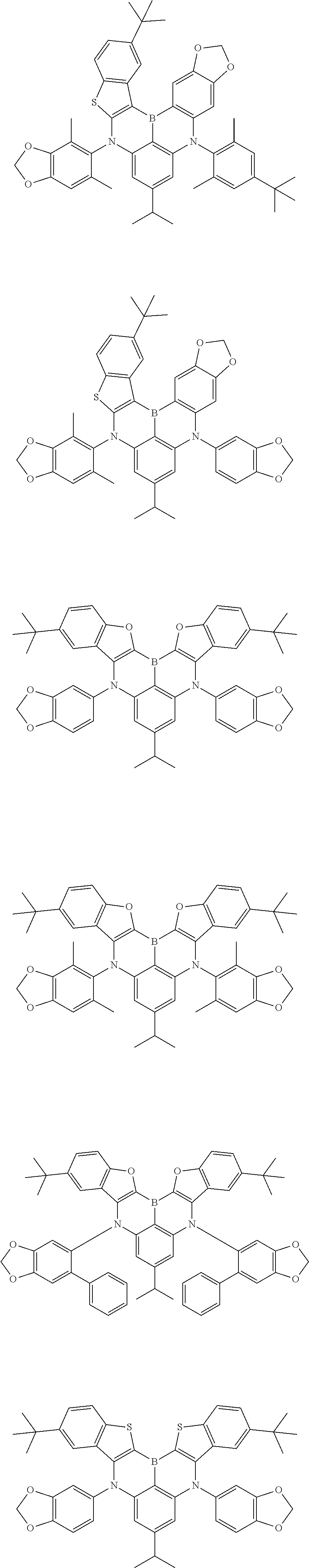

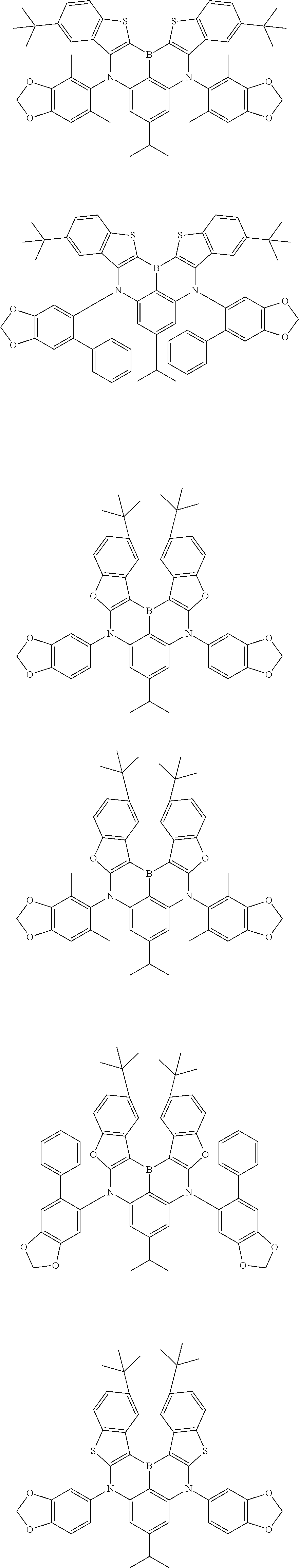

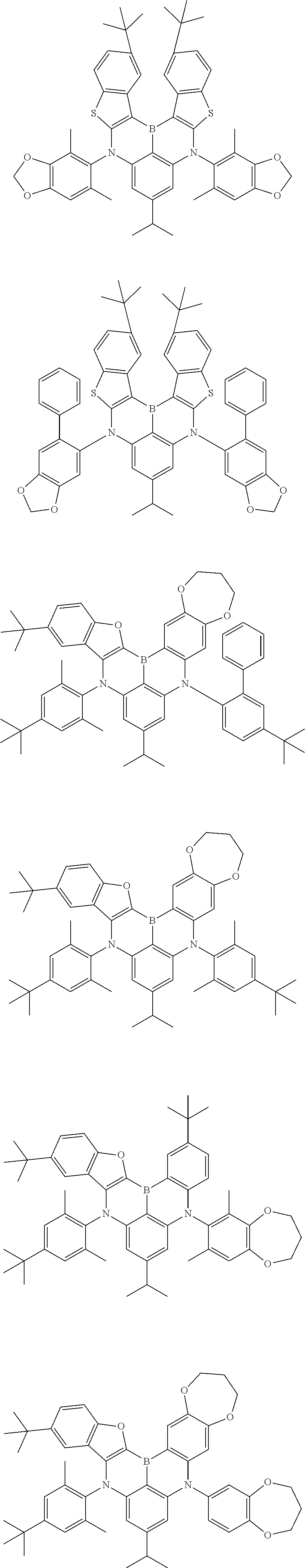

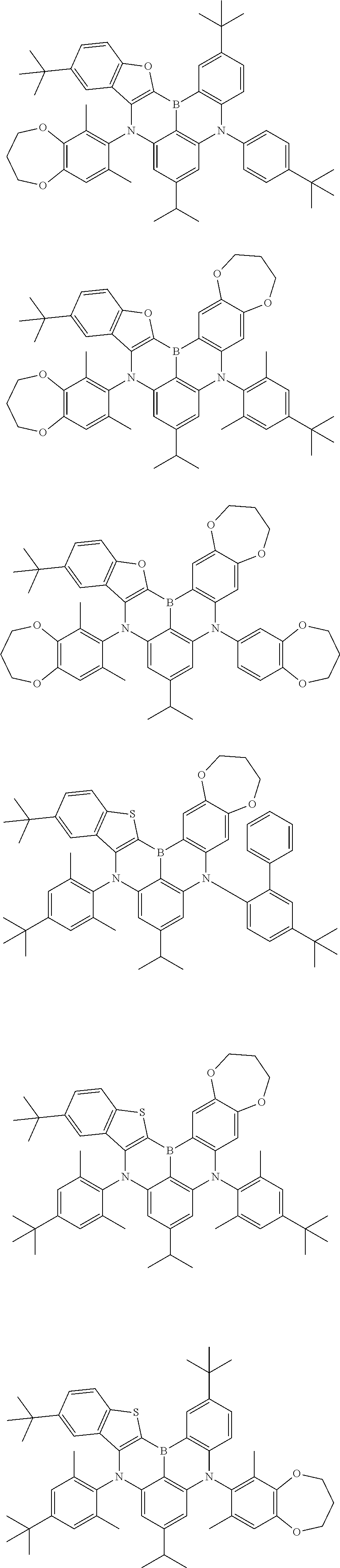

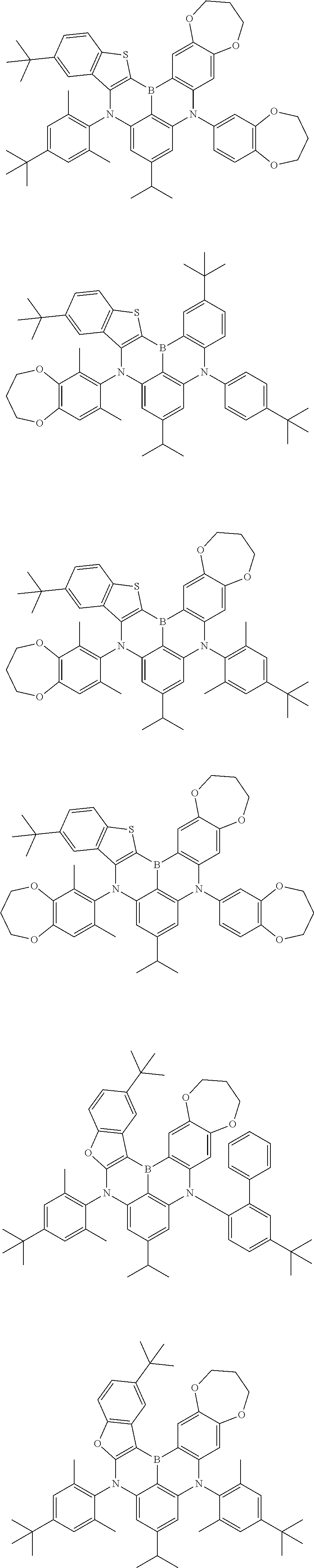

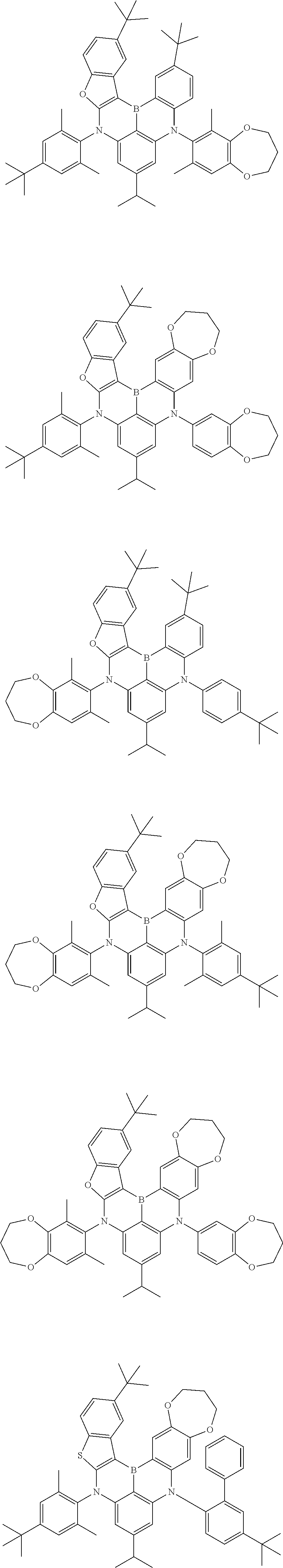

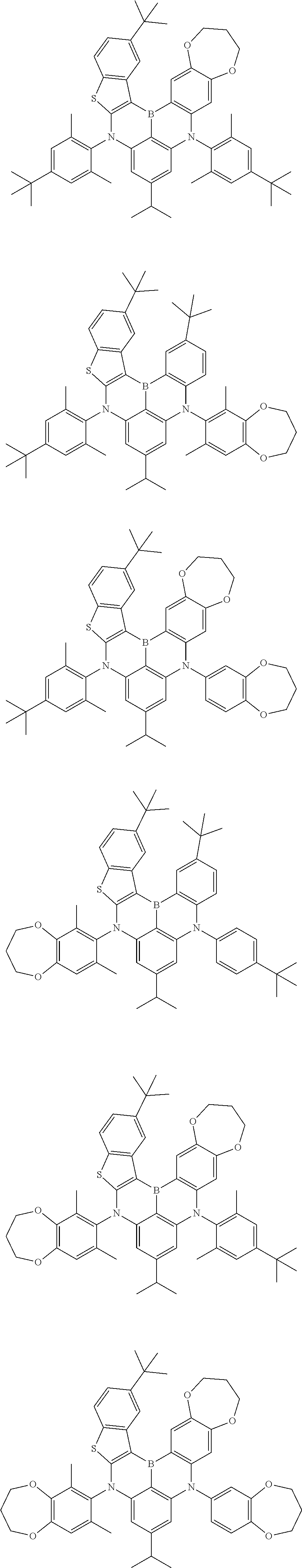

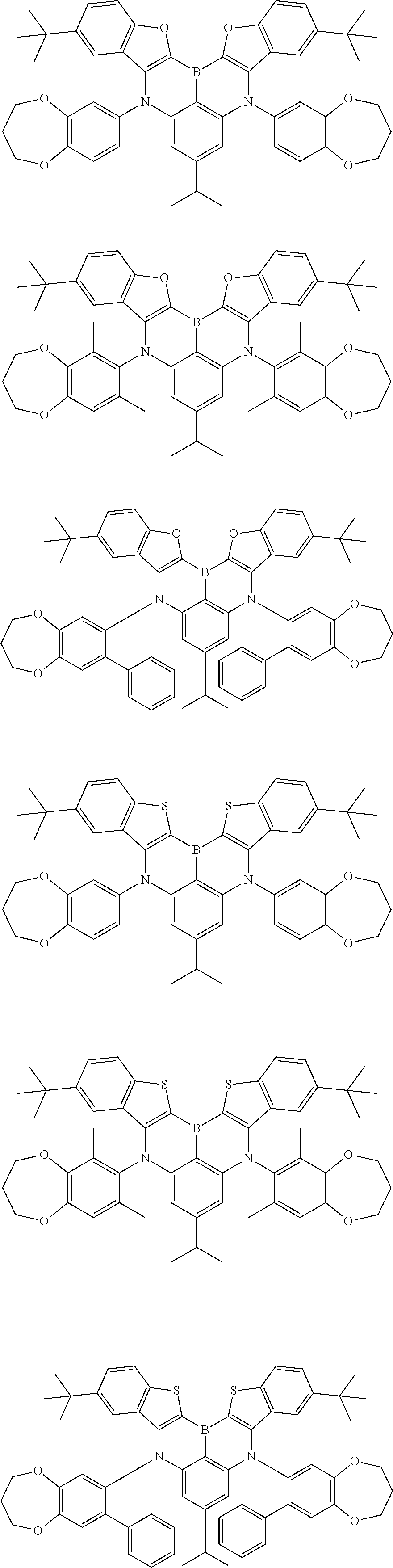

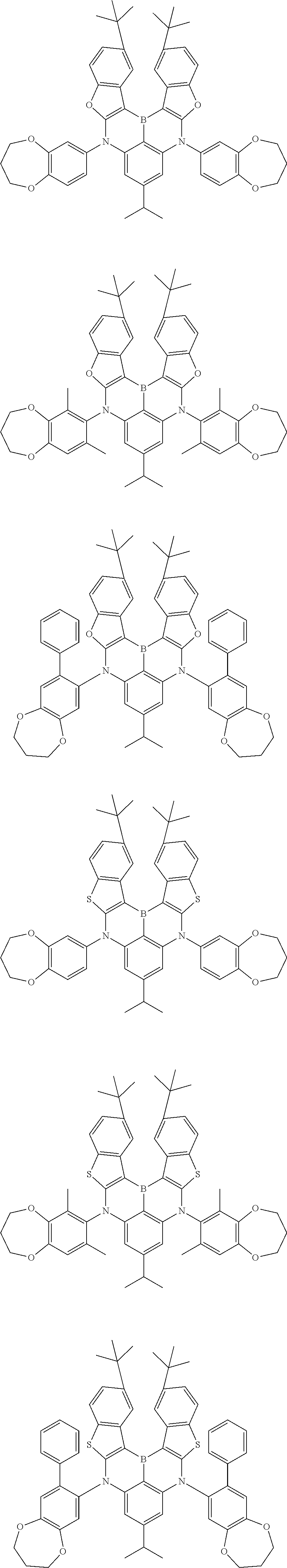

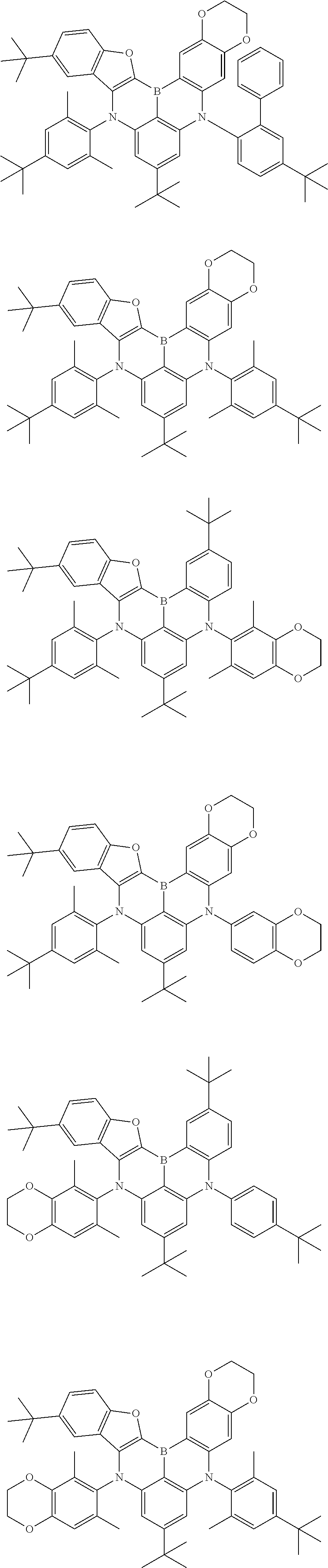

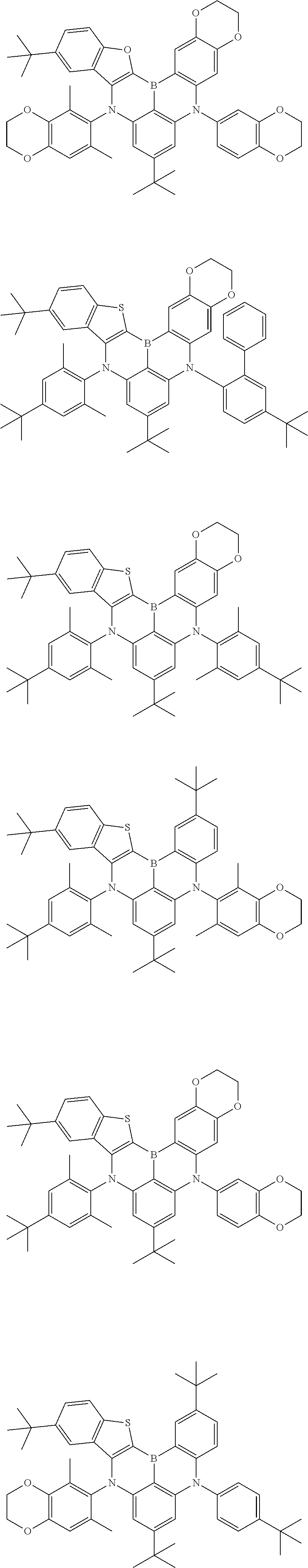

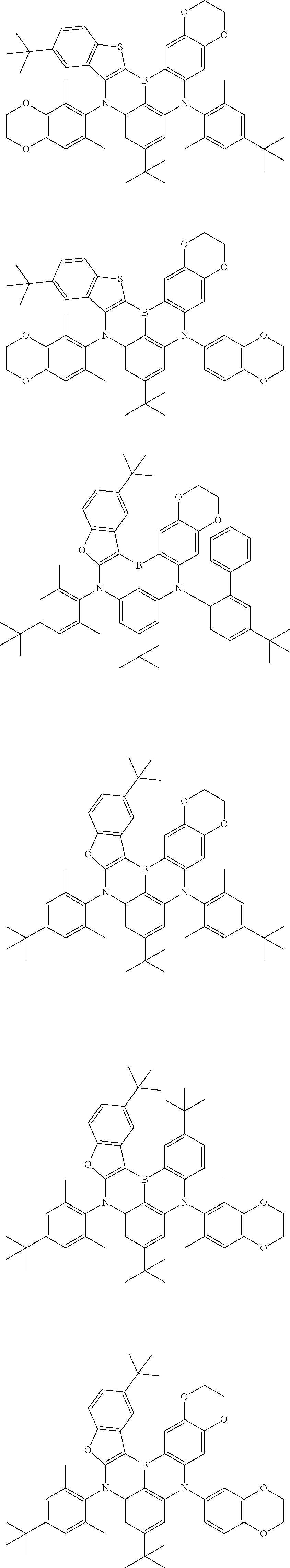

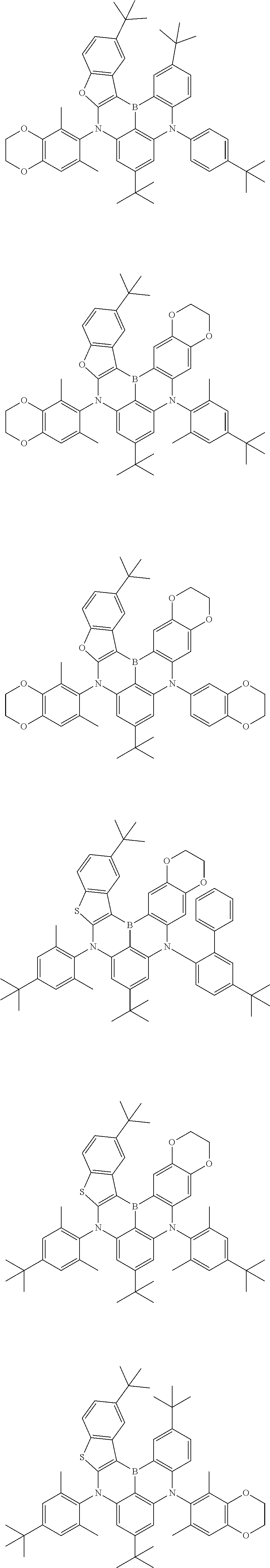

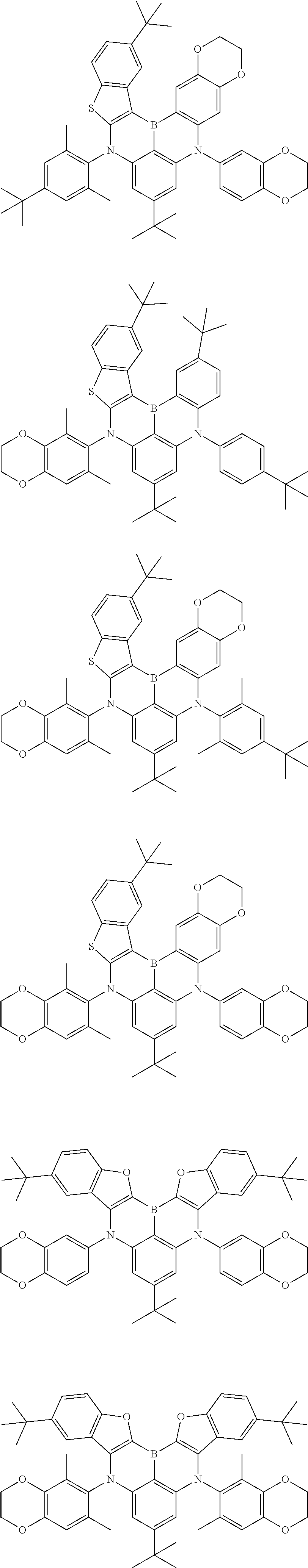

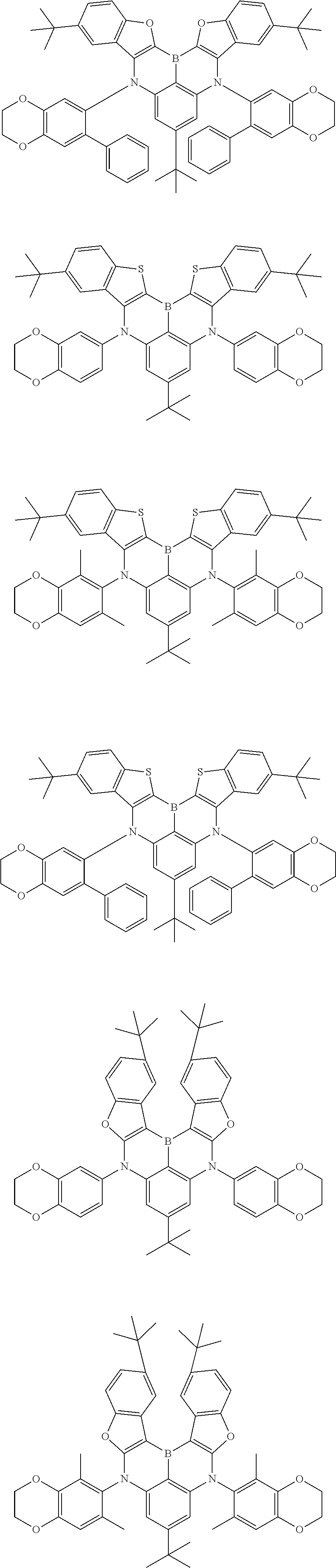

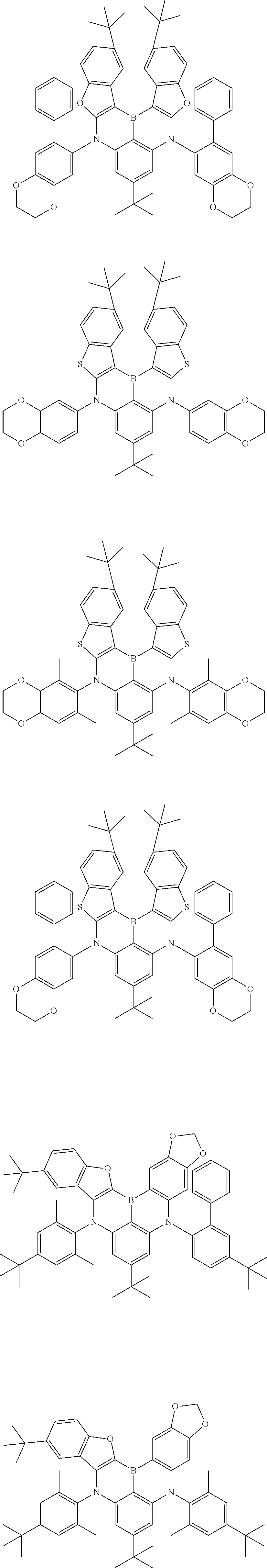

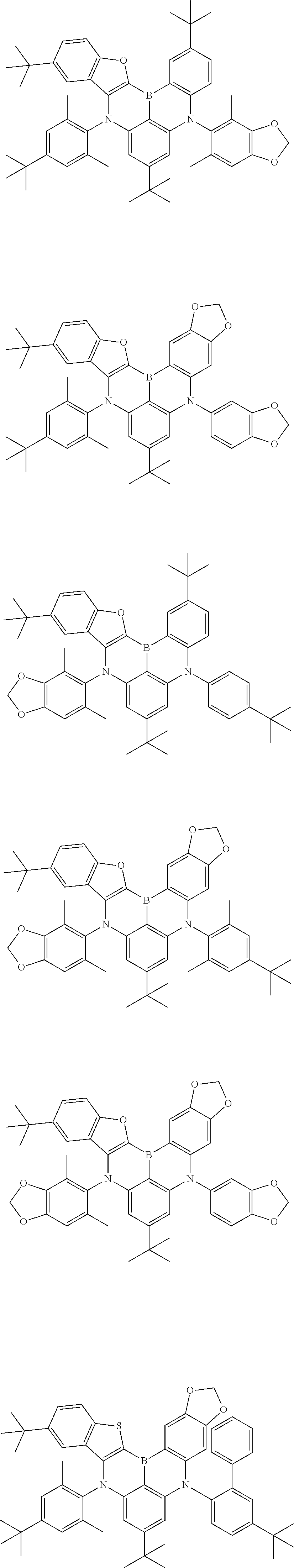

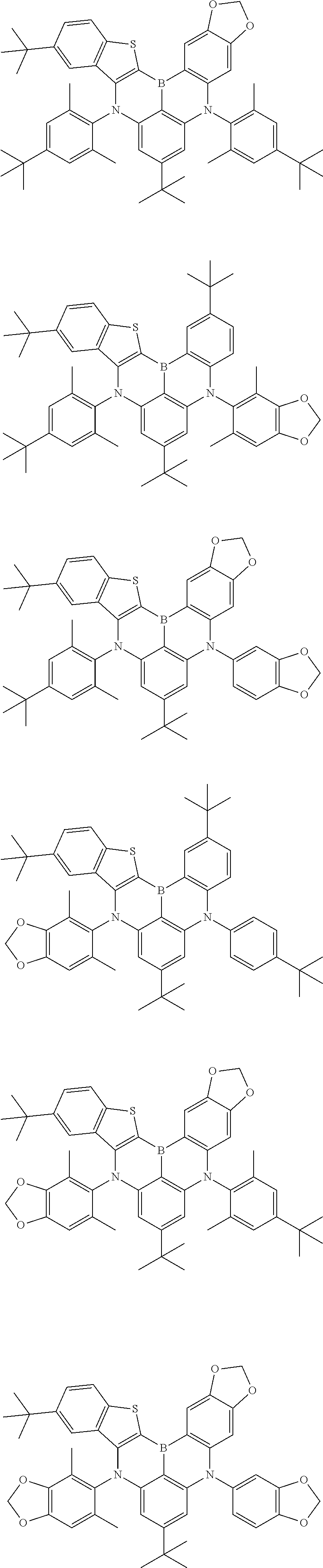

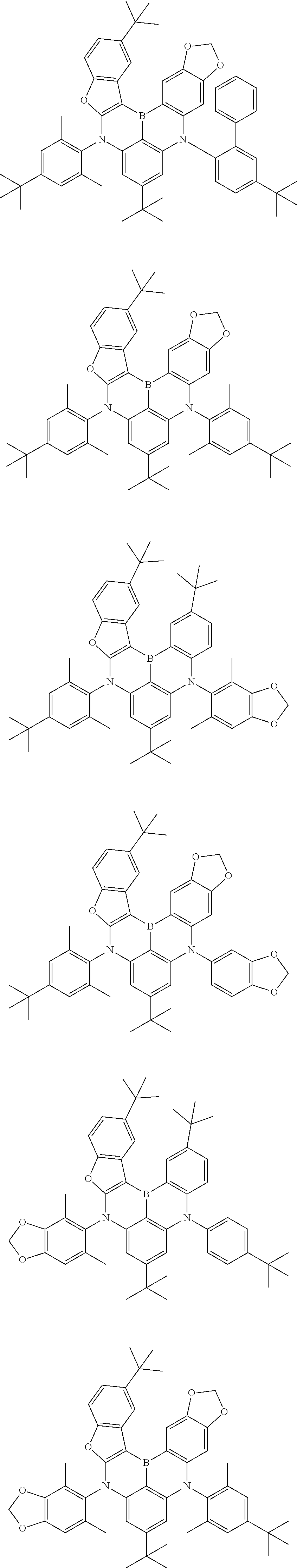

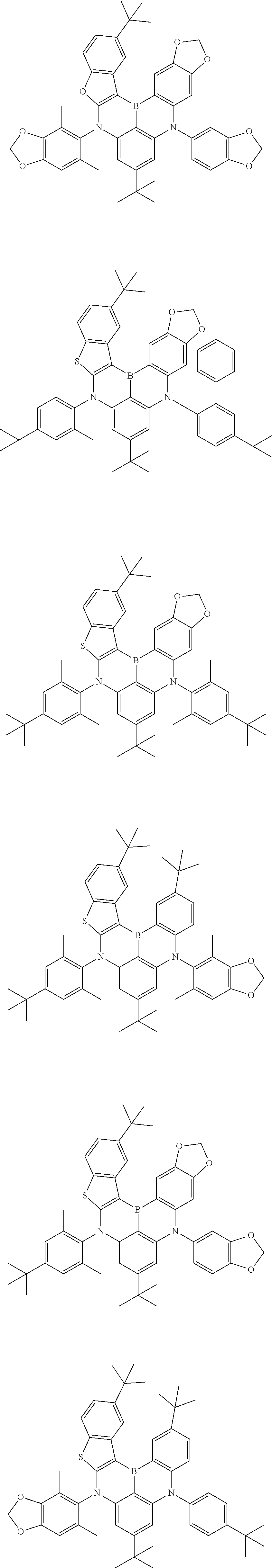

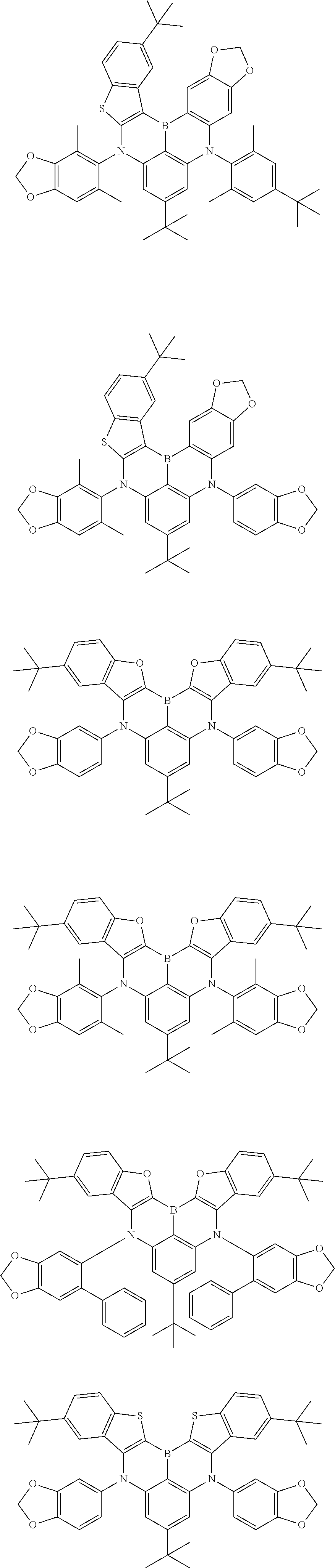

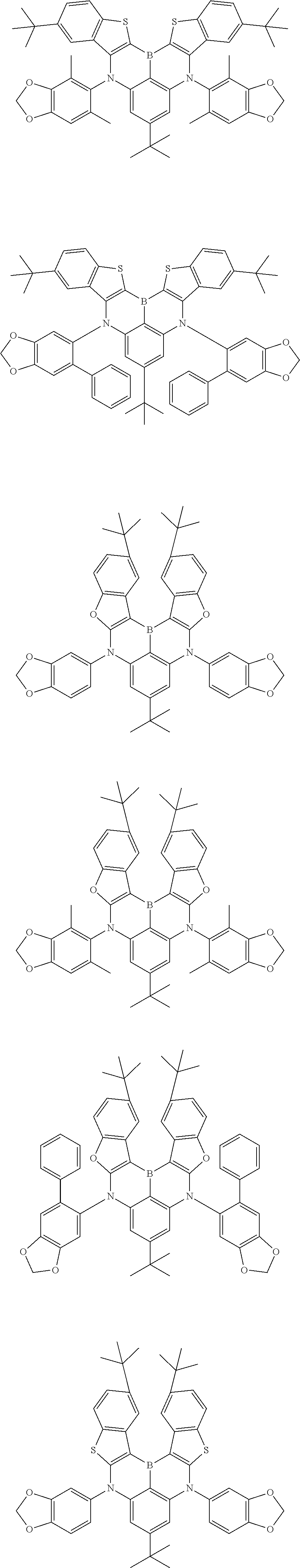

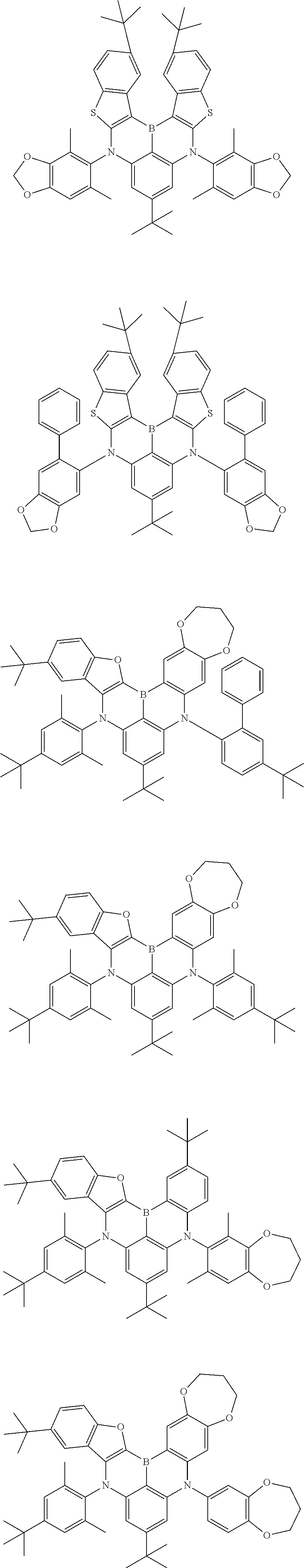

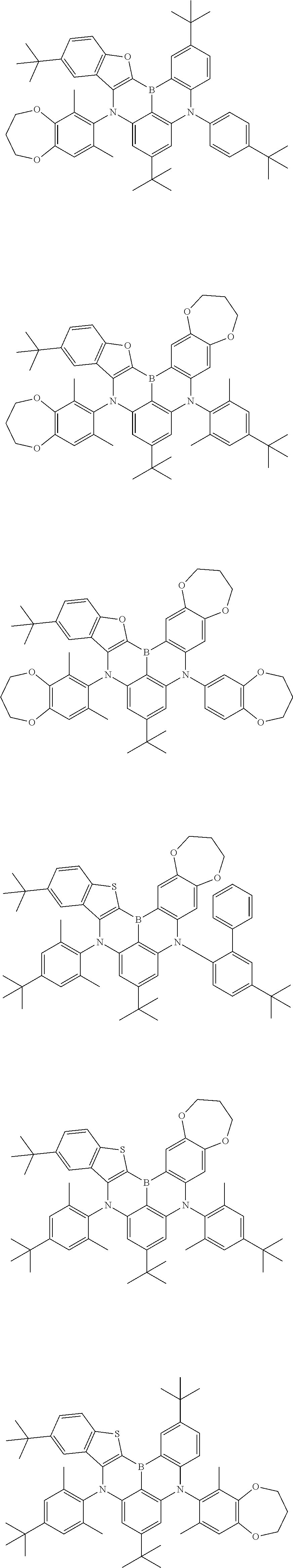

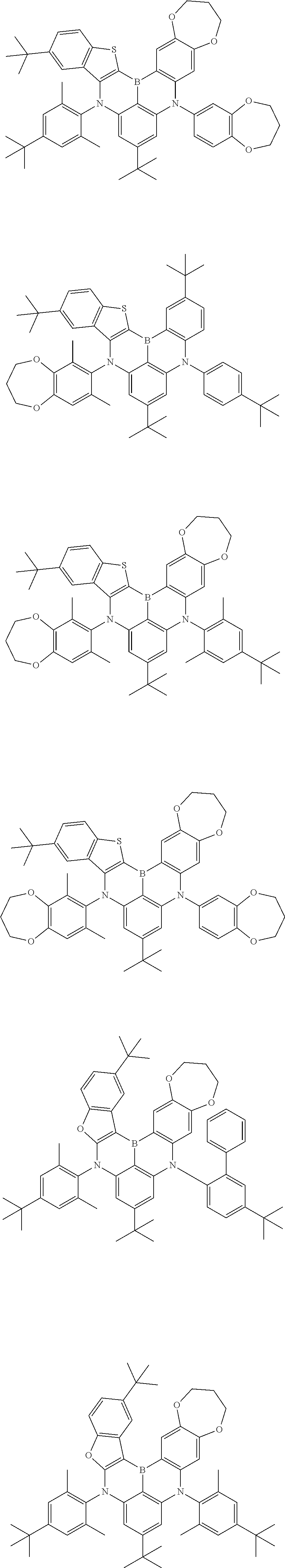

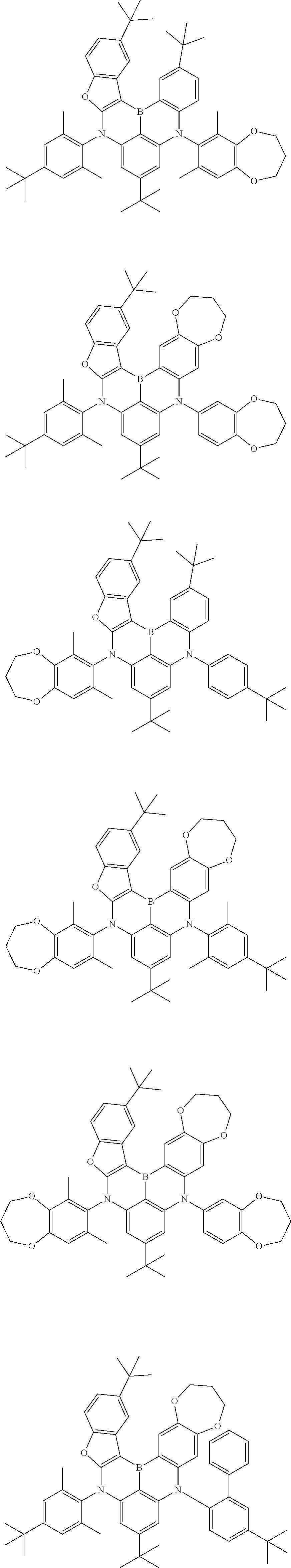

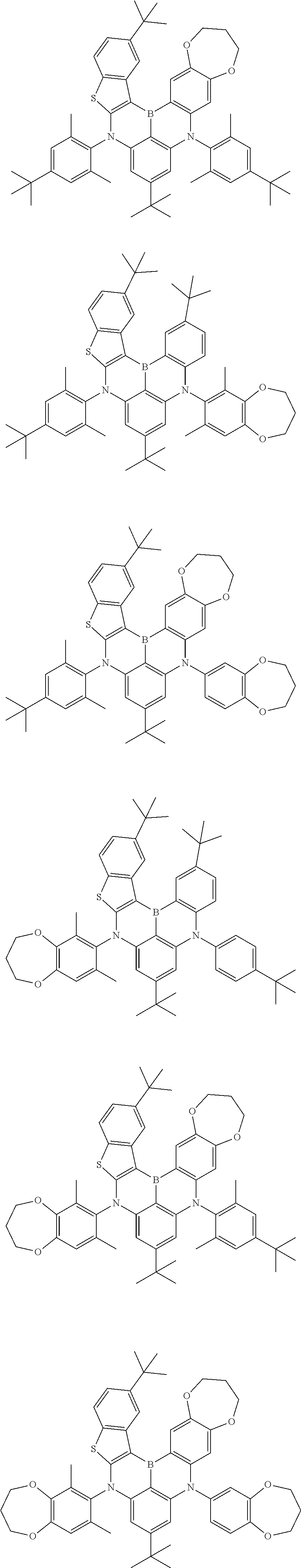

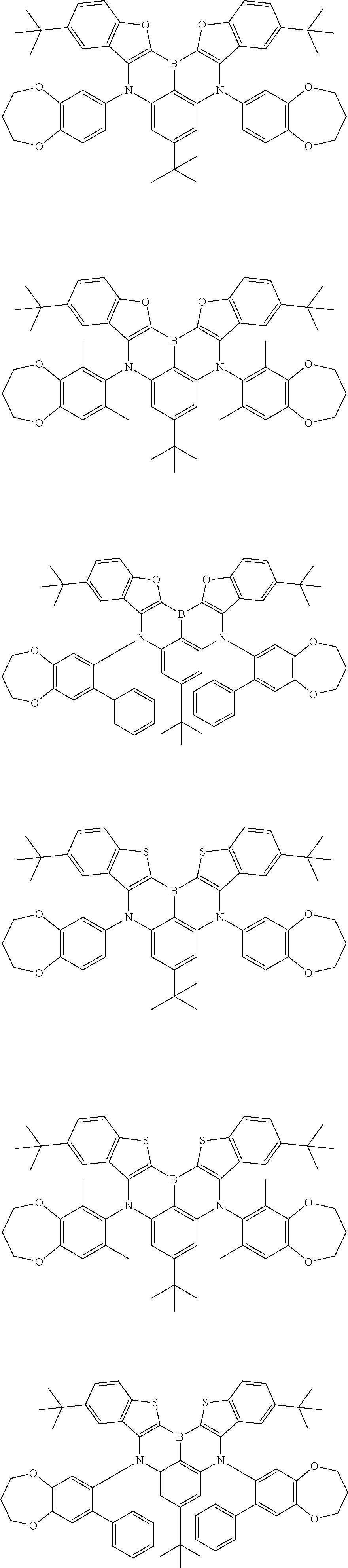

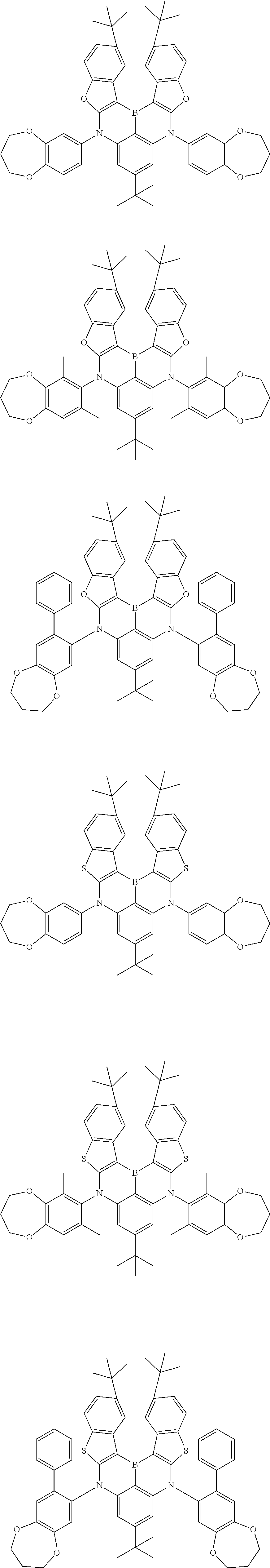

Meanwhile, there is provided a method for preparing a compound represented by the Chemical Formula 1 as shown in Reaction Scheme 1 below:

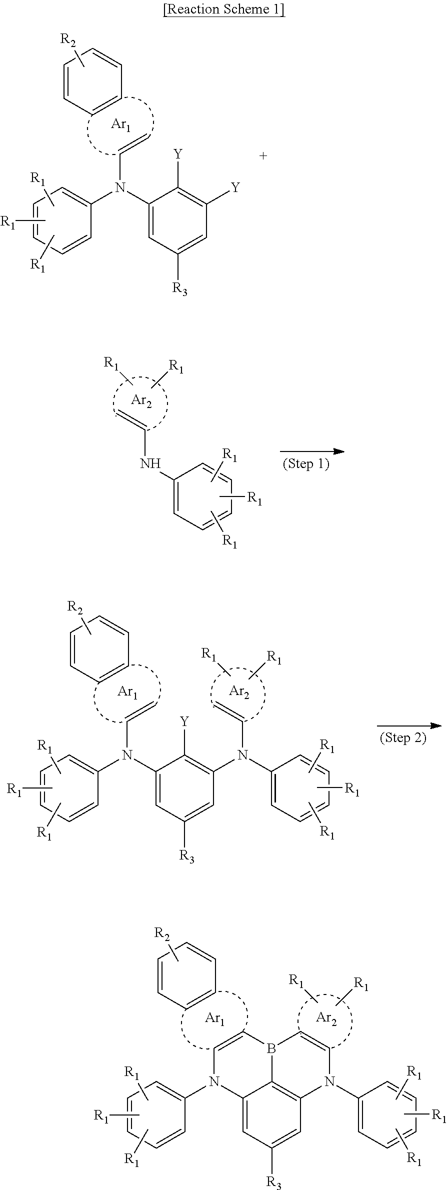

in the Reaction Scheme 1, definitions of other substituents except for Y are the same as defined above, and Y is halogen, preferably bromo, or chloro.

The step 1 is an amine substitution reaction, and preferably performed in the presence of a palladium catalyst and a base. In addition, the reactive group for the amine substitution reaction may be appropriately changed. The step 2 is a reaction with Bl₃, and preferably performed in the presence of a base. The preparation method may be more specifically described in Preparation Examples described below.

Meanwhile, the organic material layer including the compound according to the present disclosure can be prepared using various methods such as a vacuum deposition method and a solution process, and the solution process will be described in more detail below.

### (Coating Composition)

Meanwhile, the compound according to the present disclosure can form an organic material layer of an organic light emitting device, particularly, a light emitting layer by a solution process. Specifically, the compound may be used as a dopant material of the light emitting layer. To this end, there is provided a coating composition including the above-described compound according to the present disclosure and a solvent.

The solvent is not particularly limited as long as it is a solvent capable of dissolving or dispersing the compound according to the present disclosure. For example, the solvent may include a chlorine-based solvent such as chloroform, methylene chloride, 1,2-dichloroethane, 1,1,2-trichloroethane, chlorobenzene, and o-dichlorobenzene; an ether-based solvent such as tetrahydrofuran and dioxane; an aromatic hydrocarbon-based solvent such as toluene, xylene, trimethylbenzene, and mesitylene; an aliphatic hydrocarbon-based solvent such as cyclohexane, methylcyclohexane, n-pentane, n-hexane, n-heptane, n-octane, n-nonane, and n-decane; a ketone-based solvent such as acetone, methyl ethyl ketone, and cyclohexanone; an ester-based solvent such as ethyl acetate, butyl acetate, and ethyl cellosolve acetate; a polyhydric alcohol and derivatives thereof such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, and 1,2-hexane diol; an alcohol-based solvent such as methanol, ethanol, propanol, isopropanol, and cyclohexanol; a sulfoxide-based solvent such as dimethyl sulfoxide; an amide-based solvent such as N-methyl-2-pyrrolidone and N,N-dimethylformamide; a benzoate-based solvent such as butyl benzoate and methyl-2-methoxy benzoate; tetralin; and 3-phenoxytoluene. In addition, the above-mentioned solvents may be used alone or in combination of two or more thereof. Preferably, toluene may be used as the solvent.

In addition, the coating composition may further include a compound used as a host material, and the compound used for the host material will be described later. In addition, the coating composition may include a compound used as a dopant material, and the compound used for the dopant material will be described later.

In addition, a viscosity of the coating composition is preferably 1 cP or more. In order to facilitate the coating of the coating composition, the viscosity of the coating composition is preferably 10 cP or less. In addition, a concentration of the compound according to the present disclosure in the coating composition is preferably 0.1 wt/v % or more. In order for the coating composition to be optimally coated, the concentration of the compound according to the present disclosure in the coating composition is preferably 20 wt/v % or less.

In the present disclosure, there is also provided a method of forming a light emitting layer using the above-described coating composition. Specifically, the method includes the steps of: coating the coating composition according to the present disclosure on the anode or on the hole transport layer formed on the anode in a solution process; and heat-treating the coated coating composition.

The solution process uses the coating composition according to the present disclosure as described above, and refers to spin coating, dip coating, doctor blading, inkjet printing, screen printing, spraying, roll coating, etc., but is not limited thereto.

A temperature in the heat-treatment step is preferably 150 to 230° C. In addition, the heat-treatment is performed for 1 minute to 3 hours, more preferably for 10 minutes to 1 hour. In addition, the heat-treatment is preferably performed under an inert gas atmosphere such as argon or nitrogen.

### (Organic Light Emitting Device)

In addition, according to another aspect of the present disclosure, there is provided an organic light emitting device including the compound represented by the Chemical Formula 1. As an example, there is provided an organic light emitting device including: a first electrode; a second electrode that is provided opposite to the first electrode; and one or more organic material layers that are provided between the first electrode and the second electrode, wherein at least one layer of the organic material layers includes the compound represented by the Chemical Formula 1.

The organic material layer of the organic light emitting device of the present disclosure may have a single-layer structure, or it may have a multilayered structure in which two or more organic material layers are stacked. For example, the organic light emitting device of the present disclosure may have a structure including a hole injection layer, a hole transport layer, a light emitting layer, an electron transport layer, an electron injection layer, and the like as the organic material layer. However, the structure of the organic light emitting device is not limited thereto, and it may include a smaller number of organic layers.

In addition, the organic material layer may include a light emitting layer, and the light emitting layer may include the compound represented by the Chemical Formula 1. In particular, the compound according to the present disclosure can be used as a dopant in the light emitting layer.

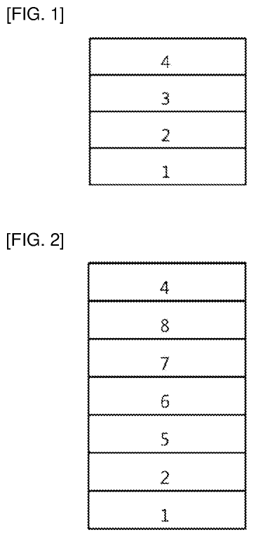

Further, the organic light emitting device according to the present disclosure may be a normal type organic light emitting device in which an anode, one or more organic material layers and a cathode are sequentially stacked on a substrate. Further, the organic light emitting device according to the present disclosure may be an inverted type organic light emitting device in which a cathode, one or more organic material layers and an anode are sequentially stacked on a substrate. For example, the structure of an organic light emitting device according to an embodiment of the present disclosure is illustrated in FIGS. 1 and 2.

FIG. 1 shows an example of an organic light emitting device including a substrate 1, an anode 2, a light emitting layer 3, and a cathode 4. In such a structure, the compound represented by the Chemical Formula 1 may be included in the light emitting layer.

FIG. 2 shows an example of an organic light emitting device including a substrate 1, an anode 2, a hole injection layer 5, a hole transport layer 6, a light emitting layer 7, an electron injection and transport layer 8, and a cathode 4. In such a structure, the compound represented by the Chemical Formula 1 may be included in the light emitting layer.

The organic light emitting device according to the present disclosure may be manufactured using materials and methods known in the art, except that at least one layer of the organic material layers includes the compound represented by the Chemical Formula 1. Moreover, when the organic light emitting device includes a plurality of organic material layers, the organic material layers may be formed of the same material or different materials.

For example, the organic light emitting device according to the present disclosure can be manufactured by sequentially stacking an anode, an organic material layer and a cathode on a substrate. In this case, the organic light emitting device may be manufactured by depositing a metal, metal oxides having conductivity, or an alloy thereof on the substrate using a PVD (physical vapor deposition) method such as a sputtering method or an e-beam evaporation method to form an anode, forming organic material layers including the hole injection layer, the hole transport layer, the light emitting layer and the electron transport layer thereon, and then depositing a material that can be used as the cathode thereon.

In addition to such a method, the organic light emitting device may be manufactured by sequentially depositing a cathode material, an organic material layer and an anode material on a substrate (International Publication WO2003/012890). However, the manufacturing method is not limited thereto.

For example, the first electrode is an anode, and the second electrode is a cathode, or alternatively, the first electrode is a cathode and the second electrode is an anode.

As the anode material, generally, a material having a large work function is preferably used so that holes can be smoothly injected into the organic material layer. Specific examples of the anode material include metals such as vanadium, chrome, copper, zinc, and gold, or an alloy thereof; metal oxides such as zinc oxides, indium oxides, indium tin oxides (ITO), and indium zinc oxides (IZO); a combination of metals and oxides, such as ZnO:Al or SnO₂:Sb; conductive compounds such as poly(3-methylthiophene), poly[3,4-(ethylene-1,2-dioxy)thiophene](PEDOT), polypyrrole, and polyaniline, and the like, but are not limited thereto.

As the cathode material, generally, a material having a small work function is preferably used so that electrons can be easily injected into the organic material layer. Specific examples of the cathode material include metals such as magnesium, calcium, sodium, potassium, titanium, indium, yttrium, lithium, gadolinium, aluminum, silver, tin, and lead, or an alloy thereof; a multilayered structure material such as LiF/Al or LiO₂/Al, and the like, but are not limited thereto.

The hole injection layer is a layer for injecting holes from the electrode, and the hole injection material is preferably a compound which has a capability of transporting the holes, thus has a hole injecting effect in the anode and an excellent hole-injecting effect to the light emitting layer or the light emitting material, prevents excitons produced in the light emitting layer from moving to an electron injection layer or the electron injection material, and is excellent in the ability to form a thin film. It is preferable that a HOMO (highest occupied molecular orbital) of the hole injection material is between the work function of the anode material and a HOMO of a peripheral organic material layer. Specific examples of the hole injection material include metal porphyrine, oligothiophene, an arylamine-based organic material, a hexanitrilehexaazatriphenylene-based organic material, a quinacridone-based organic material, a perylene-based organic material, anthraquinone, polyaniline and polythiophene-based conductive compound, and the like, but are not limited thereto.

In addition, the hole transport layer is a layer that receives holes from a hole injection layer and transports the holes to the light emitting layer. The hole transport material is suitably a material having large mobility to the holes, which may receive holes from the anode or the hole injection layer and transfer the holes to the light emitting layer. Specific examples thereof include an arylamine-based organic material, a conductive compound, a block copolymer in which a conjugate portion and a non-conjugate portion are present together, and the like, but are not limited thereto.

In addition, the light emitting layer may include a host material and a dopant material. The host material may be a fused aromatic ring derivative or a heterocycle-containing compound. Specific examples of the fused aromatic ring derivatives include anthracene derivatives, pyrene derivatives, naphthalene derivatives, pentacene derivatives, phenanthrene compounds, fluoranthene compounds, and the like. Examples of the heterocyclic-containing compounds include carbazole derivatives, dibenzofuran derivatives, ladder-type furan compounds, pyrimidine derivatives, and the like, but are not limited thereto.

The dopant material includes an aromatic amine derivative, a styrylamine compound, a boron complex, a fluoranthene compound, a metal complex, and the like. Specifically, the aromatic amine derivative is a substituted or unsubstituted fused aromatic ring derivative having an arylamino group, and examples thereof include pyrene, anthracene, chrysene, periflanthene and the like, which have an arylamino group. The styrylamine compound is a compound where at least one arylvinyl group is substituted in substituted or unsubstituted arylamine, in which one or two or more substituent groups selected from the group consisting of an aryl group, a silyl group, an alkyl group, a cycloalkyl group, and an arylamino group are substituted or unsubstituted. Specific examples thereof include styrylamine, styryldiamine, styryltriamine, styryltetramine, and the like, but are not limited thereto. Further, the metal complex includes an iridium complex, a platinum complex, and the like, but is not limited thereto.

The electron injection and transport layer is a layer that simultaneously serves as an electron transport layer and an electron injection layer by injecting electrons from an electrode and transferring the received electrons to a light emitting layer, and is formed on the light emitting layer or the electron control layer. An electron injection and transport material is suitably a material which can receive electrons well from a cathode and transfer the electrons to a light emitting layer and has large mobility for electrons. Specifically, examples thereof may include an Al complex of 8-hydroxyquinoline; a complex including Alq3; an organic radical compound; a hydroxyflavone-metal complex; triazine derivatives; and the like, but are not limited thereto. Alternatively, examples thereof may include LiF, NaF, NaCl, CsF, Li₂O, BaO, fluorenone, anthraquinodimethane, diphenoquinone, thiopyran dioxide, oxazole, oxadiazole, triazole, imidazole, perylenetetracarboxylic acid, fluorenylidene methane, and anthrone, and derivatives thereof, a metal complex compound, a nitrogen-containing 5-membered ring derivative, and the like, but are not limited thereto.

Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato)(o-cresolato)gallium, bis(2-methyl-8-quinolinato)(1-naphtholato)aluminum, bis(2-methyl-8-quinolinato)(2-naphtholato)gallium, and the like, but are not limited thereto.

In addition to the above-described materials, the light emitting layer, the hole injection layer, the hole transport layer, the electron transport layer, and the electron injection layer may further include an inorganic compound such as quantum dots or a polymer compound.

The quantum dots may be, for example, colloidal quantum dots, alloy quantum dots, core-shell quantum dots, or core quantum dots. They may be quantum dots including elements belonging to Groups 2 and 16, elements belonging to Groups 13 and 15, elements belonging to Groups 13 and 17, elements belonging to Groups 11 and 17, or elements belonging to Groups 14 and 15. Quantum dots including elements such as cadmium (Cd), selenium (Se), zinc (Zn), sulfur (S), phosphorus (P), indium (In), tellurium (Te), lead (Pb), gallium (Ga), and arsenic (As) may be used.

The organic light emitting device according to the present disclosure may be a bottom emission device, a top emission device, or a double-sided light emitting device, and in particular, may be a bottom emission device requiring relatively high luminous efficiency.

In addition, the compound according to the present disclosure may be included in an organic solar cell or an organic transistor in addition to an organic light emitting device.

The preparation of the compound represented by the Chemical Formula 1 and the organic light emitting device including the same will be described in detail in the following examples. However, these examples are presented for illustrative purposes only, and are not intended to limit the scope of the present disclosure.

### EXAMPLES

### Example 1: Preparation of Compound 1

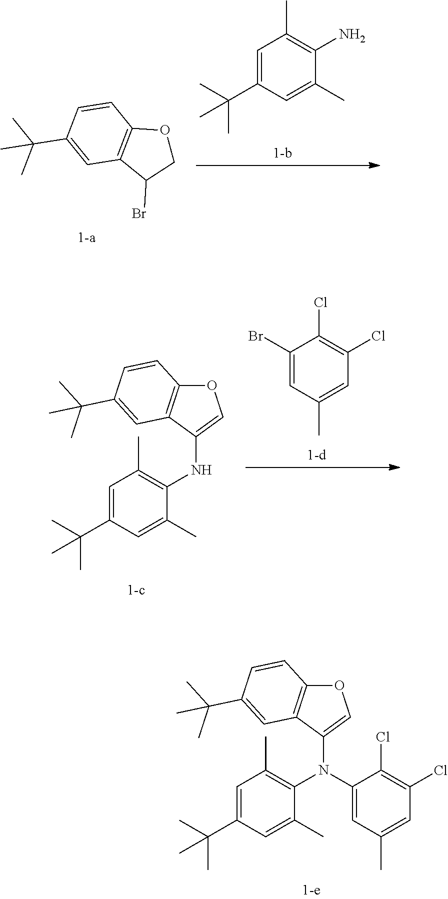

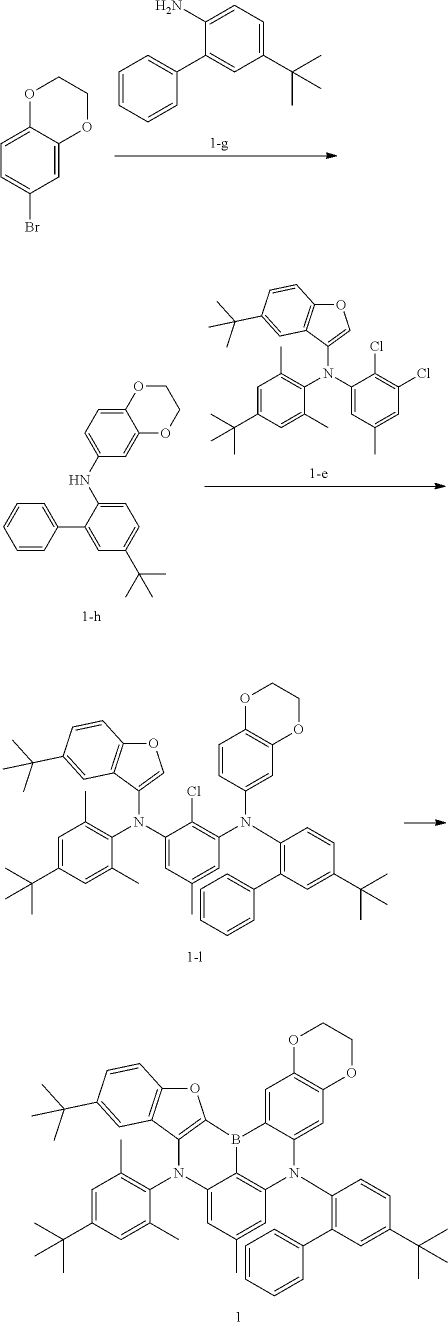

Compound 1-a (1.0 eq.), NaOt-Bu (4 eq.), and Compound 1-b (1.05 eq.) were placed in a round-bottom flask and dissolved in anhydrous toluene (0.1 M). Pd(t-Bu₃P)₂ (5 mol %) was added dropwise at a bath temperature of 100° C. and stirred for 2 hours. After the reaction, the reactant was cooled at room temperature, diluted sufficiently in CH₂Cl₂, and washed with CH₂Cl₂/brine to separate the organic layer. Water was removed with MgSO₄, and the resultant was passed through a Celite-Florisil-Silica pad. The passed solution was concentrated under reduced pressure and purified by column chromatography to prepare Compound 1-c (76% yield).

Compound 1-d (1.0 eq.), NaOt-Bu (4 eq.), and Compound 1-c (1.05 eq.) were placed in a round-bottom flask and dissolved in anhydrous toluene (0.1 M). Pd(t-BusP)₂ (5 mol %) was added dropwise at a bath temperature of 120° C. and stirred for 4 hours. After the reaction, the reactant was cooled at room temperature, diluted sufficiently in CH₂Cl₂, and washed with CH₂Cl₂/brine to separate the organic layer. Water was removed with MgSO₄, and the resultant was passed through a Celite-Florisil-Silica pad. The passed solution was concentrated under reduced pressure and purified by column chromatography to prepare Compound 1-e (81% yield).

Compound 1-f (1.0 eq.), NaOt-Bu (4 eq.), and Compound 1-g (1.05 eq.) were placed in a round-bottom flask and dissolved in anhydrous toluene (0.1 M). Pd(t-Bu₃P)₂ (5 mol %) was added dropwise at a bath temperature of 100° C. and stirred for 2 hours. After the reaction, the reactant was cooled at room temperature, diluted sufficiently in CH₂Cl₂, and washed with CH₂Cl₂/brine to separate the organic layer. Water was removed with MgSO₄, and the resultant was passed through a Celite-Florisil-Silica pad. The passed solution was concentrated under reduced pressure and purified by column chromatography to prepare Compound 1-h (82% yield).

Compound 1-h (1.0 eq.), NaOt-Bu (4 eq.), and Compound 1-e (1.05 eq.) were placed in a round-bottom flask and dissolved in anhydrous toluene (0.1 M). Pd(t-BusP)₂ (5 mol %) was added dropwise at a bath temperature of 120° C. and stirred overnight. After the reaction, the reactant was cooled at room temperature, diluted sufficiently in CH₂Cl₂, and washed with CH₂Cl₂/brine to separate the organic layer. Water was removed with MgSO₄, and the resultant was passed through a Celite-Florisil-Silica pad. The passed solution was concentrated under reduced pressure and purified by column chromatography to prepare Compound 1-i (73% yield).

Compound 1-i (1.0 eq.) was placed in a round-bottom flask and dissolved in anhydrous toluene (0.03 M). Bl₃ (2.0 eq.) was slowly added dropwise to the reactant and stirred overnight at a bath temperature of 80° C. After the reaction, the reactant was sufficiently cooled at room temperature, and diluted in CH₂Cl₂. EtNi-Pr₂ (15.0 eq.) and sat·Na₂S₂O₃ (aq.) were sequentially added dropwise to the reactant, washed with CH₂Cl₂/H₂O, and the organic layer was separated. Water was removed with MgSO₄, and the resultant was passed through a Celite-Florisil-Silica pad. The passed solution was concentrated under reduced pressure and purified by column chromatography to prepare Compound 1 (78% yield).

m/z [M+H]⁺ 805.6

### Example 2: Preparation of Compound 2

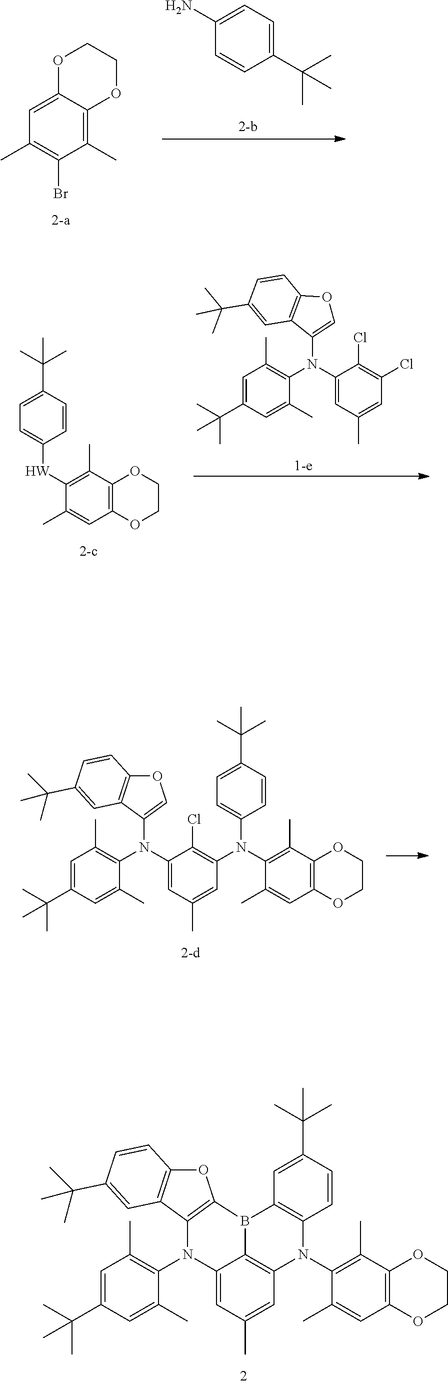

Compound 2 was prepared in the same manner as in the preparation of Compound 1, except that Compound 2-a was used instead of Compound 1-f, and Compound 2-b was used instead of Compound 1-g.

m/z [M+H]⁺ 757.5

### Example 3: Preparation of Compound 3

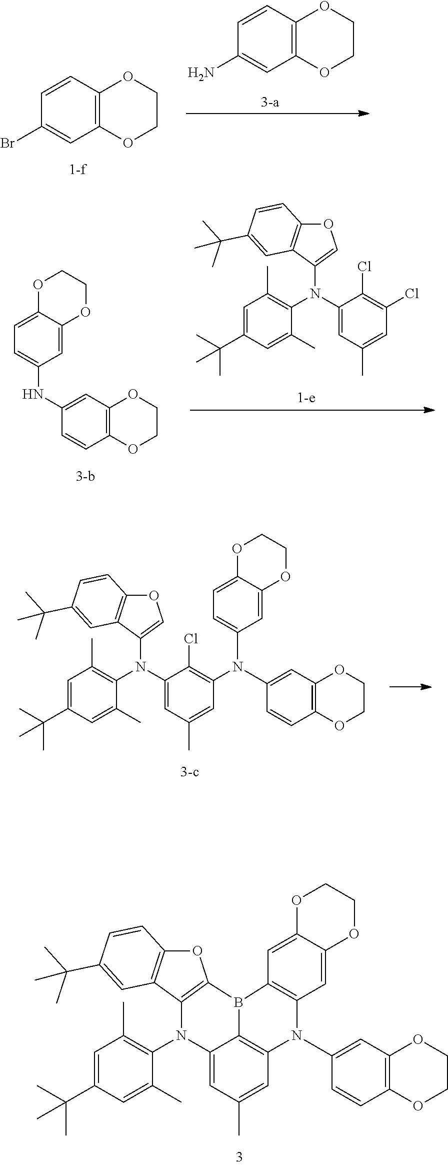 [SMILES: Nc1ccc2c(c1)OCCO2 ; Brc1ccc2c(c1)OCCO2 ; c1cc2c(cc1Nc1ccc3c(c1)OCCO3)OCCO2 ; Cc1cc(Cl)c(Cl)c(N(c2c(C)cc(C(C)(C)C)cc2C)c2coc3ccc(C(C)(C)C)cc23)c1 ; Cc1cc(N(c2ccc3c(c2)OCCO3)c2ccc3c(c2)OCCO3)c(Cl)c(N(c2c(C)cc(C(C)(C)C)cc2C)c2coc3ccc(C(C)(C)C)cc23)c1 ; Cc1cc2c3c(c1)N(c1c(C)cc(C(C)(C)C)cc1C)c1c(oc4ccc(C(C)(C)C)cc14)B3c1cc3c(cc1N2c1ccc2c(c1)OCCO2)OCCO3]

Compound 3 was prepared in the same manner as in the preparation of Compound 1, except that Compound 3-a was used instead of Compound 1-g.

m/z [M+H]⁺ 731.4

### Example 4: Preparation of Compound 4

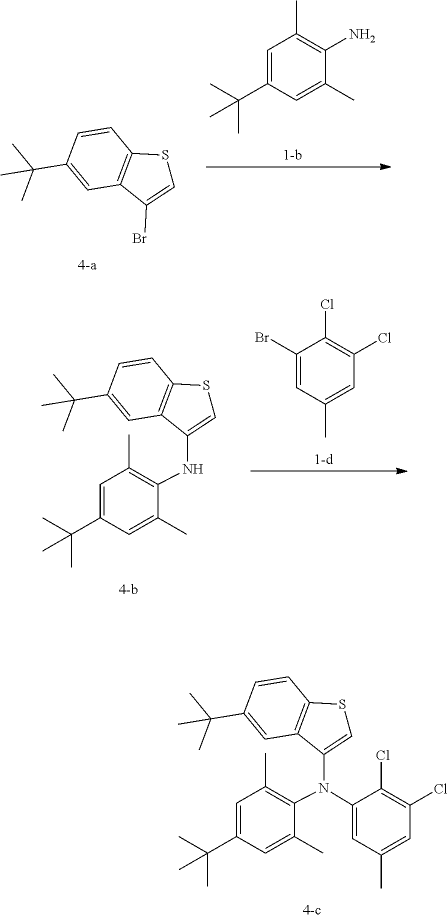

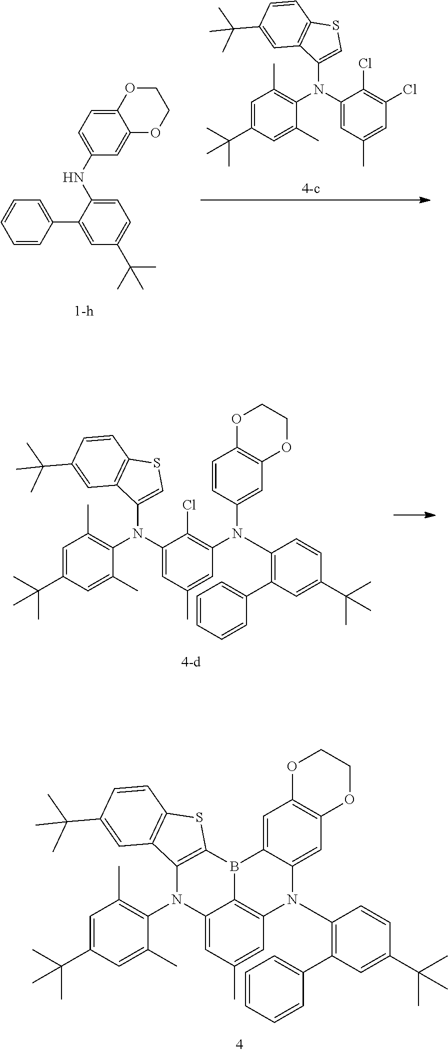

Compound 4 was prepared in the same manner as in the preparation of Compound 1, except that Compound 4-a was used instead of Compound 1-a, and Compound 4-c was used instead of Compound 1-e.

m/z [M+H]⁺ 821.3

### Example 5: Preparation of Compound 5

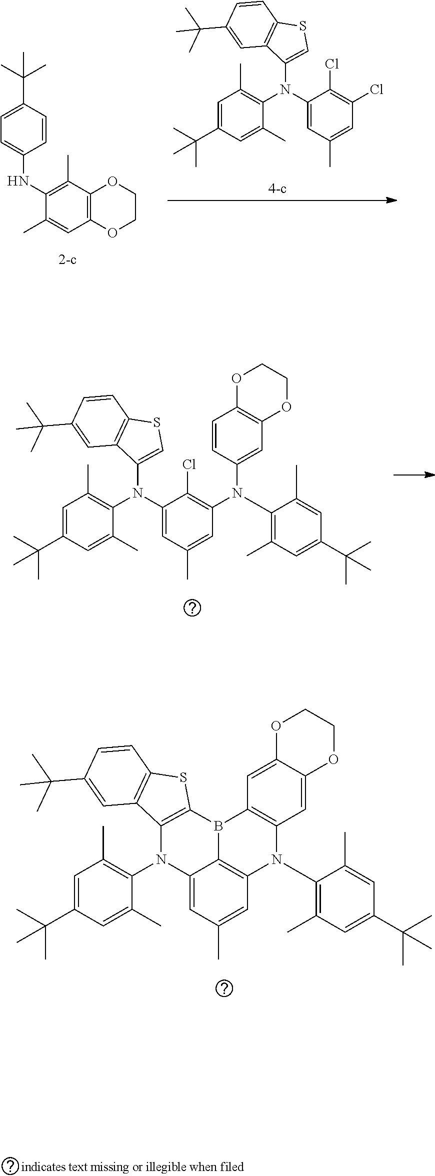

Compound 5 was prepared in the same manner as in the preparation of Compound 4, except that Compound 2-c was used instead of Compound 1-h.

m/z [M+H]⁺ 773.5

### Example 6: Preparation of Compound 6

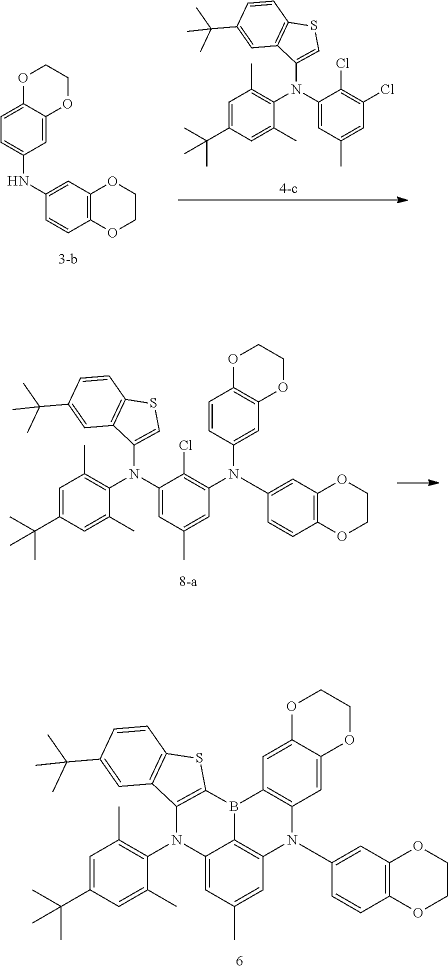 [SMILES: c1cc2c(cc1Nc1ccc3c(c1)OCCO3)OCCO2 ; Cc1cc(Cl)c(Cl)c(N(c2c(C)cc(C(C)(C)C)cc2C)c2csc3ccc(C(C)(C)C)cc23)c1 ; Cc1cc(N(c2ccc3c(c2)OCCO3)c2ccc3c(c2)OCCO3)c(Cl)c(N(c2c(C)cc(C(C)(C)C)cc2C)c2csc3ccc(C(C)(C)C)cc23)c1 ; Cc1cc2c3c(c1)N(c1c(C)cc(C(C)(C)C)cc1C)c1c(sc4ccc(C(C)(C)C)cc14)B3c1cc3c(cc1N2c1ccc2c(c1)OCCO2)OCCO3]

Compound 6 was prepared in the same manner as in the preparation of Compound 4, except that Compound 3-b was used instead of Compound 1-h.

m/z [M+H]⁺ 747.4

### Example 7: Preparation of Compound 7

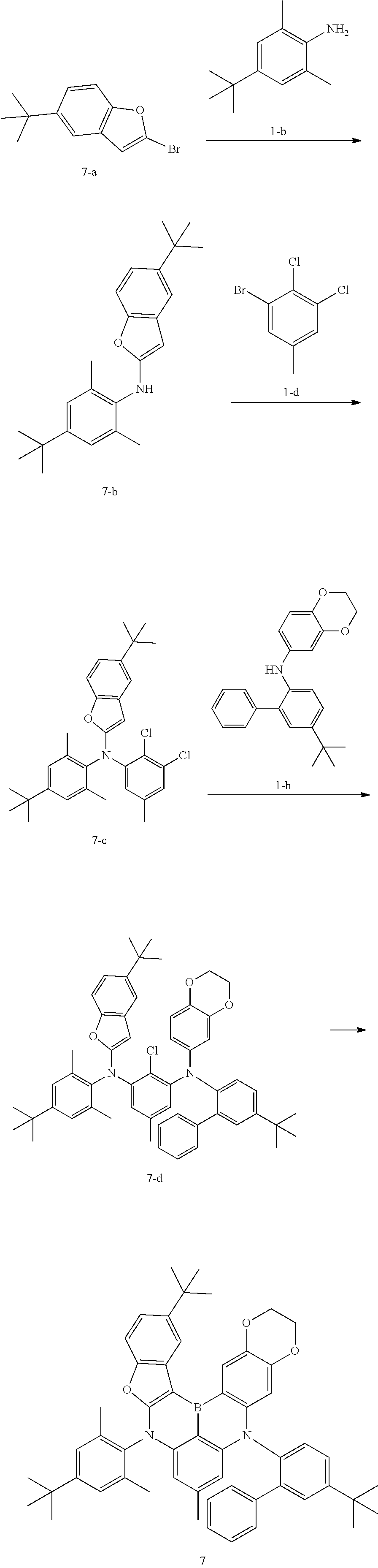

Compound 7 was prepared in the same manner as in the preparation of Compound 1, except that Compound 7-a was used instead of Compound 1-a, and Compound 7-c was used instead of Compound 1-e.

m/z [M+H]⁺ 805.6

### Example 8: Preparation of Compound 8

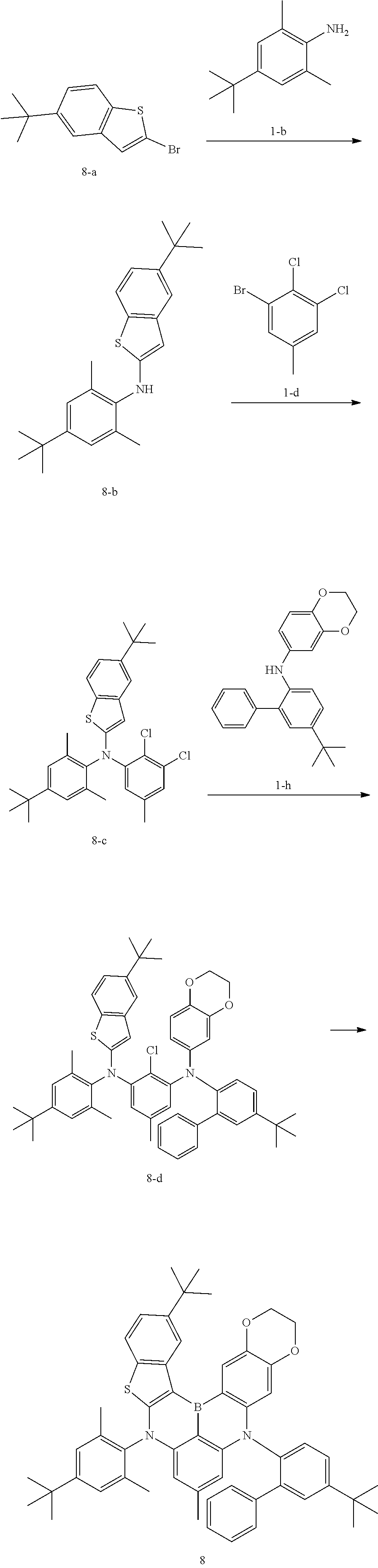

Compound 8 was prepared in the same manner as in the preparation of Compound 1, except that Compound 8-a was used instead of Compound 1-a, and Compound 8-c was used instead of Compound 1-e.

m/z [M+H]⁺ 821.7

### Example 9: Preparation of Compound 9

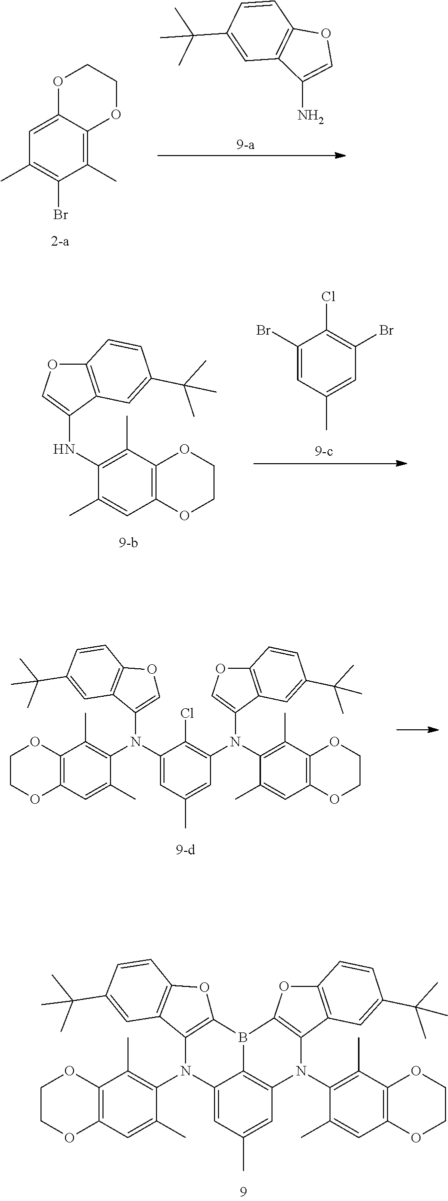

Compound 2-a (1.0 eq.), NaOt-Bu (4 eq.), and Compound 9-a (1.05 eq.) were placed in a round-bottom flask and dissolved in anhydrous toluene (0.1 M). Pd(t-BusP)₂ (5 mol %) was added dropwise at a bath temperature of 100° C. and stirred for 2 hours. After the reaction, the reactant was cooled at room temperature, diluted sufficiently in CH₂Cl₂, and washed with CH₂Cl₂/brine to separate the organic layer. Water was removed with MgSO₄, and the resultant was passed through a Celite-Florisil-Silica pad. The passed solution was concentrated under reduced pressure and purified by column chromatography to prepare Compound 9-b (87% yield).

Compound 9-c (1.0 eq.), NaOt-Bu (4 eq.), and Compound 9-b (1.05 eq.) were placed in a round-bottom flask and dissolved in anhydrous toluene (0.1 M). Pd(t-BusP)₂ (5 mol %) was added dropwise at a bath temperature of 100° C. and stirred for 2 hours. After the reaction, the reactant was cooled at room temperature, diluted sufficiently in CH₂Cl₂, and washed with CH₂Cl₂/brine to separate the organic layer. Water was removed with MgSO₄, and the resultant was passed through a Celite-Florisil-Silica pad. The passed solution was concentrated under reduced pressure and purified by column chromatography to prepare Compound 9-d (73% yield).

Compound 9-d (1.0 eq.) was placed in a round-bottom flask and dissolved in anhydrous toluene (0.03 M). Bl₃ (2.0 eq.) was slowly added dropwise to the reactant and stirred overnight at a bath temperature of 80° C. After the reaction, the reactant was sufficiently cooled at room temperature, and diluted in CH₂Cl₂. EtNi-Pr₂ (15.0 eq.) and sat·Na₂S₂O₃ (aq.) were sequentially added dropwise to the reactant, washed with CH₂Cl₂/H₂O, and the organic layer was separated. Water was removed with MgSO₄, and the resultant was passed through a Celite-Florisil-Silica pad. The passed solution was concentrated under reduced pressure and purified by column chromatography to prepare Compound 9 (76% yield).

m/z [M+H]⁺ 799.5

### Example 10: Preparation of Compound 10

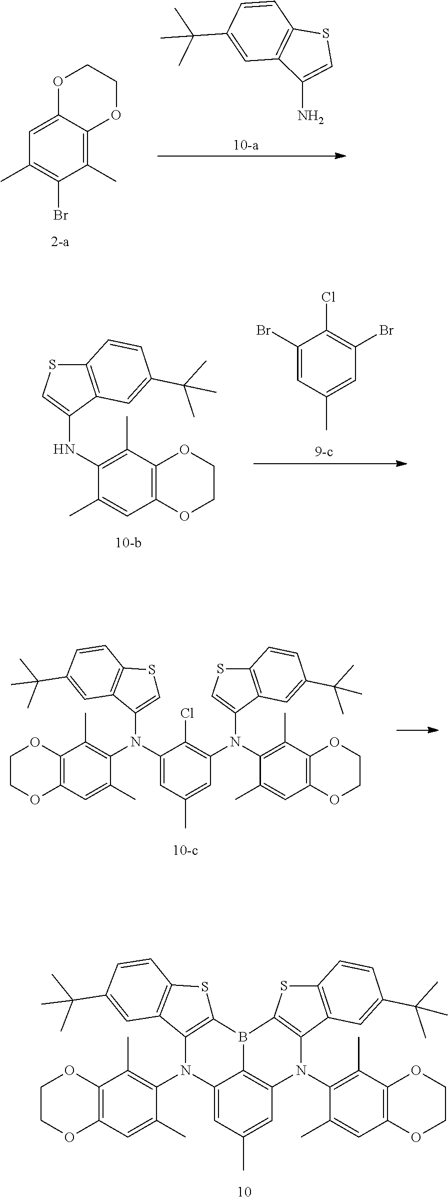

Compound 10 was prepared in the same manner as in the preparation of Compound 9, except that Compound 10-a was used instead of Compound 9-a.

m/z [M+H]⁺ 831.5

### Example 11: Preparation of Compound 11

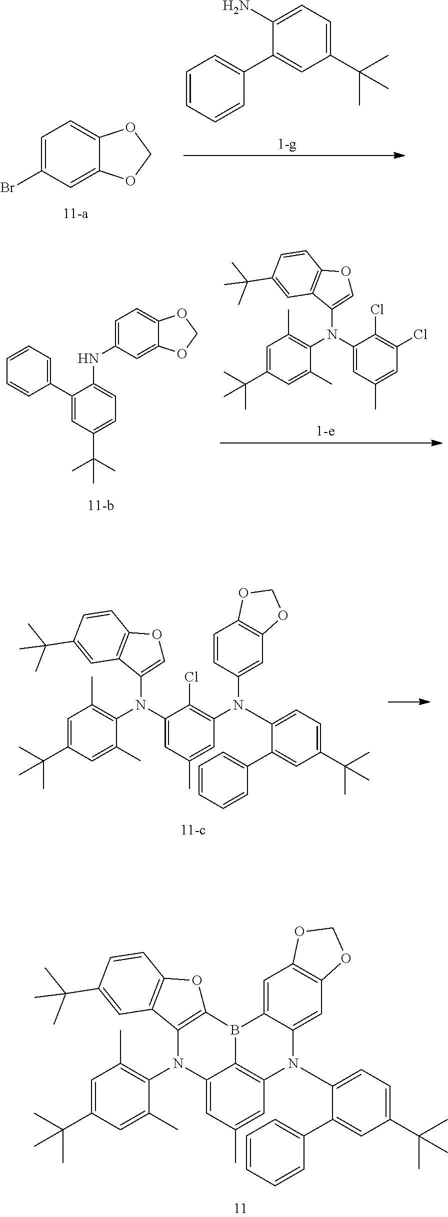

Compound 11 was prepared in the same manner as in the preparation of Compound 1, except that Compound 11-a was used instead of Compound 1-f.

m/z [M+H]⁺ 791.5

### Example 12: Preparation of Compound 12

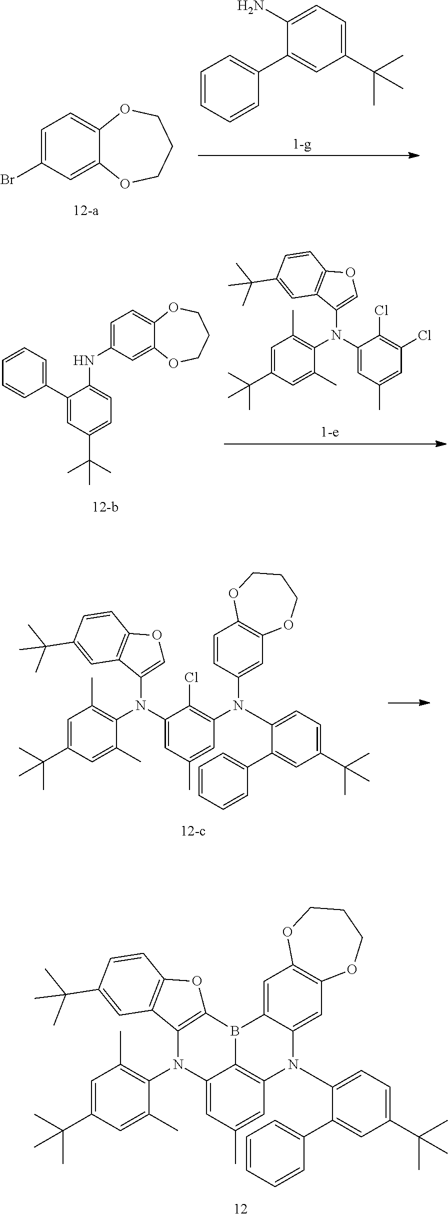

Compound 12 was prepared in the same manner as in the preparation of Compound 1, except that Compound 12-a was used instead of Compound 1-f.

m/z [M+H]⁺ 819.6

### Example 13: Preparation of Compound 13

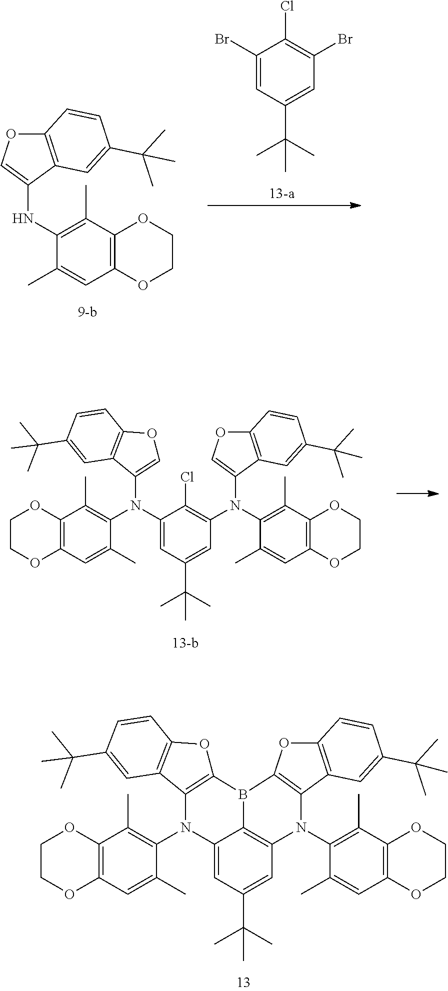 [SMILES: Cc1cc2c(c(C)c1Nc1coc3ccc(C(C)(C)C)cc13)OCCO2 ; CC(C)(C)c1cc(Br)c(Cl)c(Br)c1 ; Cc1cc2c(c(C)c1N(c1cc(C(C)(C)C)cc(N(c3c(C)cc4c(c3C)OCCO4)c3coc4ccc(C(C)(C)C)cc34)c1Cl)c1coc3ccc(C(C)(C)C)cc13)OCCO2 ; Cc1cc2c(c(C)c1N1c3cc(C(C)(C)C)cc4c3B(c3oc5ccc(C(C)(C)C)cc5c31)c1oc3ccc(C(C)(C)C)cc3c1N4c1c(C)cc3c(c1C)OCCO3)OCCO2]

Compound 13 was prepared in the same manner as in the preparation of Compound 9, except that Compound 13-a was used instead of Compound 9-C.

m/z [M+H]⁺ 841.5

### COMPARATIVE EXAMPLES

### Comparative Example 1: Preparation of Comparative Compound F

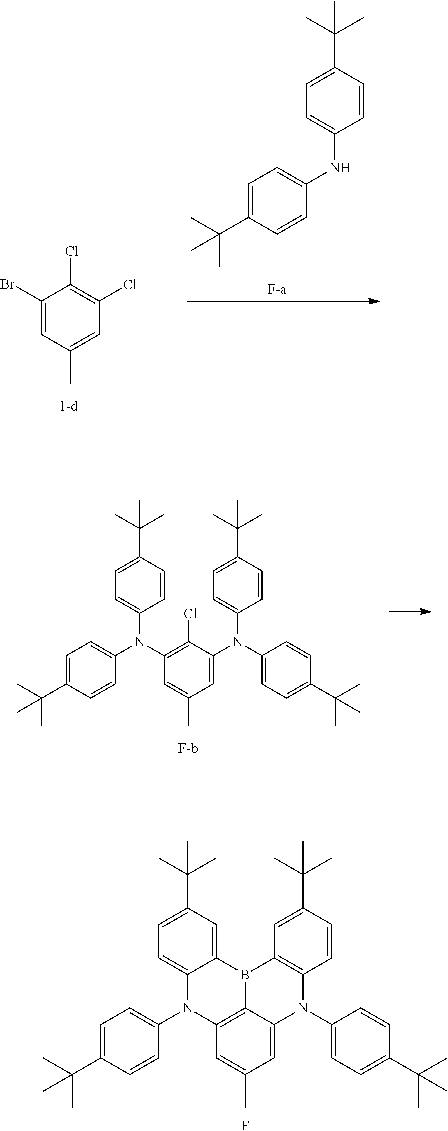

Compound 1-d (1.0 eq.), NaOt-Bu (4 eq.), and Compound F-a (2.05 eq.) were placed in a round-bottom flask and dissolved in anhydrous toluene (0.1 M). Pd(t-Bu₃P)₂ (5 mol %) was added dropwise at a bath temperature of 120° C. and stirred overnight. After the reaction, the reactant was cooled at room temperature, diluted sufficiently in CH₂Cl₂, and washed with CH₂Cl₂/brine to separate the organic layer. Water was removed with MgSO₄, and the resultant was passed through a Celite-Florisil-Silica pad. The passed solution was concentrated under reduced pressure and purified by column chromatography to prepare Compound F-b (75% yield).

Compound F-b (1.0 eq.) was placed in a round-bottom flask and dissolved in anhydrous toluene (0.03 M). Bl₃ (2.0 eq.) was slowly added dropwise to the reactant and stirred overnight at a bath temperature of 80° C. After the reaction, the reactant was sufficiently cooled at room temperature, and diluted in CH₂Cl₂. EtNi-Pr₂ (15.0 eq.) and sat·Na₂S₂O₃ (aq.) were sequentially added dropwise to the reactant, washed with CH₂Cl₂/H₂O, and the organic layer was separated. Water was removed with MgSO₄, and the resultant was passed through a Celite-Florisil-Silica pad. The passed solution was concentrated under reduced pressure and purified by column chromatography to prepare Compound F (87% yield).

m/z [M+H]⁺=659.6

### Comparative Example 2: Preparation of Comparative Compound G

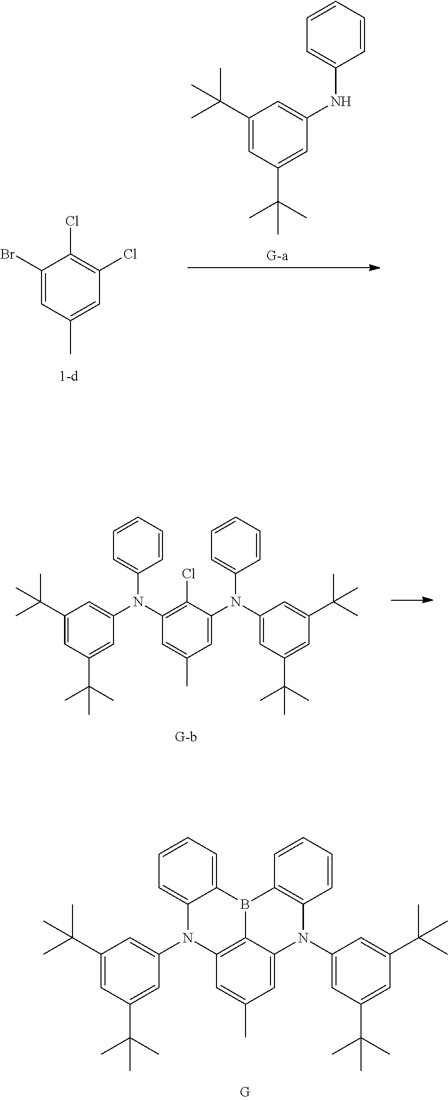

Compound G was prepared in the same manner as in the preparation of Comparative Example 1, except that Compound G-a was used instead of Compound F-a.

m/z [M+H]⁺=659.5

### Comparative Example 3: Preparation of Comparative Compound

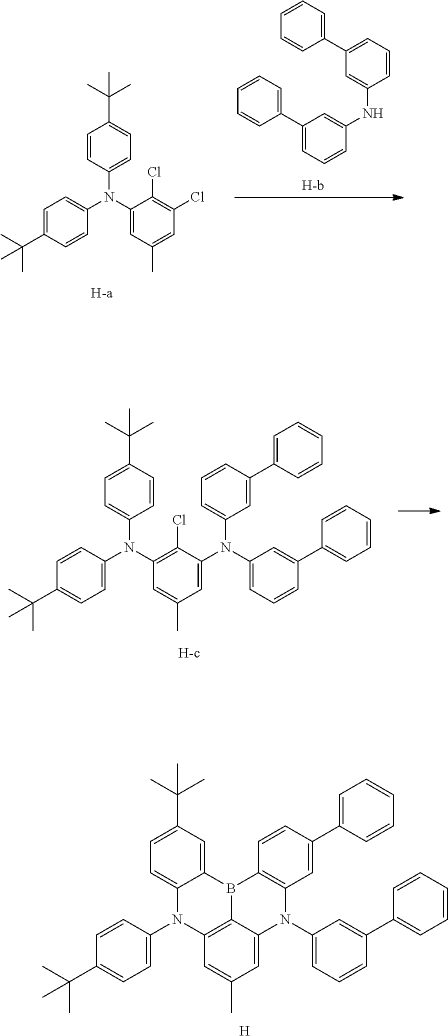

Compound H-a (1.0 eq.), NaOt-Bu (4.0 eq.), and Compound H-b (1.05 eq.) were placed in a round-bottom flask and dissolved in anhydrous toluene (0.1 M). Pd(t-Bu₃P)₂ (5 mol %) was added dropwise at a bath temperature of 120° C. and stirred overnight. After the reaction, the reactant was cooled at room temperature, diluted sufficiently in CH₂Cl₂, and washed with CH₂Cl₂/brine to separate the organic layer. Water was removed with MgSO₄, and the resultant was passed through a Celite-Florisil-Silica pad. The passed solution was concentrated under reduced pressure and purified by column chromatography to prepare Compound H-c (79% yield).

Compound H-c (1.0 eq.) was placed in a round-bottom flask and dissolved in anhydrous toluene (0.03 M). Bl₃ (2.0 eq.) was slowly added dropwise to the reactant and stirred overnight at a bath temperature of 80° C. After the reaction, the reactant was sufficiently cooled at room temperature, and diluted in CH₂Cl₂. EtNi-Pr₂ (15.0 eq.) and sat·Na₂S₂O₃ (aq.) were sequentially added dropwise to the reactant, washed with CH₂Cl₂/H₂O, and the organic layer was separated. Water was removed with MgSO₄, and the resultant was passed through a Celite-Florisil-Silica pad. The passed solution was concentrated under reduced pressure and purified by column chromatography to prepare Compound H (73% yield).

m/z [M+H]⁺=725.5

### EXPERIMENTAL EXAMPLES

### Experimental Example 1

A glass substrate on which ITO (Indium Tin Oxide) was coated as a thin film to a thickness of 500 Å was put into distilled water in which a detergent was dissolved, and ultrasonically cleaned. At this time, a product manufactured by Fischer Co. was used as the detergent, and distilled water filtered twice using a filter manufactured by Millipore Co. was used as the distilled water. After the ITO was cleaned for 30 minutes, ultrasonic cleaning was repeated twice using distilled water for 10 minutes. After the cleaning with distilled water was completed, the substrate was ultrasonically cleaned with solvents of isopropyl and acetone, and dried. Thereafter, the substrate was cleaned for 5 minutes, and transferred to a glove box.

A coating composition in which the following Compound O and Compound P (weight ratio: 2:8) were dissolved in cyclohexanone at 20 wt/v % was spin-coated (4000 rpm) on the ITO transparent electrode, and heat-treated (cured) at 200° C. for 30 minutes to prepare a hole injection layer having a thickness of 400 Å. A coating composition in which the following Compound Q (Mn: 27,900; Mw: 35,600; measured by GPC with PC Standard using Agilent 1200 series) was dissolved in toluene at 6 wt/v % was spin-coated (4000 rpm) on the hole injection layer, and heat-treated at 200° C. for 30 minutes to form a hole transport layer having a thickness of 200 Å. A coating composition in which the Compound 1 and the following Compound R (weight ratio: 2:98) were dissolved in cyclohexanone at 2 wt/v % was spin-coated (4000 rpm) on the hole transport layer, and heat-treated at 180° C. for 30 minutes to form a light emitting layer having a thickness of 400 Å.

After transferring to a vacuum evaporator, the following Compound S was vacuum-deposited to a thickness of 350 Å on the light emitting layer to form an electron injection and transport layer. On the electron injection and transport layer, LiF and aluminum were sequentially deposited to a thickness of 10 Å and 1,000 Å, respectively to form a cathode.

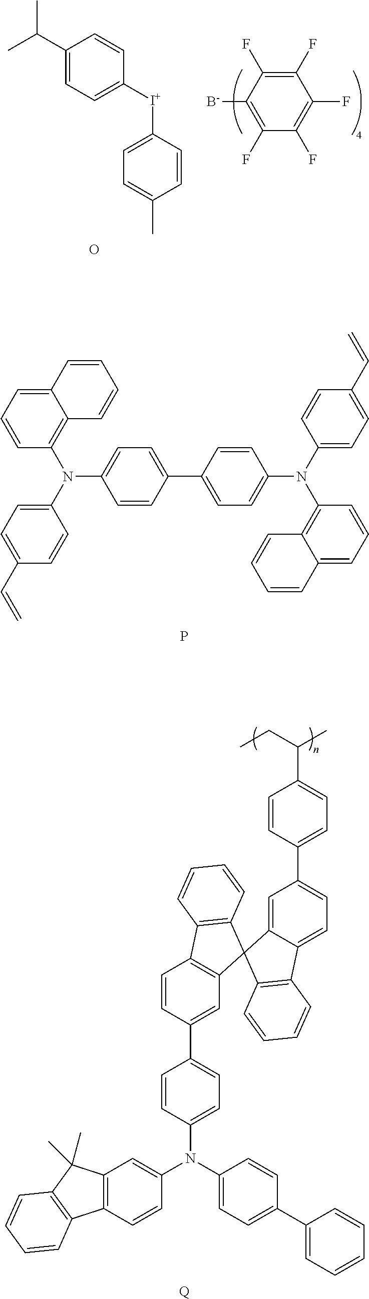

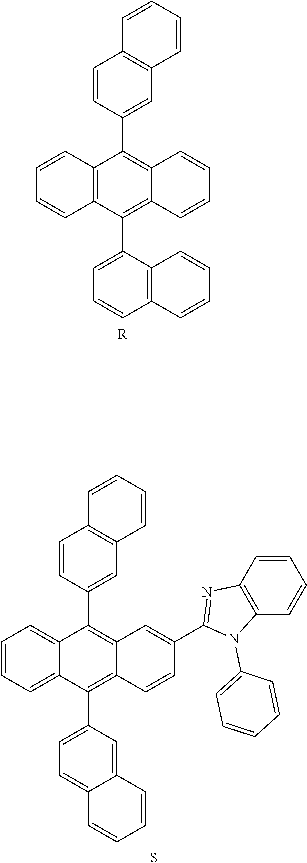

In the above process, the deposition rate of the organic material was maintained at 0.4 to 0.7 Å/sec, the deposition rate of LiF was maintained at 0.3 Å/sec, and the deposition rate of aluminum was maintained at 2 Å/sec. In addition, the degree of vacuum during the deposition was maintained at 2*10-7 to 5*10-8 torr.

### Experimental Examples 2 to 12

An organic light emitting device was manufactured in the same manner as in Experimental Example 1, except that the compound shown in Table 1 was used instead of Compound 1 as the dopant of the light emitting layer.

### Comparative Experimental Examples 1 to 3

An organic light emitting device was manufactured in the same manner as in Experimental Example 1, except that the compound shown in Table 1 was used instead of Compound 1 as the dopant of the light emitting layer.

For the organic light emitting devices prepared in Experimental Examples and Comparative Experimental Examples, the driving voltage, external quantum efficiency (EQE) and lifespan were measured at a current density of 10 mA/cm², and the results are shown in Table 1 below. At this time, the external quantum efficiency (EQE) was calculated as “(the number of emitted photons)/(the number of injected charge carriers)*100”, and T90 means the time taken until the initial luminance (500 nit) decreases to 90%.

TABLE 1

| | | Driving | | |
|---|---|---|---|---|
| | Dopant in | voltage | EQE | Lifespan |
| | light | (V@10 | (% @ | (hr) |
| | emitting layer | mA/cm²) | 10 mA/cm²) | (T90@500 nit) |
| Experimental | Compound 1 | 4.66 | 6.13 | 204 |
| Example 1 | | | | |
| Experimental | Compound 2 | 4.81 | 6.17 | 203 |
| Example 2 | | | | |
| Experimental | Compound 3 | 4.82 | 6.15 | 213 |
| Example 3 | | | | |
| Experimental | Compound 4 | 4.79 | 6.12 | 199 |
| Example 4 | | | | |
| Experimental | Compound 5 | 4.70 | 6.02 | 204 |
| Example 5 | | | | |
| Experimental | Compound 6 | 4.72 | 6.08 | 203 |
| Example 6 | | | | |
| Experimental | Compound 7 | 4.69 | 6.17 | 199 |
| Example 7 | | | | |
| Experimental | Compound 8 | 4.66 | 6.21 | 202 |
| Example 8 | | | | |
| Experimental | Compound 9 | 4.62 | 5.99 | 208 |
| Example 9 | | | | |
| Experimental | Compound 10 | 4.71 | 6.02 | 206 |
| Example 10 | | | | |
| Experimental | Compound 11 | 4.69 | 6.05 | 204 |
| Example 11 | | | | |
| Experimental | Compound 12 | 4.68 | 6.08 | 187 |
| Example 12 | | | | |
| Experimental | Compound 13 | 4.80 | 6.03 | 212 |
| Example 13 | | | | |
| Comparative | Compound F | 4.69 | 4.39 | 105 |
| Experimental | | | | |
| Example 1 | | | | |
| Comparative | Compound G | 4.68 | 4.23 | 99 |
| Experimental | | | | |
| Example 2 | | | | |
| Comparative | Compound H | 4.62 | 3.98 | 83 |
| Experimental | | | | |
| Example 3 | | | | |

As shown in Table 1, the organic light emitting device including the compound of the present disclosure in the light emitting layer exhibited excellent efficiency, driving voltage, and lifespan.

### DESCRIPTION OF SYMBOLS

| | |
|---|---|
| 1: | Substrate |
| 2: | Anode |
| 3: | Light emitting layer |
| 4: | Cathode |
| 5: | Hole injection layer |
| 6: | Hole transport layer |
| 7: | Light emitting layer |
| 8: | Electron injection and transport layer |

1. A compound represented by Chemical Formula 1: 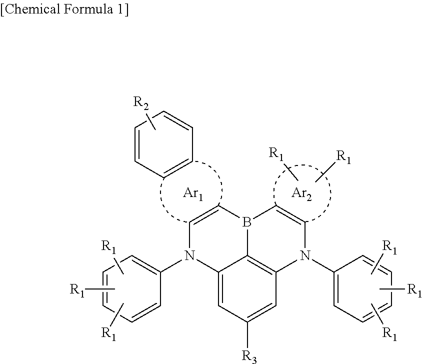
in Chemical Formula 1,
Ar₁ is furan, or thiophene, which is fused with two adjacent rings,
Ar₂ is benzene, benzofuran, or benzothiophene, which is fused with an adjacent ring,
each R₁ is independently not present, or deuterium, a substituted or unsubstituted C₁₋₆₀ alkyl, or a substituted or unsubstituted C₆₋₆₀ aryl, or two adjacent R₁s are combined to form —O—(CH₂)ₘ—O—, wherein m is an integer of 1 to 4;
R₂ is not present, or deuterium, or a substituted or unsubstituted C₁₋₆₀ alkyl, and
R₃ is hydrogen, deuterium, or a substituted or unsubstituted C₁₋₆₀ alkyl,
provided that Chemical Formula 1 comprises at least one —O—(CH₂)ₘ—O-formed by combining the two adjacent R₁s.

2. The compound of claim 1,
wherein the compound is represented by any one of Chemical Formulae 1-1 to 1-4: 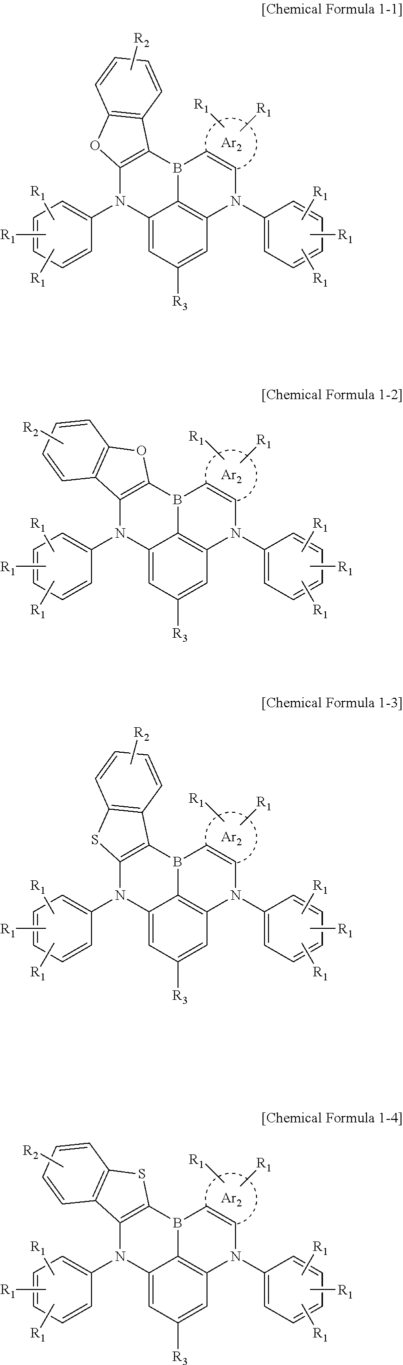
in Chemical Formulae 1-1 to 1-4,
Ar₂ and R₁ to R₃ are as defined in Chemical Formula 1.

3. The compound of claim 1,
wherein each R₁ is independently not present, or deuterium, C₁₋₁₀ alkyl, or C₆₋₂₀ aryl, or two adjacent R₁s are combined to form

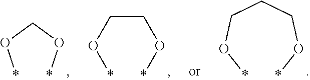

4. The compound of claim 1,
wherein each R₁ is independently not present, or deuterium, methyl, ethyl, propyl, isopropyl, butyl, isobutyl, tertbutyl, or phenyl, or two adjacent R₁s are combined to form

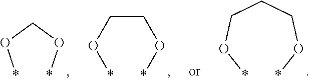

5. The compound of claim 1,
wherein R₂ is not present, or deuterium, or C₁₋₁₀ alkyl.

6. The compound of claim 1,
wherein R₂ is not present, or deuterium, methyl, ethyl, propyl, isopropyl, butyl, isobutyl, or tertbutyl.

7. The compound of claim 1,
wherein R₃ is hydrogen, deuterium, or C₁₋₁₀ alkyl.

8. The compound of claim 1,
wherein R₃ is hydrogen, deuterium, methyl, ethyl, propyl, isopropyl, butyl, isobutyl, or tertbutyl.

9. The compound of claim 1,
wherein the compound is any one selected from the group consisting of:

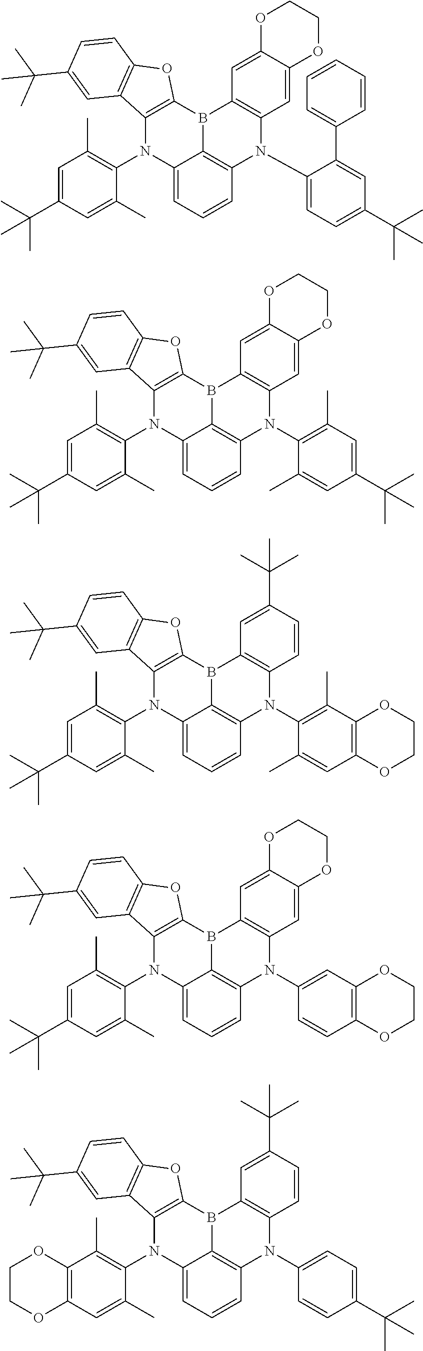

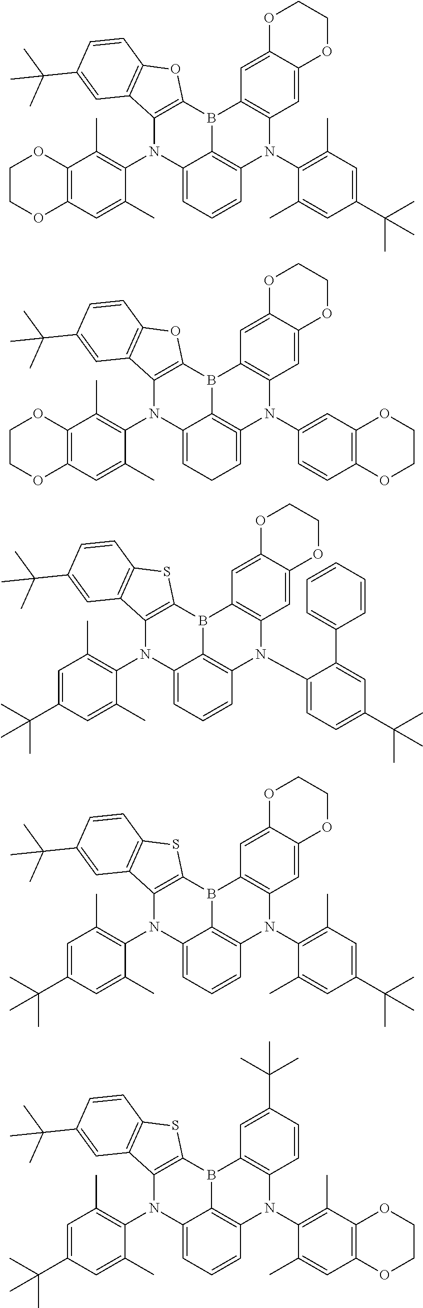

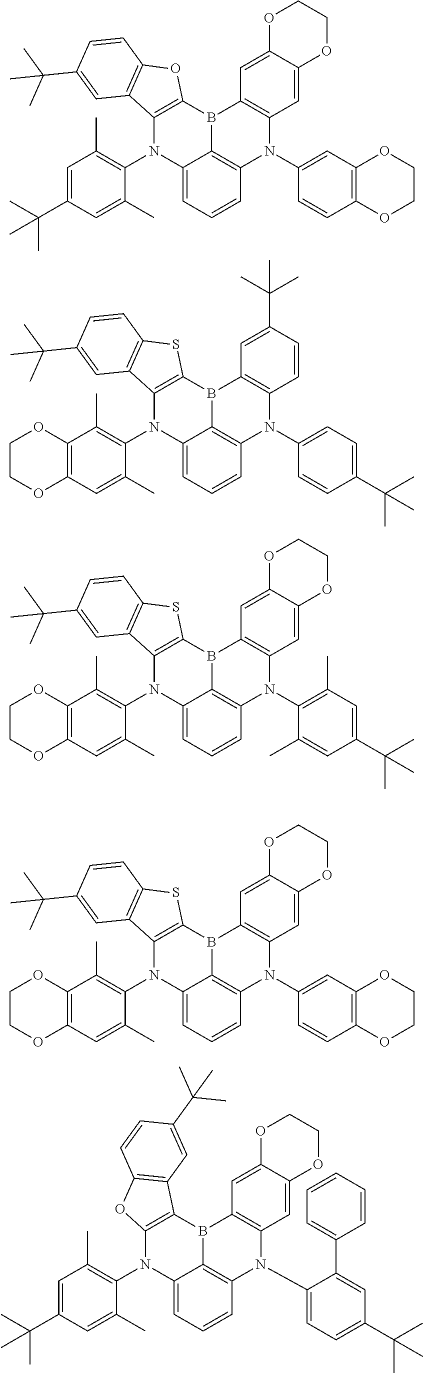

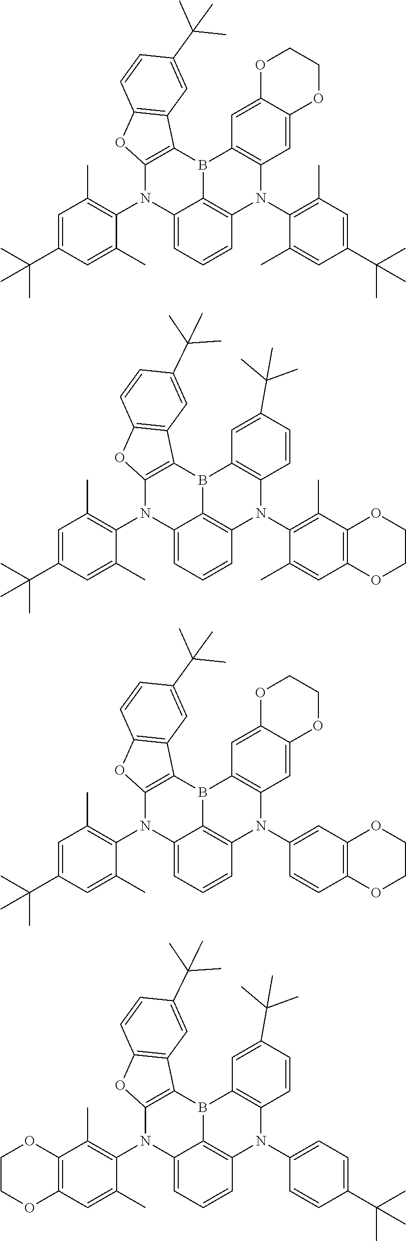

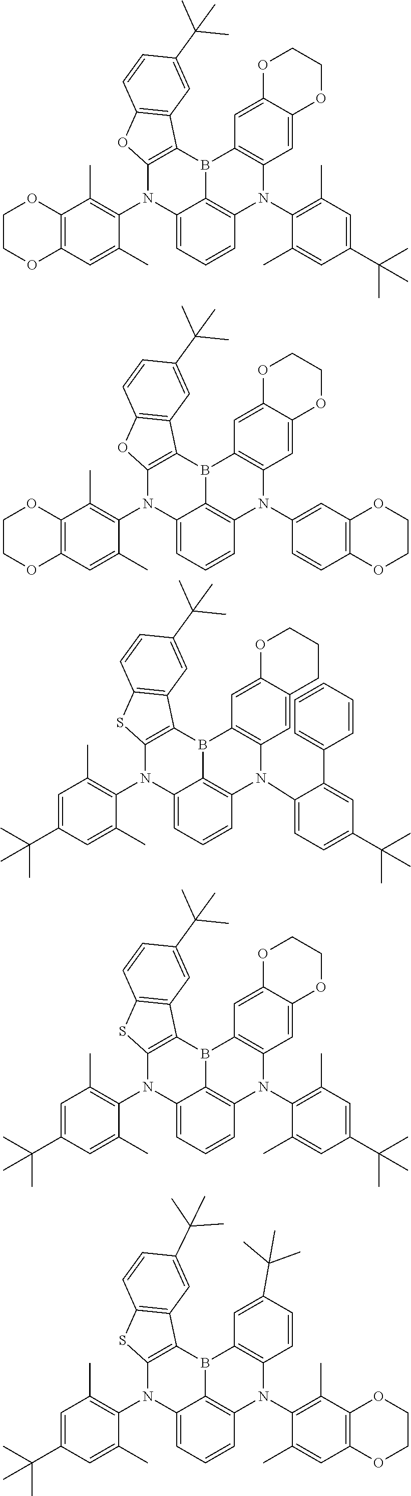

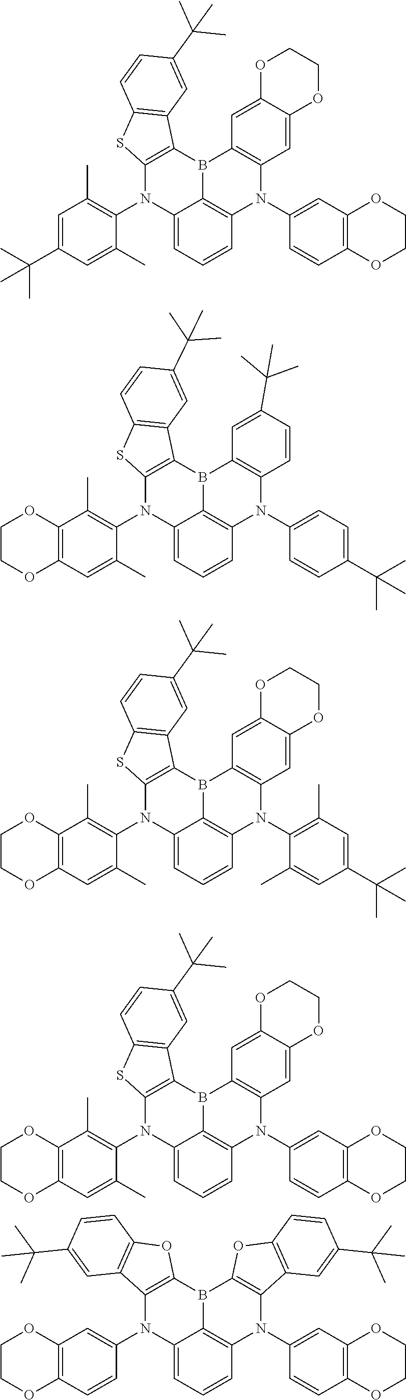

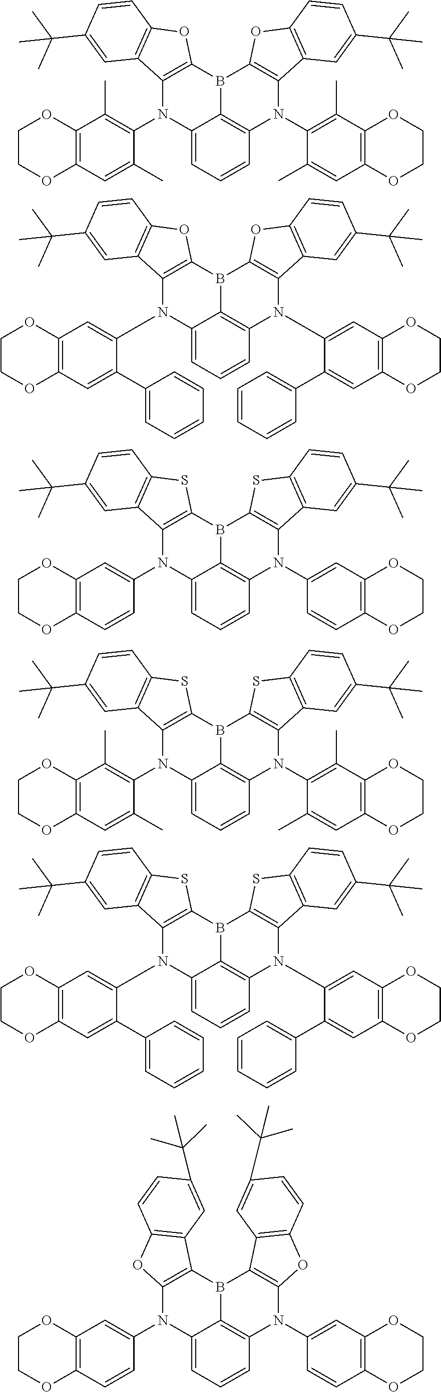

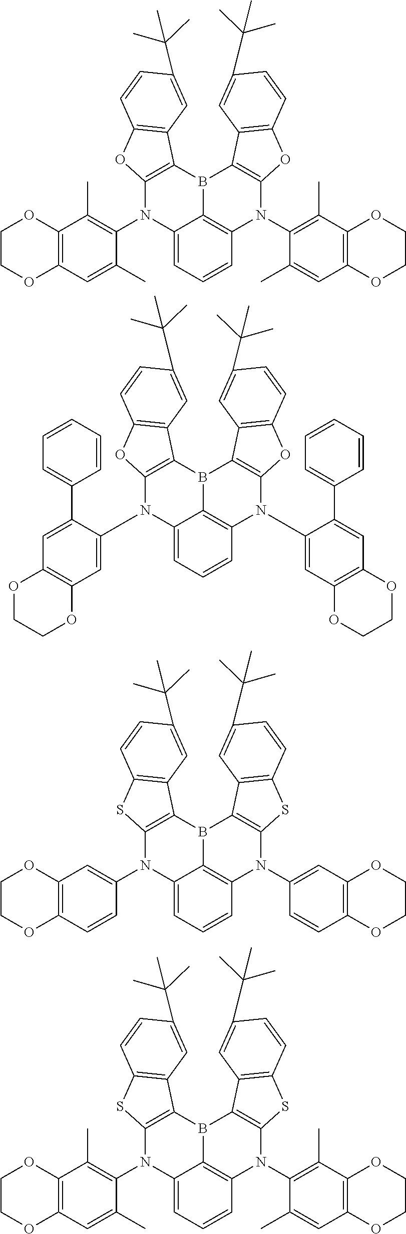

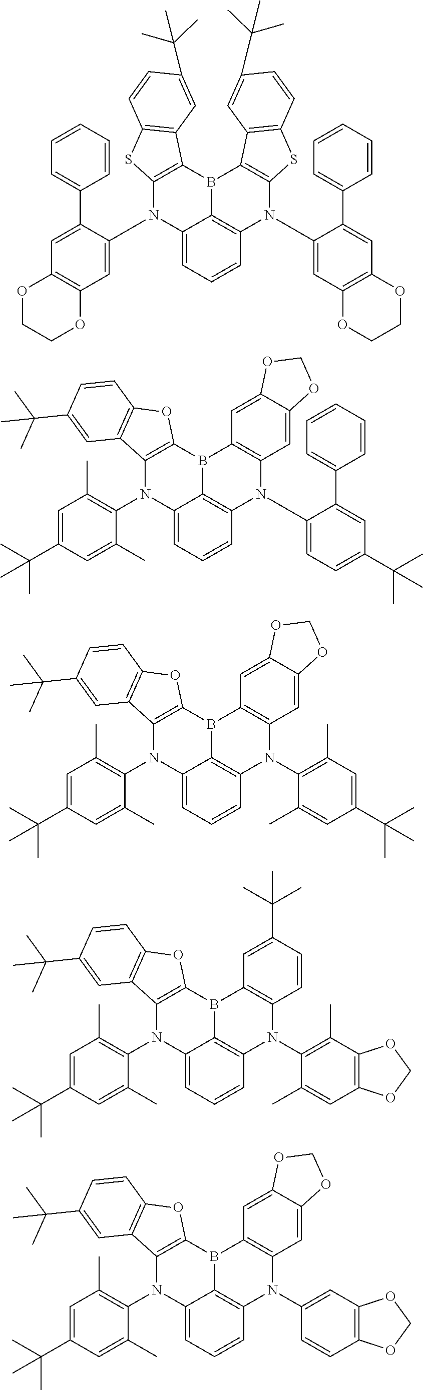

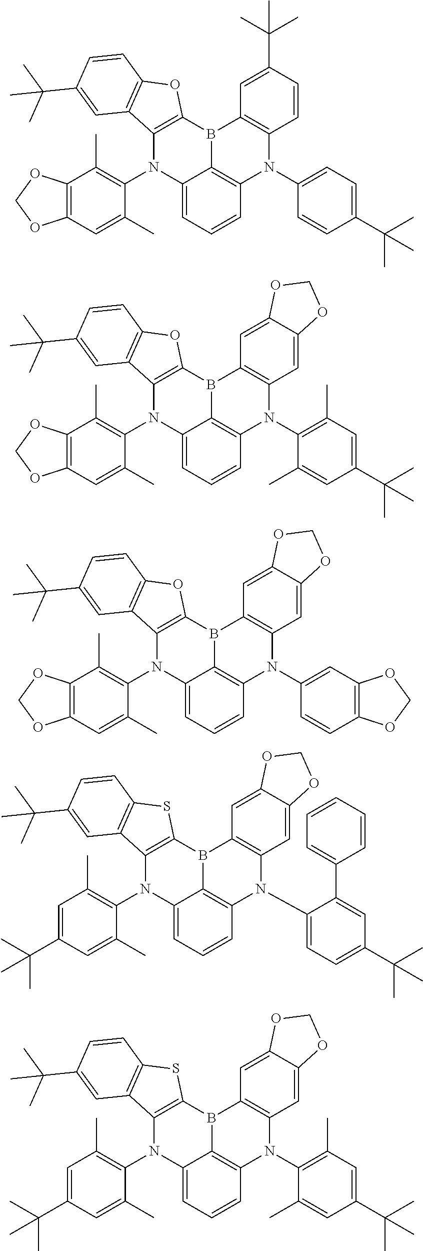

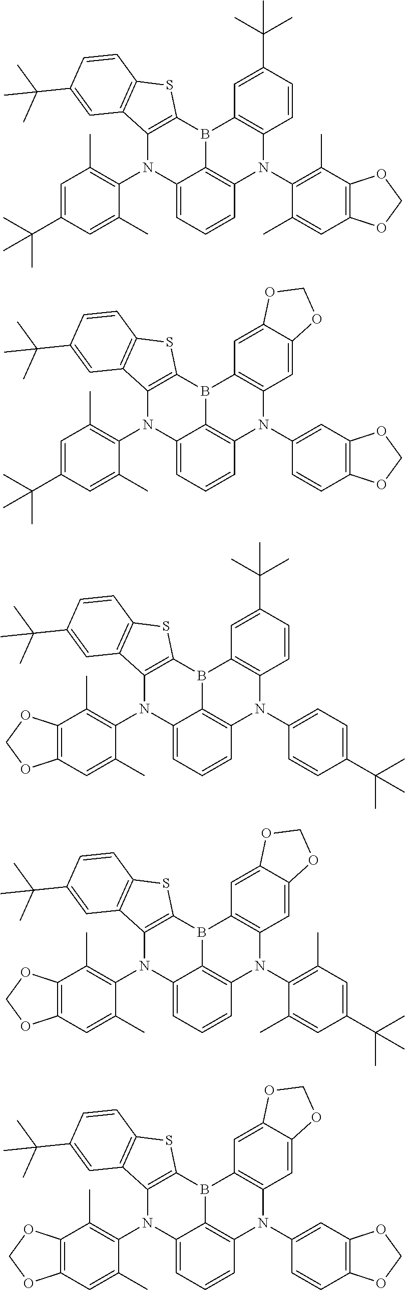

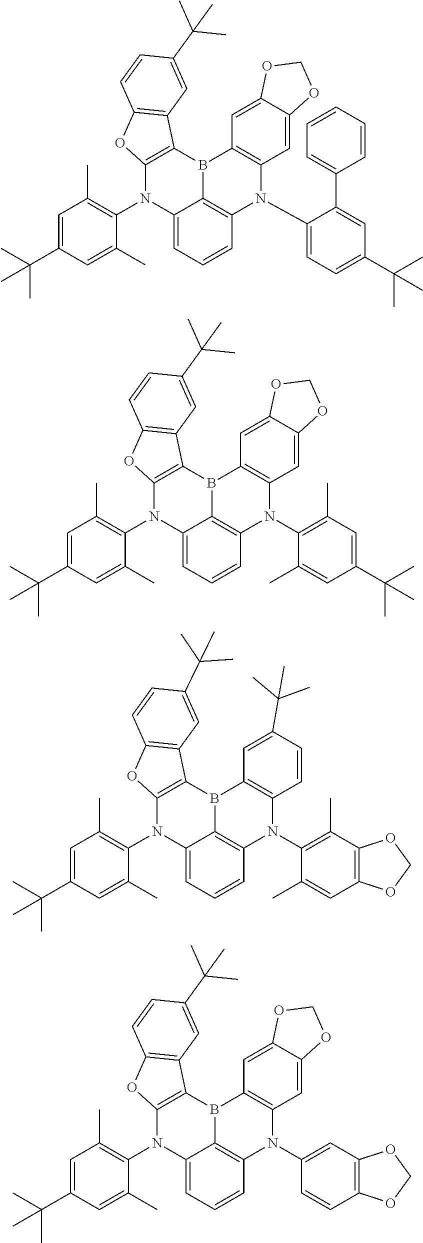

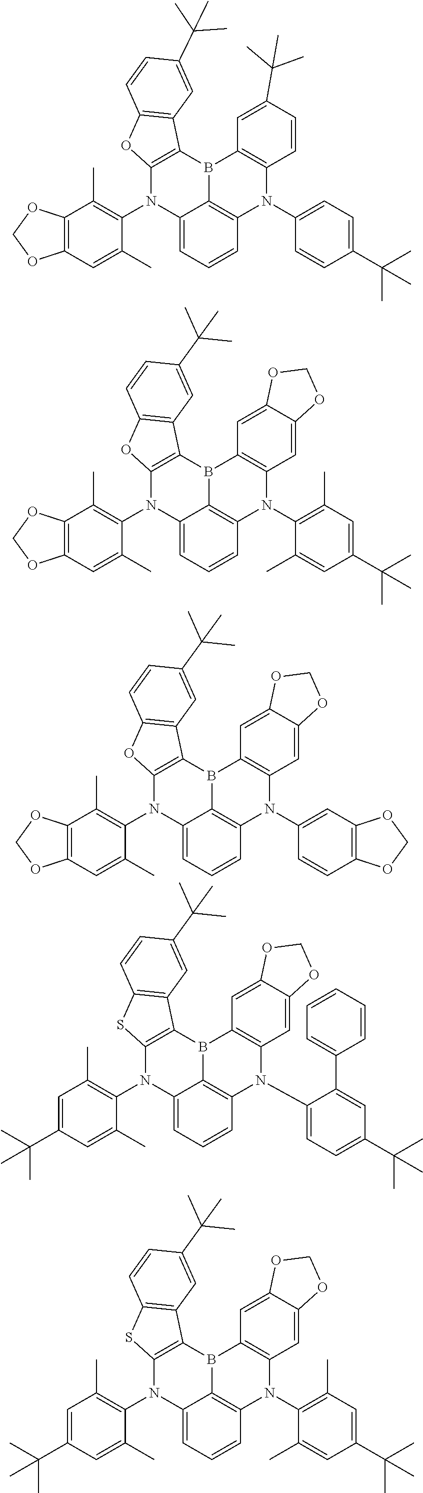

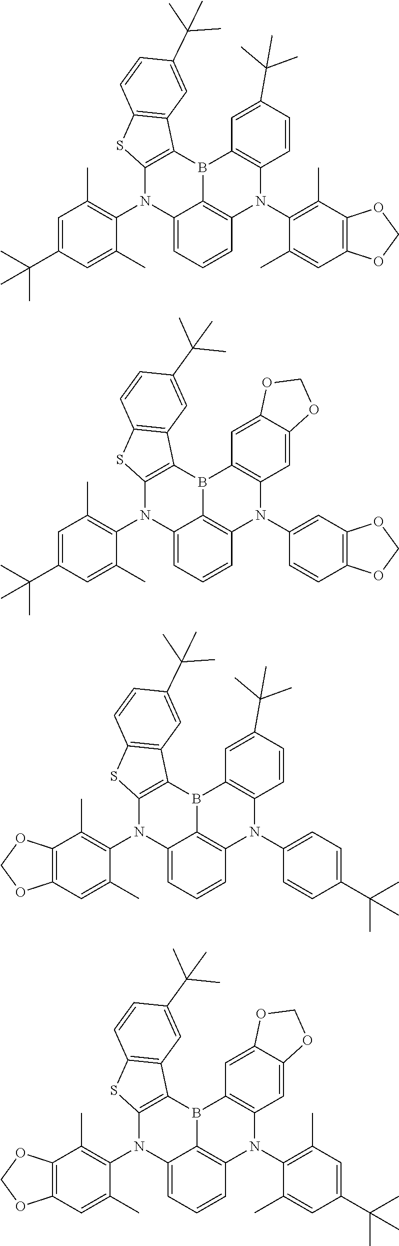 [SMILES: Cc1cc(C(C)(C)C)cc(C)c1N1c2cccc3c2B(c2cc(C(C)(C)C)ccc2N3c2c(C)cc3c(c2C)OCO3)c2c1sc1ccc(C(C)(C)C)cc21 ; Cc1cc(C(C)(C)C)cc(C)c1N1c2cccc3c2B(c2cc4c(cc2N3c2ccc3c(c2)OCO3)OCO4)c2c1sc1ccc(C(C)(C)C)cc21 ; Cc1cc2c(c(C)c1N1c3cccc4c3B(c3cc(C(C)(C)C)ccc3N4c3ccc(C(C)(C)C)cc3)c3c1sc1ccc(C(C)(C)C)cc31)OCO2 ; Cc1cc(C(C)(C)C)cc(C)c1N1c2cc3c(cc2B2c4c1cccc4N(c1c(C)cc4c(c1C)OCO4)c1sc4ccc(C(C)(C)C)cc4c12)OCO3]

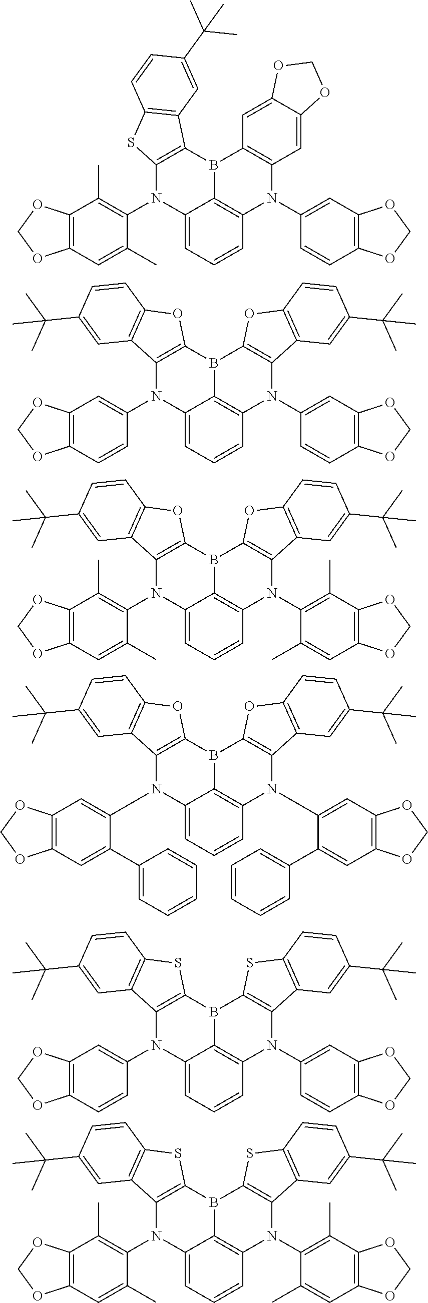

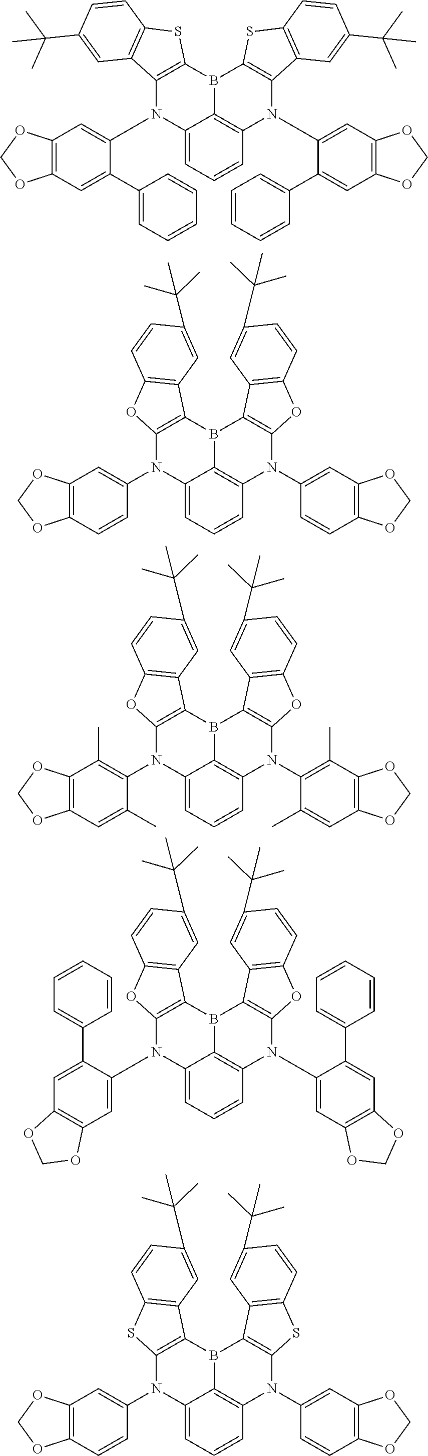

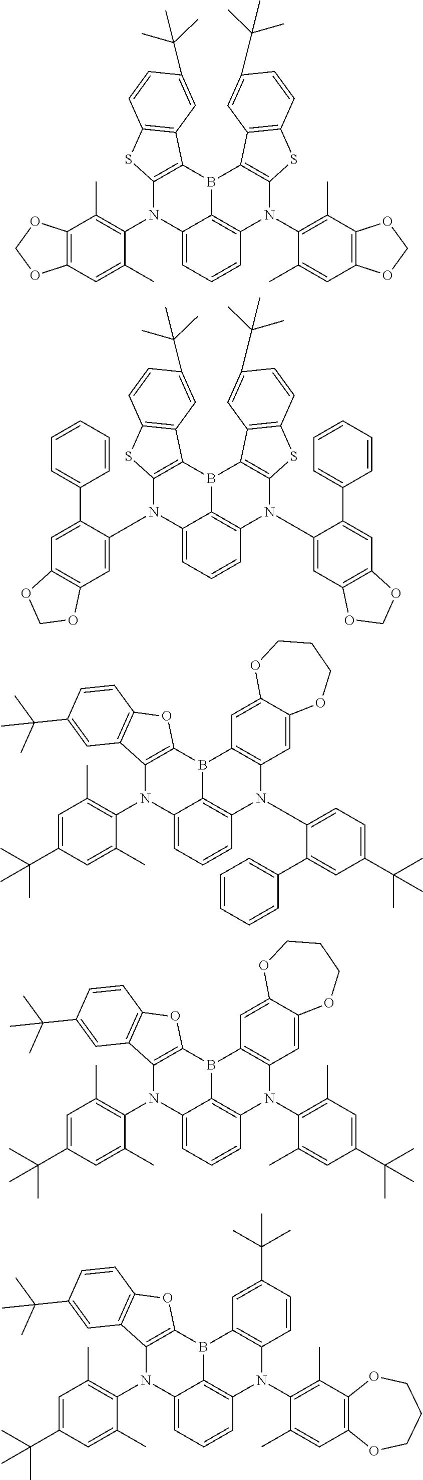

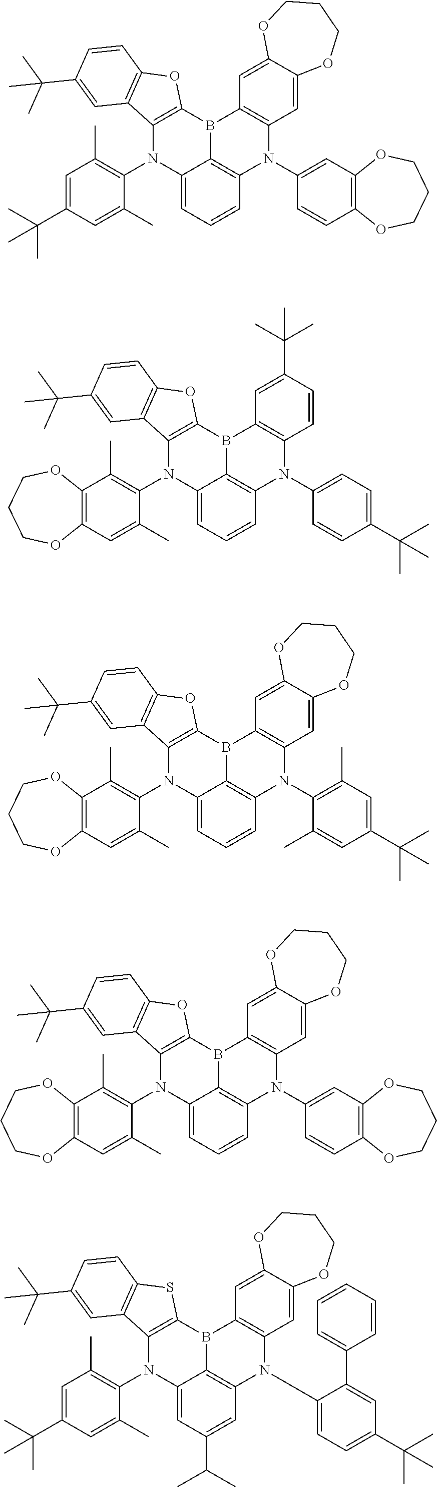

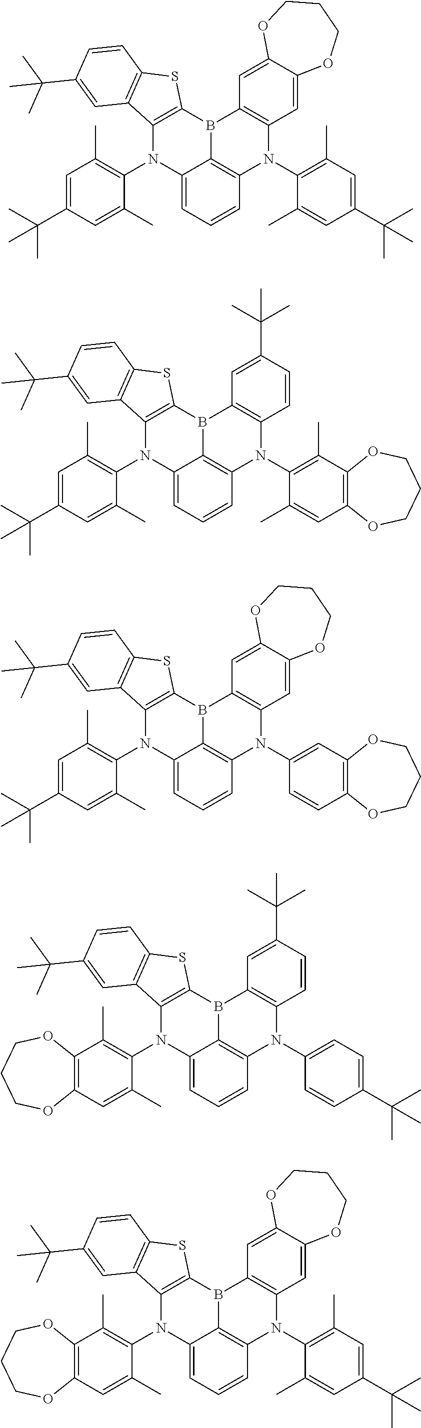

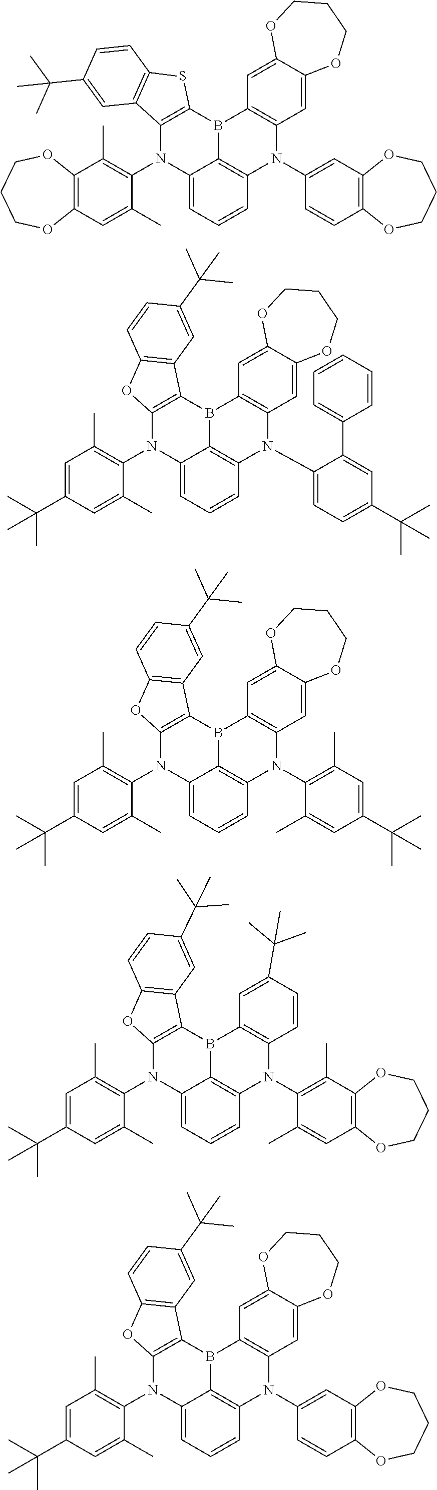

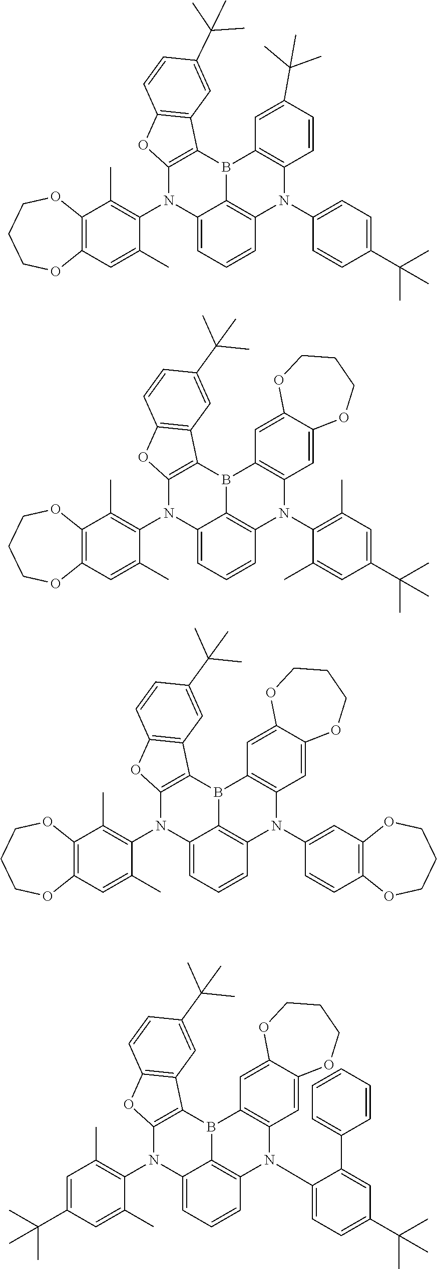

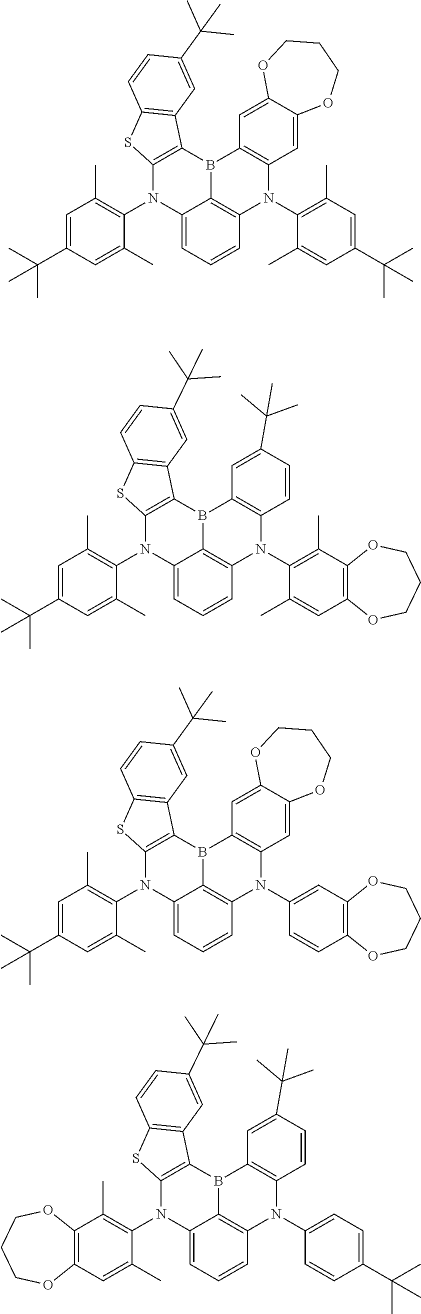

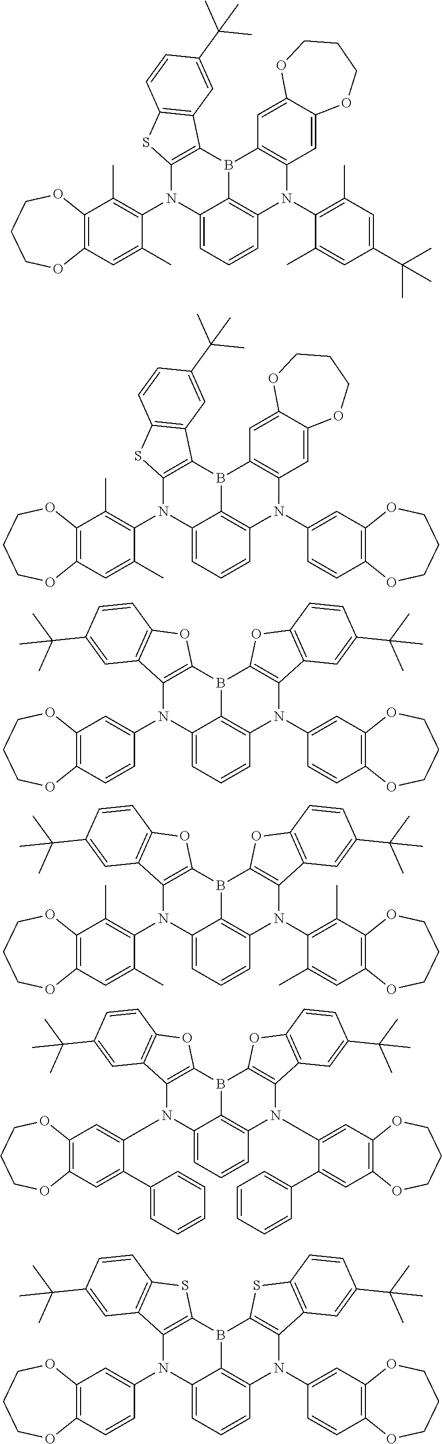

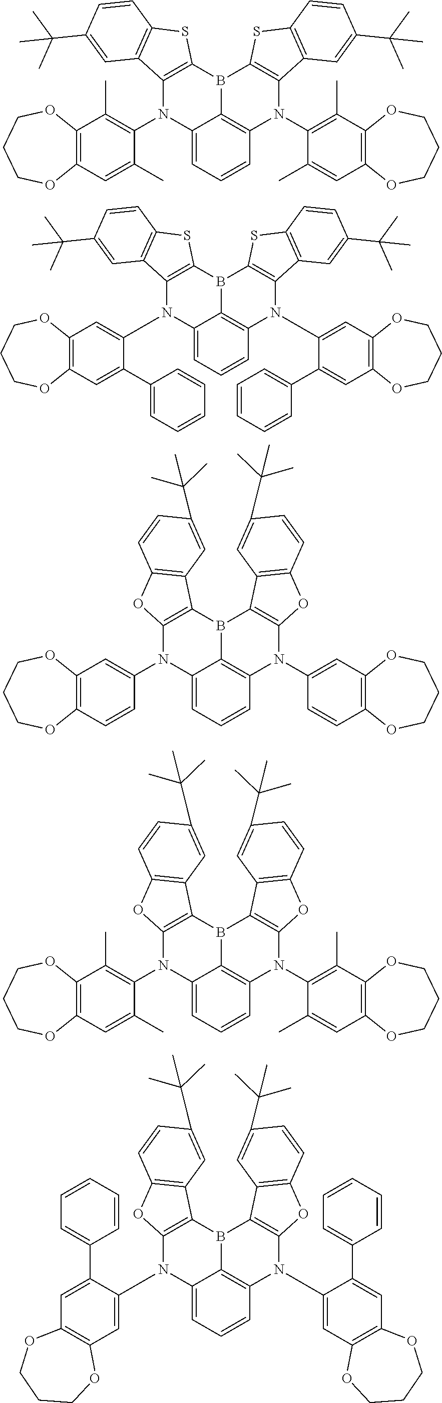

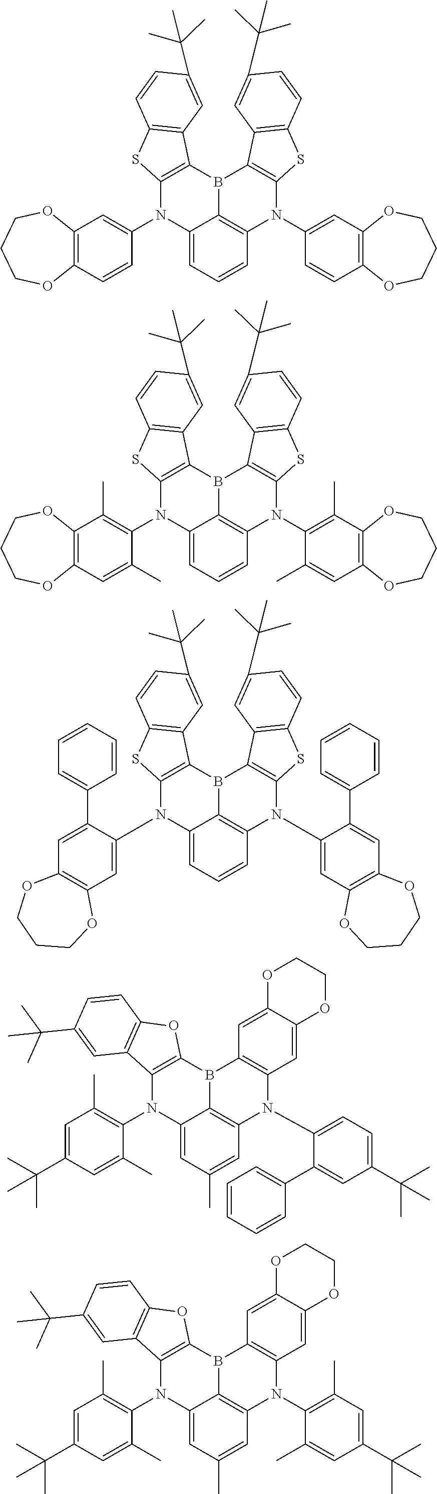

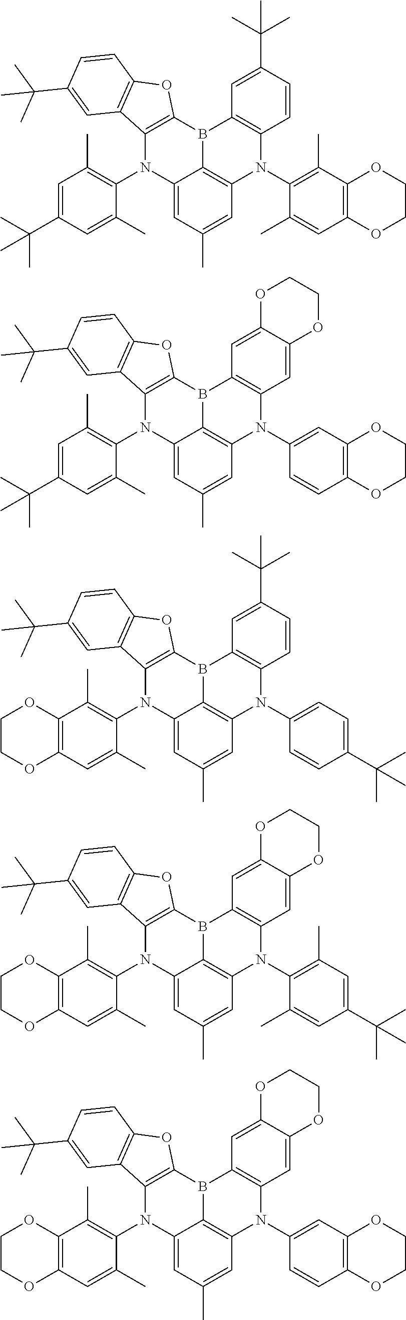

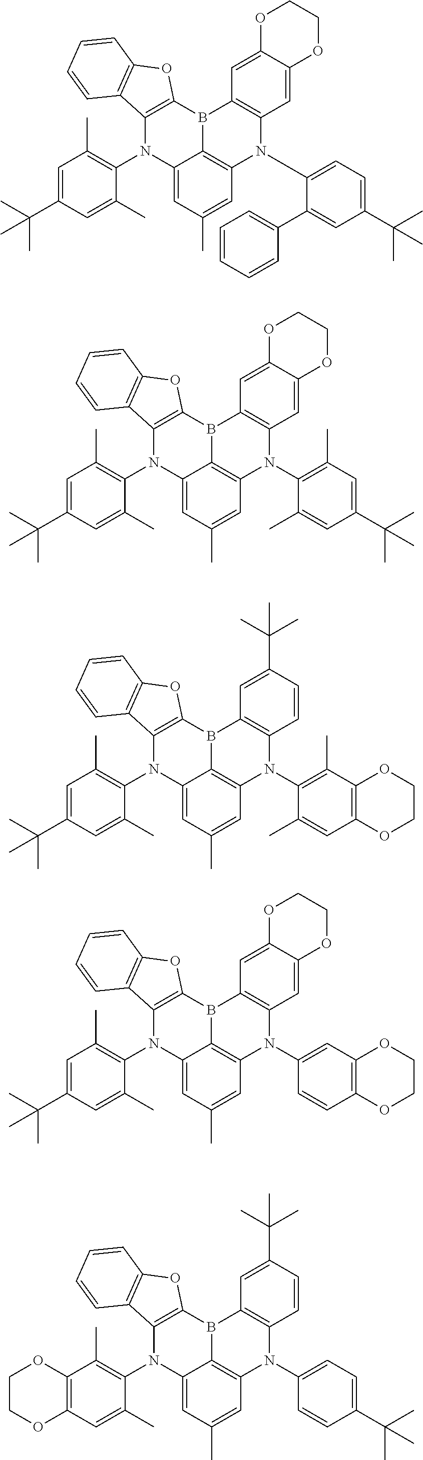

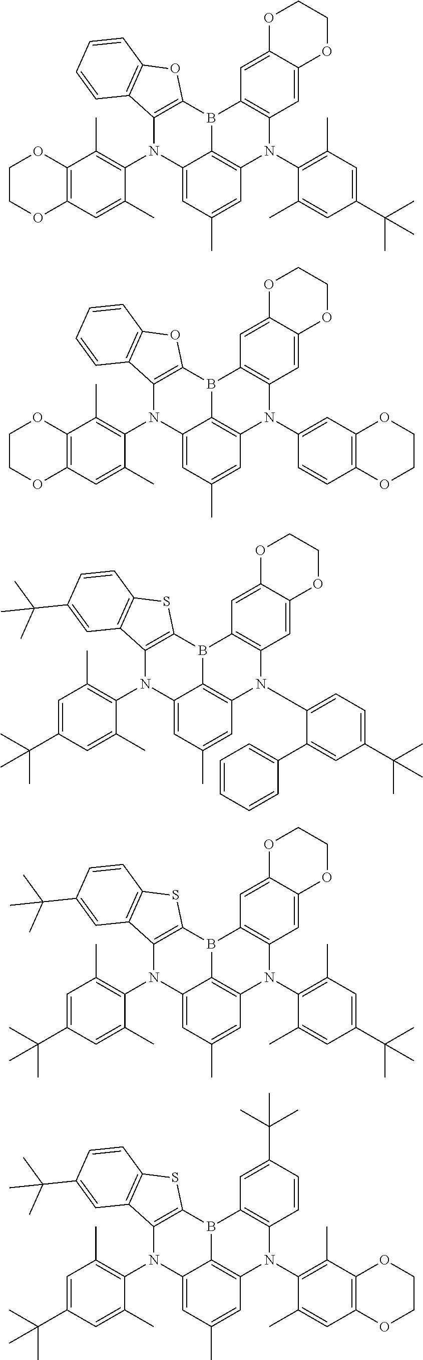

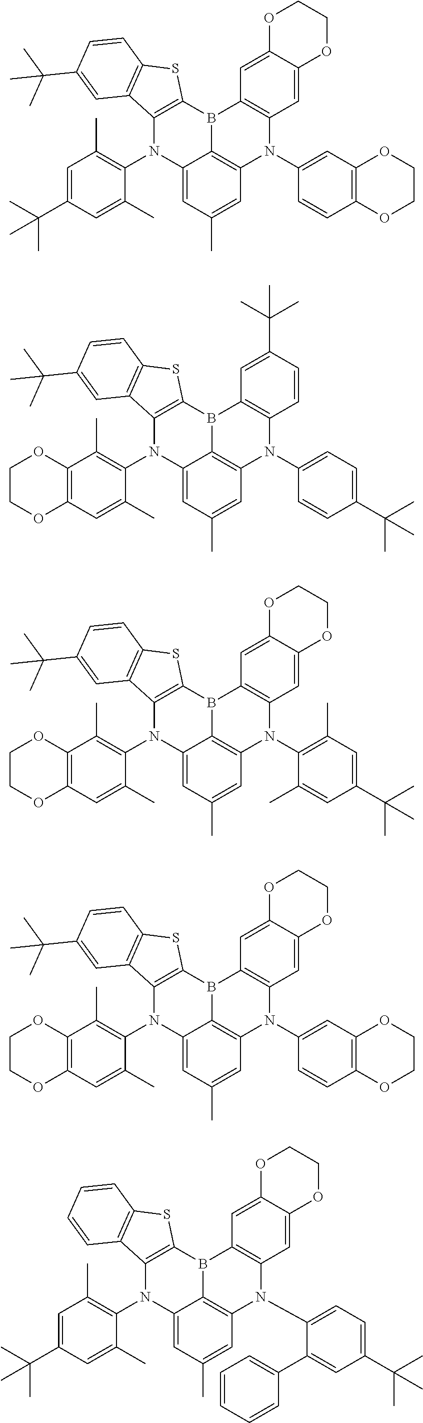

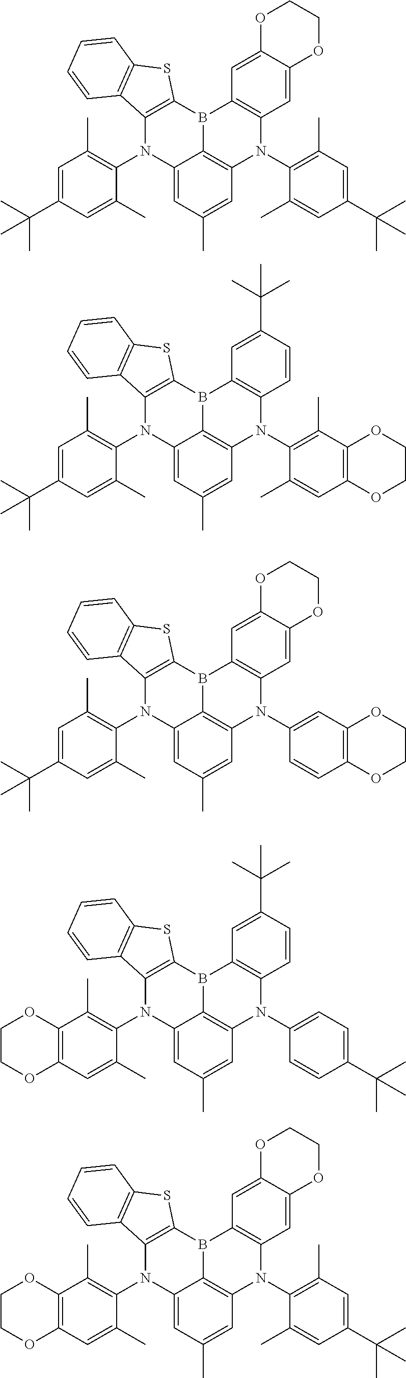

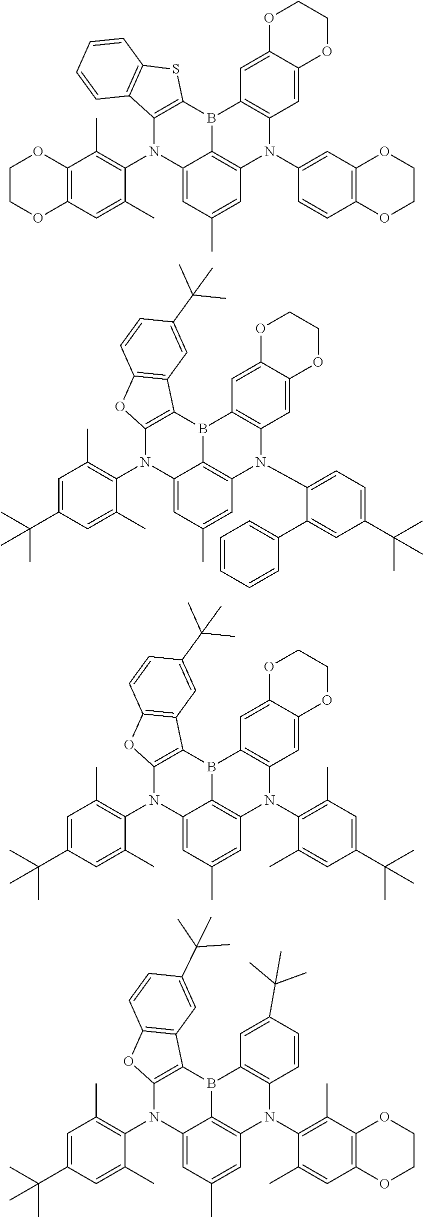

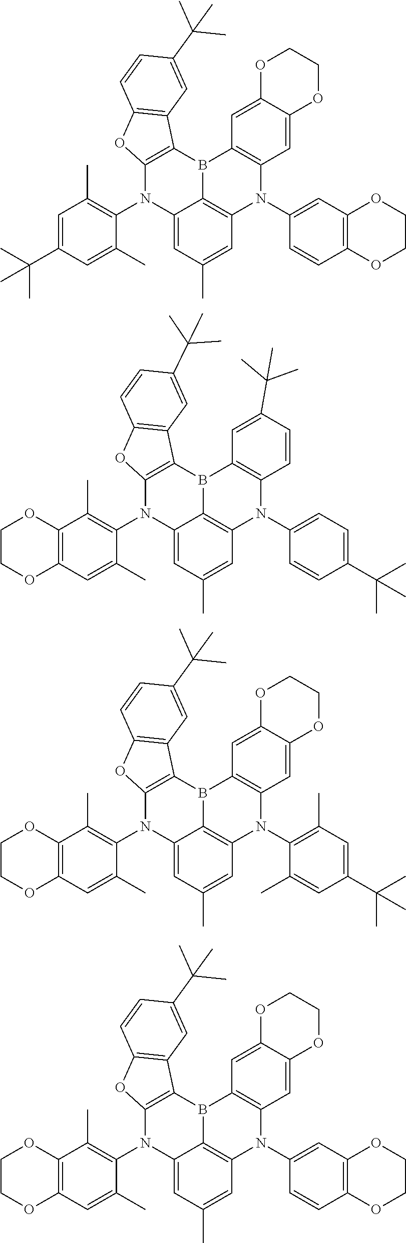

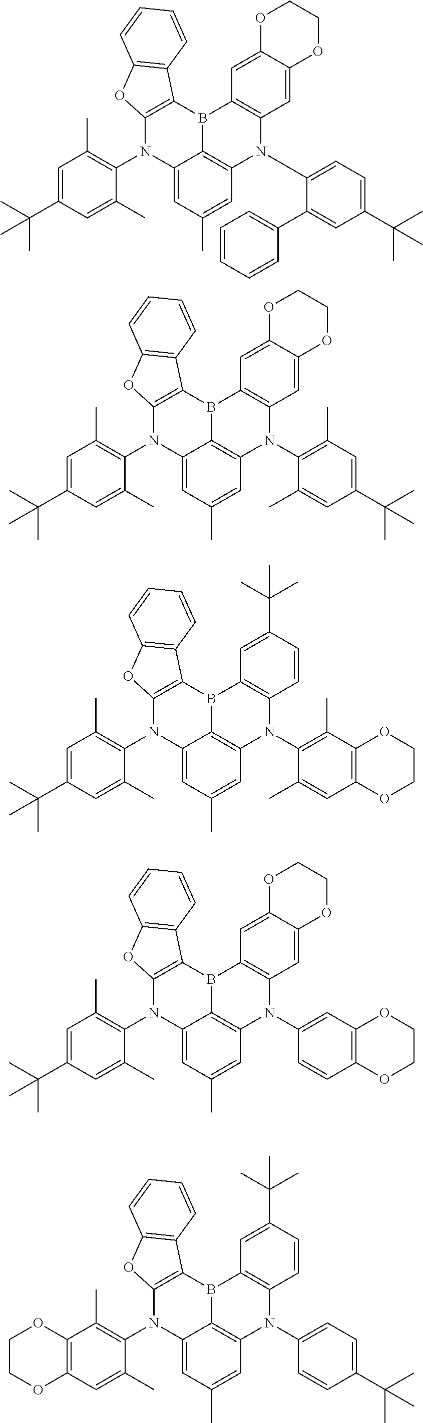

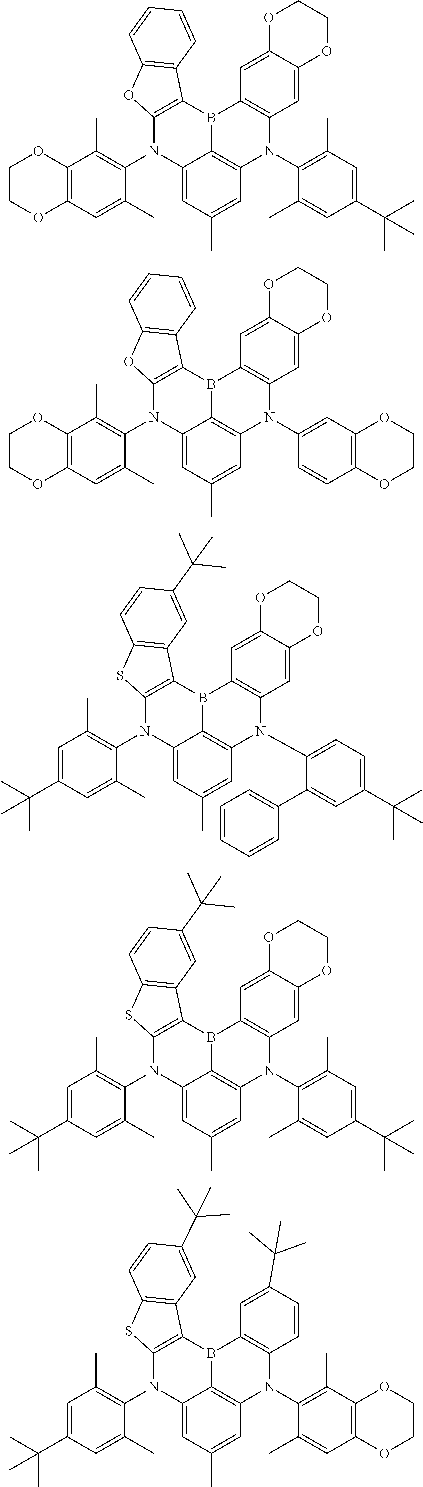

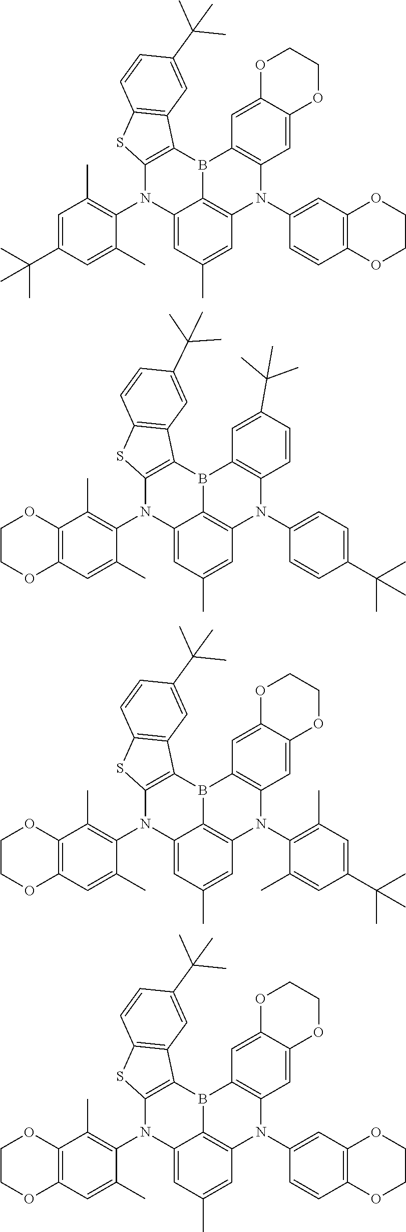

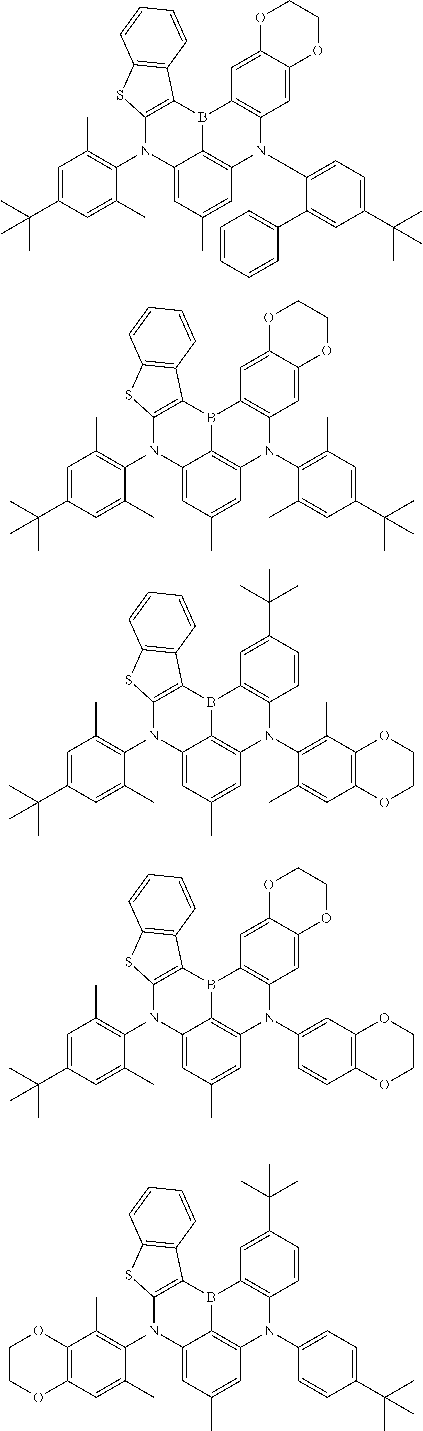

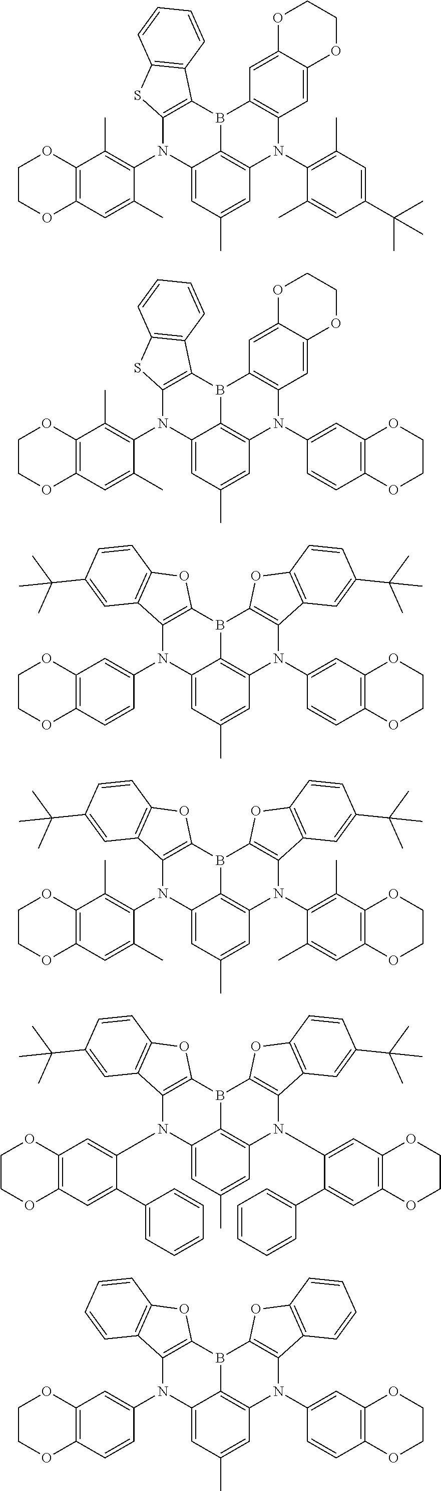

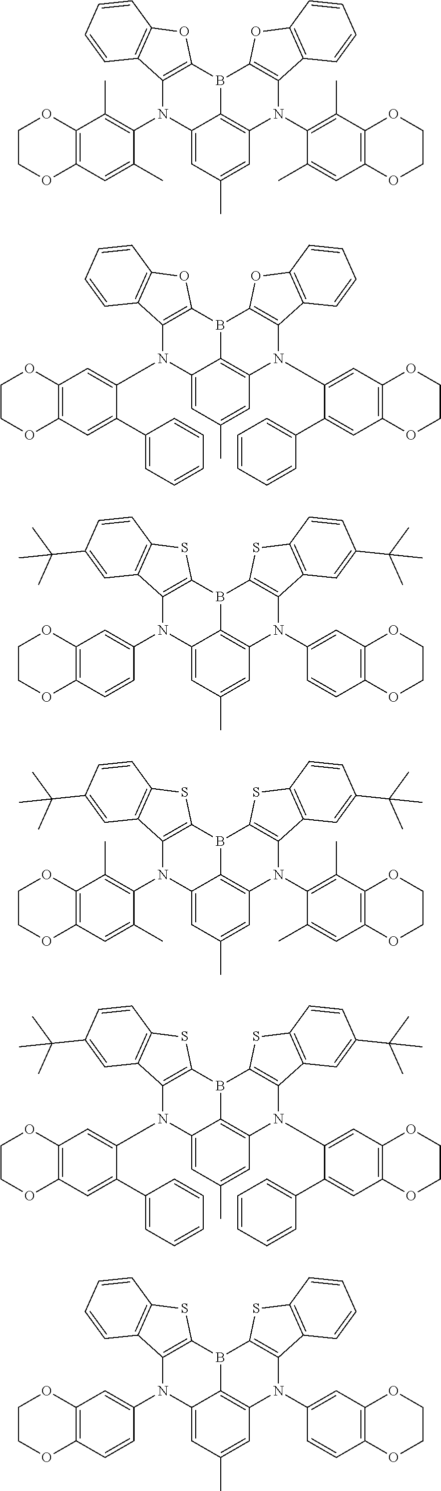

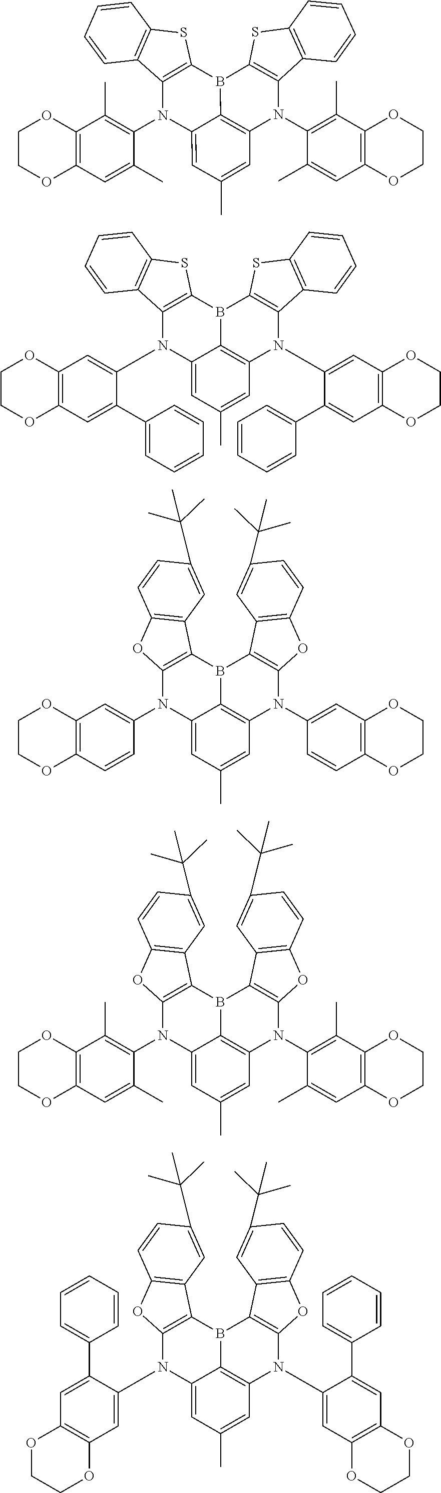

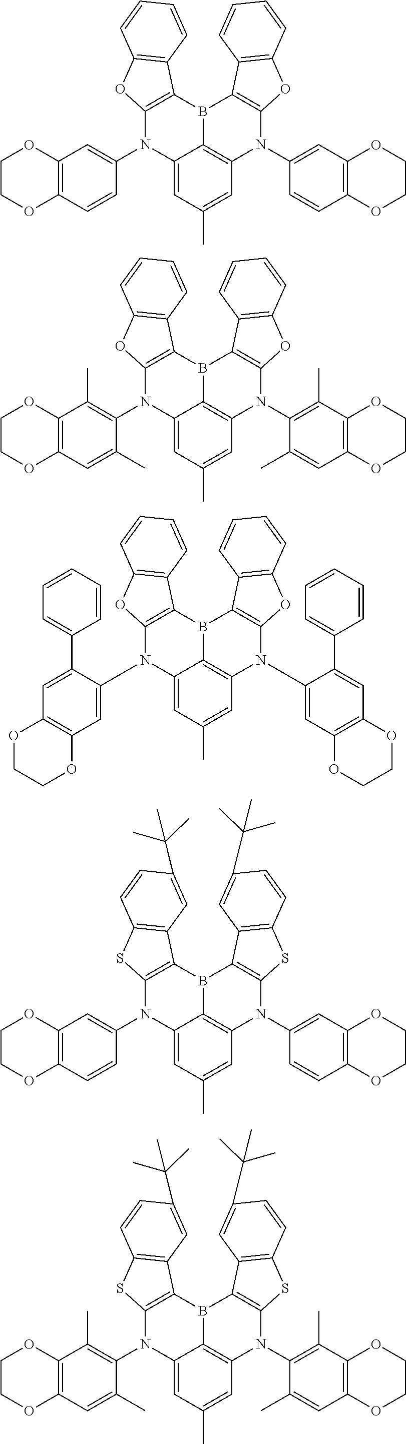

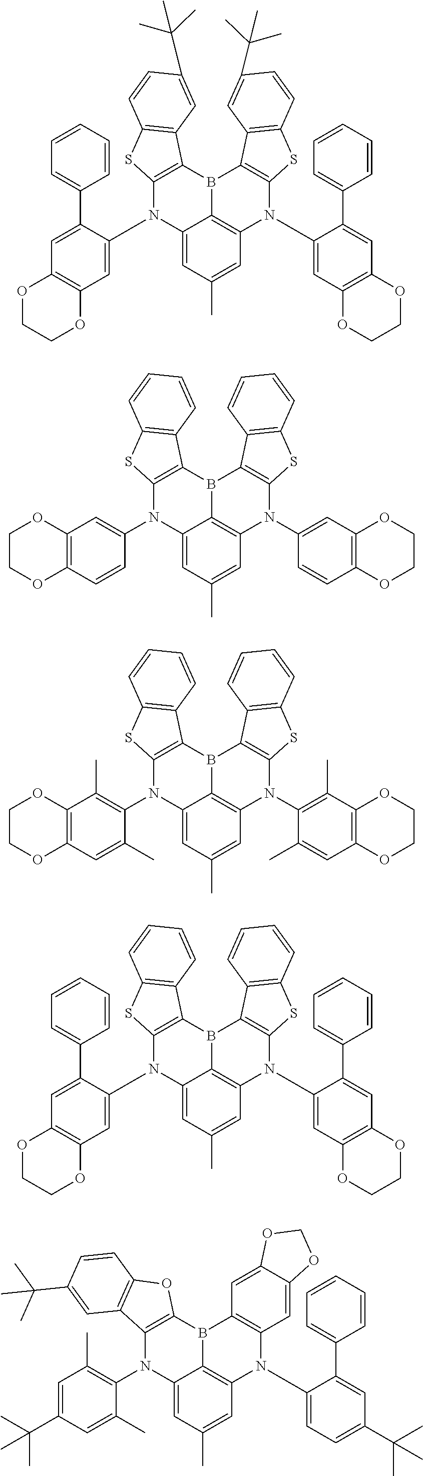

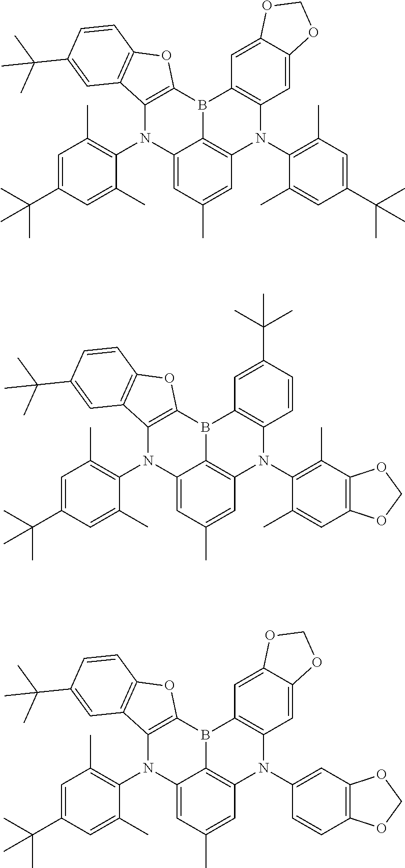

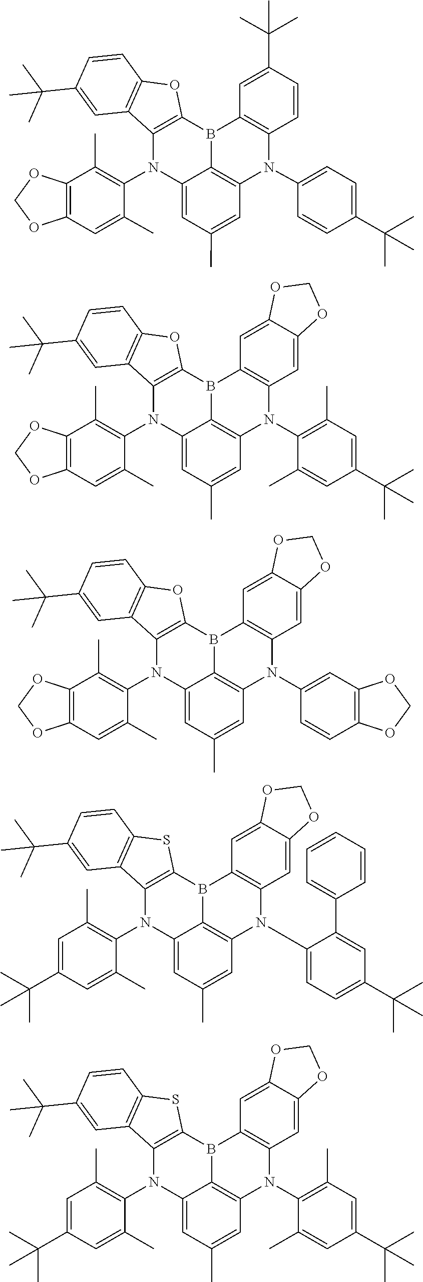

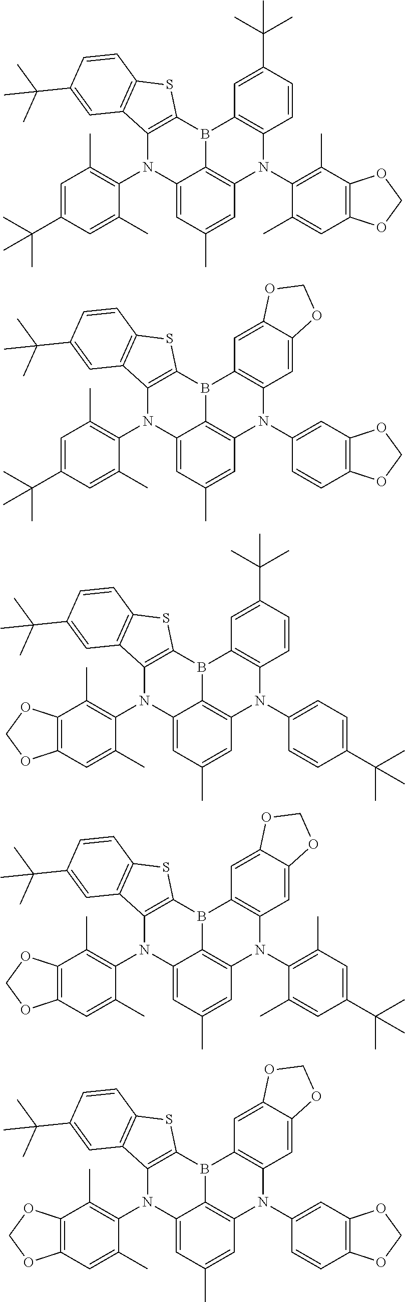

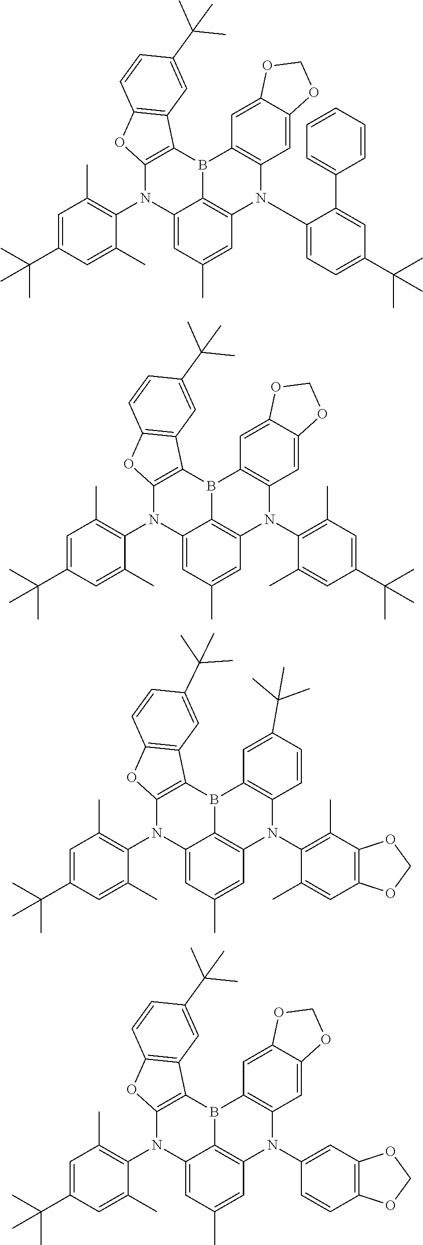

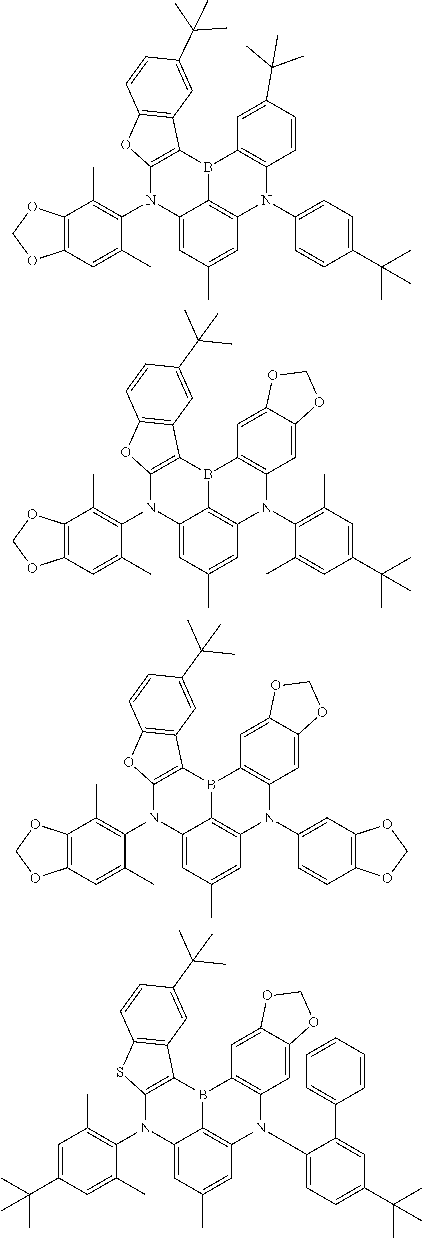

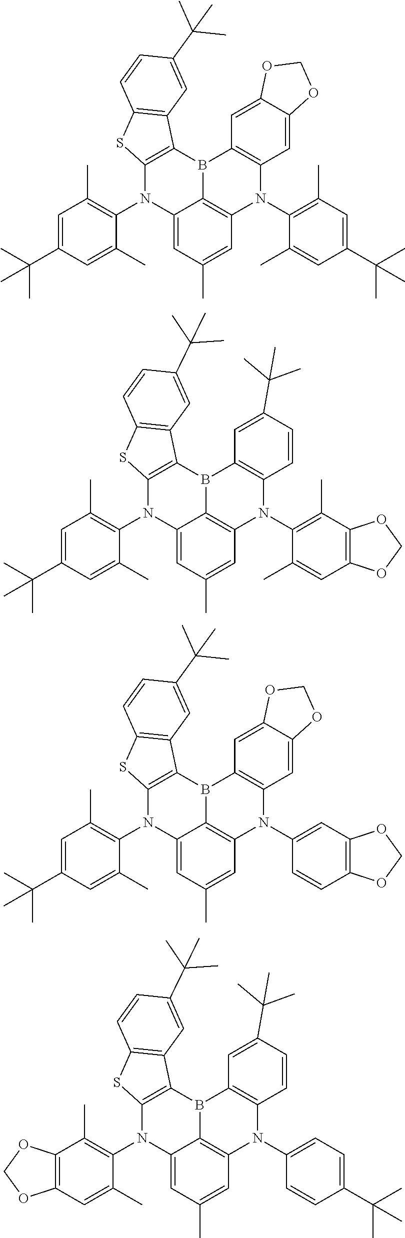

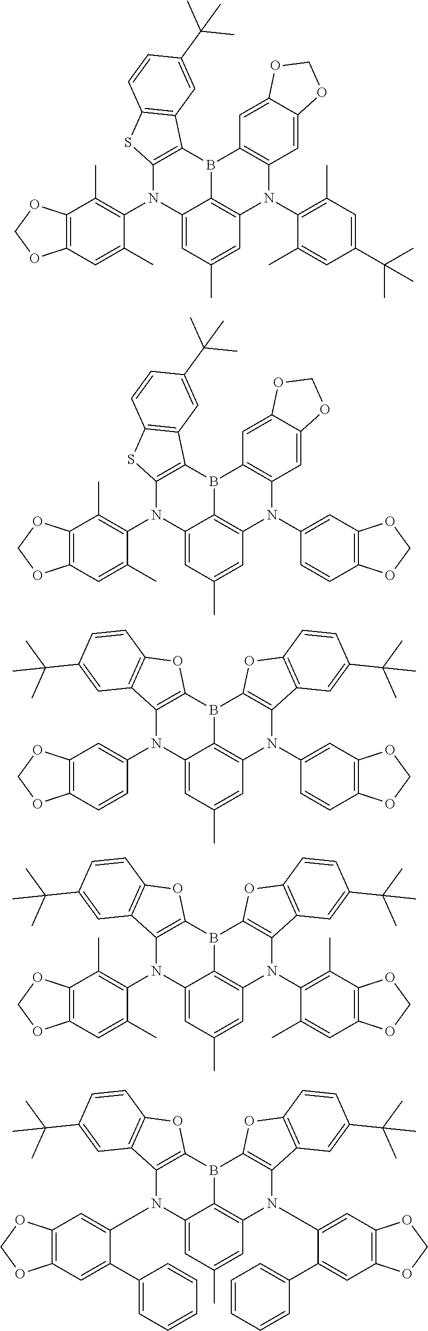

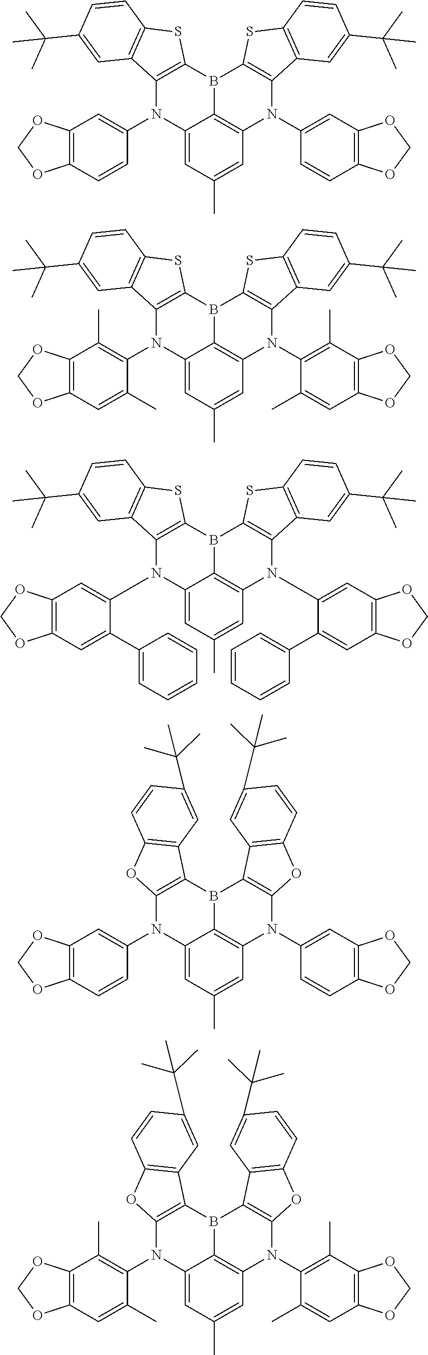

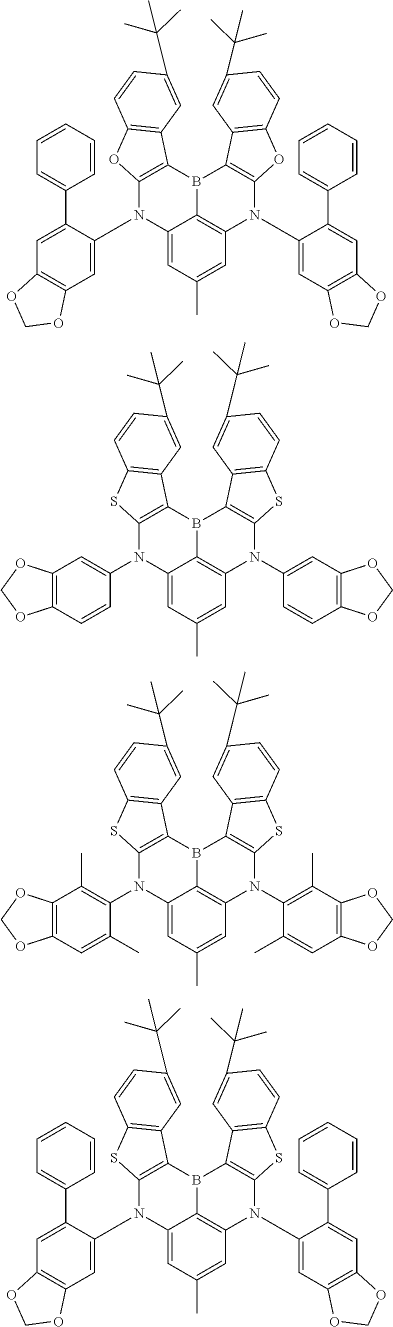

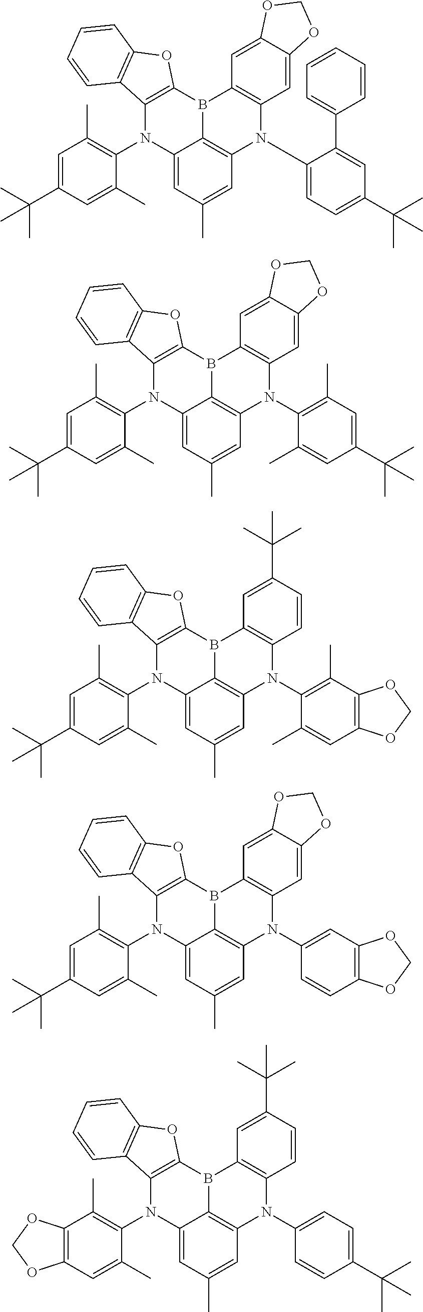

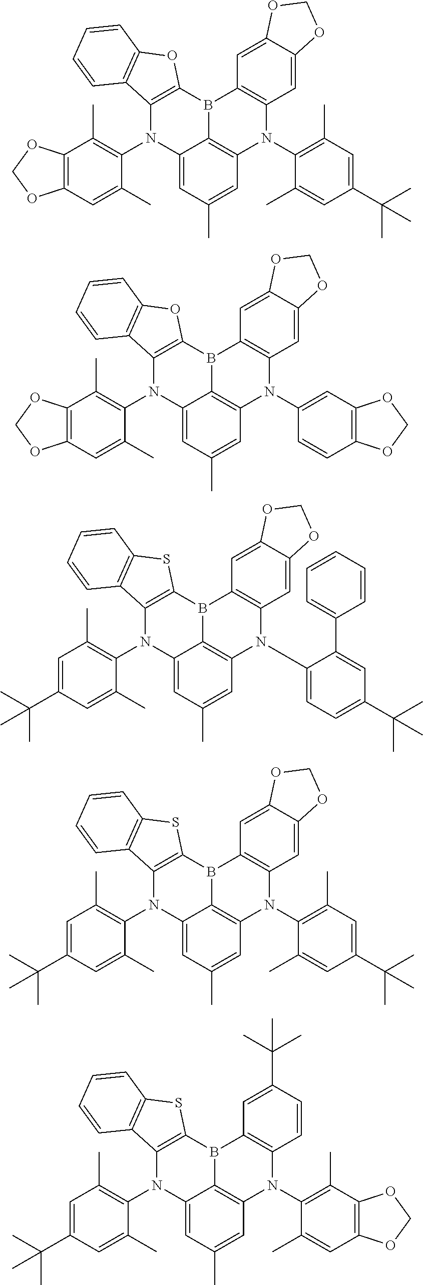

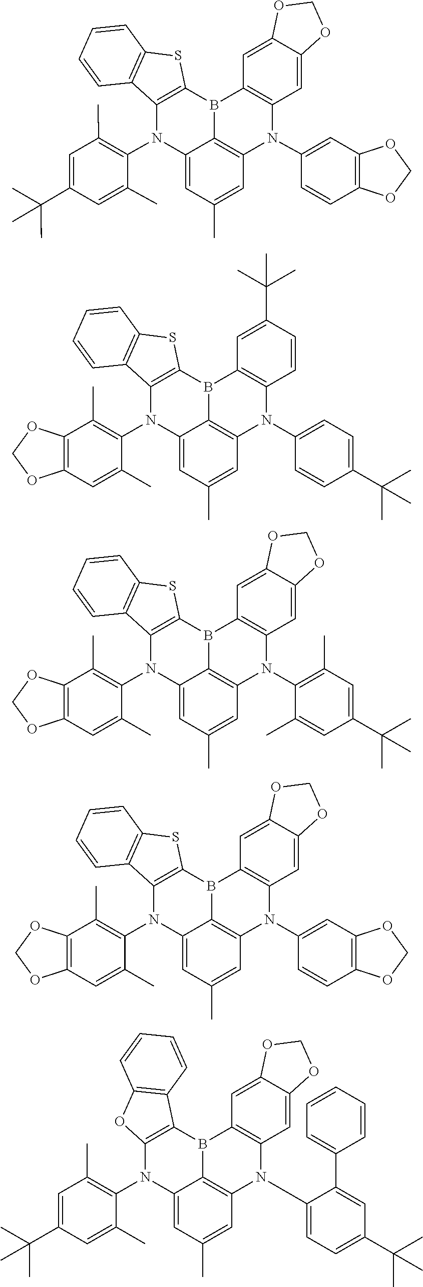

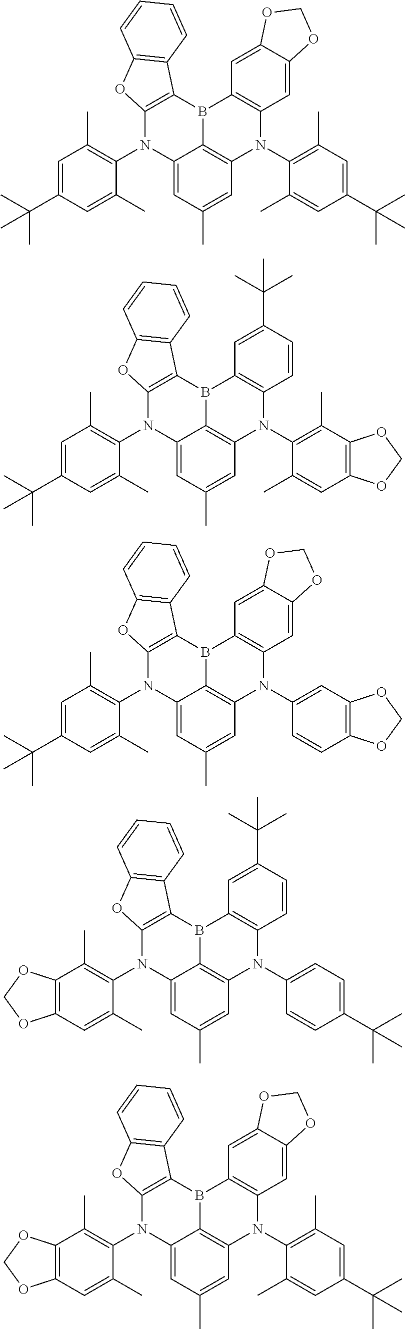

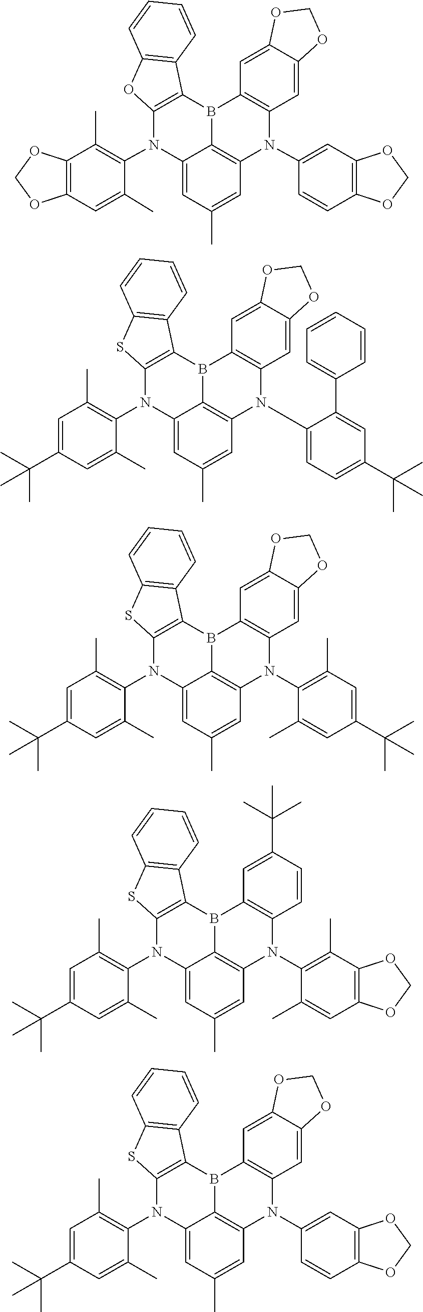

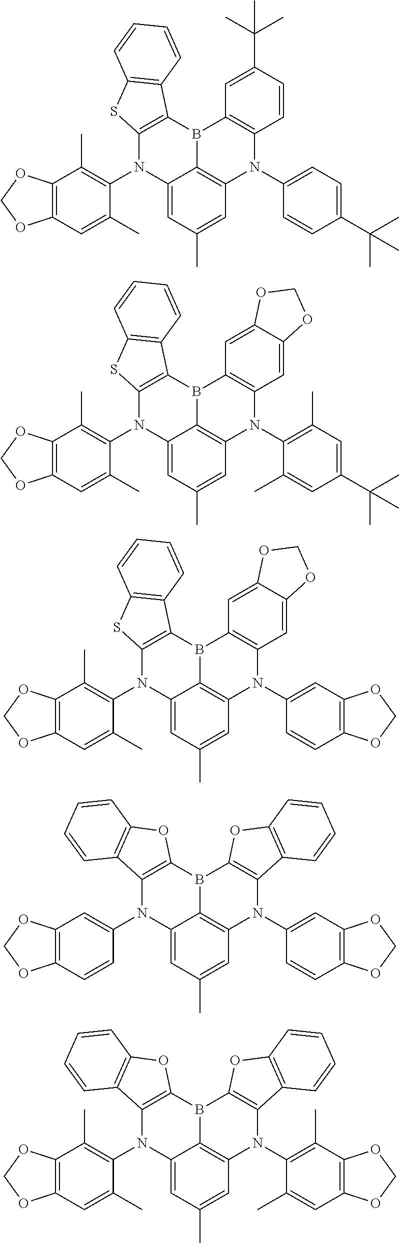

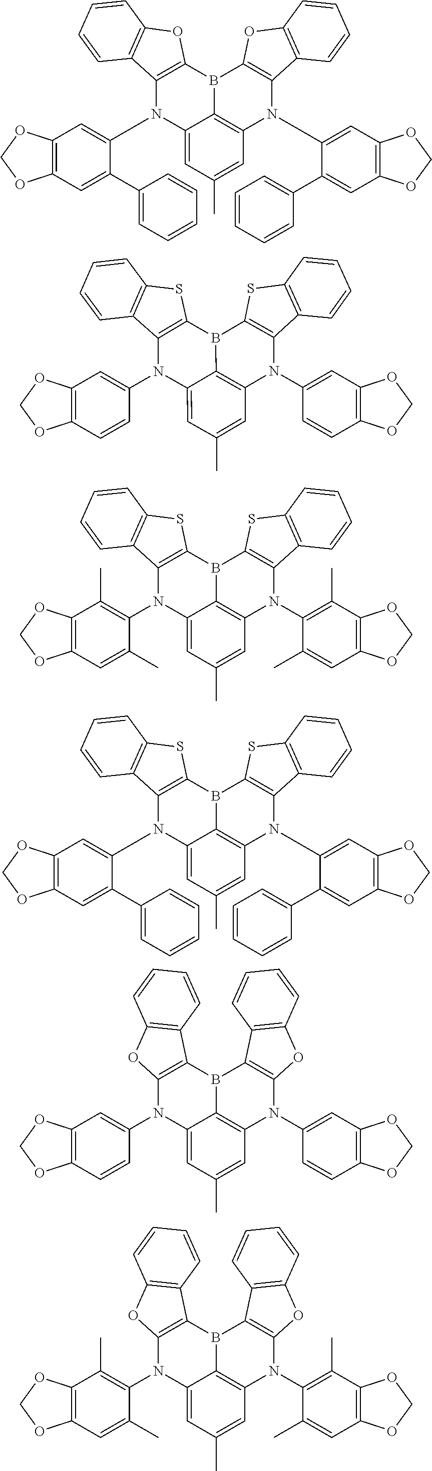

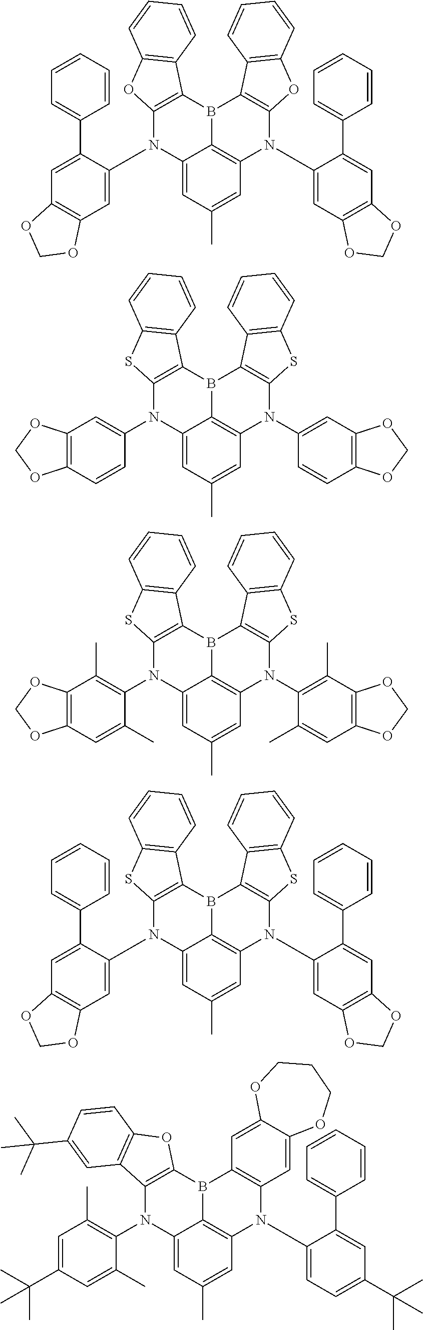

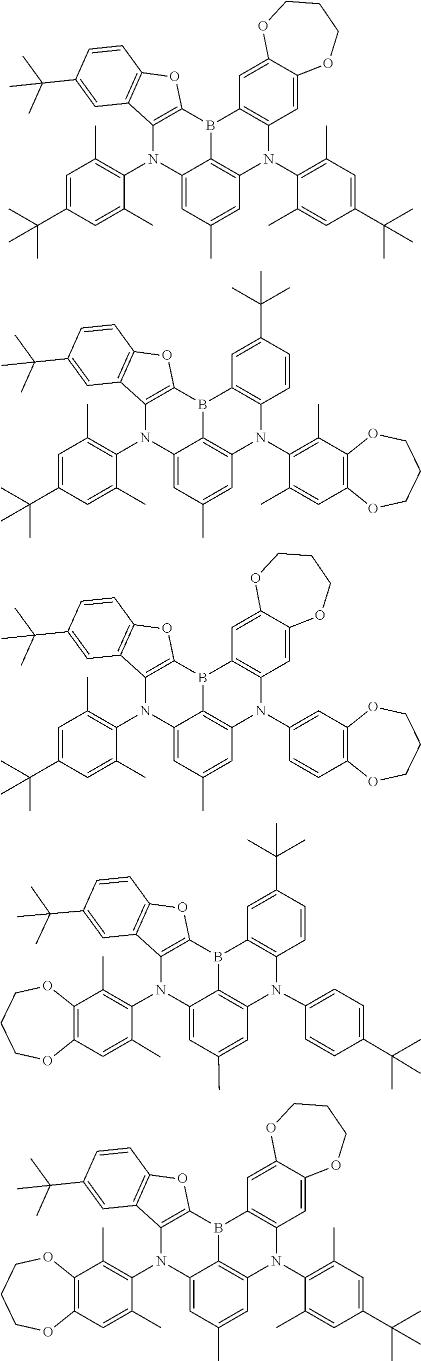

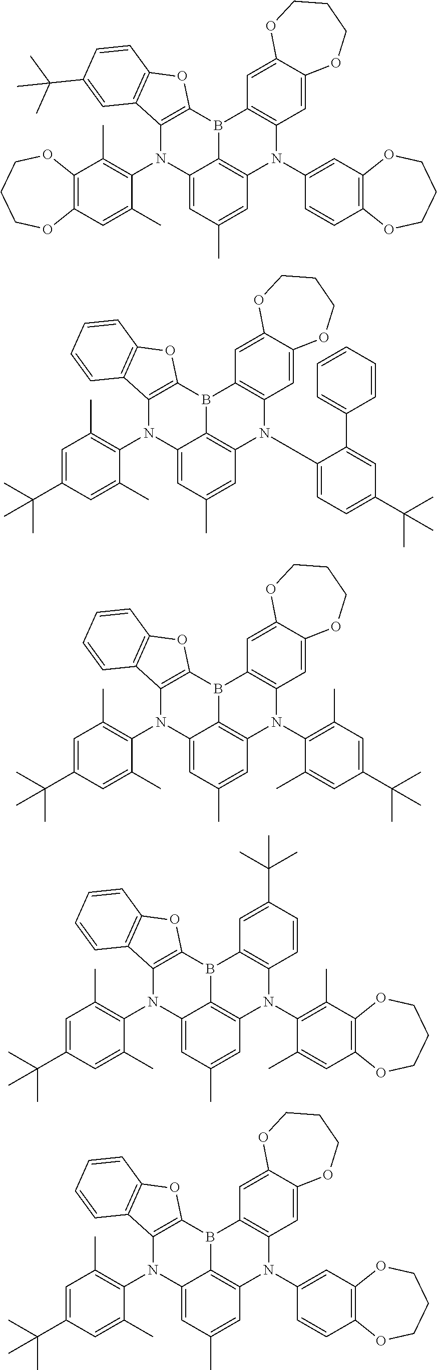

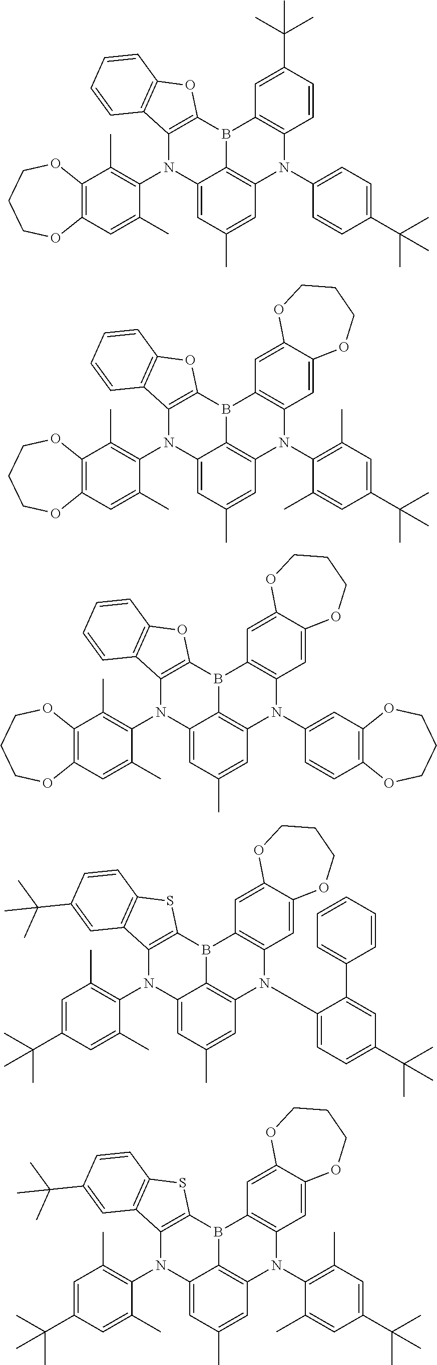

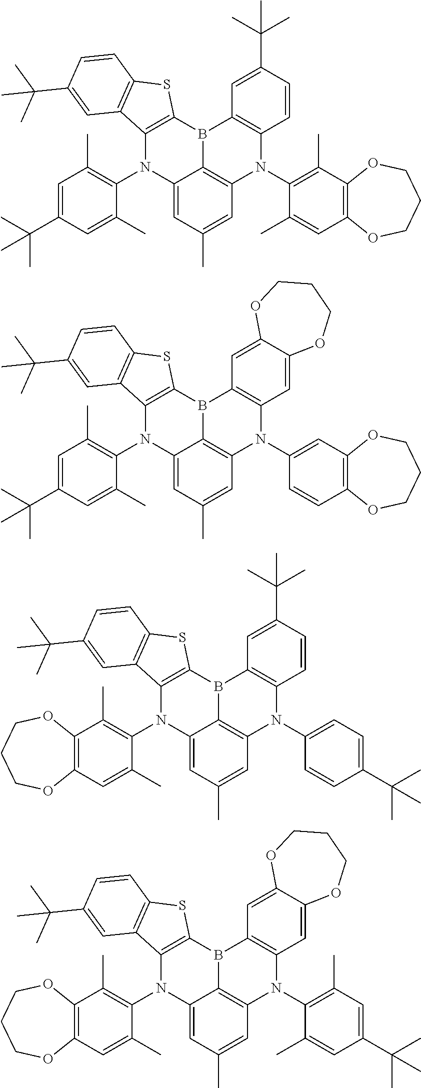 [SMILES: Cc1cc2c3c(c1)N(c1c(C)cc(C(C)(C)C)cc1C)c1c(sc4ccc(C(C)(C)C)cc14)B3c1cc(C(C)(C)C)ccc1N2c1c(C)cc2c(c1C)OCCCO2 ; Cc1cc2c3c(c1)N(c1c(C)cc(C(C)(C)C)cc1C)c1c(sc4ccc(C(C)(C)C)cc14)B3c1cc3c(cc1N2c1ccc2c(c1)OCCCO2)OCCCO3 ; Cc1cc2c3c(c1)N(c1c(C)cc4c(c1C)OCCCO4)c1c(sc4ccc(C(C)(C)C)cc14)B3c1cc(C(C)(C)C)ccc1N2c1ccc(C(C)(C)C)cc1 ; Cc1cc2c3c(c1)N(c1c(C)cc4c(c1C)OCCCO4)c1c(sc4ccc(C(C)(C)C)cc14)B3c1cc3c(cc1N2c1c(C)cc(C(C)(C)C)cc1C)OCCCO3]

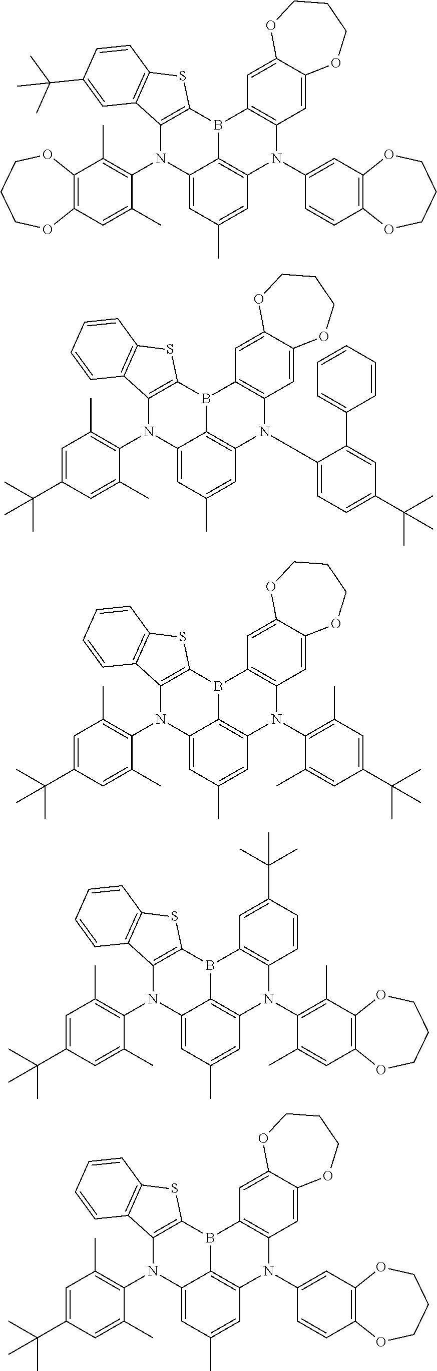

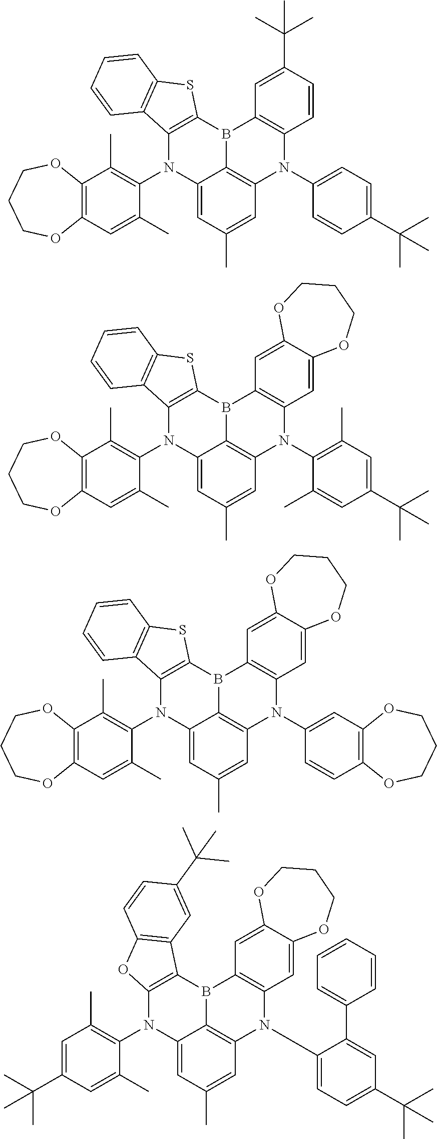

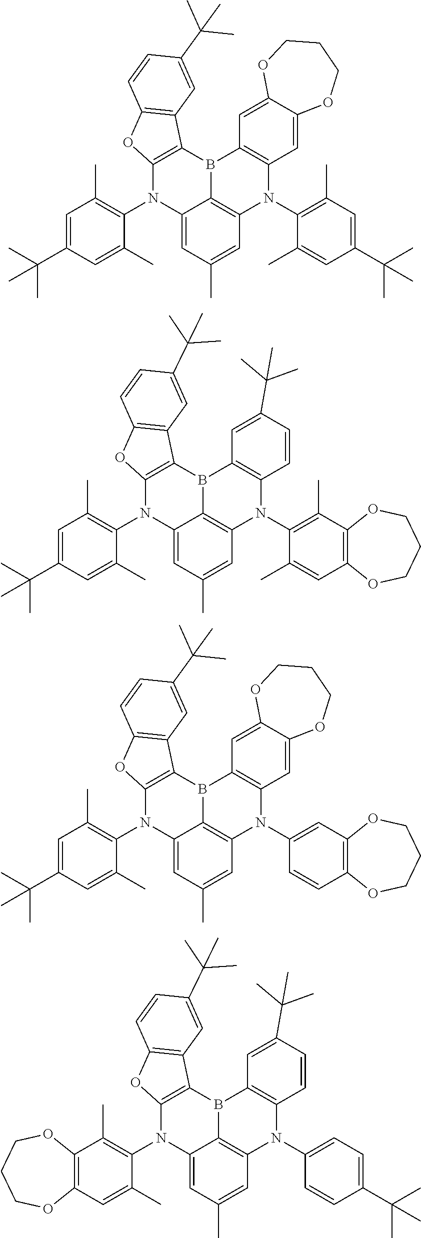

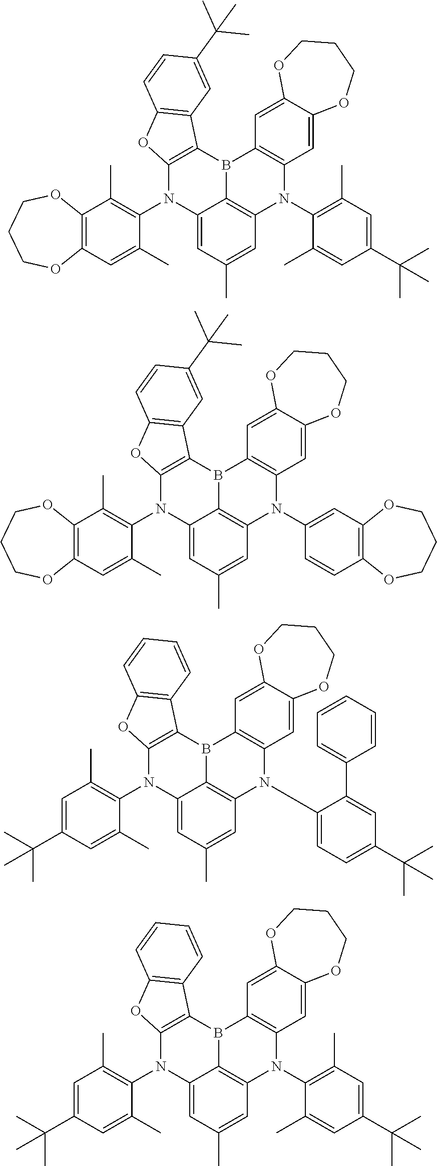

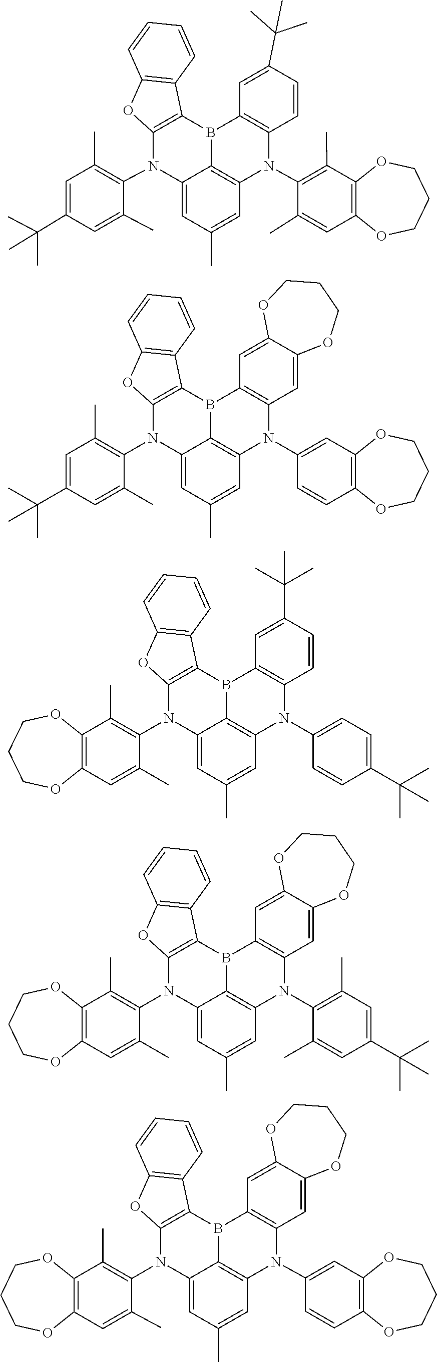

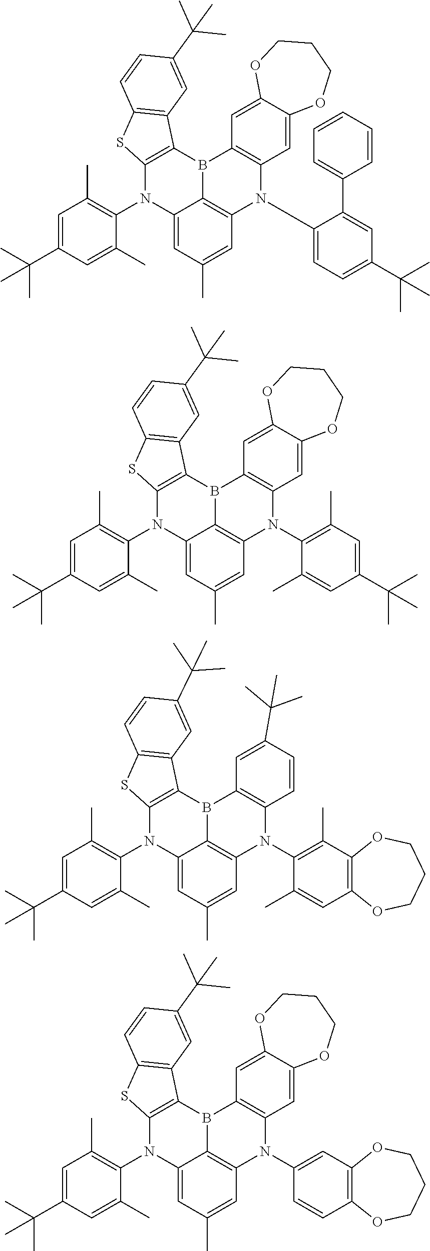

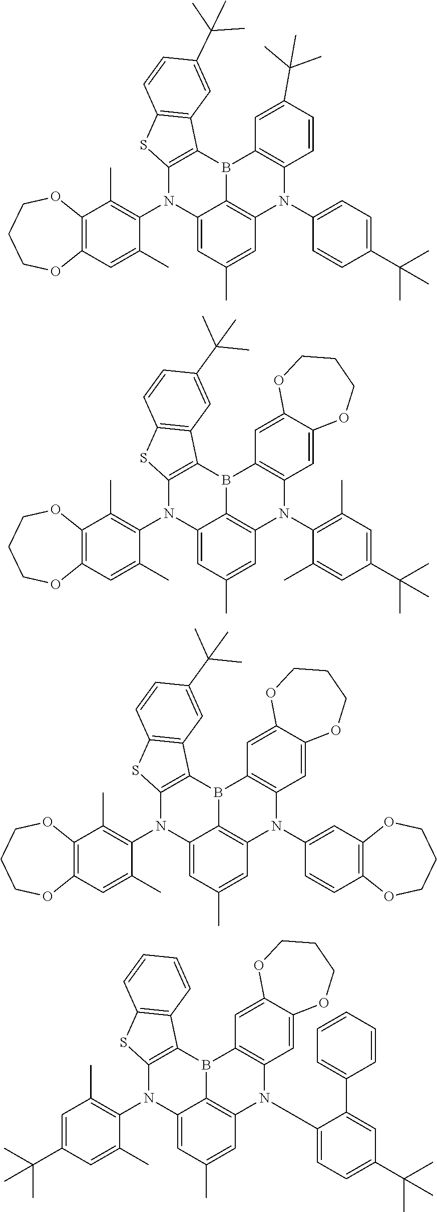

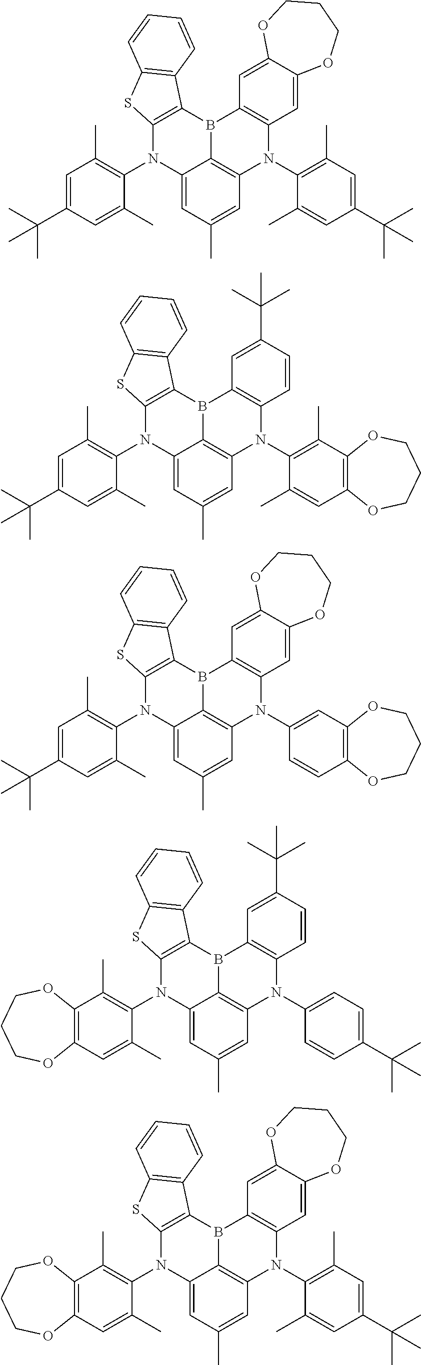

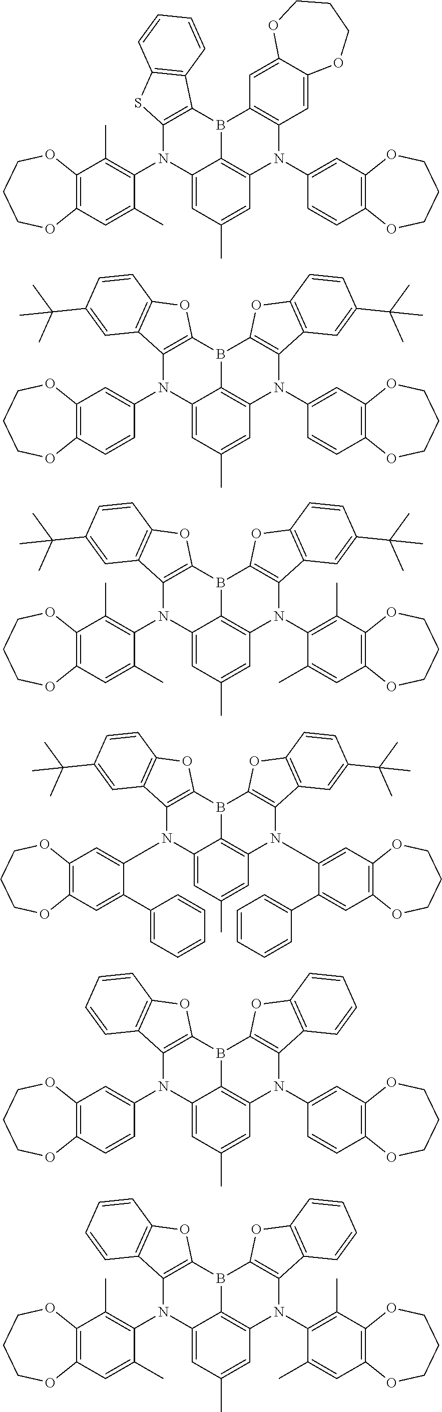

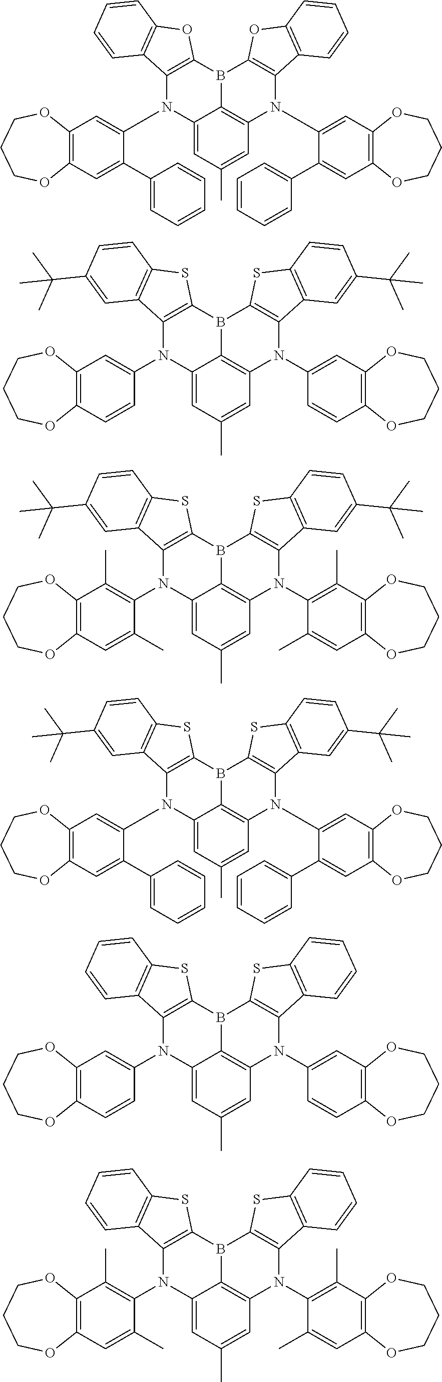

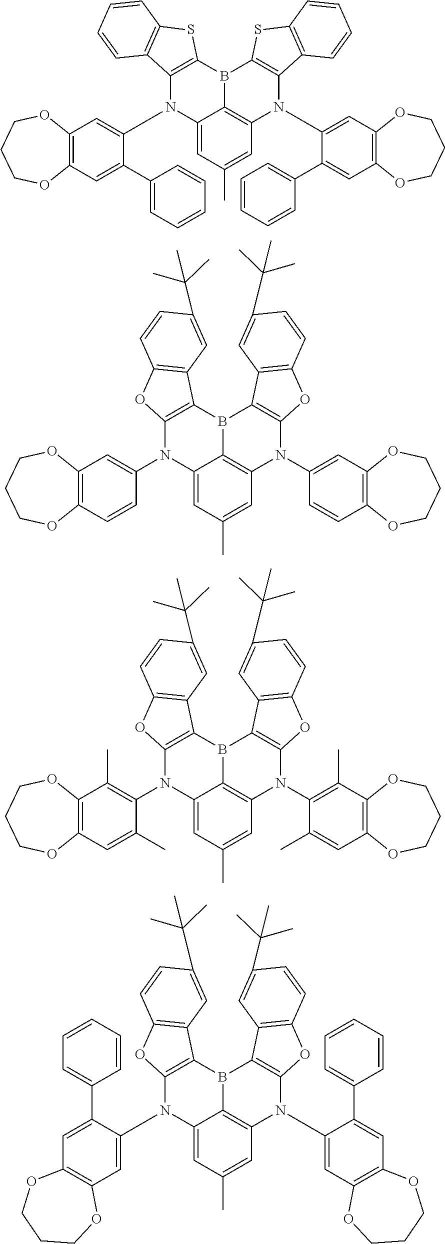

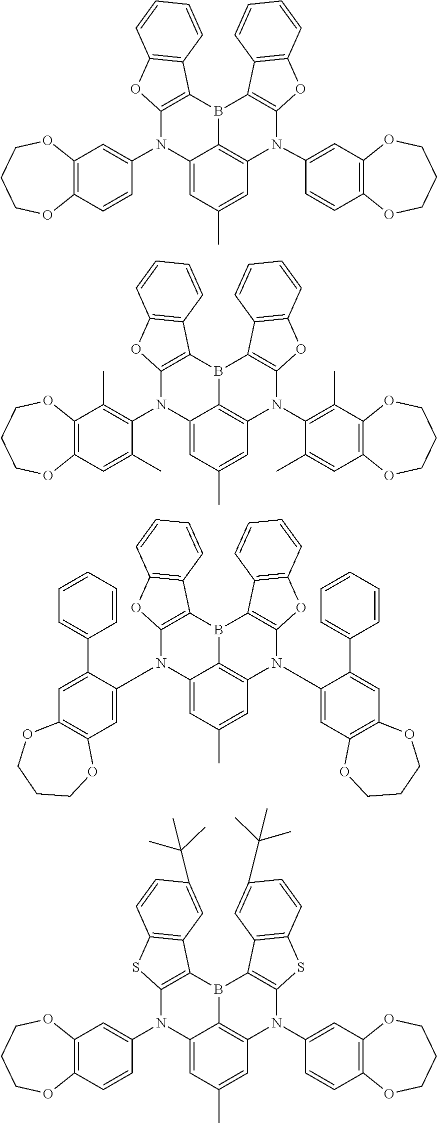

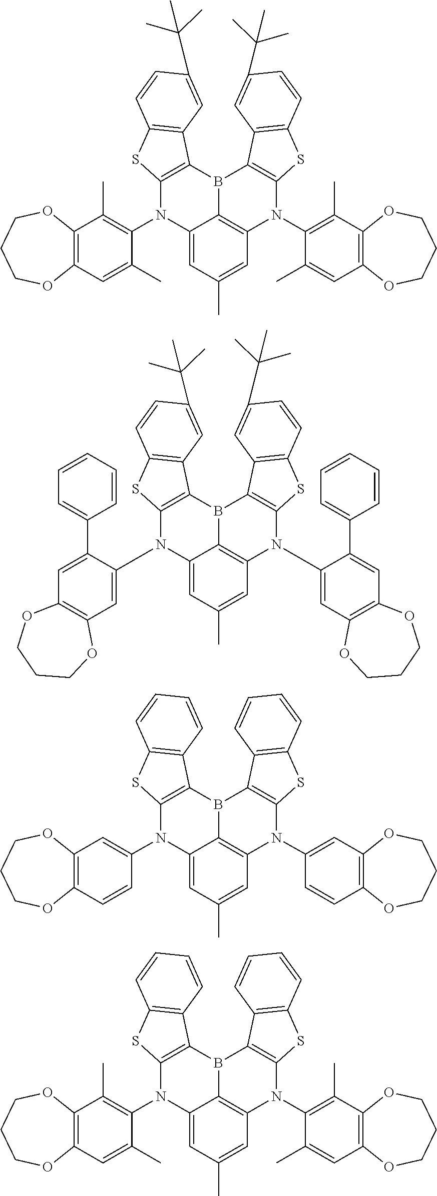

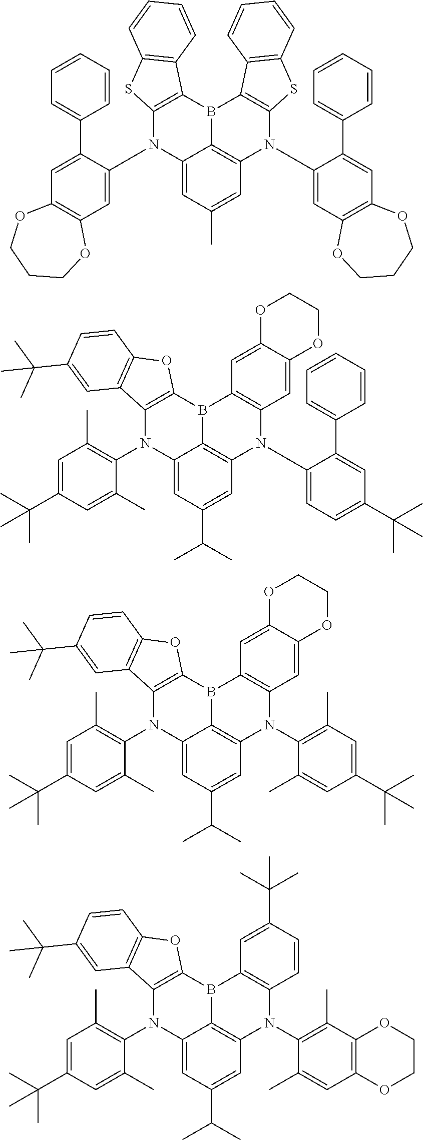

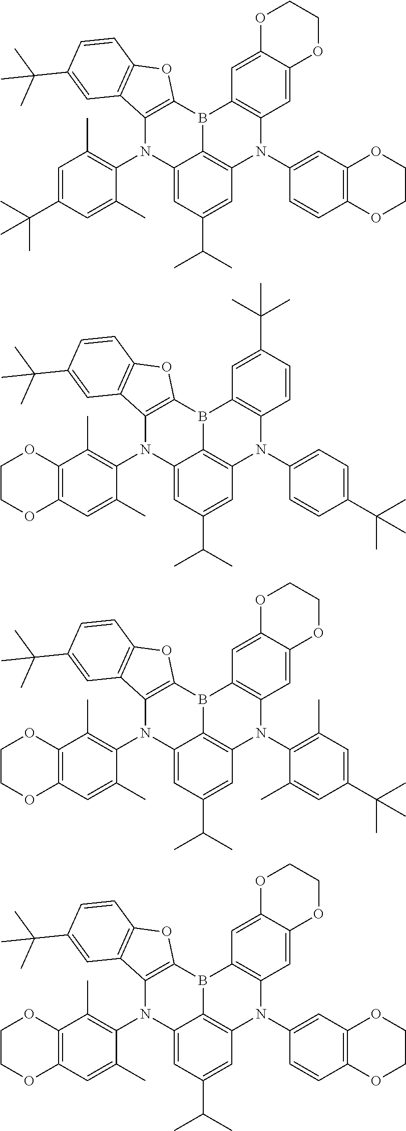

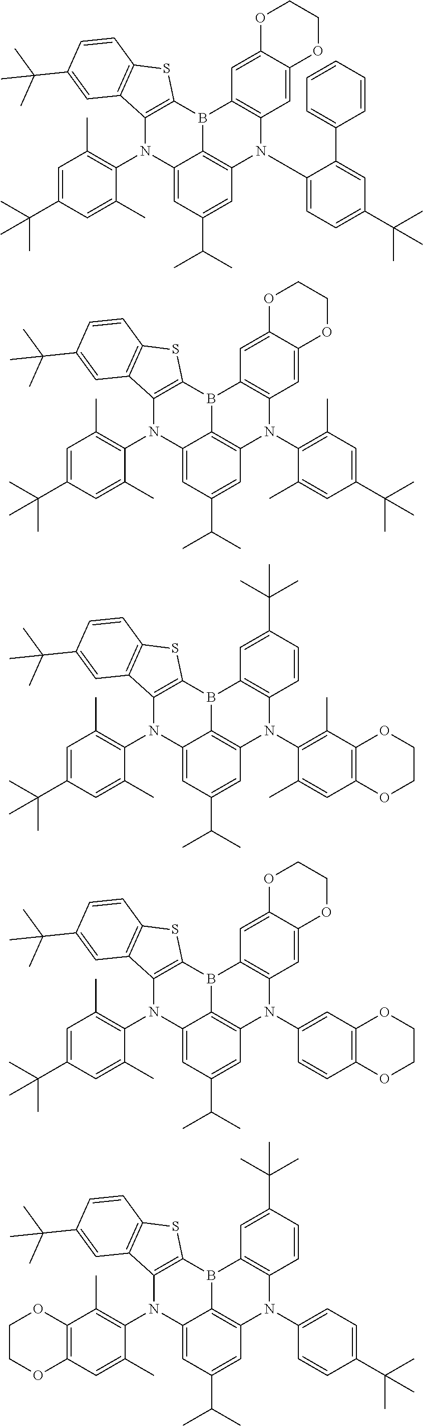

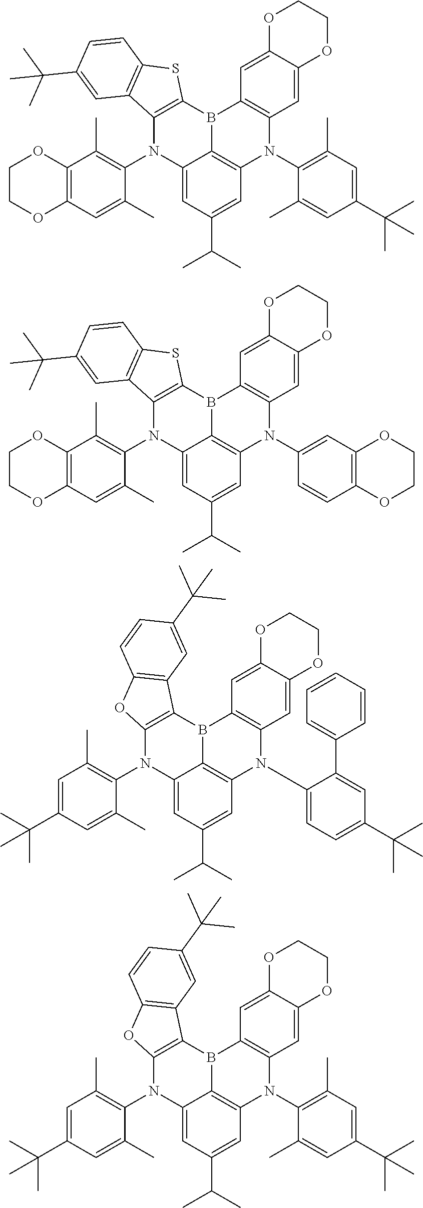

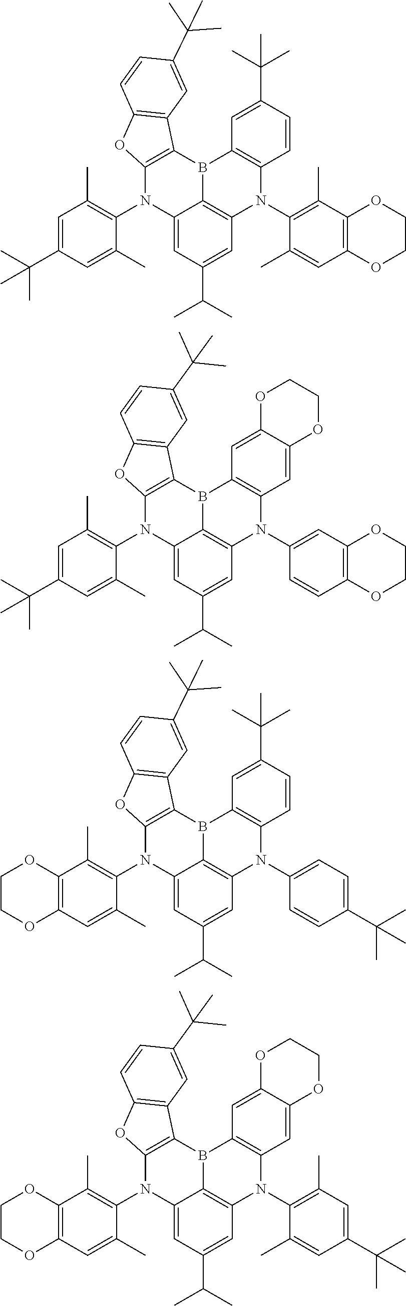

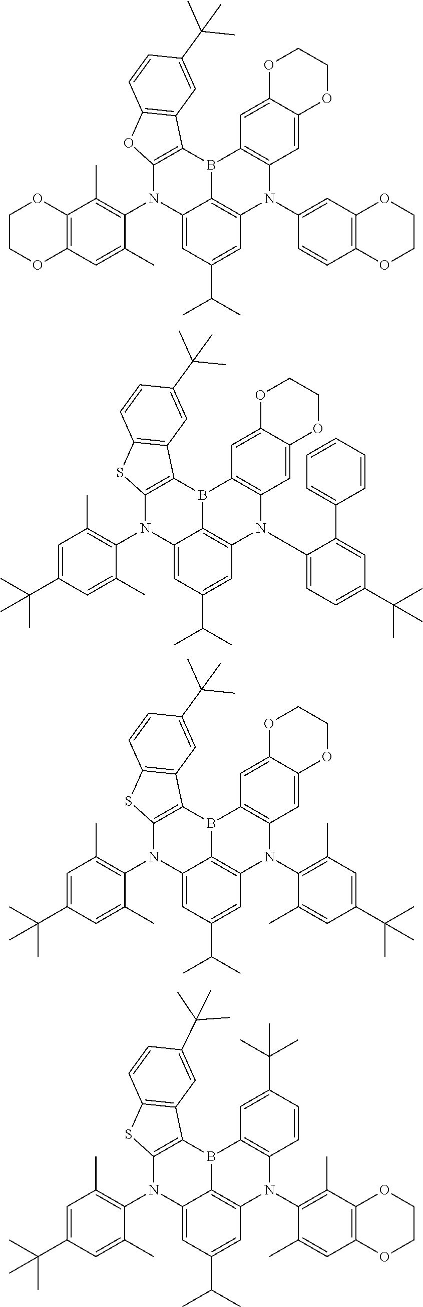

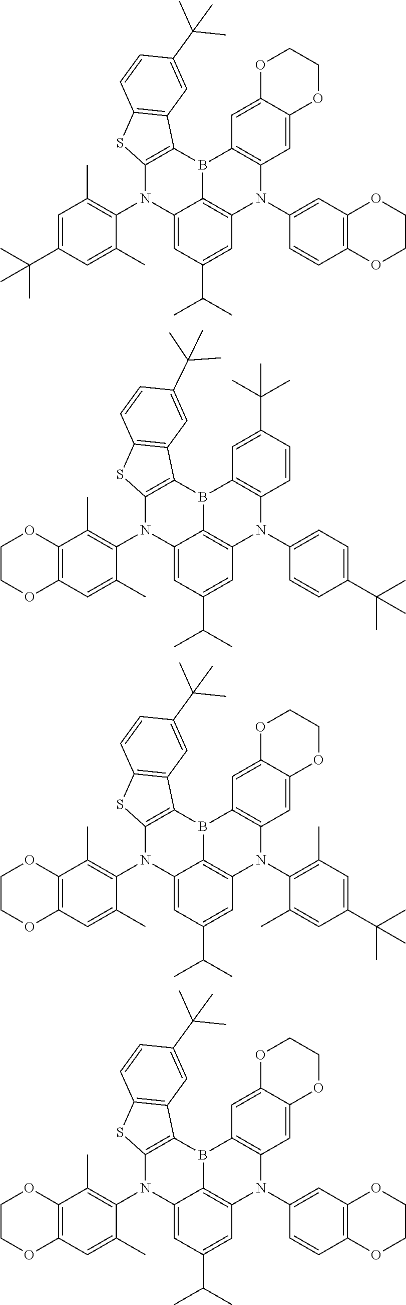

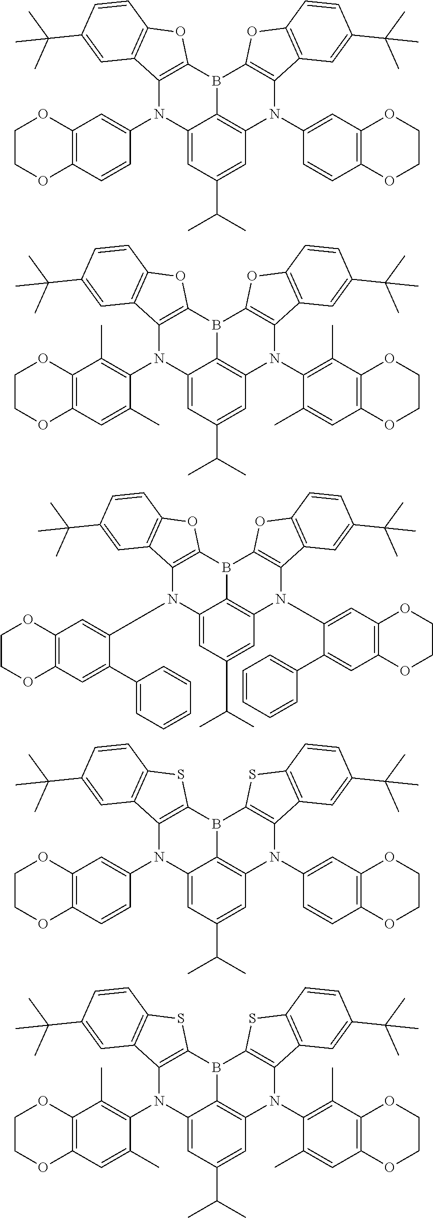

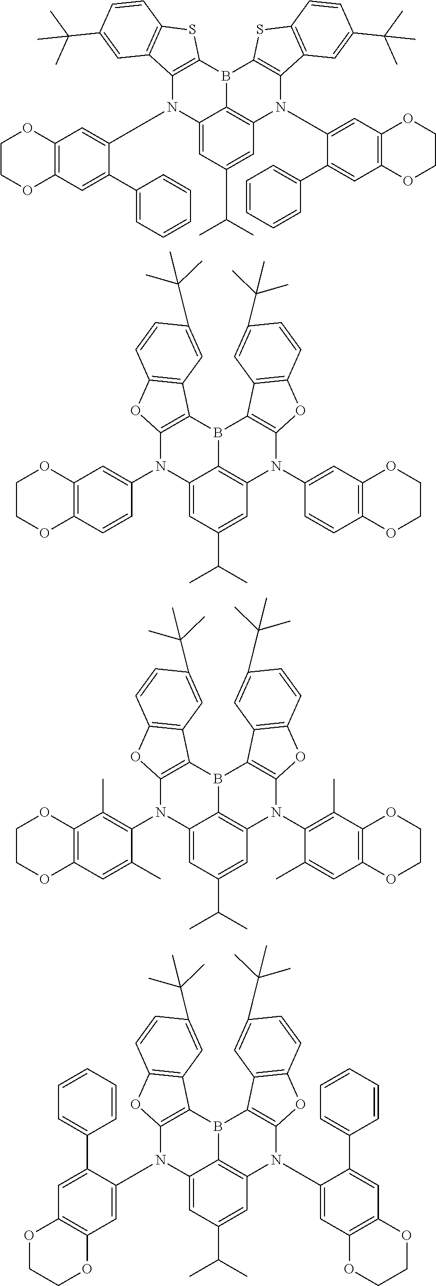

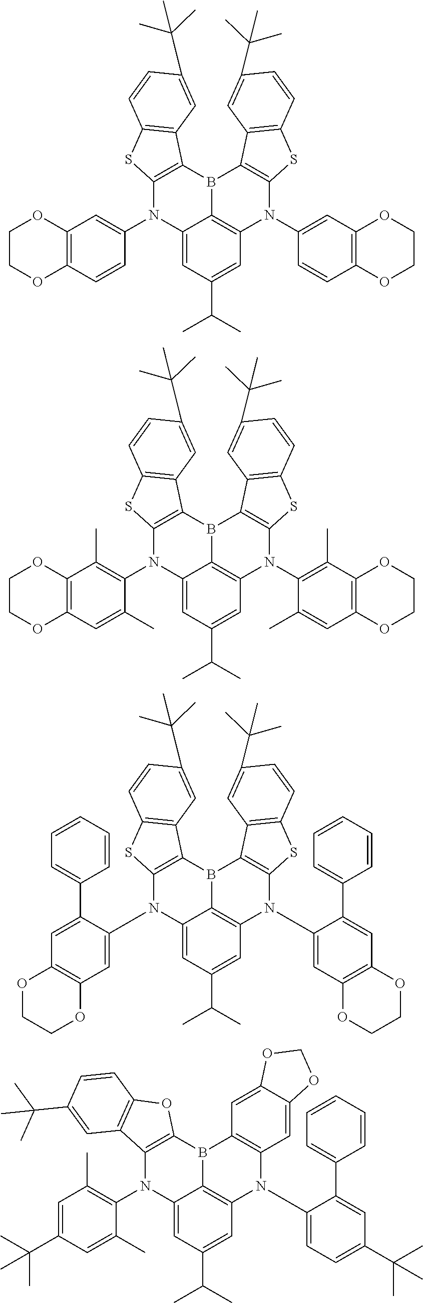

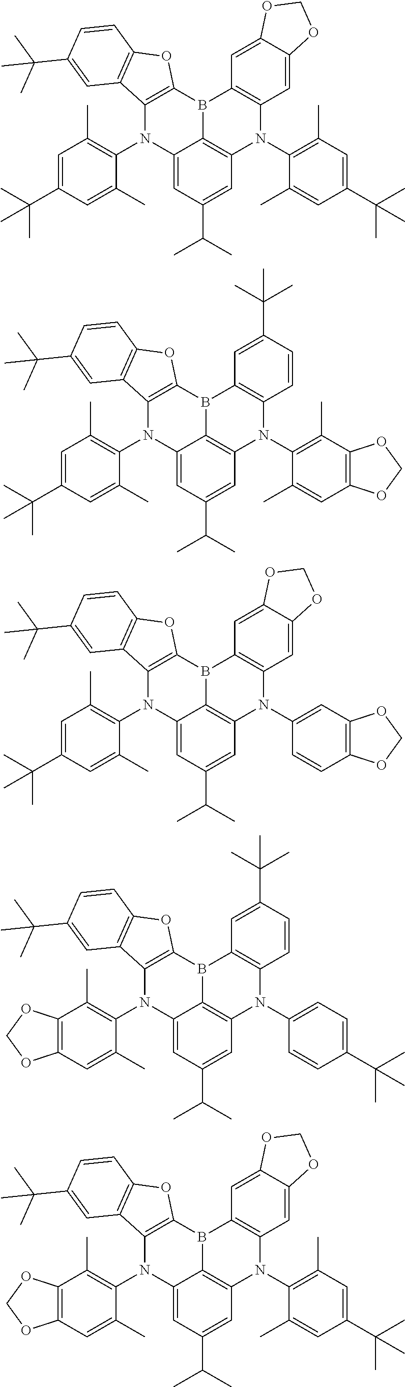

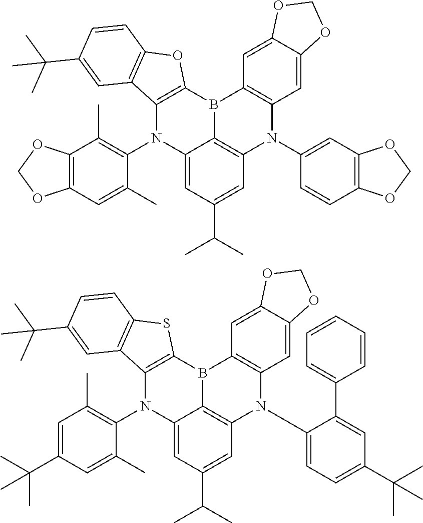

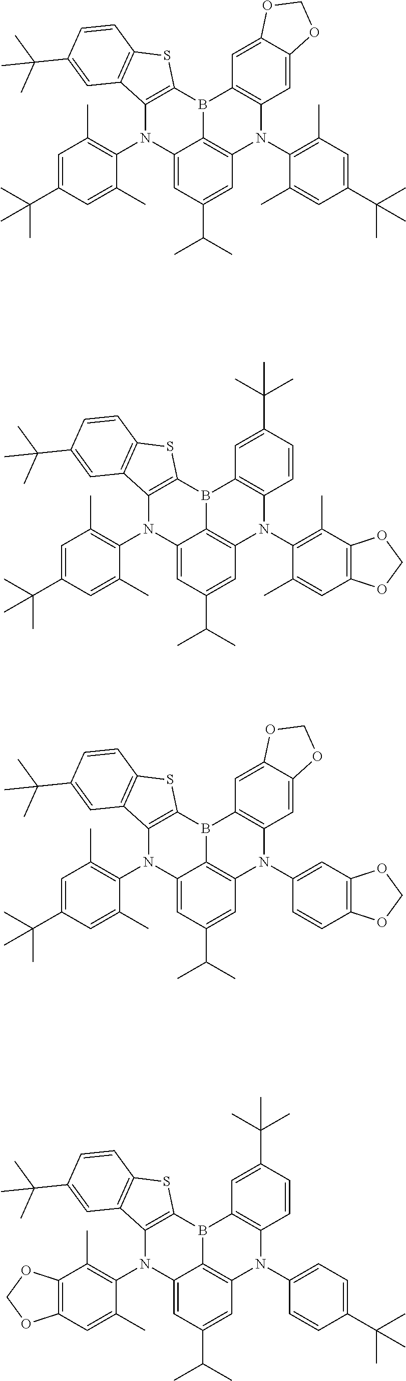

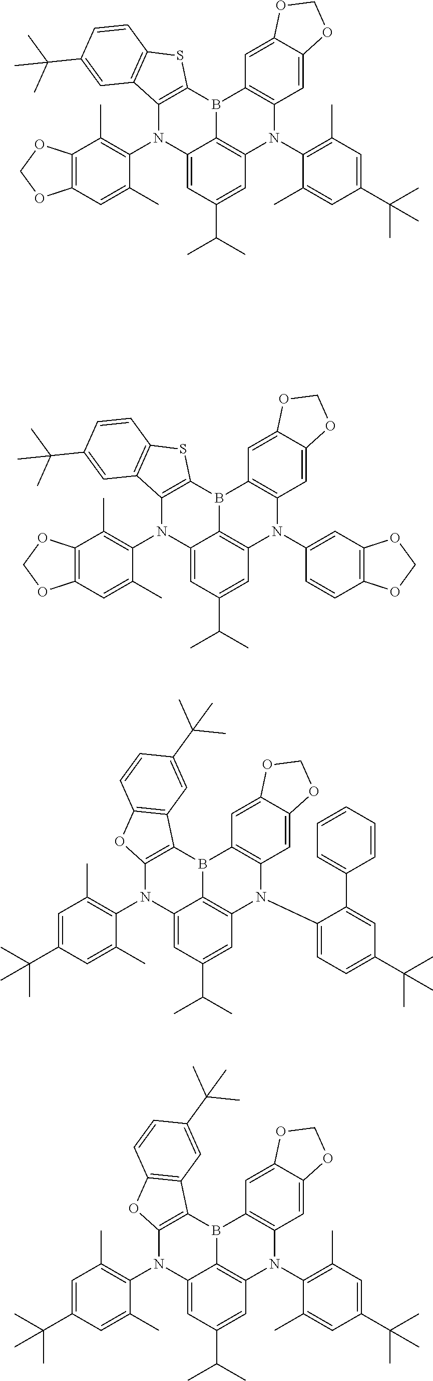

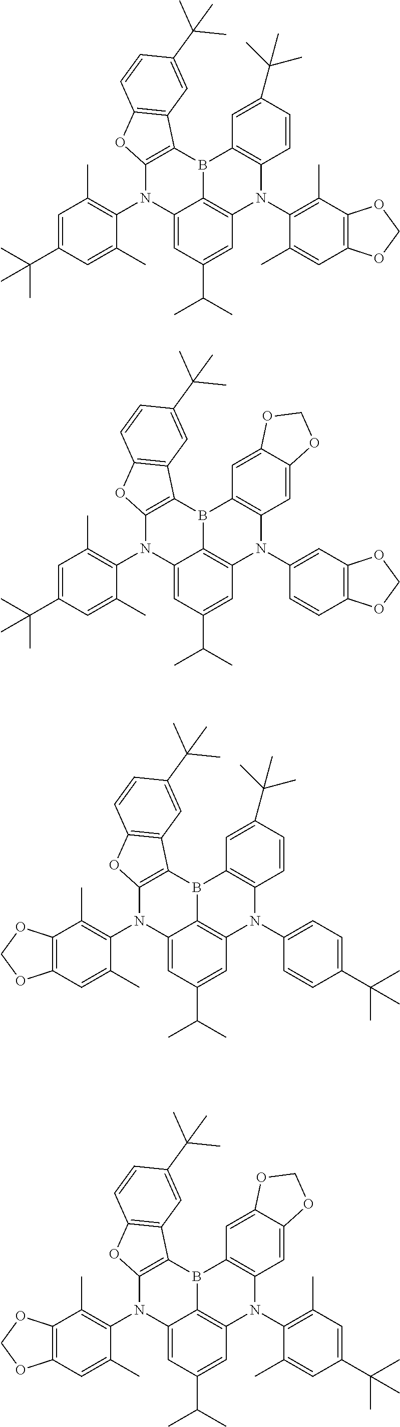

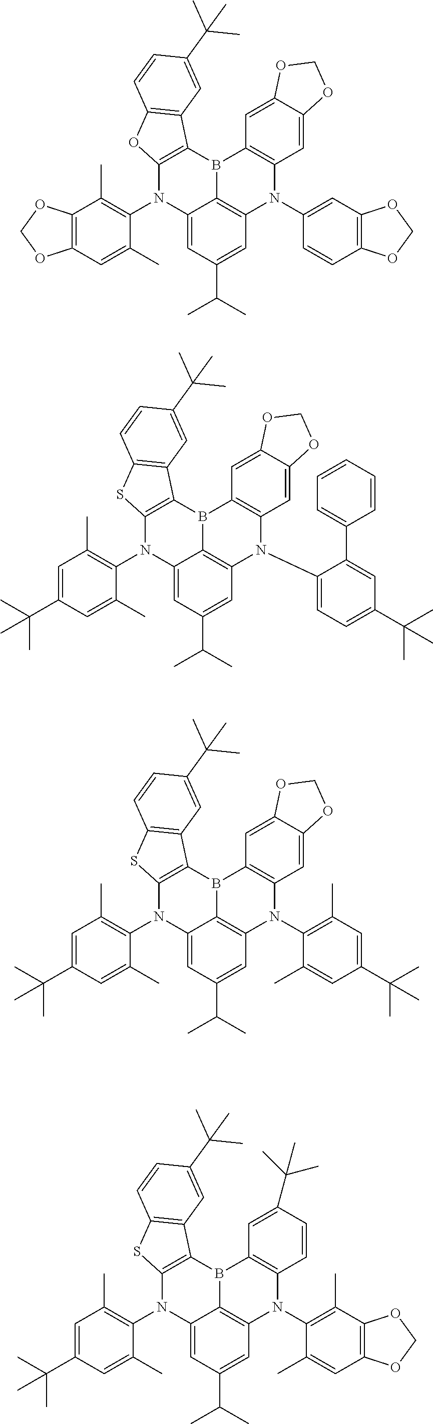

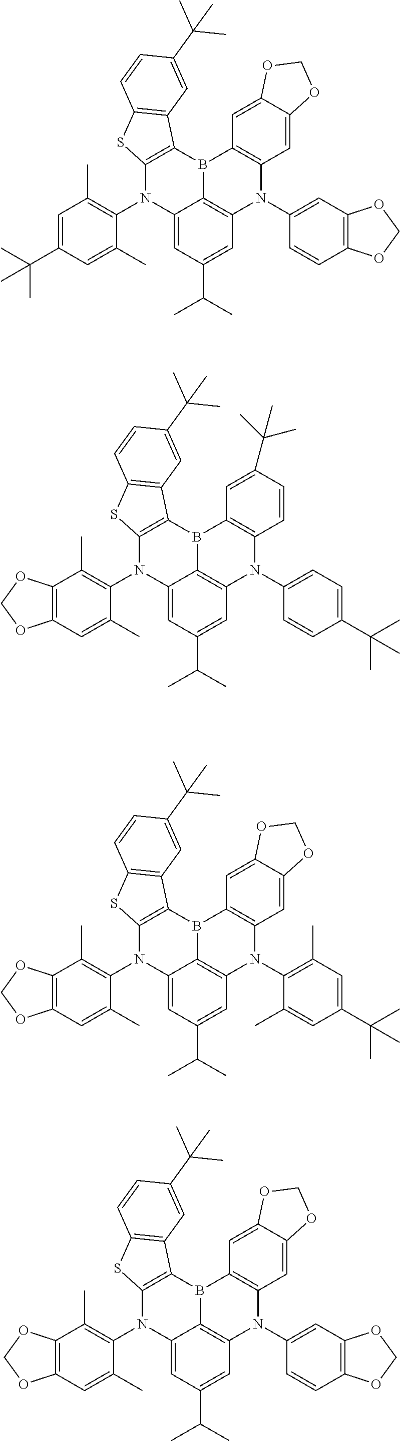 [SMILES: Cc1cc(C(C)(C)C)cc(C)c1N1c2cc(C(C)C)cc3c2B(c2cc4c(cc2N3c2ccc3c(c2)OCO3)OCO4)c2c1sc1ccc(C(C)(C)C)cc21 ; Cc1cc2c(c(C)c1N1c3cc(C(C)C)cc4c3B(c3cc(C(C)(C)C)ccc3N4c3ccc(C(C)(C)C)cc3)c3c1sc1ccc(C(C)(C)C)cc31)OCO2 ; Cc1cc(C(C)(C)C)cc(C)c1N1c2cc3c(cc2B2c4c1cc(C(C)C)cc4N(c1c(C)cc4c(c1C)OCO4)c1sc4ccc(C(C)(C)C)cc4c12)OCO3 ; Cc1cc2c(c(C)c1N1c3cc(C(C)C)cc4c3B(c3cc5c(cc3N4c3ccc4c(c3)OCO4)OCO5)c3c1sc1ccc(C(C)(C)C)cc31)OCO2]

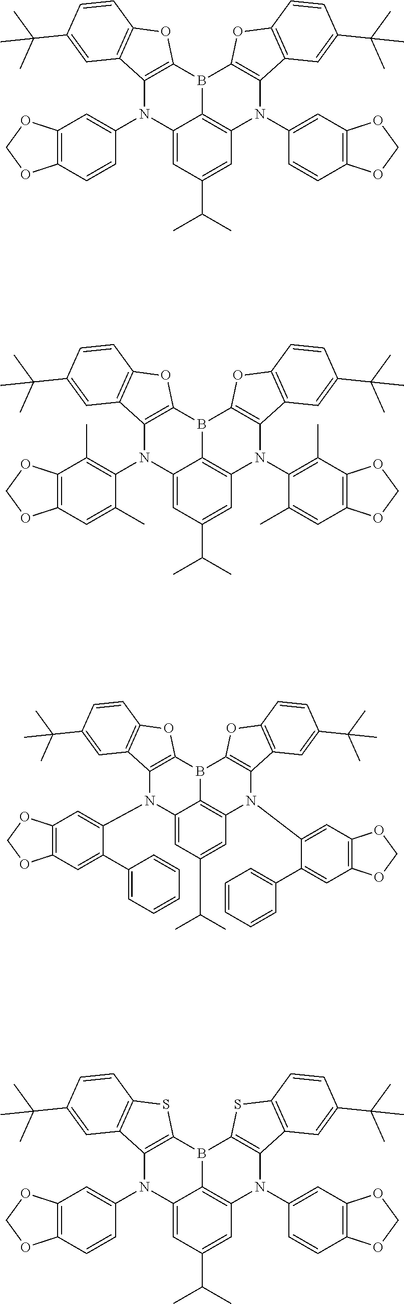

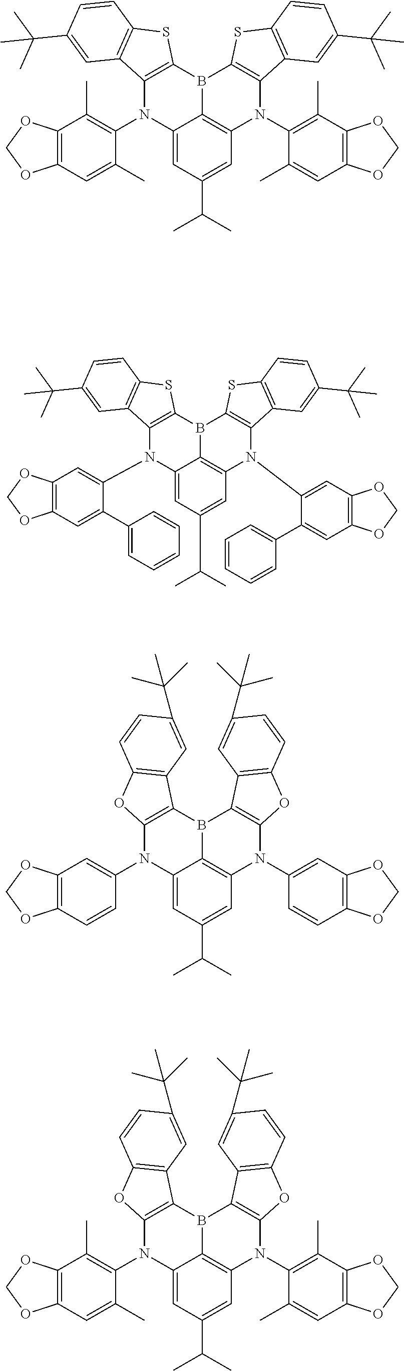 [SMILES: Cc1cc2c(c(C)c1N1c3cc(C(C)C)cc4c3B(c3sc5ccc(C(C)(C)C)cc5c31)c1sc3ccc(C(C)(C)C)cc3c1N4c1c(C)cc3c(c1C)OCO3)OCO2 ; CC(C)c1cc2c3c(c1)N(c1cc4c(cc1-c1ccccc1)OCO4)c1c(sc4ccc(C(C)(C)C)cc14)B3c1sc3ccc(C(C)(C)C)cc3c1N2c1cc2c(cc1-c1ccccc1)OCO2 ; CC(C)c1cc2c3c(c1)N(c1ccc4c(c1)OCO4)c1oc4ccc(C(C)(C)C)cc4c1B3c1c(oc3ccc(C(C)(C)C)cc13)N2c1ccc2c(c1)OCO2 ; Cc1cc2c(c(C)c1N1c3cc(C(C)C)cc4c3B(c3c1oc1ccc(C(C)(C)C)cc31)c1c(oc3ccc(C(C)(C)C)cc13)N4c1c(C)cc3c(c1C)OCO3)OCO2]

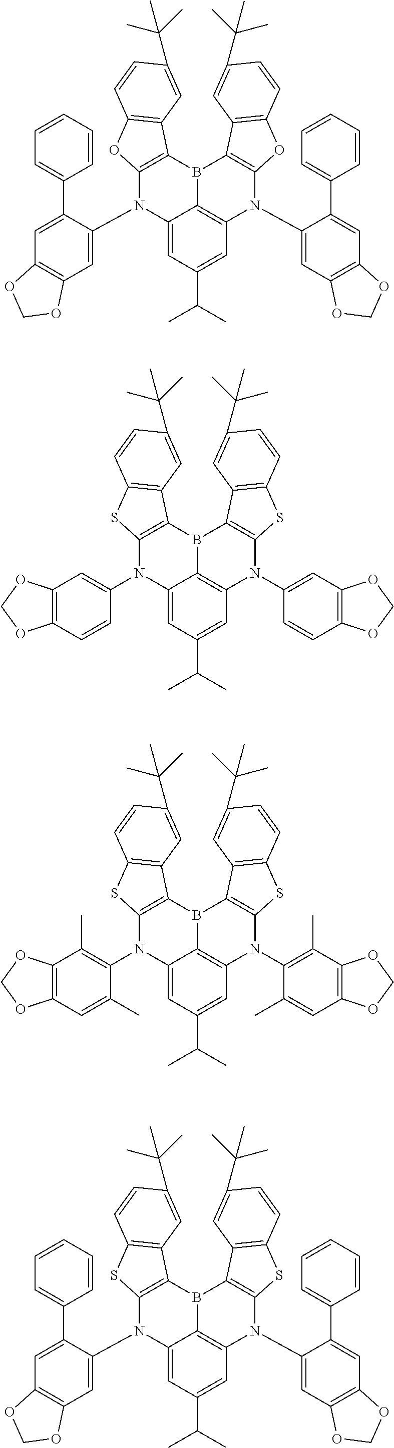 [SMILES: CC(C)c1cc2c3c(c1)N(c1cc4c(cc1-c1ccccc1)OCO4)c1oc4ccc(C(C)(C)C)cc4c1B3c1c(oc3ccc(C(C)(C)C)cc13)N2c1cc2c(cc1-c1ccccc1)OCO2 ; CC(C)c1cc2c3c(c1)N(c1ccc4c(c1)OCO4)c1sc4ccc(C(C)(C)C)cc4c1B3c1c(sc3ccc(C(C)(C)C)cc13)N2c1ccc2c(c1)OCO2 ; Cc1cc2c(c(C)c1N1c3cc(C(C)C)cc4c3B(c3c1sc1ccc(C(C)(C)C)cc31)c1c(sc3ccc(C(C)(C)C)cc13)N4c1c(C)cc3c(c1C)OCO3)OCO2 ; CC(C)c1cc2c3c(c1)N(c1cc4c(cc1-c1ccccc1)OCO4)c1sc4ccc(C(C)(C)C)cc4c1B3c1c(sc3ccc(C(C)(C)C)cc13)N2c1cc2c(cc1-c1ccccc1)OCO2]

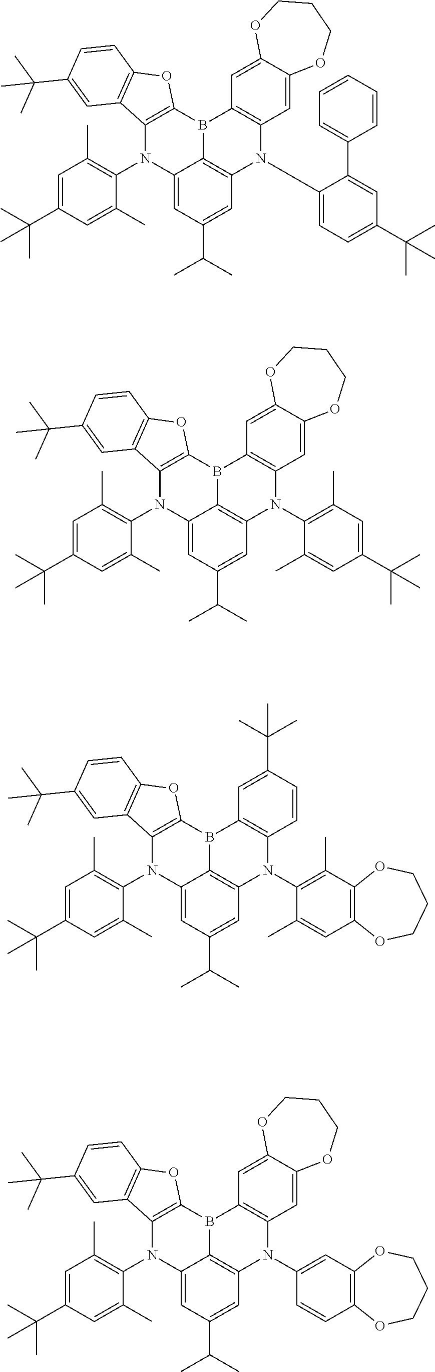

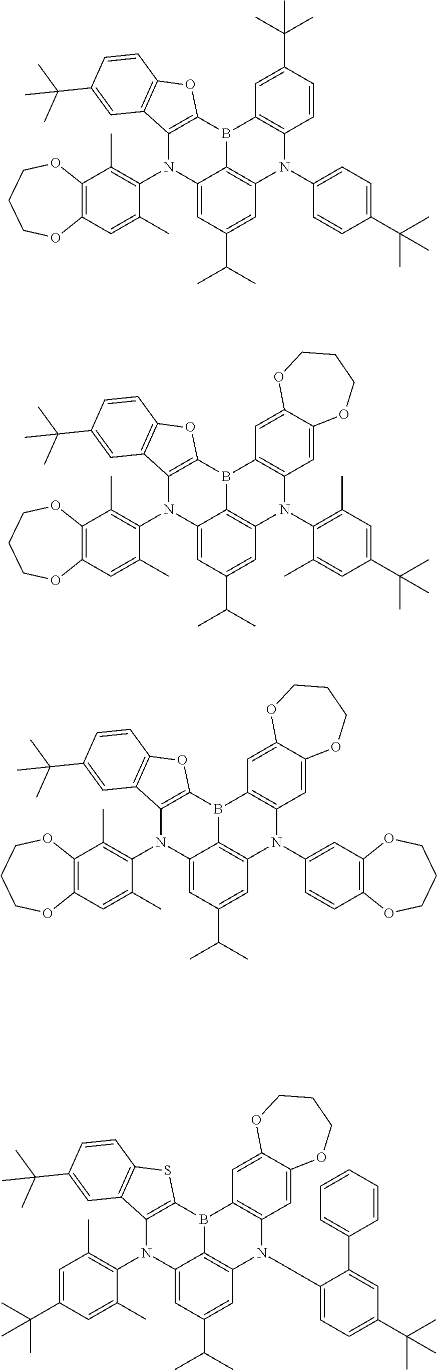

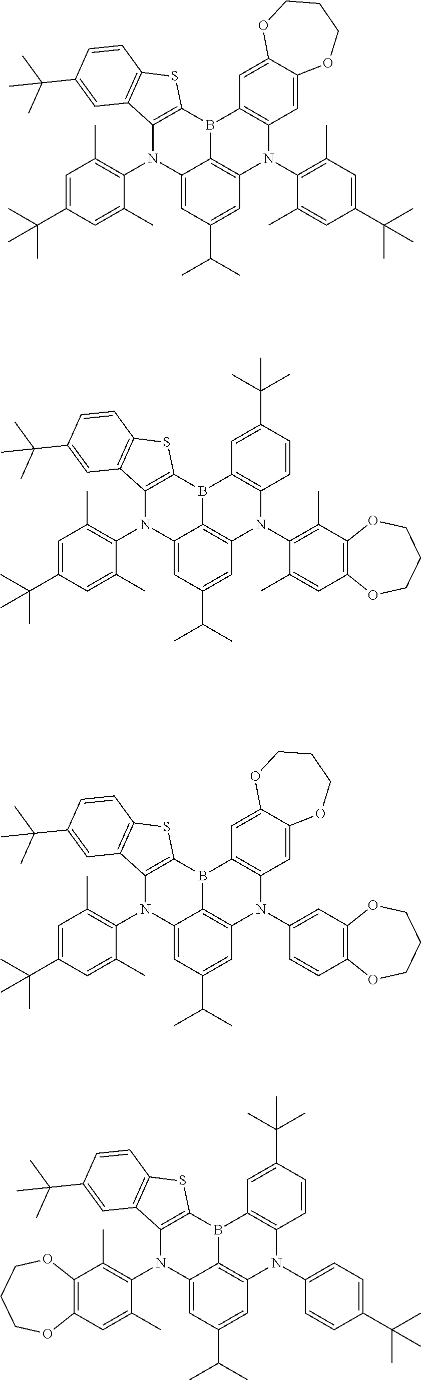

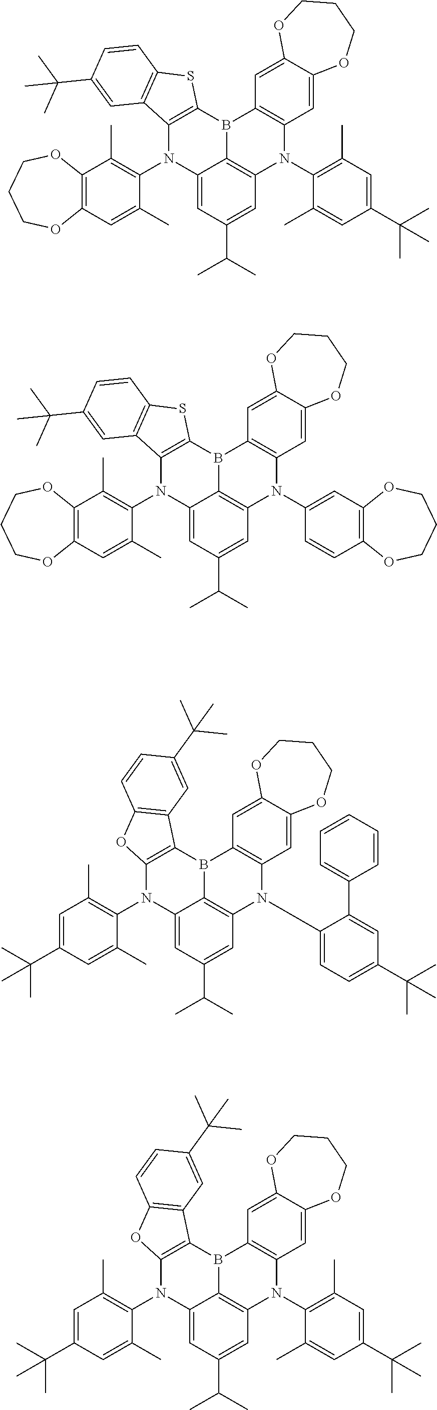

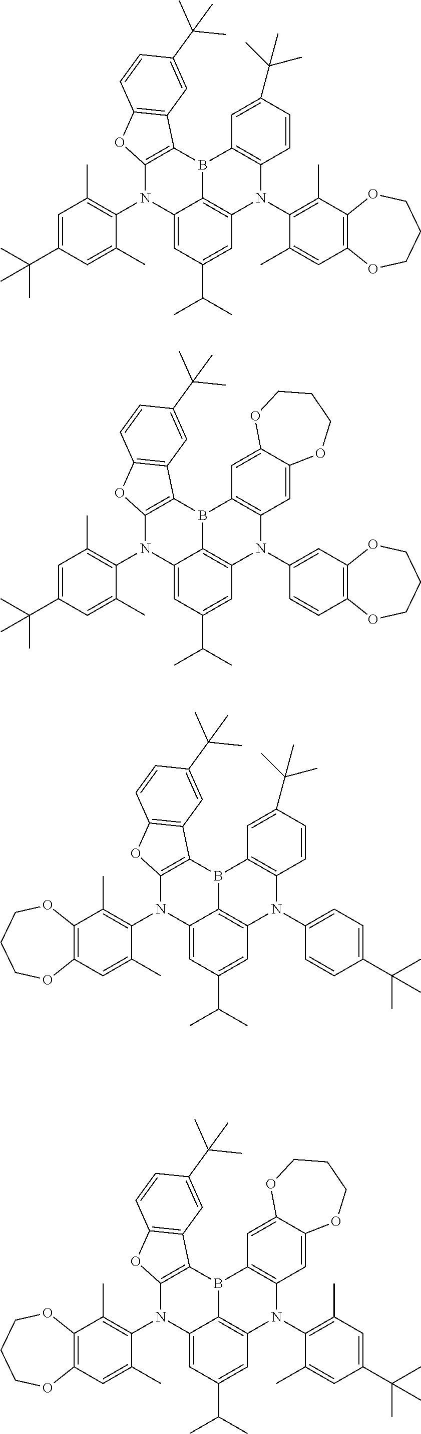

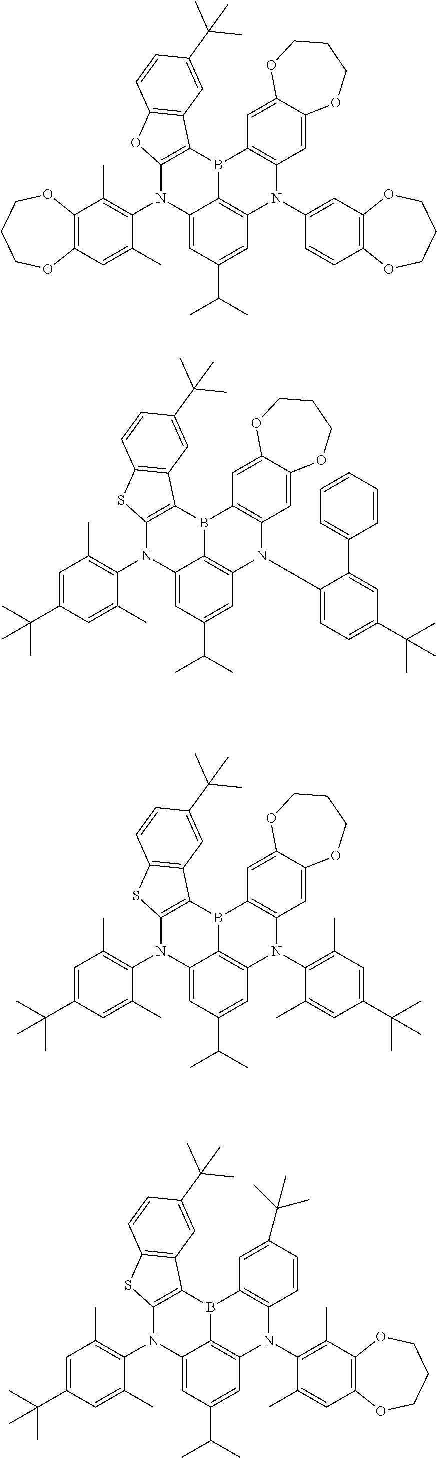

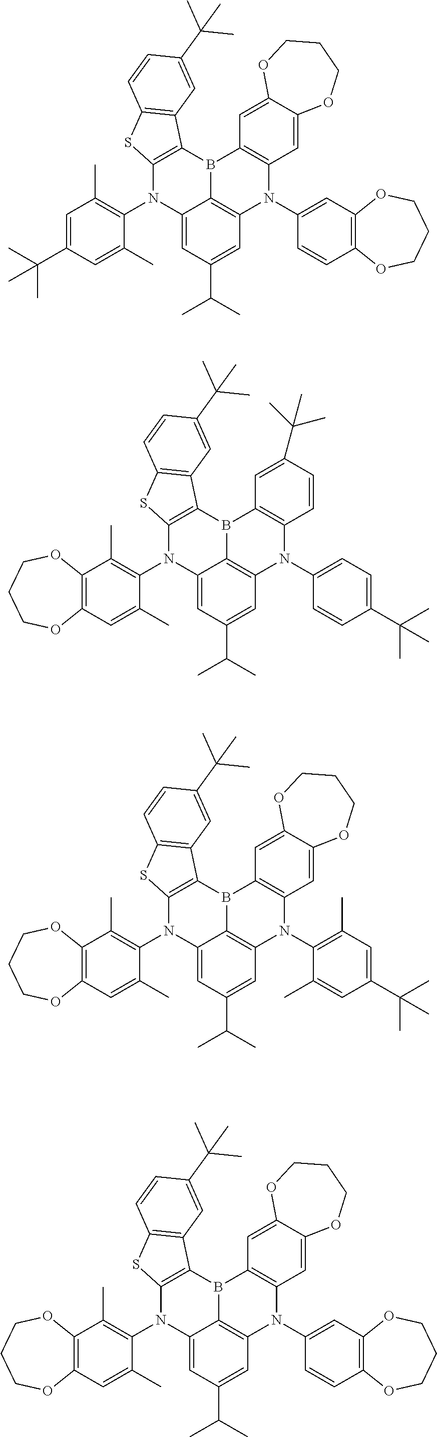 [SMILES: Cc1cc(C(C)(C)C)cc(C)c1N1c2cc(C(C)C)cc3c2B(c2cc4c(cc2N3c2ccc3c(c2)OCCCO3)OCCCO4)c2c1sc1ccc(C(C)(C)C)cc21 ; Cc1cc2c(c(C)c1N1c3cc(C(C)C)cc4c3B(c3cc(C(C)(C)C)ccc3N4c3ccc(C(C)(C)C)cc3)c3c1sc1ccc(C(C)(C)C)cc31)OCCCO2 ; Cc1cc(C(C)(C)C)cc(C)c1N1c2cc3c(cc2B2c4c1cc(C(C)C)cc4N(c1c(C)cc4c(c1C)OCCCO4)c1sc4ccc(C(C)(C)C)cc4c12)OCCCO3 ; Cc1cc2c(c(C)c1N1c3cc(C(C)C)cc4c3B(c3cc5c(cc3N4c3ccc4c(c3)OCCCO4)OCCCO5)c3c1sc1ccc(C(C)(C)C)cc31)OCCCO2]

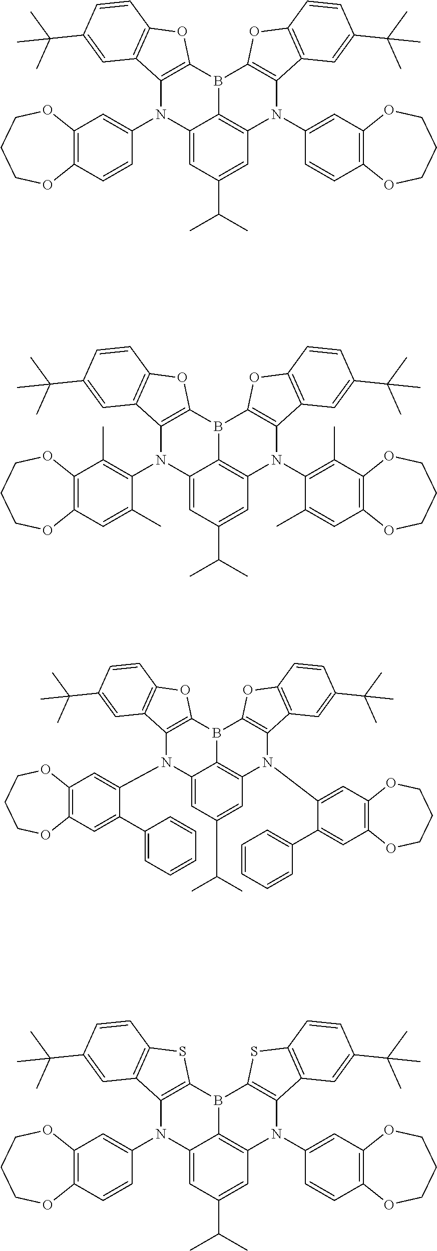 [SMILES: CC(C)c1cc2c3c(c1)N(c1ccc4c(c1)OCCCO4)c1c(oc4ccc(C(C)(C)C)cc14)B3c1oc3ccc(C(C)(C)C)cc3c1N2c1ccc2c(c1)OCCCO2 ; Cc1cc2c(c(C)c1N1c3cc(C(C)C)cc4c3B(c3oc5ccc(C(C)(C)C)cc5c31)c1oc3ccc(C(C)(C)C)cc3c1N4c1c(C)cc3c(c1C)OCCCO3)OCCCO2 ; CC(C)c1cc2c3c(c1)N(c1cc4c(cc1-c1ccccc1)OCCCO4)c1c(oc4ccc(C(C)(C)C)cc14)B3c1oc3ccc(C(C)(C)C)cc3c1N2c1cc2c(cc1-c1ccccc1)OCCCO2 ; CC(C)c1cc2c3c(c1)N(c1ccc4c(c1)OCCCO4)c1c(sc4ccc(C(C)(C)C)cc14)B3c1sc3ccc(C(C)(C)C)cc3c1N2c1ccc2c(c1)OCCCO2]

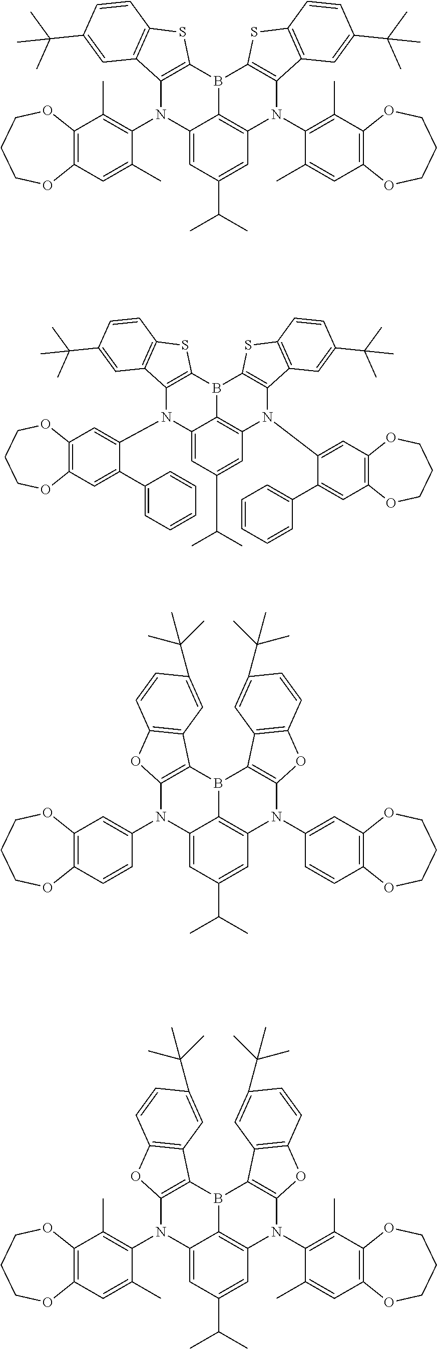 [SMILES: Cc1cc2c(c(C)c1N1c3cc(C(C)C)cc4c3B(c3sc5ccc(C(C)(C)C)cc5c31)c1sc3ccc(C(C)(C)C)cc3c1N4c1c(C)cc3c(c1C)OCCCO3)OCCCO2 ; CC(C)c1cc2c3c(c1)N(c1cc4c(cc1-c1ccccc1)OCCCO4)c1c(sc4ccc(C(C)(C)C)cc14)B3c1sc3ccc(C(C)(C)C)cc3c1N2c1cc2c(cc1-c1ccccc1)OCCCO2 ; CC(C)c1cc2c3c(c1)N(c1ccc4c(c1)OCCCO4)c1oc4ccc(C(C)(C)C)cc4c1B3c1c(oc3ccc(C(C)(C)C)cc13)N2c1ccc2c(c1)OCCCO2 ; Cc1cc2c(c(C)c1N1c3cc(C(C)C)cc4c3B(c3c1oc1ccc(C(C)(C)C)cc31)c1c(oc3ccc(C(C)(C)C)cc13)N4c1c(C)cc3c(c1C)OCCCO3)OCCCO2]

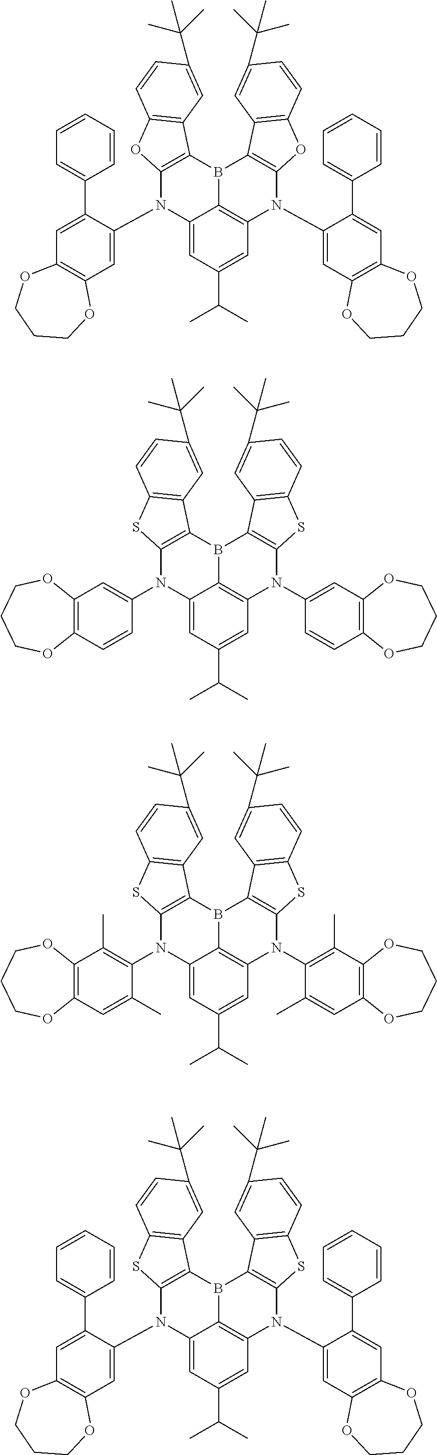 [SMILES: CC(C)c1cc2c3c(c1)N(c1cc4c(cc1-c1ccccc1)OCCCO4)c1oc4ccc(C(C)(C)C)cc4c1B3c1c(oc3ccc(C(C)(C)C)cc13)N2c1cc2c(cc1-c1ccccc1)OCCCO2 ; CC(C)c1cc2c3c(c1)N(c1ccc4c(c1)OCCCO4)c1sc4ccc(C(C)(C)C)cc4c1B3c1c(sc3ccc(C(C)(C)C)cc13)N2c1ccc2c(c1)OCCCO2 ; Cc1cc2c(c(C)c1N1c3cc(C(C)C)cc4c3B(c3c1sc1ccc(C(C)(C)C)cc31)c1c(sc3ccc(C(C)(C)C)cc13)N4c1c(C)cc3c(c1C)OCCCO3)OCCCO2 ; CC(C)c1cc2c3c(c1)N(c1cc4c(cc1-c1ccccc1)OCCCO4)c1sc4ccc(C(C)(C)C)cc4c1B3c1c(sc3ccc(C(C)(C)C)cc13)N2c1cc2c(cc1-c1ccccc1)OCCCO2]

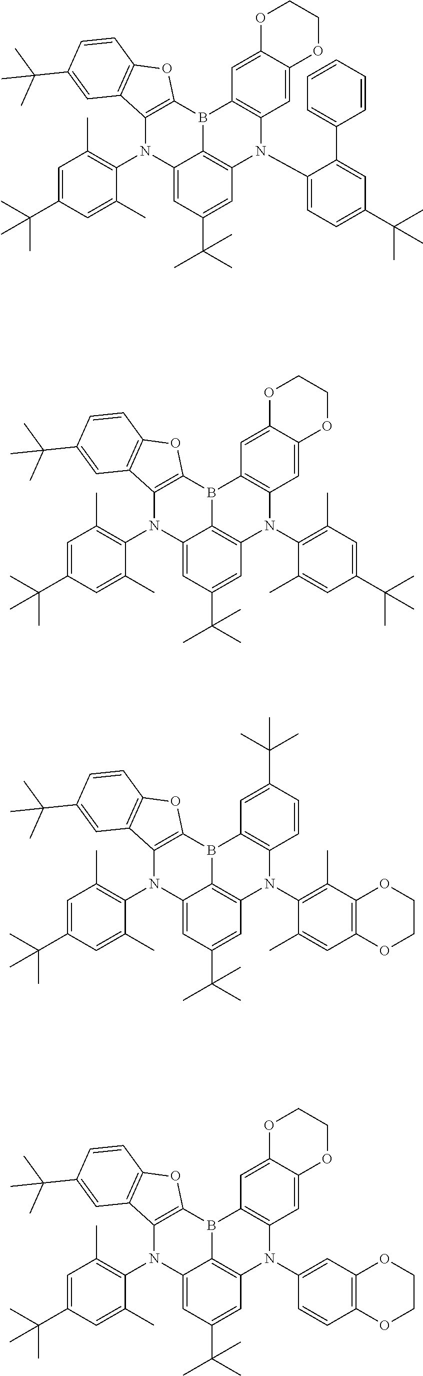

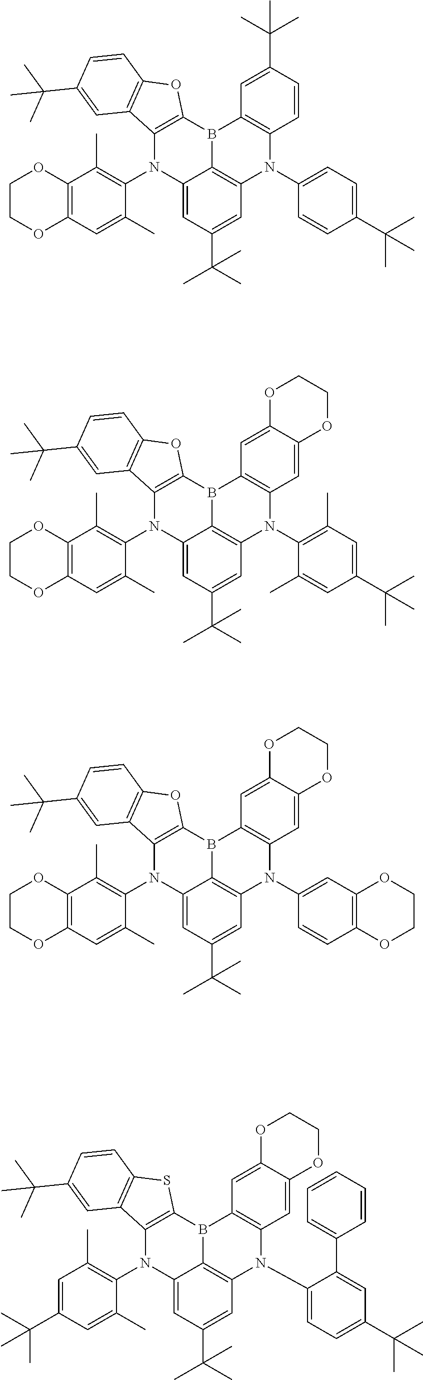

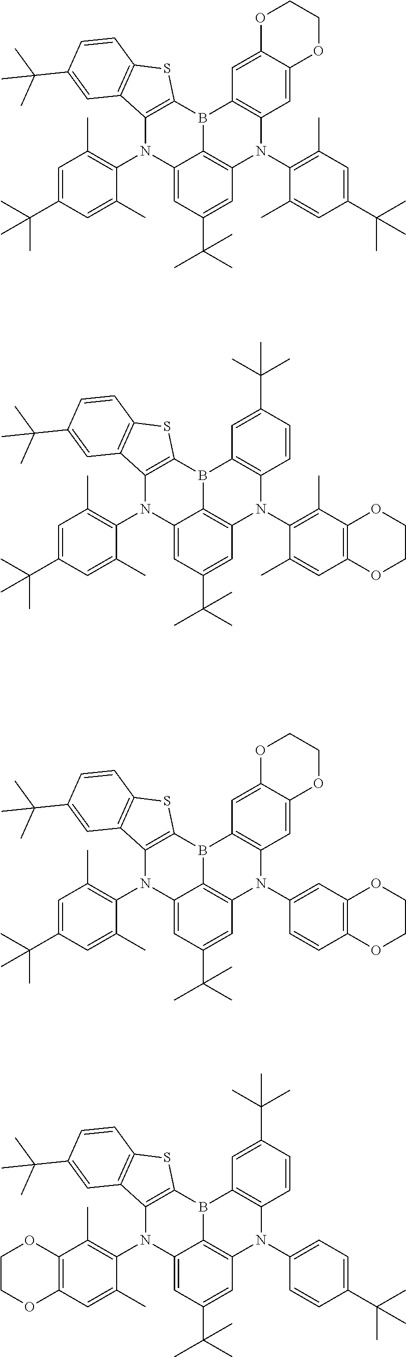

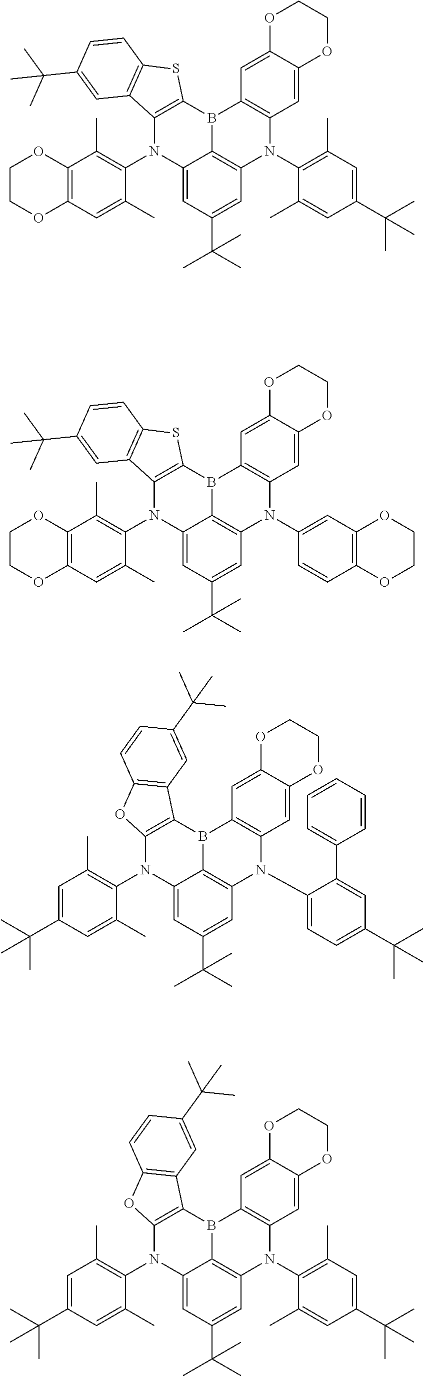

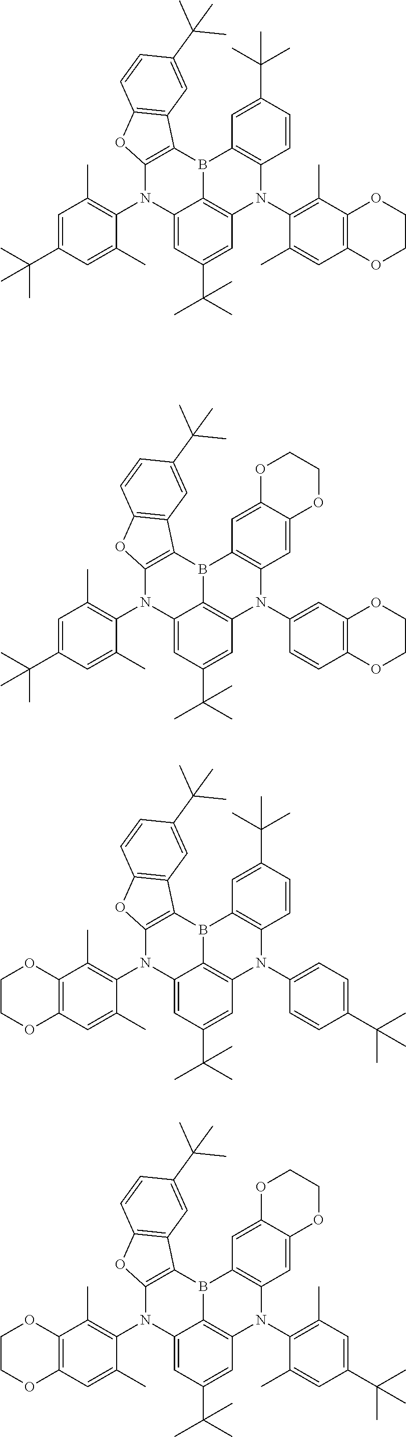

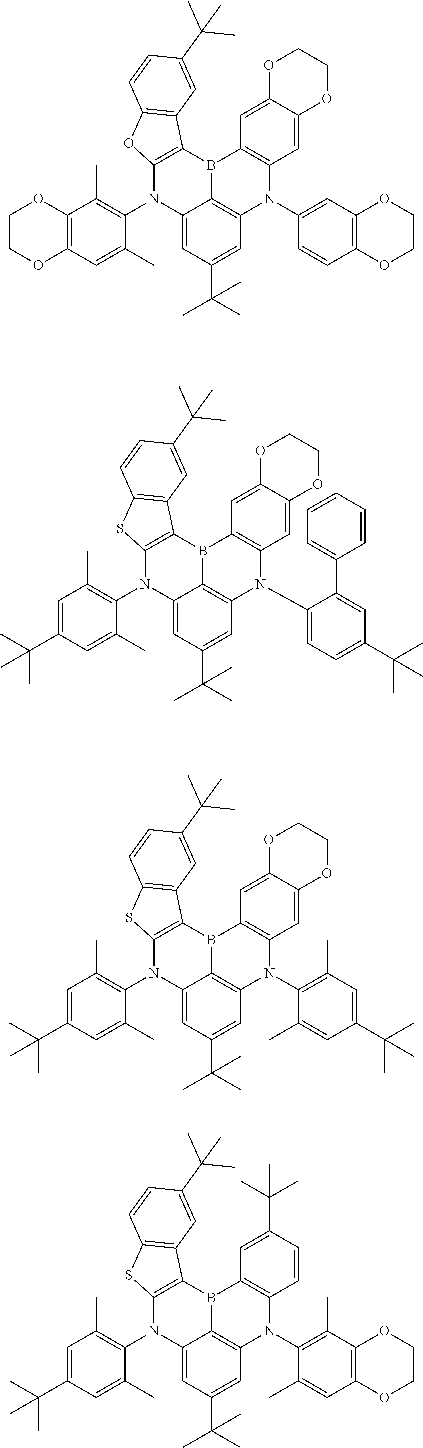

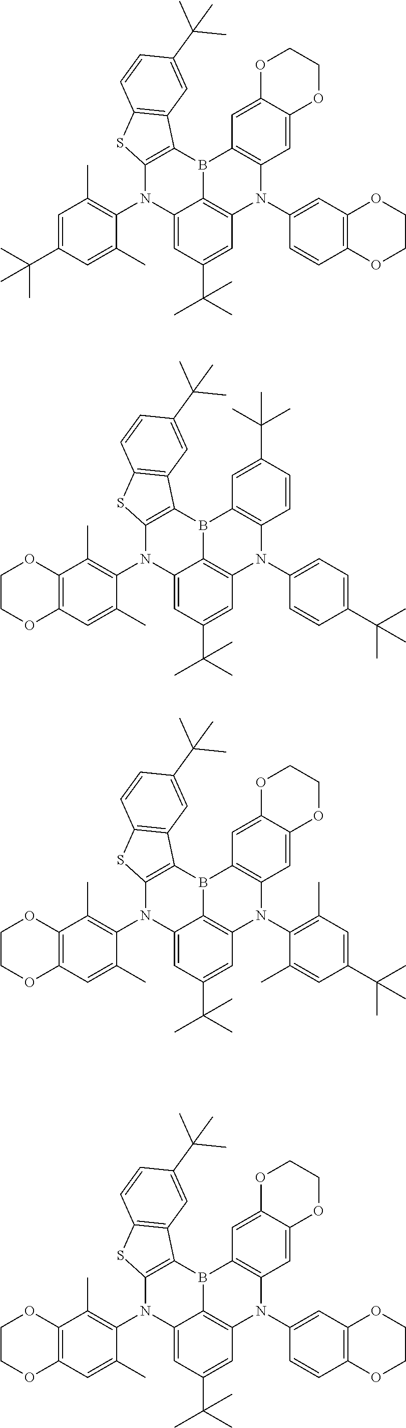

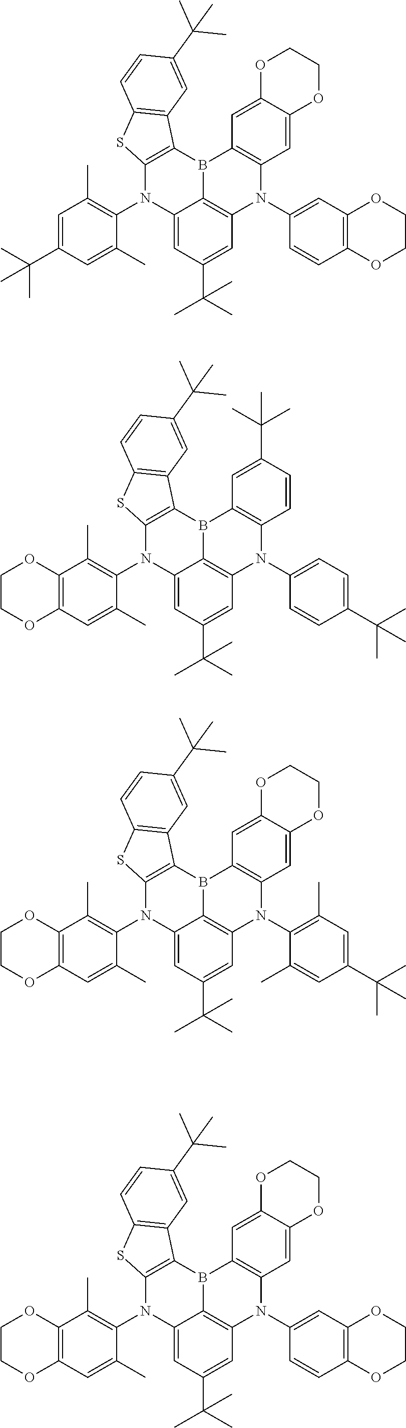

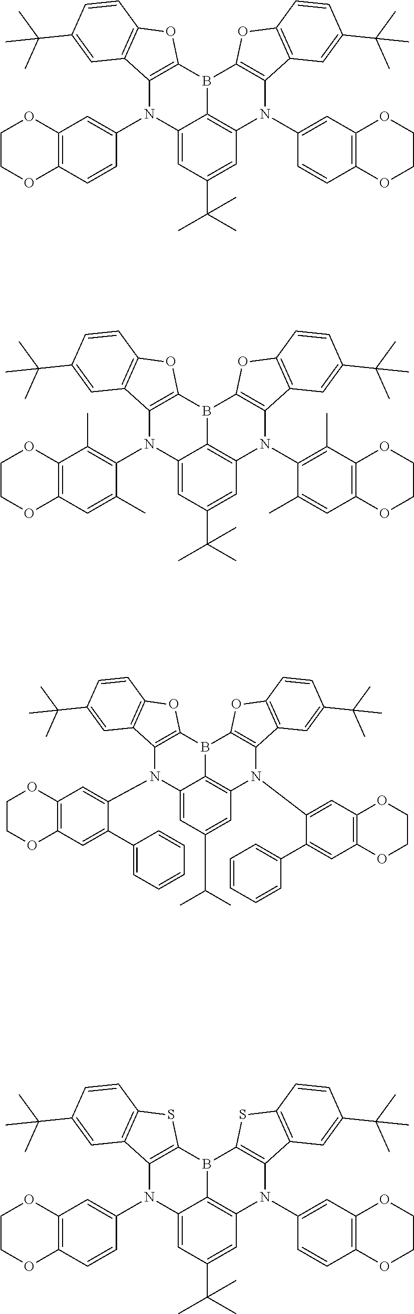 [SMILES: CC(C)(C)c1cc2c3c(c1)N(c1ccc4c(c1)OCCO4)c1c(oc4ccc(C(C)(C)C)cc14)B3c1oc3ccc(C(C)(C)C)cc3c1N2c1ccc2c(c1)OCCO2 ; Cc1cc2c(c(C)c1N1c3cc(C(C)(C)C)cc4c3B(c3oc5ccc(C(C)(C)C)cc5c31)c1oc3ccc(C(C)(C)C)cc3c1N4c1c(C)cc3c(c1C)OCCO3)OCCO2 ; CC(C)c1cc2c3c(c1)N(c1cc4c(cc1-c1ccccc1)OCCO4)c1c(oc4ccc(C(C)(C)C)cc14)B3c1oc3ccc(C(C)(C)C)cc3c1N2c1cc2c(cc1-c1ccccc1)OCCO2 ; CC(C)(C)c1cc2c3c(c1)N(c1ccc4c(c1)OCCO4)c1c(sc4ccc(C(C)(C)C)cc14)B3c1sc3ccc(C(C)(C)C)cc3c1N2c1ccc2c(c1)OCCO2]

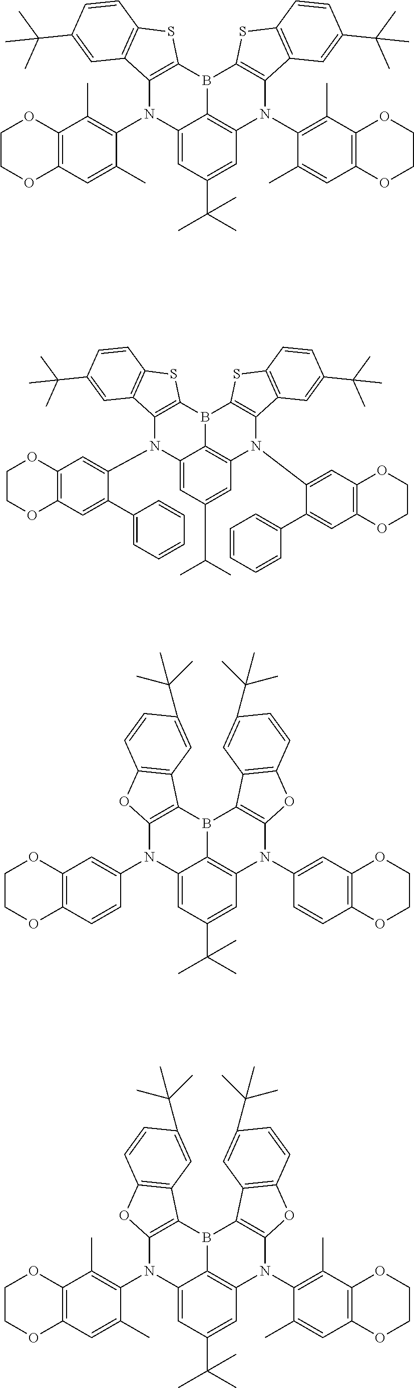 [SMILES: Cc1cc2c(c(C)c1N1c3cc(C(C)(C)C)cc4c3B(c3sc5ccc(C(C)(C)C)cc5c31)c1sc3ccc(C(C)(C)C)cc3c1N4c1c(C)cc3c(c1C)OCCO3)OCCO2 ; CC(C)c1cc2c3c(c1)N(c1cc4c(cc1-c1ccccc1)OCCO4)c1c(sc4ccc(C(C)(C)C)cc14)B3c1sc3ccc(C(C)(C)C)cc3c1N2c1cc2c(cc1-c1ccccc1)OCCO2 ; CC(C)(C)c1cc2c3c(c1)N(c1ccc4c(c1)OCCO4)c1oc4ccc(C(C)(C)C)cc4c1B3c1c(oc3ccc(C(C)(C)C)cc13)N2c1ccc2c(c1)OCCO2 ; Cc1cc2c(c(C)c1N1c3cc(C(C)(C)C)cc4c3B(c3c1oc1ccc(C(C)(C)C)cc31)c1c(oc3ccc(C(C)(C)C)cc13)N4c1c(C)cc3c(c1C)OCCO3)OCCO2]

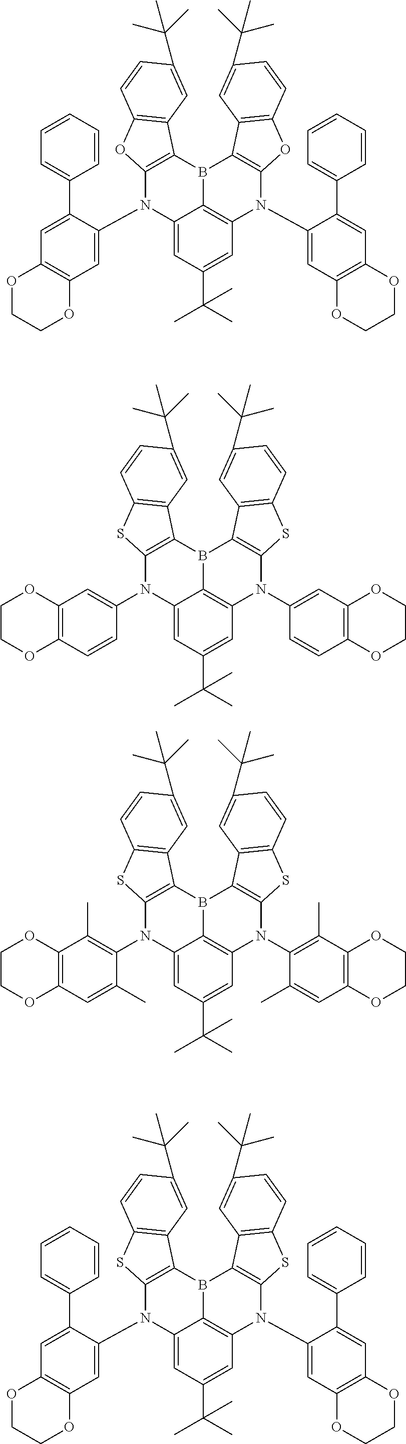

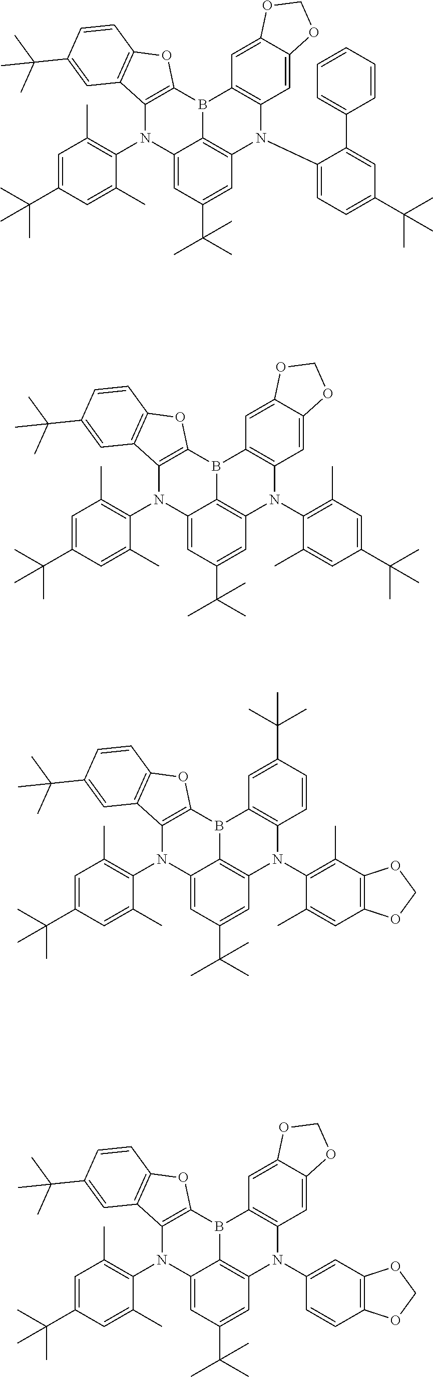

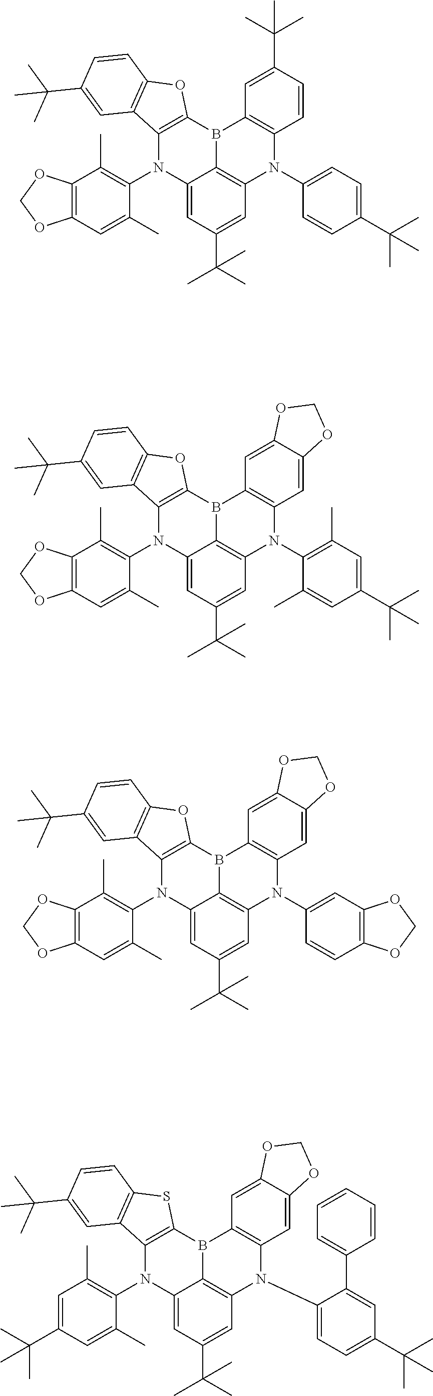

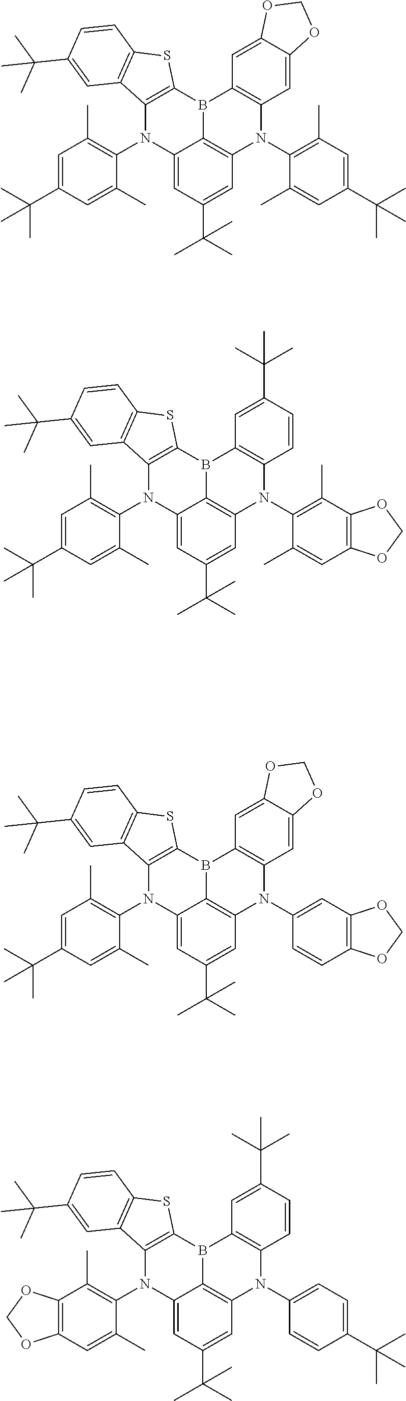

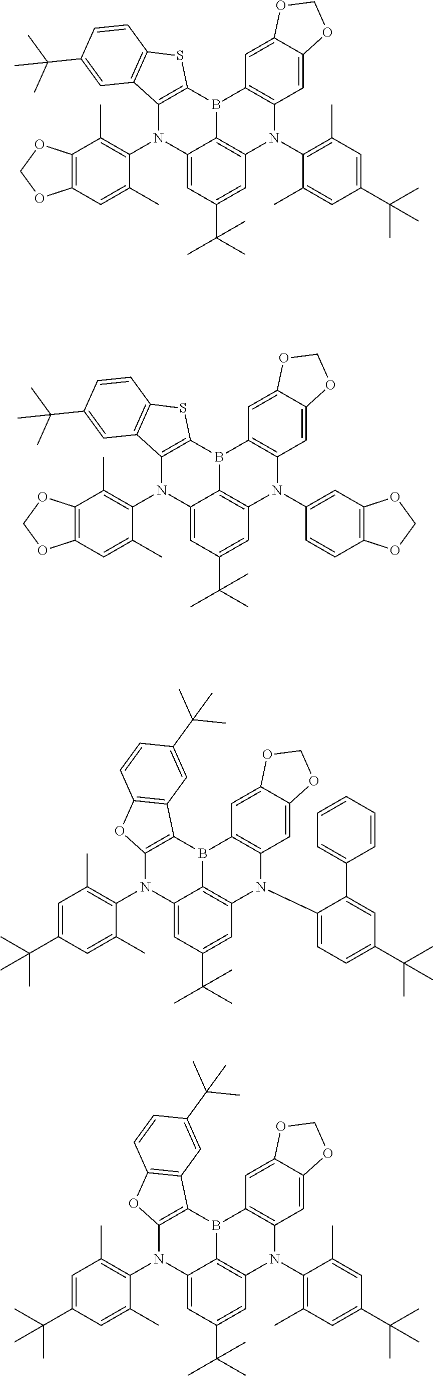

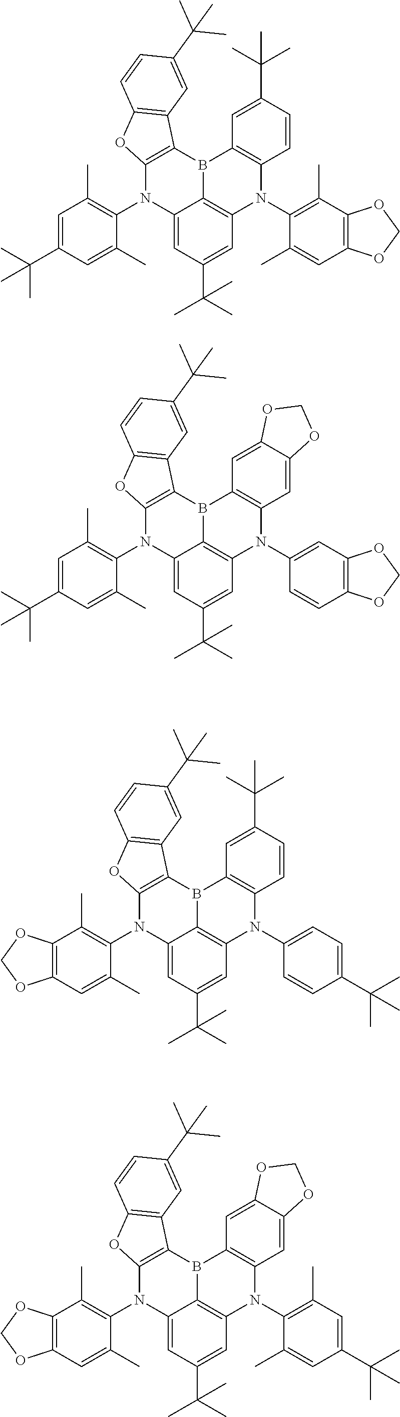

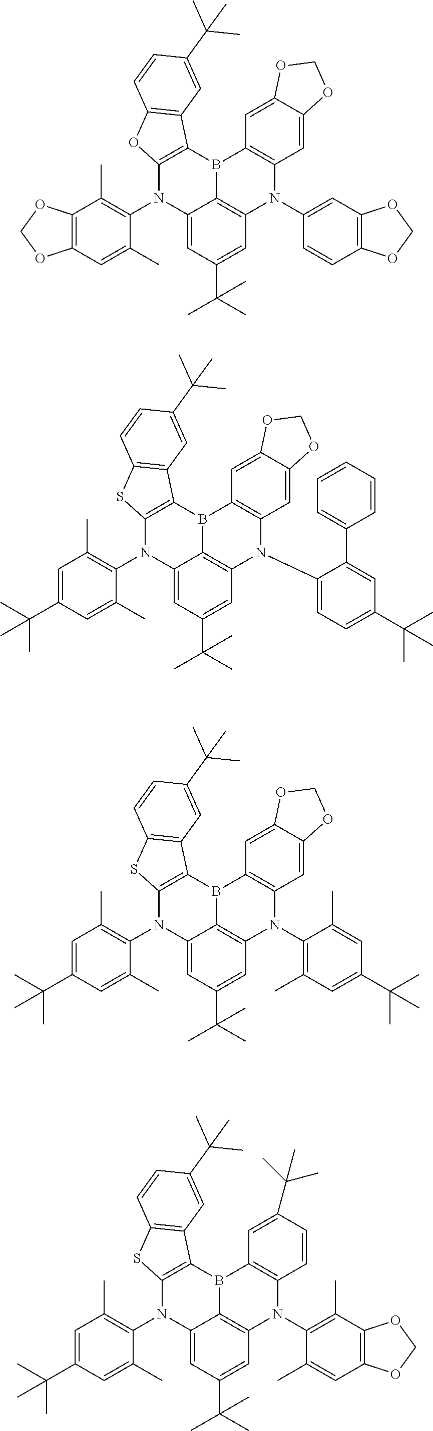

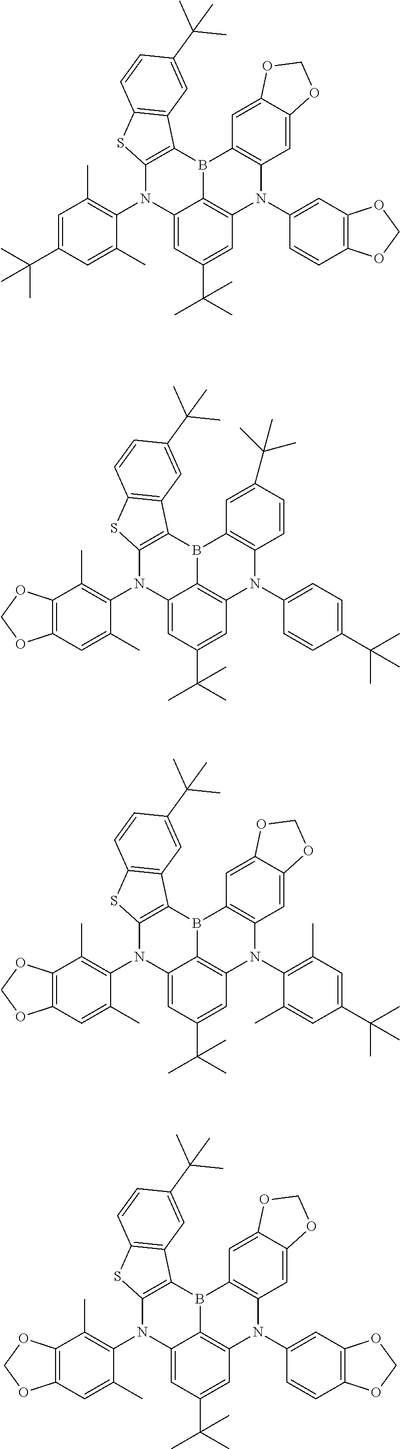 [SMILES: Cc1cc(C(C)(C)C)cc(C)c1N1c2cc(C(C)(C)C)cc3c2B(c2cc4c(cc2N3c2ccc3c(c2)OCO3)OCO4)c2c1sc1ccc(C(C)(C)C)cc21 ; Cc1cc2c(c(C)c1N1c3cc(C(C)(C)C)cc4c3B(c3cc(C(C)(C)C)ccc3N4c3ccc(C(C)(C)C)cc3)c3c1sc1ccc(C(C)(C)C)cc31)OCO2 ; Cc1cc(C(C)(C)C)cc(C)c1N1c2cc3c(cc2B2c4c1cc(C(C)(C)C)cc4N(c1c(C)cc4c(c1C)OCO4)c1sc4ccc(C(C)(C)C)cc4c12)OCO3 ; Cc1cc2c(c(C)c1N1c3cc(C(C)(C)C)cc4c3B(c3cc5c(cc3N4c3ccc4c(c3)OCO4)OCO5)c3c1sc1ccc(C(C)(C)C)cc31)OCO2]

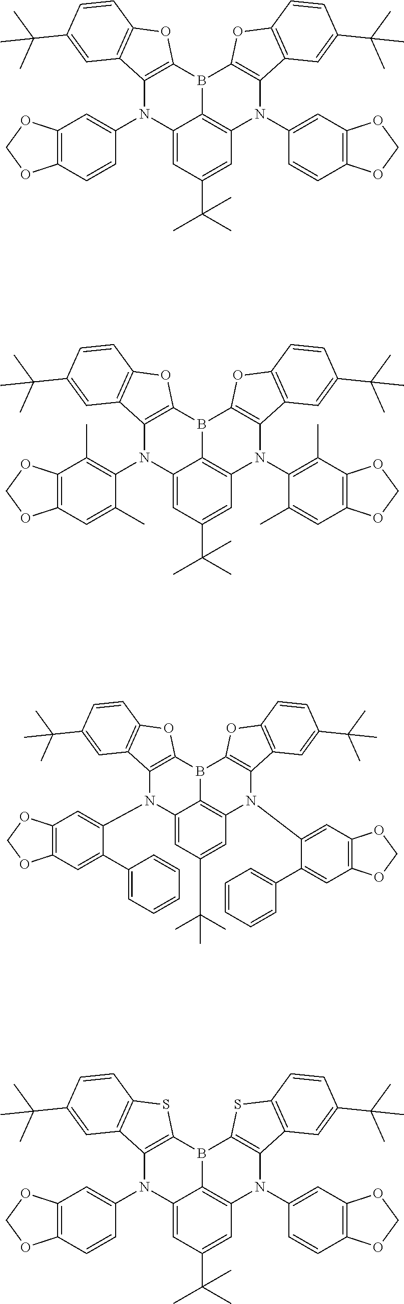

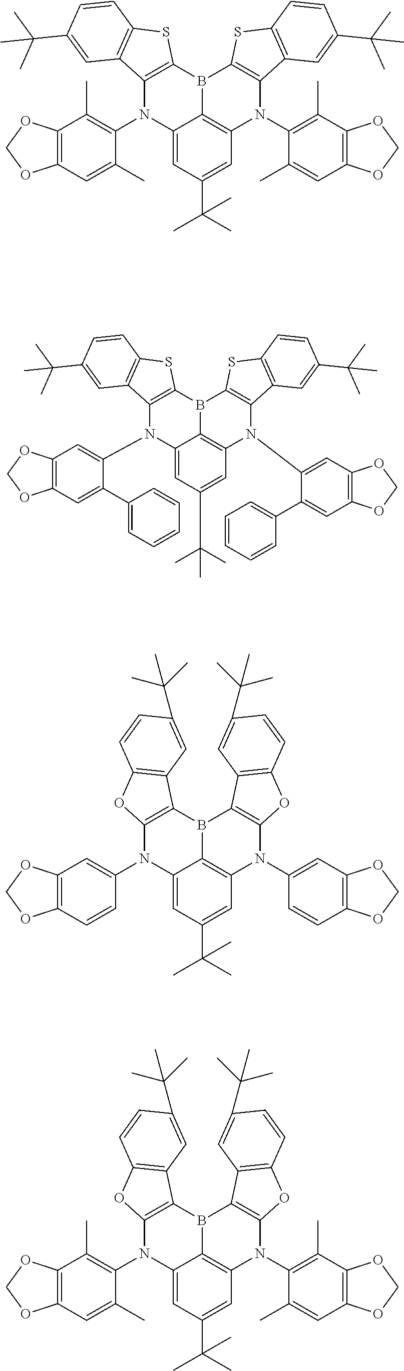 [SMILES: Cc1cc2c(c(C)c1N1c3cc(C(C)(C)C)cc4c3B(c3sc5ccc(C(C)(C)C)cc5c31)c1sc3ccc(C(C)(C)C)cc3c1N4c1c(C)cc3c(c1C)OCO3)OCO2 ; CC(C)(C)c1cc2c3c(c1)N(c1cc4c(cc1-c1ccccc1)OCO4)c1c(sc4ccc(C(C)(C)C)cc14)B3c1sc3ccc(C(C)(C)C)cc3c1N2c1cc2c(cc1-c1ccccc1)OCO2 ; CC(C)(C)c1cc2c3c(c1)N(c1ccc4c(c1)OCO4)c1oc4ccc(C(C)(C)C)cc4c1B3c1c(oc3ccc(C(C)(C)C)cc13)N2c1ccc2c(c1)OCO2 ; Cc1cc2c(c(C)c1N1c3cc(C(C)(C)C)cc4c3B(c3c1oc1ccc(C(C)(C)C)cc31)c1c(oc3ccc(C(C)(C)C)cc13)N4c1c(C)cc3c(c1C)OCO3)OCO2]

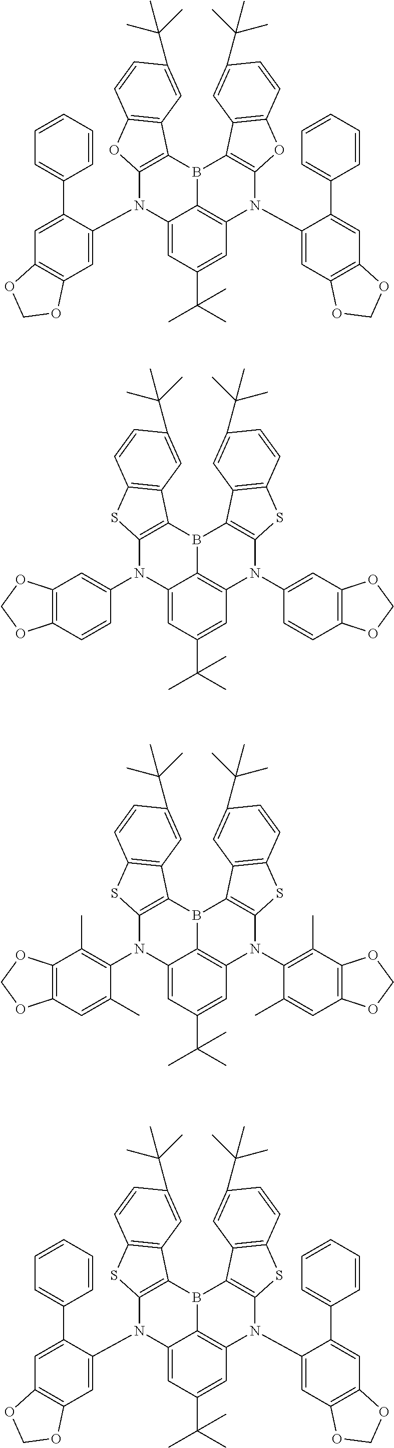 [SMILES: CC(C)(C)c1cc2c3c(c1)N(c1cc4c(cc1-c1ccccc1)OCO4)c1oc4ccc(C(C)(C)C)cc4c1B3c1c(oc3ccc(C(C)(C)C)cc13)N2c1cc2c(cc1-c1ccccc1)OCO2 ; CC(C)(C)c1cc2c3c(c1)N(c1ccc4c(c1)OCO4)c1sc4ccc(C(C)(C)C)cc4c1B3c1c(sc3ccc(C(C)(C)C)cc13)N2c1ccc2c(c1)OCO2 ; Cc1cc2c(c(C)c1N1c3cc(C(C)(C)C)cc4c3B(c3c1sc1ccc(C(C)(C)C)cc31)c1c(sc3ccc(C(C)(C)C)cc13)N4c1c(C)cc3c(c1C)OCO3)OCO2 ; CC(C)(C)c1cc2c3c(c1)N(c1cc4c(cc1-c1ccccc1)OCO4)c1sc4ccc(C(C)(C)C)cc4c1B3c1c(sc3ccc(C(C)(C)C)cc13)N2c1cc2c(cc1-c1ccccc1)OCO2]

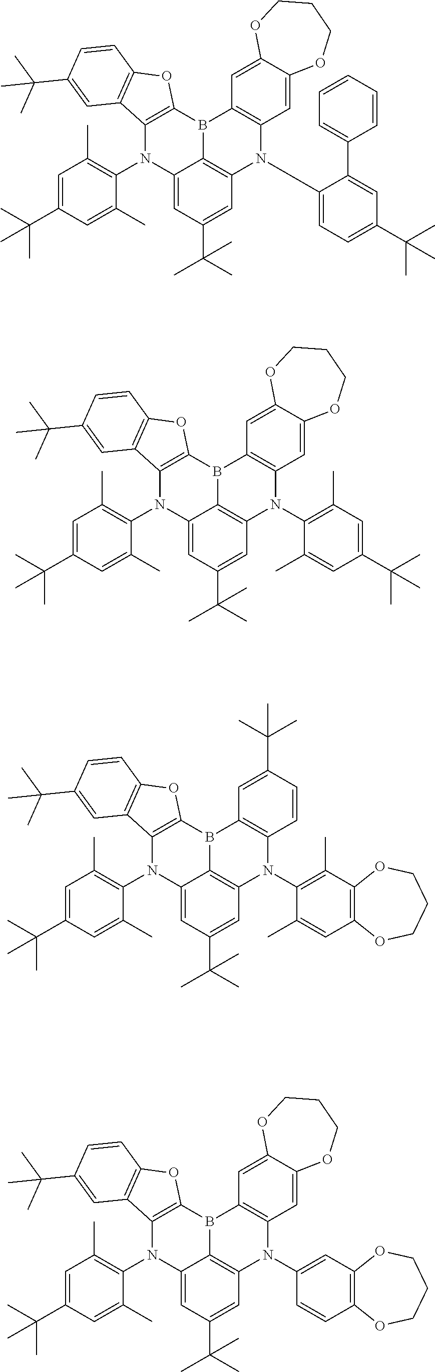

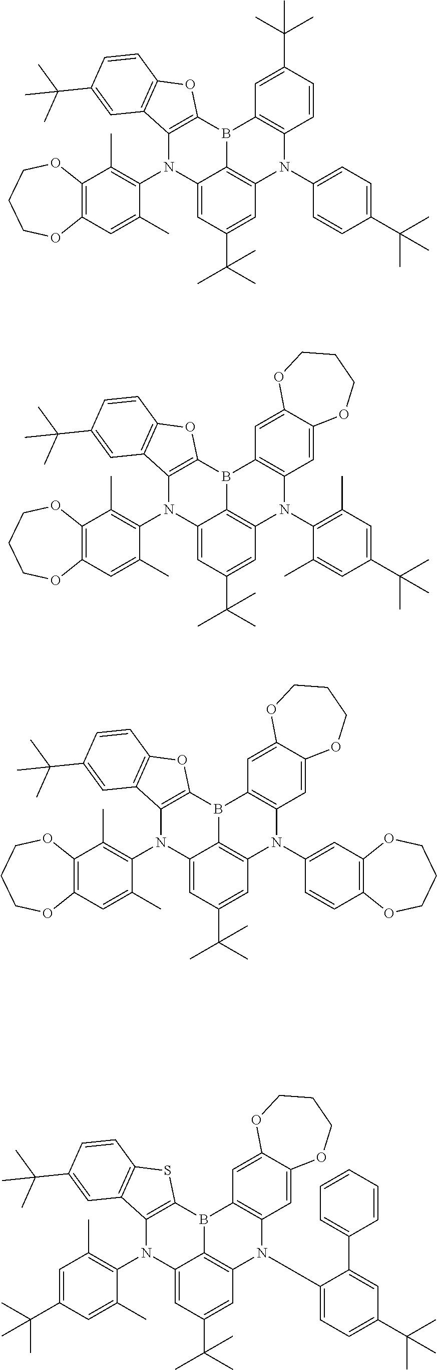

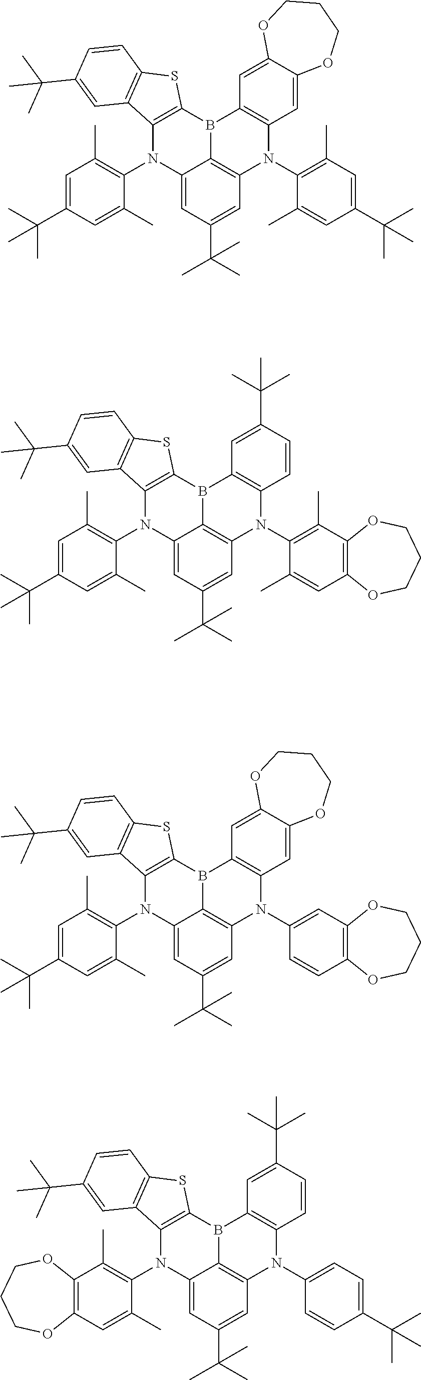

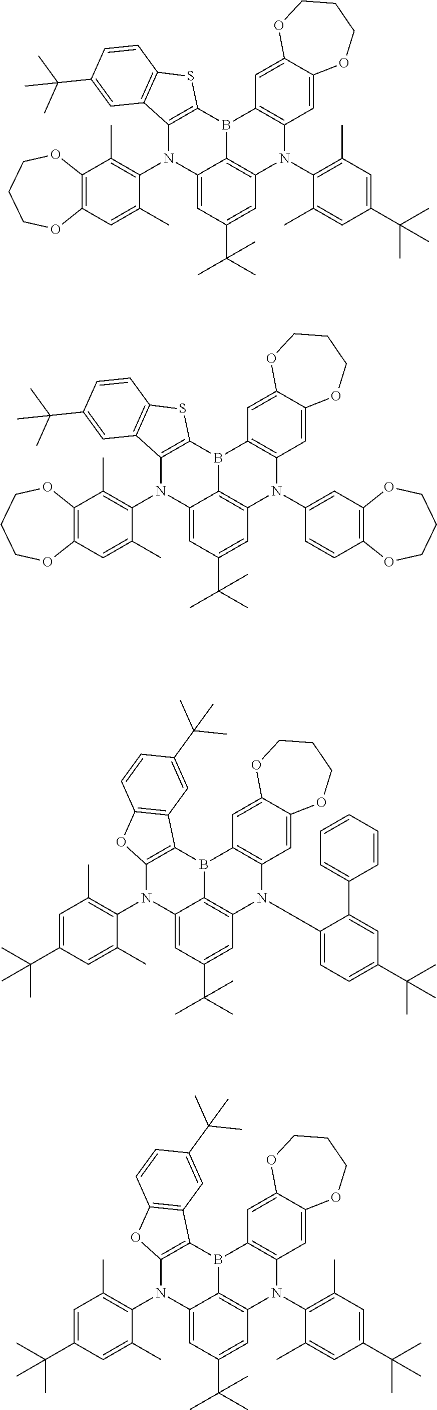

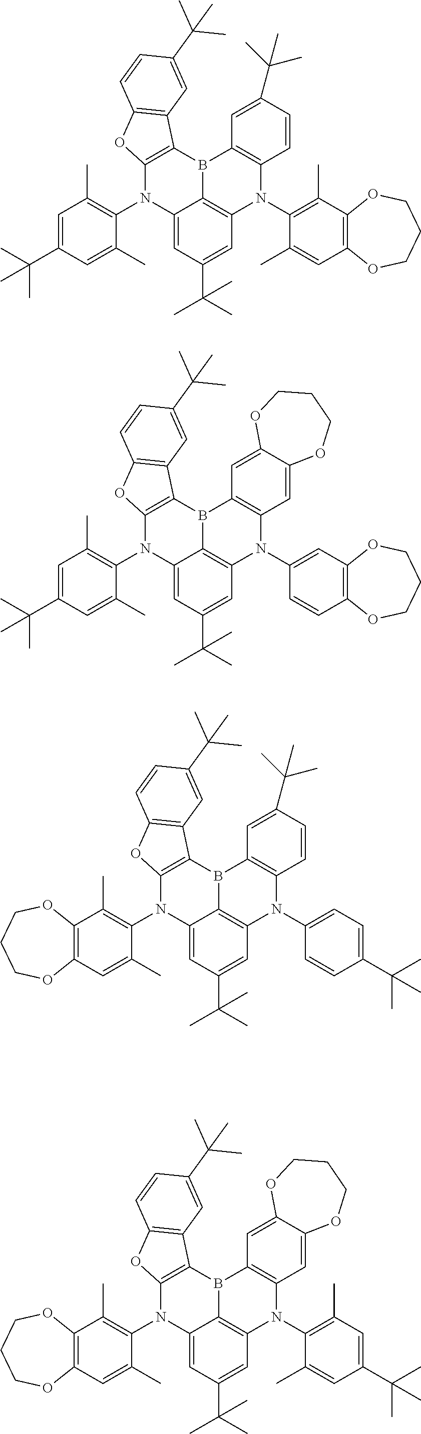

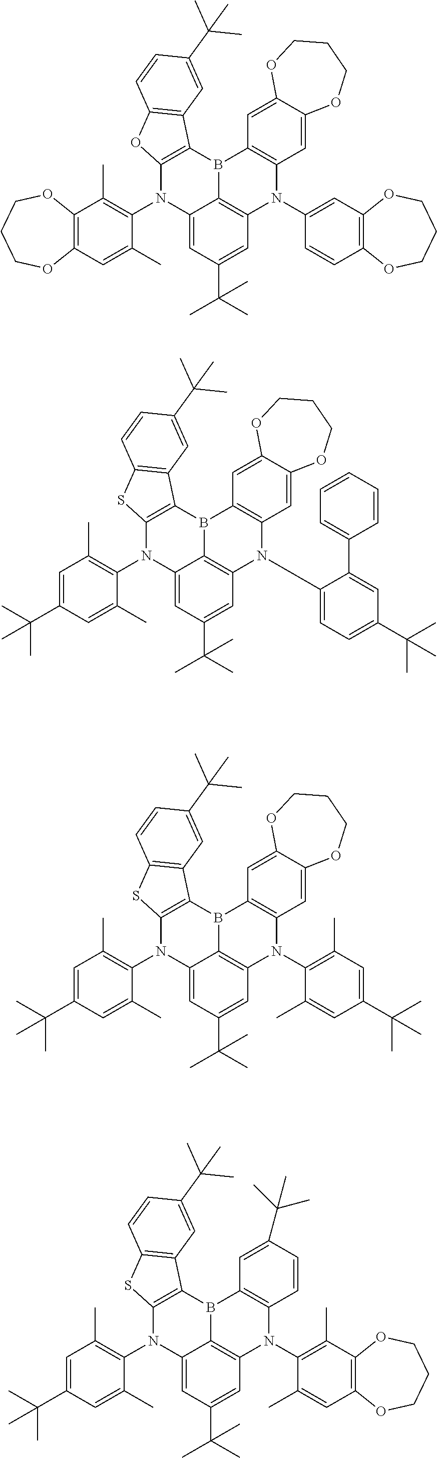

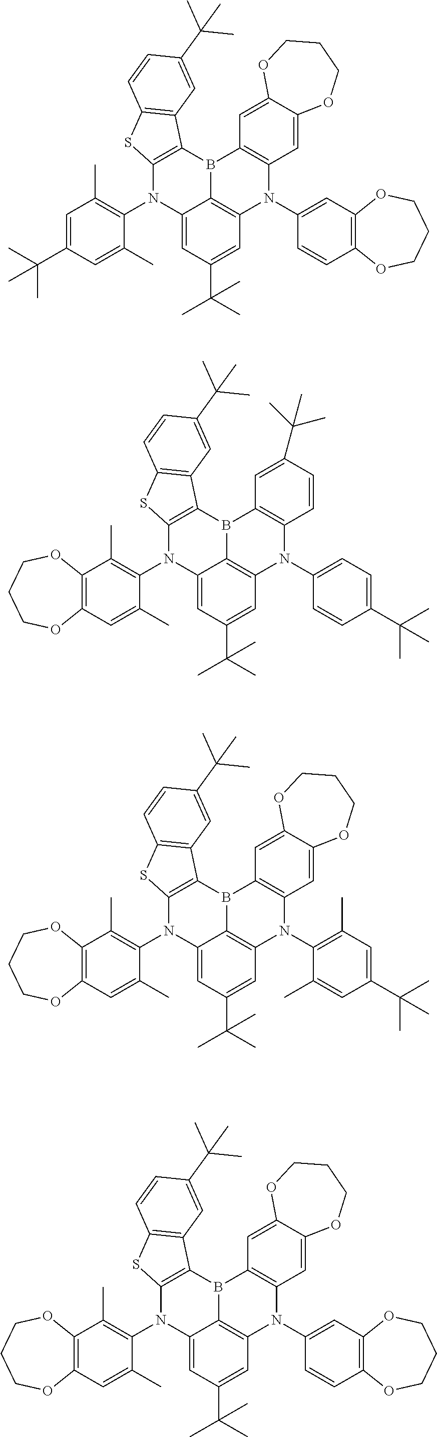 [SMILES: Cc1cc(C(C)(C)C)cc(C)c1N1c2cc(C(C)(C)C)cc3c2B(c2cc4c(cc2N3c2ccc3c(c2)OCCCO3)OCCCO4)c2c1sc1ccc(C(C)(C)C)cc21 ; Cc1cc2c(c(C)c1N1c3cc(C(C)(C)C)cc4c3B(c3cc(C(C)(C)C)ccc3N4c3ccc(C(C)(C)C)cc3)c3c1sc1ccc(C(C)(C)C)cc31)OCCCO2 ; Cc1cc(C(C)(C)C)cc(C)c1N1c2cc3c(cc2B2c4c1cc(C(C)(C)C)cc4N(c1c(C)cc4c(c1C)OCCCO4)c1sc4ccc(C(C)(C)C)cc4c12)OCCCO3 ; Cc1cc2c(c(C)c1N1c3cc(C(C)(C)C)cc4c3B(c3cc5c(cc3N4c3ccc4c(c3)OCCCO4)OCCCO5)c3c1sc1ccc(C(C)(C)C)cc31)OCCCO2]

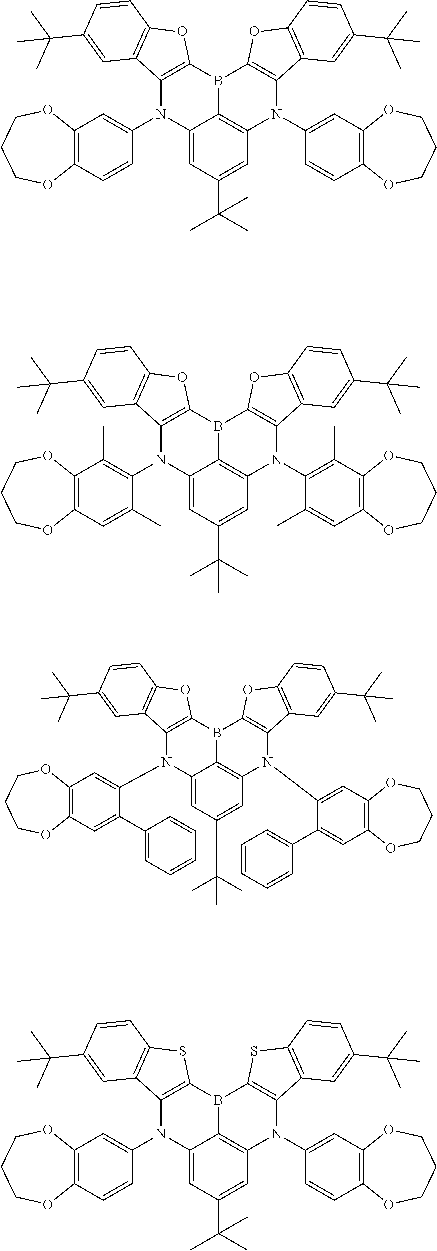 [SMILES: CC(C)(C)c1cc2c3c(c1)N(c1ccc4c(c1)OCCCO4)c1c(oc4ccc(C(C)(C)C)cc14)B3c1oc3ccc(C(C)(C)C)cc3c1N2c1ccc2c(c1)OCCCO2 ; Cc1cc2c(c(C)c1N1c3cc(C(C)(C)C)cc4c3B(c3oc5ccc(C(C)(C)C)cc5c31)c1oc3ccc(C(C)(C)C)cc3c1N4c1c(C)cc3c(c1C)OCCCO3)OCCCO2 ; CC(C)(C)c1cc2c3c(c1)N(c1cc4c(cc1-c1ccccc1)OCCCO4)c1c(oc4ccc(C(C)(C)C)cc14)B3c1oc3ccc(C(C)(C)C)cc3c1N2c1cc2c(cc1-c1ccccc1)OCCCO2 ; CC(C)(C)c1cc2c3c(c1)N(c1ccc4c(c1)OCCCO4)c1c(sc4ccc(C(C)(C)C)cc14)B3c1sc3ccc(C(C)(C)C)cc3c1N2c1ccc2c(c1)OCCCO2]

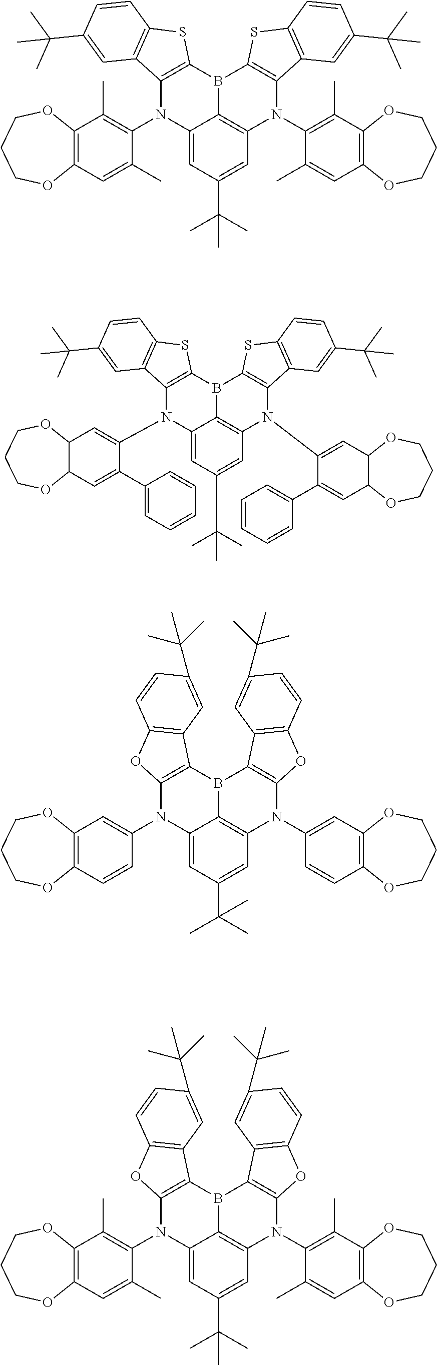 [SMILES: Cc1cc2c(c(C)c1N1c3cc(C(C)(C)C)cc4c3B(c3sc5ccc(C(C)(C)C)cc5c31)c1sc3ccc(C(C)(C)C)cc3c1N4c1c(C)cc3c(c1C)OCCCO3)OCCCO2 ; CC(C)(C)c1cc2c3c(c1)N(C1=CC4OCCCOC4C=C1c1ccccc1)c1c(sc4ccc(C(C)(C)C)cc14)B3c1sc3ccc(C(C)(C)C)cc3c1N2C1=CC2OCCCOC2C=C1c1ccccc1 ; CC(C)(C)c1cc2c3c(c1)N(c1ccc4c(c1)OCCCO4)c1oc4ccc(C(C)(C)C)cc4c1B3c1c(oc3ccc(C(C)(C)C)cc13)N2c1ccc2c(c1)OCCCO2 ; Cc1cc2c(c(C)c1N1c3cc(C(C)(C)C)cc4c3B(c3c1oc1ccc(C(C)(C)C)cc31)c1c(oc3ccc(C(C)(C)C)cc13)N4c1c(C)cc3c(c1C)OCCCO3)OCCCO2]

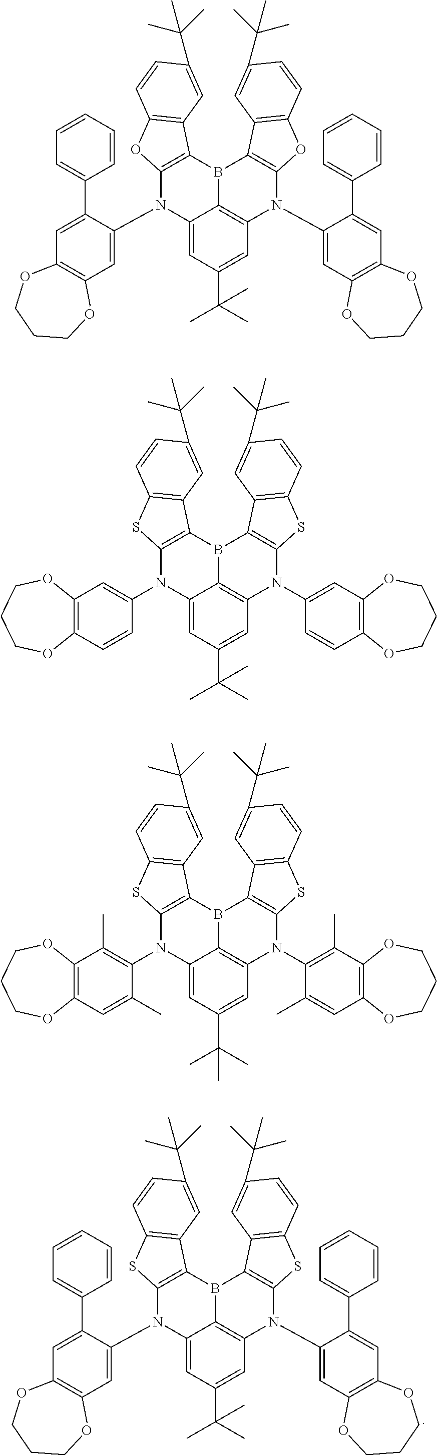

10. An organic light emitting device comprising: a first electrode; a second electrode that is provided opposite to the first electrode; and one or more organic material layers that are provided between the first electrode and the second electrode, wherein at least one layer of the organic material layers comprises the compound according to claim 1.

11. The organic light emitting device of claim 10,
wherein the organic material layers comprise a light emitting layer, which comprises the compound.

12. The compound of claim 1,
wherein the Chemical Formula 1 is represented by any one of the following Chemical Formulae 1-5 to 1-9: 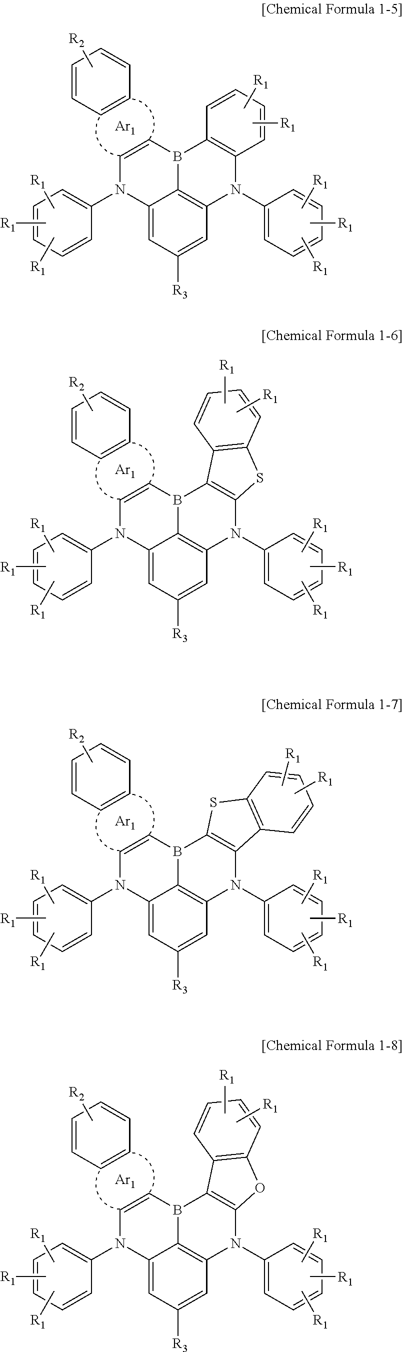 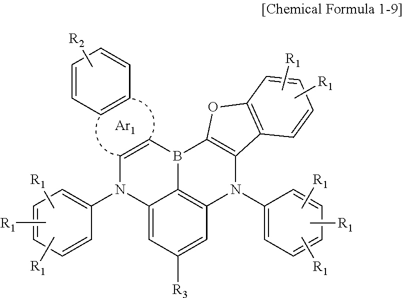
in Chemical Formulae 1-5 to 1-9,
Ar₁ and R₁ to R₃ are as defined in Chemical Formula 1.
